(19) United States
(12) Patent Application Publication
(10) Pub. No.: US 2026/0231431 A1
(43) Pub. Date: Aug. 6, 2026

(54) THREE-DIMENSIONAL FLAT CELL MEMORY DEVICE WITH LATERAL ACCESS TRANSISTORS AND METHOD OF MAKING THE SAME

(71) Applicant: Sandisk Technologies, Inc., Milpitas, CA (US)

(72) Inventors: Ruogu Matthew ZHU, San Jose, CA (US); Adarsh RAJASHEKHAR, Santa Clara, CA (US); Koichi MATSUNO, Fremont, CA (US); Senaka KANAKAMEDALA, San Jose, CA (US); Johann ALSMEIER, San Jose, CA (US)

(21) Appl. No.: 19/044,185

(22) Filed: Feb. 3, 2025

(51) Int. Cl. H10B 53/30; H10B 53/20

(52) U.S. Cl. CPC H10B 53/30; H10B 53/20

(57) ABSTRACT

An array of vertical rail stacks can be formed. Each of the vertical rail stacks includes, from bottom to top, a first spacer rail, a semiconductor rail, a second spacer rail, and a sacrificial rail. Each of the semiconductor rails includes a respective first semiconductor end wall contacting a respective first capping structure and further includes a respective second semiconductor end wall contacting a respective second capping structure. First cavities can be formed by removing first portions of the sacrificial rails and portions of the first spacer rails and the second spacer rails. Gate dielectrics and gate electrodes of access transistors can be formed in the first cavities. Portions of the semiconductor rails that are distal from the gate electrodes can be used to form a memory transistor, or may be replaced with a memory storage device, such as a capacitor.

### FIELD

The present disclosure relates generally to the field of semiconductor devices, and particularly to three-dimensional memory devices with laterally integrated access transistors and methods of manufacturing the same.

### BACKGROUND

NAND memory devices provide high memory cell density at a low per-bit cost. As the number of layers in NAND memory devices increases, the length of vertical channels increases and the memory latency of the NAND memory devices increases.

### SUMMARY

According to an aspect of the present disclosure, a method of forming a device structure comprises: forming an array of vertical rail stacks, wherein each of the vertical rail stacks comprises, from bottom to top, a first spacer rail, a semiconductor rail, a second spacer rail, and a sacrificial rail, wherein each of the vertical rail stacks laterally extends along a first horizontal direction, and each of the semiconductor rail comprises a respective first semiconductor end wall contacting a respective first capping structure and further comprises a respective second semiconductor end wall contacting a respective second capping structure; forming first voids by removing first portions of the sacrificial rails that are proximal to the first capping structures; forming first cavities by removing portions of the first spacer rails and the second spacer rails that are proximal to the first voids; forming gate dielectrics and gate electrodes in the first cavities to form access transistors; forming second voids by removing second portions of the sacrificial rails that are proximal to the second capping structures; forming second cavities by removing remaining portions of the first spacer rails and the second spacer rails that are proximal to the second voids; and forming memory devices that are accessed through the respective access transistors.

### BRIEF DESCRIPTION OF THE DRAWINGS

For all figures between FIGS. 1A and 40E and between FIGS. 51A and 72E, which are labeled with a combination of a figure numeral and a letter figure suffix, each figure with a figure label including a letter figure suffix of “A” is a vertical cross-sectional view; each figure with a figure label including a letter figure suffix of “B” is a horizontal cross-sectional view along the horizontal plane B-B′ within the figure with the same figure numeral and the letter figure suffix of “A”; each figure with a figure label including a letter figure suffix of “C” is a horizontal cross-sectional view along the horizontal plane C-C′ within the figure with the same figure numeral and the letter figure suffix of “A”; each figure with a figure label including a letter figure suffix of “D” is a vertical cross-sectional view along the vertical plane D-D′ within the figures with the same figure numeral and the letter figure suffix of “B” or “C”; and each figure with a figure label including a letter figure suffix of “E” is a vertical cross-sectional view along the vertical plane E-E′ within the figures with the same figure numeral and the letter figure suffix of “B” or “C”. The vertical plane A-A′ shown in figures with a respective letter figure suffix of “B,” “C,” “D,” or “E” corresponds to the cut plane for the vertical cross-sectional view of the figure with the same figure numeral and the letter figure suffix of “A.”

FIGS. 1A, 1B, 1C, 1D, and 1E are various views of a first exemplary structure after formation of an etch-stop structure and a vertically alternating sequence of sacrificial layers and semiconductor layers according to a first embodiment of the present disclosure.

FIGS. 2A, 2B, 2C, 2D, and 2E are various views of the first exemplary structure after formation of bit-line trenches and source trenches according to the first embodiment of the present disclosure.

FIGS. 3A, 3B, 3C, 3D, and 3E are various views of the first exemplary structure after formation of sacrificial bit-line trench fill structures and sacrificial source trench fill structures according to the first embodiment of the present disclosure.

FIGS. 4A, 4B, 4C, 4D, and 4E are various views of the first exemplary structure after formation of lateral isolation trenches according to the first embodiment of the present disclosure.

FIGS. 5A, 5B, 5C, 5D, and 5E are various views of the first exemplary structure after formation of sacrificial isolation trench fill structures according to the first embodiment of the present disclosure.

FIGS. 6A, 6B, 6C, 6D, and 6E are various views of the first exemplary structure after formation of first inter-rail cavities and first lateral isolation trenches according to the first embodiment of the present disclosure.

FIGS. 7A, 7B, 7C, 7D, and 7E are various views of the first exemplary structure after formation of a first gate dielectric material layer and a first gate electrode material layer according to the first embodiment of the present disclosure.

FIGS. 8A, 8B, 8C, 8D, and 8E are various views of the first exemplary structure after formation of a two-dimensional array of dielectric plates according to the first embodiment of the present disclosure.

FIGS. 9A, 9B, 9C, 9D, and 9E are various views of the first exemplary structure after patterning the first gate electrode material layer into first gate electrode material layers according to the first embodiment of the present disclosure.

FIGS. 10A, 10B, 10C, 10D, and 10E are various views of the first exemplary structure after patterning the first gate dielectric material layer into first gate dielectric layers according to the first embodiment of the present disclosure.

FIGS. 11A, 11B, 11C, 11D, and 11E are various views of the first exemplary structure after formation of bit-line trench isolation structures according to the first embodiment of the present disclosure.

FIGS. 12A, 12B, 12C, 12D, and 12E are various views of the first exemplary structure after formation of sacrificial bit-line structures according to the first embodiment of the present disclosure.

FIGS. 13A, 13B, 13C, 13D, and 13E are various views of the first exemplary structure after removal of the sacrificial source trench fill structures according to the first embodiment of the present disclosure.

FIGS. 14A, 14B, 14C, 14D, and 14E are various views of the first exemplary structure after formation of second inter-rail cavities and second lateral isolation trenches according to the first embodiment of the present disclosure.

FIGS. 15A, 15B, 15C, 15D, and 15E are various views of the first exemplary structure after patterning the first gate dielectric layers into a three-dimensional array of gate dielectrics and after patterning the first gate electrode material layers into a two-dimensional array of first word lines according to the first embodiment of the present disclosure.

FIGS. 16A, 16B, 16C, 16D, and 16E are various views of the first exemplary structure after deposition of a dielectric matrix material layer according to the first embodiment of the present disclosure.

FIGS. 17A, 17B, 17C, 17D, and 17E are various views of the first exemplary structure after patterning the dielectric matrix material layer into a one-dimensional array of perforated dielectric matrices according to the first embodiment of the present disclosure.

FIGS. 18A, 18B, 18C, 18D, and 18E are various views of the first exemplary structure after formation of a three-dimensional array of lateral recesses according to the first embodiment of the present disclosure.

FIGS. 19A, 19B, 19C, 19D, and 19E are various views of the first exemplary structure after formation of bit-line via cavities according to the first embodiment of the present disclosure.

FIGS. 20A, 20B, 20C, 20D, and 20E are various views of the first exemplary structure after formation of source regions and drain regions according to the first embodiment of the present disclosure.

FIGS. 21A, 21B, 21C, 21D, and 21E are various views of the first exemplary structure after formation of a first conductive material layer and a sacrificial cover material layer according to the first embodiment of the present disclosure.

FIGS. 22A, 22B, 22C, 22D, and 22E are various views of the first exemplary structure after patterning the sacrificial cover material layer into a three-dimensional array of sacrificial cover layers according to the first embodiment of the present disclosure.

FIGS. 23A, 23B, 23C, 23D, and 23E are various views of the first exemplary structure after patterning the first conductive material layer into a three-dimensional array of first electrodes according to the first embodiment of the present disclosure.

FIGS. 24A, 24B, 24C, 24D, and 24E are various views of the first exemplary structure after formation of memory material layers according to the first embodiment of the present disclosure.

FIGS. 25A, 25B, 25C, 25D, and 25E are various views of the first exemplary structure after deposition of the second conductive material layer according to the first embodiment of the present disclosure.

FIGS. 26A, 26B, 26C, 26D, and 26E are various views of the first exemplary structure after patterning the second conductive material layer into bit lines and a one-dimensional array of conductive structures according to the first embodiment of the present disclosure.

FIGS. 26F and 26G are respective vertical cross-sectional view and top view of an alternative configuration of the first exemplary structure after patterning the second conductive material layer according to the first embodiment of the present disclosure.

FIGS. 27A, 27B, 27C, 27D, and 27E are various views of a second exemplary structure after formation of bit-line trench isolation structures and removal of the sacrificial source trench fill structures according to a second embodiment of the present disclosure.

FIGS. 28A, 28B, 28C, 28D, and 28E are various views of the second exemplary structure after formation of second inter-rail cavities and second lateral isolation trenches according to the second embodiment of the present disclosure.

FIGS. 29A, 29B, 29C, 29D, and 29E are various views of the second exemplary structure after patterning the first gate dielectric layers into a three-dimensional array of gate dielectrics and after patterning the first gate electrode material layers into a two-dimensional array of first word lines according to the second embodiment of the present disclosure.

FIGS. 30A, 30B, 30C, 30D, and 30E are various views of the second exemplary structure after altering a dopant concentration of a second horizontally-extending semiconductor channel within each semiconductor rail according to the second embodiment of the present disclosure.

FIGS. 31A, 31B, 31C, 31D, and 31E are various views of the second exemplary structure after formation of a second gate dielectric material layer according to the second embodiment of the present disclosure.

FIGS. 32A, 32B, 32C, 32D, and 32E are various views of the second exemplary structure after deposition of a dielectric gate spacer material layer according to the second embodiment of the present disclosure.

FIGS. 33A, 33B, 33C, 33D, and 33E are various views of the second exemplary structure after formation of a two-dimensional array of dielectric plates according to the second embodiment of the present disclosure.

FIGS. 34A, 34B, 34C, 34D, and 34E are various views of the second exemplary structure after recessing the dielectric gate spacer material layer and formation of gate cavities according to the second embodiment of the present disclosure.

FIGS. 35A, 35B, 35C, 35D, and 35E are various views of the second exemplary structure after formation of second word lines including a three-dimensional array of gate electrodes and removing physically exposed portions of the second gate dielectric material layer according to the second embodiment of the present disclosure.

FIGS. 36A, 36B, 36C, 36D, and 36E are various views of the second exemplary structure after formation of source trench isolation structures according to the second embodiment of the present disclosure.

FIGS. 37A, 37B, 37C, 37D, and 37E are various views of the second exemplary structure after formation of bit-line via cavities and source-line via cavities according to the second embodiment of the present disclosure.

FIGS. 38A, 38B, 38C, 38D, and 38E are various views of the second exemplary structure after formation of source regions and drain regions according to the second embodiment of the present disclosure.

FIGS. 39A, 39B, 39C, 39D, and 39E are various views of the second exemplary structure after formation of bit lines and source lines according to the second embodiment of the present disclosure.

FIGS. 40A, 40B, 40C, 40D, and 40E are various views of an alternative configuration of the second exemplary structure after formation of bit lines and source structures according to the second embodiment of the present disclosure.

FIG. 41 is a schematic circuit diagram of a first exemplary circuit that may be employed to implement a three-dimensional memory device including the first exemplary structure.

FIG. 42 is a schematic circuit diagram of a second exemplary circuit that may be employed to implement a three-dimensional memory device including the first exemplary structure.

FIG. 43 is a schematic circuit diagram of a third exemplary circuit that may be employed to implement a three-dimensional memory device including the second exemplary structure.

FIG. 44 is a schematic circuit diagram of a fourth exemplary circuit that may be employed to implement a three-dimensional memory device including the alternative configuration of the second exemplary structure.

FIG. 45 is a vertical cross-sectional view of a first semiconductor die containing the three-dimensional memory array of the embodiments of the present disclosure.

FIG. 46 is a vertical cross-sectional view of a second semiconductor containing the three-dimensional memory array of the embodiments of the present disclosure.

FIG. 47 is a vertical cross-sectional view of a third semiconductor die containing the three-dimensional memory array of the embodiments of the present disclosure.

FIG. 48 is a vertical cross-sectional view of a fourth semiconductor die containing the three-dimensional memory array of the embodiments of the present disclosure.

FIG. 49 is a vertical cross-sectional view of a fifth semiconductor die containing the three-dimensional memory array of the embodiments of the present disclosure.

FIG. 50 is a vertical cross-sectional view of a sixth semiconductor die containing the three-dimensional memory array of the embodiments of the present disclosure.

FIGS. 51A, 51B, 51C, 51D, and 51E are various views of a third exemplary structure after formation of a vertical repetition of instances of a unit layer stack according to a third embodiment of the present disclosure.

FIGS. 52A, 52B, 52C, 52D, and 52E are various views of the third exemplary structure after formation of bit-line trenches and source trenches according to the third embodiment of the present disclosure.

FIGS. 53A, 53B, 53C, 53D, and 53E are various views of the third exemplary structure after laterally recessing semiconductor layers and sacrificial layers according to the third embodiment of the present disclosure.

FIGS. 54A, 54B, 54C, 54D, and 54E are various views of the third exemplary structure after formation of capping structure according to the third embodiment of the present disclosure.

FIGS. 55A, 55B, 55C, 55D, and 55E are various views of the third exemplary structure after formation of sacrificial bit-line trench fill structures and sacrificial source trench fill structures according to the third embodiment of the present disclosure.

FIGS. 56A, 56B, 56C, 56D, and 56E are various views of the third exemplary structure after formation of lateral isolation trenches according to the third embodiment of the present disclosure.

FIGS. 57A, 57B, 57C, 57D, and 57E are various views of the third exemplary structure after formation of sacrificial isolation trench fill structures according to the third embodiment of the present disclosure.

FIGS. 58A, 58B, 58C, 58D, and 58E are various views of the third exemplary structure after removal of the sacrificial bit-line trench fill structures according to the third embodiment of the present disclosure.

FIGS. 59A, 59B, 59C, 59D, and 59E are various views of the third exemplary structure after formation of first voids according to the third embodiment of the present disclosure.

FIGS. 60A, 60B, 60C, 60D, and 69E are various views of the third exemplary structure after formation of first cavities according to the third embodiment of the present disclosure.

FIGS. 61A, 61B, 61C, 61D, and 61E are various views of the third exemplary structure after formation of a first gate dielectric material layer and a first continuous gate electrode material layer according to the third embodiment of the present disclosure.

FIGS. 62A, 62B, 62C, 62D, and 62E are various views of the third exemplary structure after formation of a two-dimensional array of dielectric plates according to the third embodiment of the present disclosure.

FIGS. 63A, 63B, 63C, 63D, and 63E are various views of the third exemplary structure after patterning the first continuous gate electrode material layer into first gate electrode material layers according to the third embodiment of the present disclosure.

FIGS. 64A, 64B, 64C, 64D, and 64E are various views of the third exemplary structure after patterning the first gate dielectric material layer into first gate dielectric layers according to the third embodiment of the present disclosure.

FIGS. 65A, 65B, 65C, 65D, and 65E are various views of the third exemplary structure after formation of bit-line trench isolation structures according to the third embodiment of the present disclosure.

FIGS. 66A, 66B, 66C, 66D, and 66E are various views of the third exemplary structure after formation of sacrificial bit-line structures according to the third embodiment of the present disclosure.

FIGS. 67A, 67B, 67C, 67D, and 67E are various views of the third exemplary structure after removal of the sacrificial source trench fill structures according to the third embodiment of the present disclosure.

FIGS. 68A, 68B, 68C, 68D, and 68E are various views of the third exemplary structure after formation of second voids according to the third embodiment of the present disclosure.

FIGS. 69A, 69B, 69C, 69D, and 69E are various views of the third exemplary structure after formation of second cavities according to the third embodiment of the present disclosure.

FIGS. 70A, 70B, 70C, 70D, and 70E are various views of the third exemplary structure after patterning the first gate dielectric layers into a three-dimensional array of gate dielectrics and after patterning the first gate electrode material layers into a two-dimensional array of first word lines according to the third embodiment of the present disclosure.

FIGS. 71A, 71B, 71C, 71D, and 71E are various views of the third exemplary structure after formation a three-dimensional memory device including access transistors, storage devices, bit lines, and a one-dimensional array of conductive structures according to the third embodiment of the present disclosure.

FIGS. 72A, 72B, 72C, 72D, and 72E are various views of a first alternative embodiment of the third exemplary structure after formation a three-dimensional memory device including access transistors, memory transistors, bit lines, and source lines according to the third embodiment of the present disclosure.

FIG. 73-80 are sequential vertical cross-sectional views of a second alternative embodiment of the third exemplary structure during a subset of processing steps according to the third embodiment of the present disclosure.

FIG. 81-91 are sequential vertical cross-sectional views of a third alternative embodiment of the third exemplary structure during a subset of processing steps according to the third embodiment of the present disclosure.

FIG. 92 is a vertical cross-sectional view of a fourth alternative embodiment of the third exemplary structure according to the third embodiment of the present disclosure.

FIG. 93-98 are sequential vertical cross-sectional views of a fifth alternative embodiment of the third exemplary structure during a subset of processing steps for forming a ferroelectric capacitor storage device according to the third embodiment of the present disclosure.

### DETAILED DESCRIPTION

Embodiments of the present disclosure are directed to three-dimensional memory devices with laterally integrated access transistors and methods of manufacturing the same, various aspects of which are described below. The embodiments of the disclosure may be employed to form various multilevel memory structures, non-limiting examples of which include non-volatile memory arrays and volatile memory arrays that can be implemented as three-dimensional memory arrays. Each unit cell may comprise a combination of an access transistor and an impedance element (such as a capacitive element or a resistive element), or may comprise a combination of an access transistor and a memory transistor.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition and the same function.

Unless otherwise indicated, a “contact” between elements refers to a direct contact between elements that provides an edge or a surface shared by the elements. As used herein, a first element located “on” a second element may be located on the exterior side of a surface of the second element or on the interior side of the second element. As used herein, a first element is located “directly on” a second element if there exists a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of planes therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

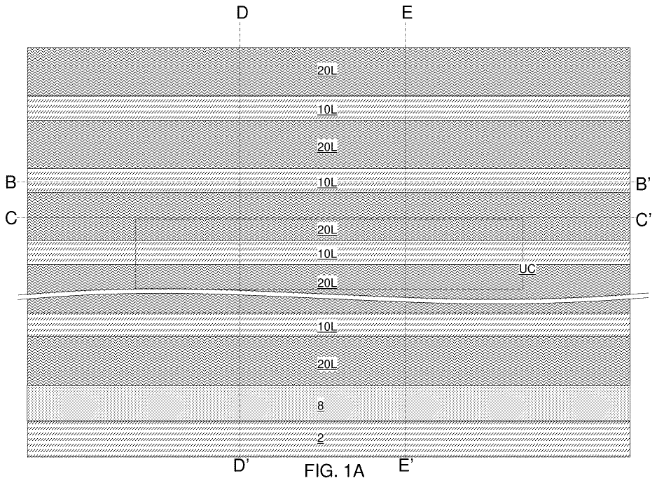

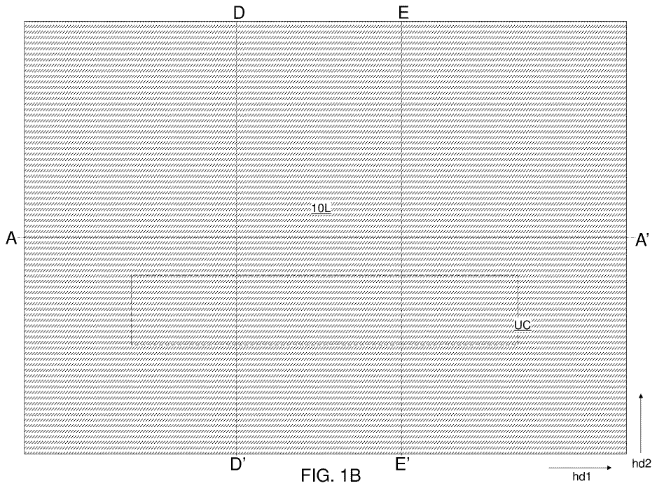

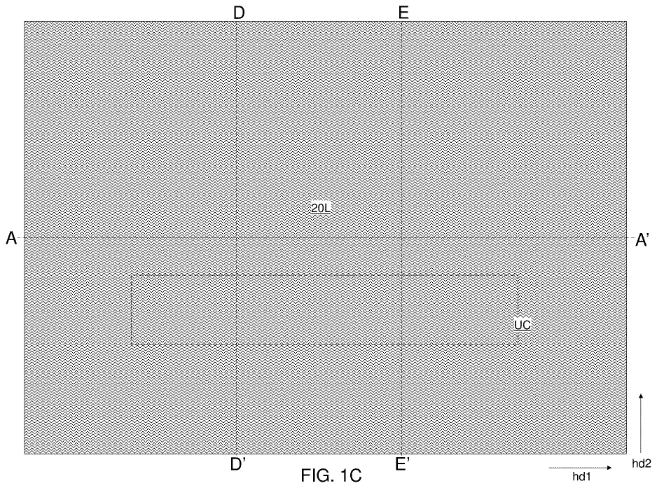

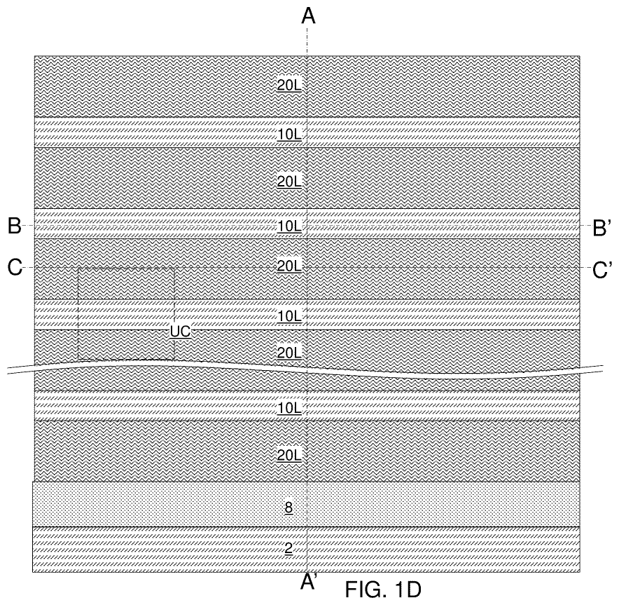

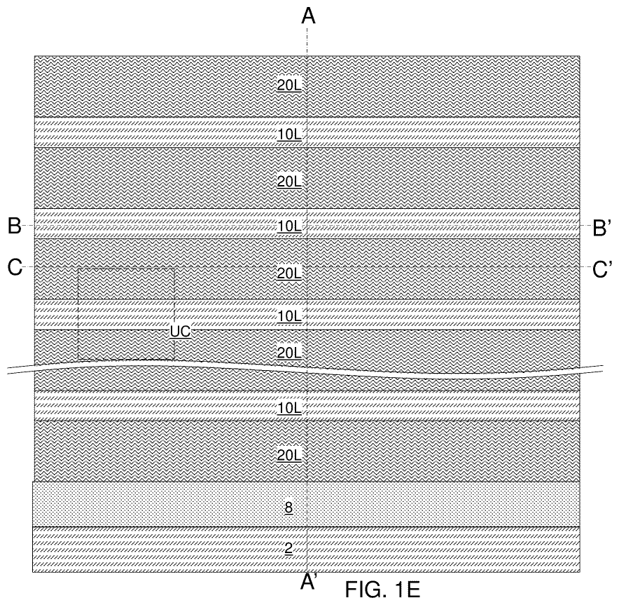

Referring to FIGS. 1A, 1B, 1C, 1D, and 1E, a first exemplary structure according to a first embodiment of the present disclosure is illustrated. The first exemplary structure comprises a substrate 2, which may be a semiconductor substrate, an insulating substrate, a conductive substrate, or a composite substrate including a stack of multiple layers. In some embodiments, the substrate 2 may comprise a single crystalline semiconductor substrate, such as a commercially available single crystalline silicon wafer. Preferably, but not necessarily, an etch stop structure 8 can be formed on the top surface of the substrate 2. The etch stop structure 8 may comprise at least one etch stop material layer and/or may comprise patterned discrete etch stop structures. Generally, any material layer and/or patterned material portions may be employed as the etch stop structure 8. In some embodiments, the etch stop structure 8 may comprise a single crystalline carbon doped silicon layer or a single crystalline nitrogen doped silicon layer. In some other embodiments, the etch stop structure 8 may comprise at least one dielectric material layer, such as a silicon oxide layer, a silicon nitride layer, a silicon carbonitride layer, a silicon oxynitride layer, a dielectric metal oxide layer, or a combination thereof. Alternatively, the etch stop structure 8 comprises patterned dielectric material portions that are embedded in an upper portion of the substrate 2.

A vertically alternating sequence of sacrificial layers 20L and semiconductor layers 10L can be formed over the etch stop structure 8. In one embodiment, the sacrificial layers 20L and the semiconductor layers 10L may comprise nanolayers comprising an unpatterned layer having a thickness greater than 1 nm and less than 1 micron. Each sacrificial layer 20L comprises a sacrificial material, and each semiconductor layer 10L comprises a semiconductor material. The sacrificial material of the sacrificial layers 20L is a material that may be subsequently removed selectively to the material of the semiconductor layers 10L and selectively to the material of the etch stop structure 8. For example, the semiconductor layers 10L may comprise silicon (such as single crystalline silicon, polycrystalline silicon, or amorphous silicon that may be subsequently crystallized into polycrystalline silicon), and the sacrificial layers 20L may comprise a silicon germanium compound semiconductor material including germanium atoms at an atomic percentage in a range from 10% to 40%, silicon nitride, organosilicate glass, or a polymer material. Each semiconductor layer 10L may have a first thickness in a range from 10 nm to 200 nm (such as from 20 nm to 100 nm), although lesser and greater first thicknesses may also be employed. In one embodiment, the semiconductor layers 10L may comprise single crystalline silicon that are epitaxially aligned to a single crystalline semiconductor material within the substrate 2, and the sacrificial layers 20L may comprise single crystalline silicon-germanium compound semiconductor layers that are epitaxially aligned to the single crystalline silicon in the semiconductor layers 10L and to the single crystalline semiconductor material within the substrate 2. In this case, the entire set of the substrate 2, the semiconductor layers 10L, and the sacrificial layers 20L may be single crystalline, and may be epitaxially aligned to each other. Each sacrificial layer 20L may have a second thickness in a range from 20 nm to 300 nm (such as from 30 nm to 150 nm), although lesser and greater second thicknesses may also be employed.

The vertically alternating sequence (20L, 10L) may be formed by an alternating sequence of deposition steps that each deposit a respective sacrificial layer 20L or a respective semiconductor layer 10L. For example, each semiconductor layer 10L may be deposited by a first-type chemical vapor deposition or atomic layer deposition process, and each sacrificial layer 20L may be deposited by a second-type chemical vapor deposition or atomic layer deposition process. The bottommost layer of the vertically alternating sequence (20L, 10L) may be a sacrificial layer 20L or a semiconductor layer 10L. The topmost layer of the vertically alternating sequence (20L, 10L) may be a sacrificial layer 20L or a semiconductor layer 10L. The (N+1) pairs of a sacrificial layer 20L and a semiconductor layer 10L can be present in the vertically alternating sequence (20L, 10L). The number N may be in a range from 2 to 2¹⁰, such as from 8 to 2⁸, although lesser and greater numbers of pairs may also be employed. The three-dimensional array of unit cells UC is a subsequently formed within the volume of the vertically alternating sequence (20L, 10L). A volume of a unit cell UC is a schematically illustrated in each of FIGS. 1A, 1B, 1C, 1D, and 1E. The three-dimensional array of unit cells UC comprises a three-dimensional memory array. The three-dimensional array of unit cells UC may have a first periodicity along a first horizontal direction hd1, a second periodicity along a second horizontal direction hd2 that is perpendicular to the first horizontal direction hd1, and the third periodicity along the vertical direction. The third periodicity may equal the sum of the first thickness and the second thickness.

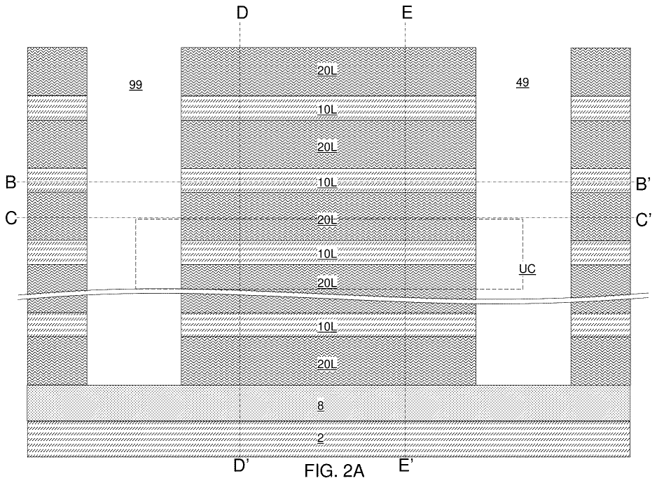

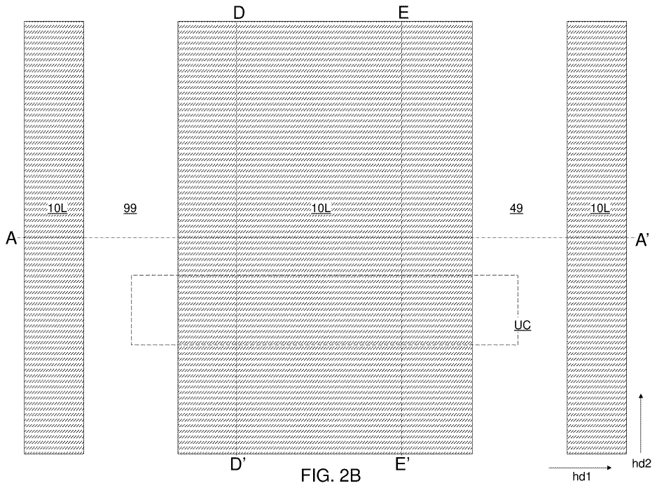

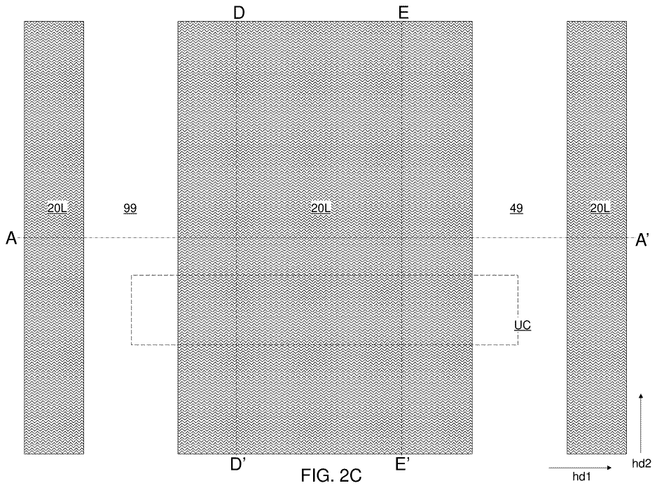

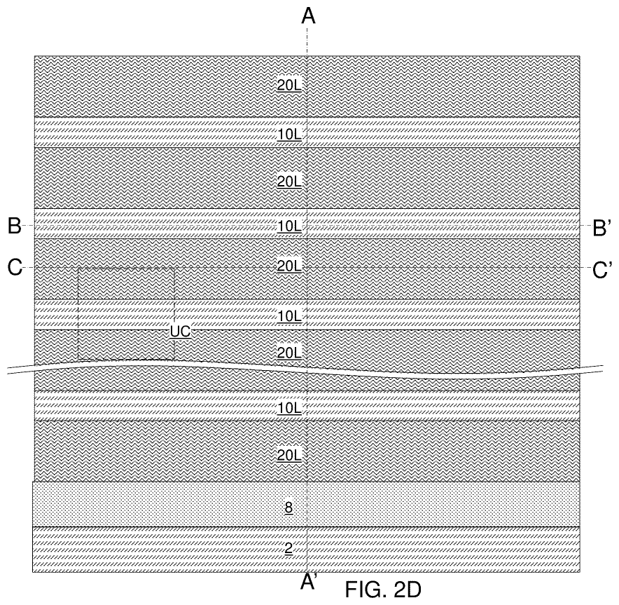

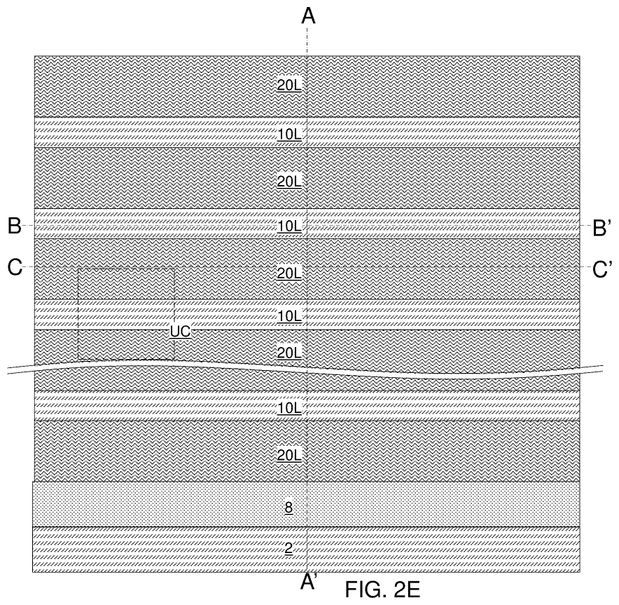

Referring to FIGS. 2A, 2B, 2C, 2D, and 2E, a first photoresist layer (not shown) can be applied over the vertically alternating sequence (20L, 10L), and can be lithographically patterned to form elongated openings that laterally extend along the second horizontal direction hd2. The elongated openings may have a uniform width along the first horizontal direction hd1, and are formed at boundaries of neighboring pairs of unit cells UC. A first anisotropic etch process can be performed to transfer the pattern of the openings in the first photoresist layer through the vertically alternating sequence (20L, 10L). Trenches (49, 99) that laterally extend along the second horizontal direction hd2 can be formed. The total number of the trenches (49, 99) may be L+1, in which L is an integer in a range from 2⁶ to 2¹⁸, although lesser and greater numbers may also be employed for the integer L. The trenches (49, 99) may comprise a laterally alternating sequence of source trenches 49 (e.g., write-side trenches) and bit-line trenches 99 (e.g., read-side trenches) that alternate along the first horizontal direction hd1.

Each of the source trenches 49 and the bit-line trenches 99 may have a respective uniform width along the first horizontal direction hd1, which may be in a range from 50 nm to 600 nm, such as from 100 nm to 400 nm, although lesser and greater widths may also be employed. The center-to-center distance between neighboring pairs of the trenches (49, 99) can be the same as the first periodicity of the three-dimensional array of unit cells UC along the first horizontal direction hd1. The first periodicity may be in a range from 200 nm to 10,000 nm, such as from 400 nm to 1,000 nm, although lesser and greater dimensions may also be employed for the first periodicity. The vertically alternating sequence (20L, 10L) as formed at the processing steps of FIGS. 1A, 1B, 1C, 1D, and 1E is divided into a one-dimensional array of vertically alternating sequences (20L, 10L) arranged along the first horizontal direction hd1, and are laterally spaced apart from each other by an alternating sequence of source trenches 49 and bit-line trenches 99. Each vertically alternating sequence (20L, 10L) of semiconductor layers 10L and sacrificial layers 20L may have a respective first planar sidewall that is perpendicular to the first horizontal direction hd1 and is exposed to a respective bit-line trench 99, and a respective second planar sidewall that is perpendicular to the first horizontal direction hd1 and is exposed to a respective source trench 49. The first photoresist layer can be subsequently removed, for example, by ashing.

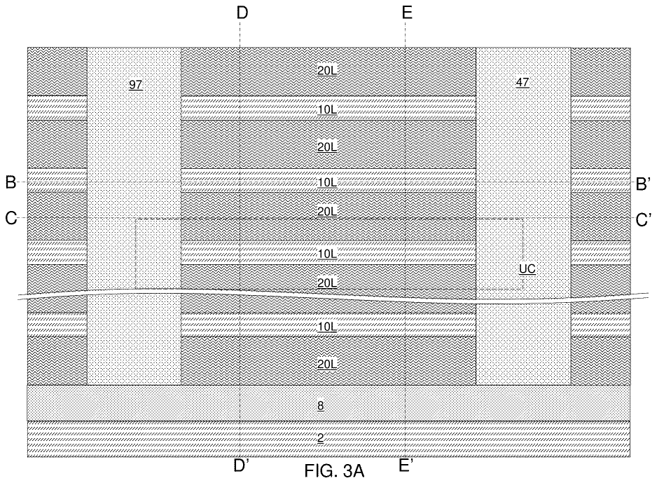

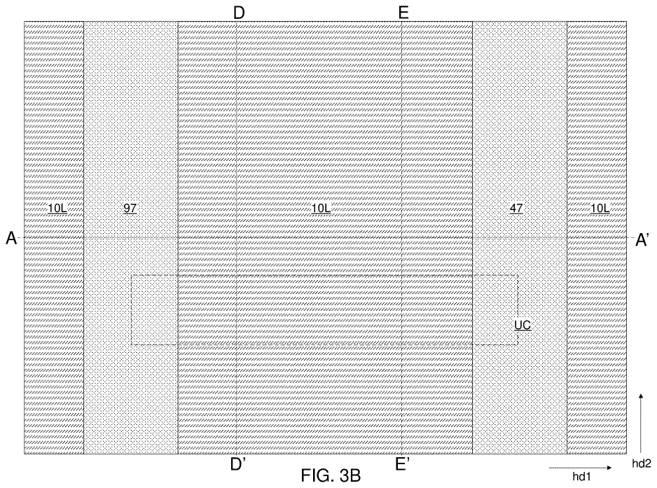

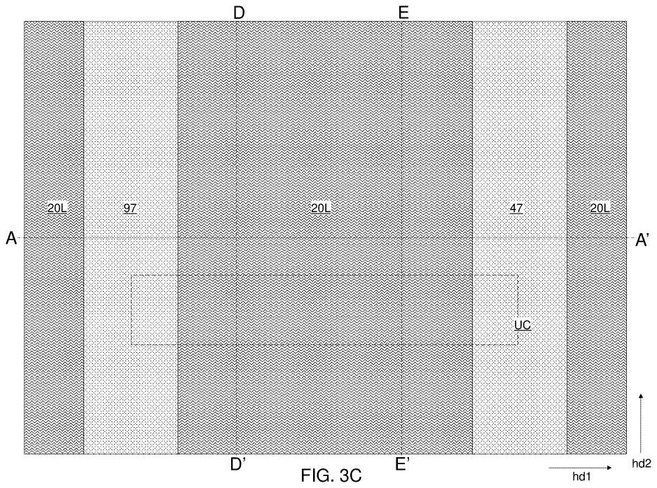

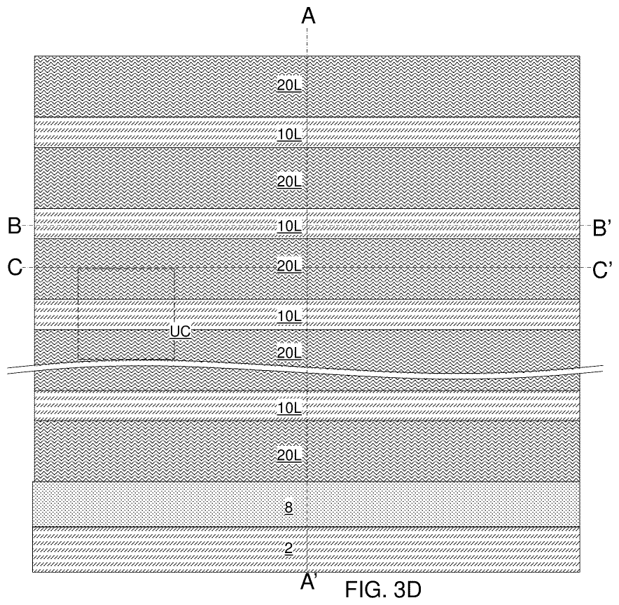

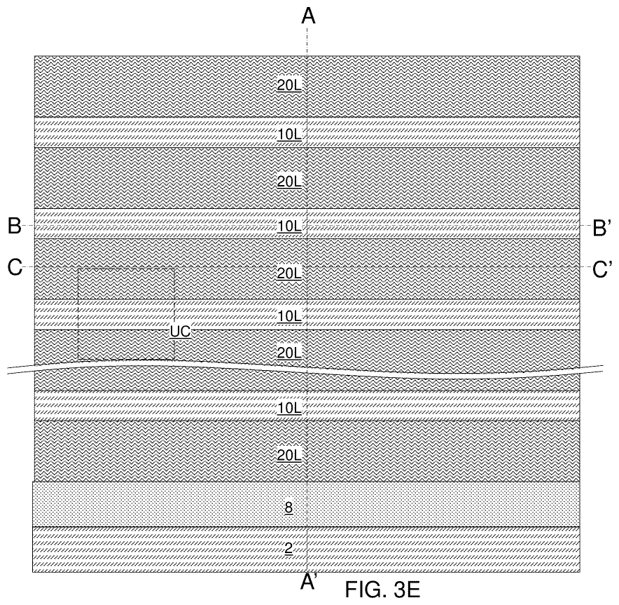

Referring to FIGS. 3A, 3B, 3C, 3D, and 3E, a first sacrificial fill material can be deposited in the source trenches 49 and the bit-line trenches 99. The first sacrificial fill material may comprise a carbon-based material (such as amorphous carbon or diamond-like carbon), organosilicate glass, silicon oxide, silicon nitride, or a polymer material. Generally, the first sacrificial fill material is different from the material of the sacrificial layers 20L. Excess portions of the first sacrificial fill material can be removed from above the horizontal plane including the top surfaces of the vertically alternating sequence (20L, 10L) by a planarization process, which may employ a chemical mechanical polishing process and/or a recess etch process. Each portion of the first sacrificial fill material that fills a source trench 49 constitutes a sacrificial source trench fill structure 47. Each portion of the first sacrificial fill material that fills a bit-line trench 99 constitutes a sacrificial bit-line trench fill structure 97.

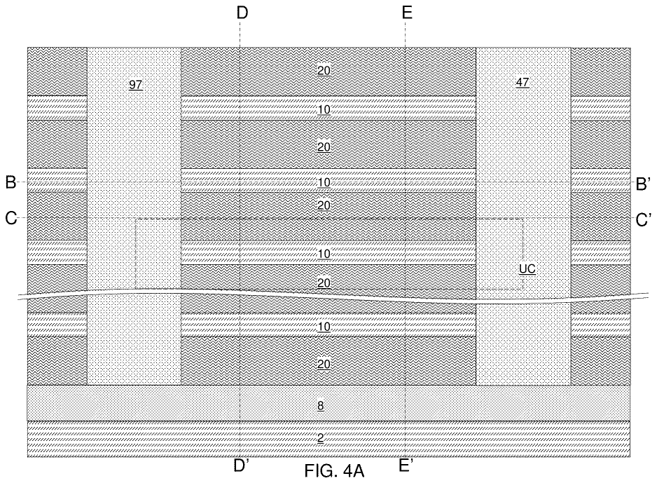

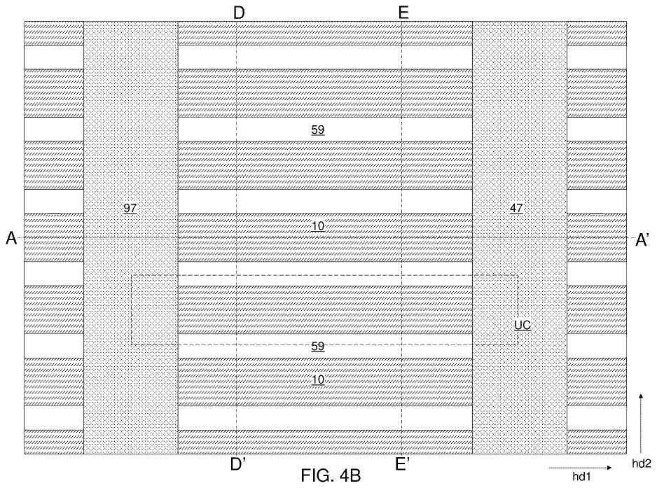

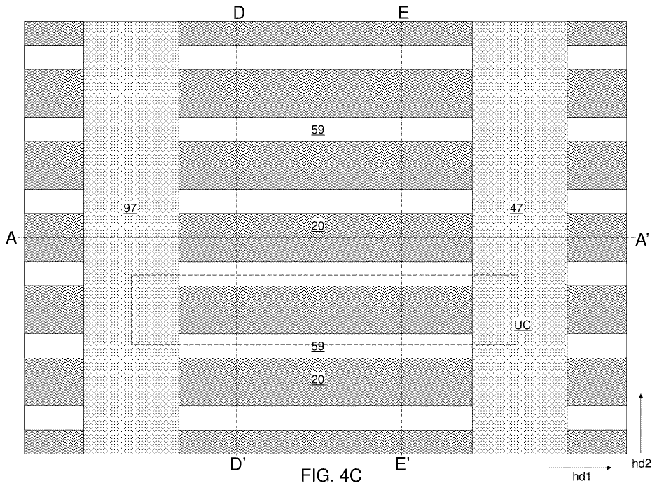

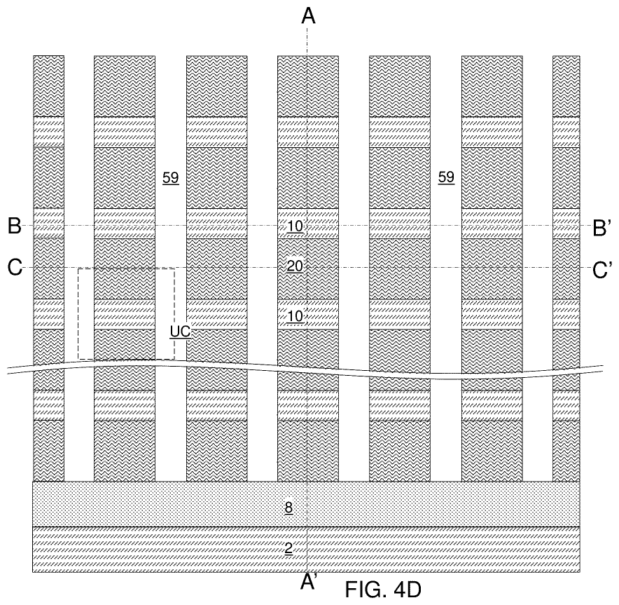

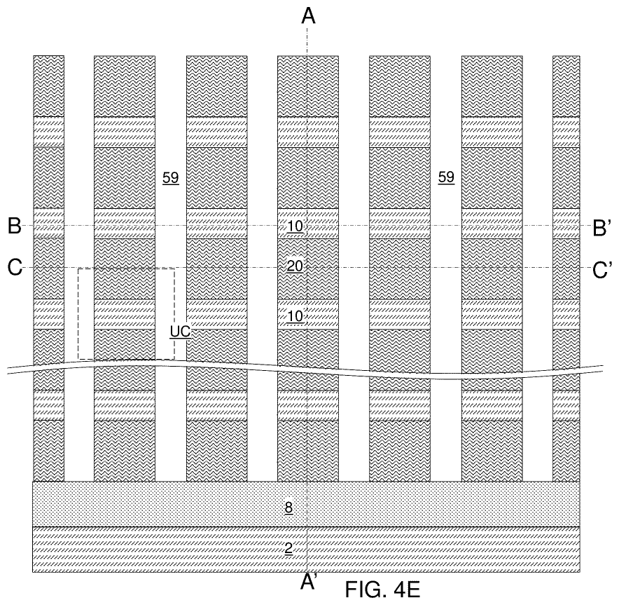

Referring to FIGS. 4A, 4B, 4C, 4D, and 4E, a second photoresist layer (not shown) can be applied over the vertically alternating sequences (20L, 10L) and the sacrificial trench fill structures (47, 97), and can be lithographically patterned to form elongated openings that laterally extend along the first horizontal direction hd1. The elongated openings may have a uniform width along the second horizontal direction hd1, and may laterally extend through the entire length of the one-dimensional array of vertically alternating sequences (20L, 10L) along the first horizontal direction hd1, or may laterally extend between a respective neighboring pair of sacrificial trench fill structures (47, 97). Generally, each elongated opening in the second photoresist layer may be formed at boundaries of neighboring pairs of unit cells UC that are spaced apart along the second horizontal direction. A second anisotropic etch process can be performed to transfer the pattern of the openings in the second photoresist layer through the vertically alternating sequences (20L, 10L). Lateral isolation trenches 59 that laterally extend along the first horizontal direction hd1 can be formed. Each of the lateral isolation trenches 59 may have a respective uniform width along the second horizontal direction hd2, which is less than the thickness of each sacrificial layer 20L. The uniform width of each lateral isolation trench 59 may be in a range from 10 nm to 200 nm, such as from 20 nm to 100 nm, although lesser and greater widths may also be employed. The total number of the lateral isolation trenches 59 may be M+1, in which M is an integer in a range from 2⁶ to 2²⁰, although lesser and greater numbers may also be employed for the integer M. The center-to-center distance between neighboring pairs of the lateral isolation trenches 59 can be the same as the second periodicity of the three-dimensional array of unit cells UC along the second horizontal direction hd2. The second periodicity may be in a range from 20 nm to 1,000 nm, such as from 40 nm to 500 nm, although lesser and greater dimensions may also be employed for the second periodicity.

Each patterned portion of a semiconductor layer 10L comprises a semiconductor rail 10. Each patterned portion of a sacrificial layer 20L comprises a sacrificial rail 20. A one-dimensional array of vertically alternating sequences (20L, 10L) as formed at the processing steps of FIGS. 2A, 2B, 2C, 2D, and 2E is divided into a two-dimensional array of alternating stacks (20, 10) of semiconductor rails 10 and sacrificial rails 20. As used herein, a rail refers to an elongated structure that laterally extends along a lengthwise direction (such as the first horizontal direction hd1) and composed primarily of at least one material portion having uniform widthwise dimensions along all widthwise dimensions (such as the second horizontal direction hd1 and the vertical direction). In the instant case, each of the semiconductor rails 10 and sacrificial rails 20 may have a respective first widthwise dimension along the second horizontal direction hd2, and may have a second widthwise dimension along the vertical dimension. The lateral dimension of the semiconductor rails 10 and the sacrificial rails 20 along the second horizontal direction hd2 may be in a range from 100 nm to 900 nm, such as from 200 nm to 500 nm, although lesser and greater lateral dimensions may also be employed.

A three-dimensional array of semiconductor rails 10 can be formed. The three-dimensional array of semiconductor rails 10 may be an L×M×(N+1) cubic three-dimensional array in which instances of a unit cell UC are repeated along the first horizontal direction hd1 L times, are repeated along the second horizontal direction hd2 M times, and are repeated along the vertical direction (N+1) times. Each of the semiconductor rails 10 may have a shape of a respective rectangular parallelepiped. Each of the sacrificial rails 20 may have a shape of a respective rectangular parallelepiped. The second photoresist layer can be subsequently removed, for example, by ashing.

Generally, a three-dimensional array of horizontally-extending semiconductor rails 10 laterally extending along the first horizontal direction hd1 can be formed over a substrate 2. The three-dimensional array of horizontally-extending semiconductor rails 10 can be structurally supported by a three-dimensional array of horizontally-extending sacrificial rails 20.

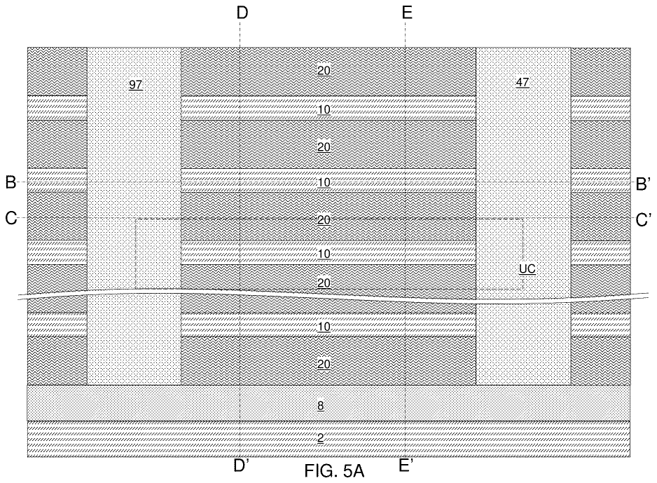

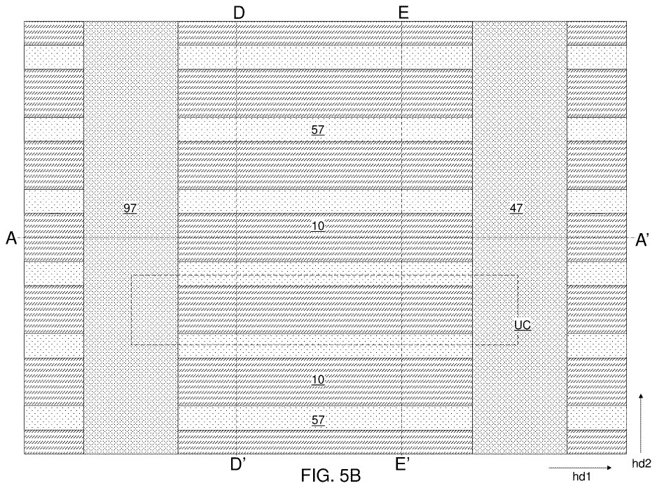

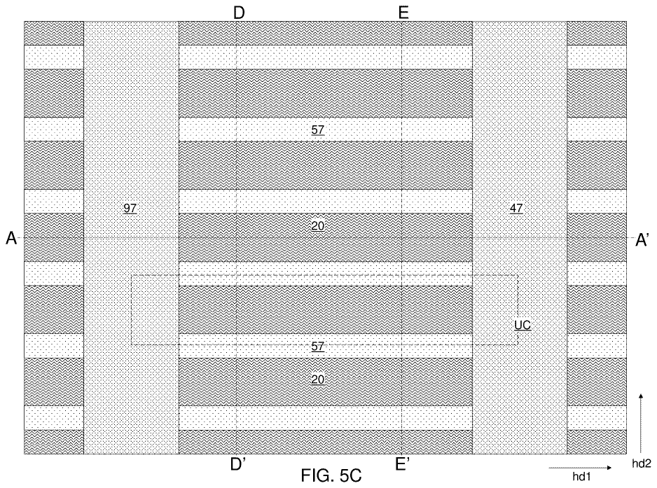

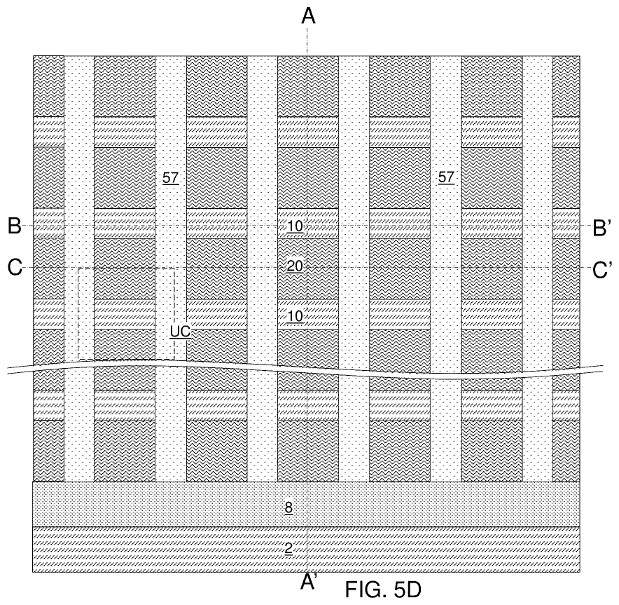

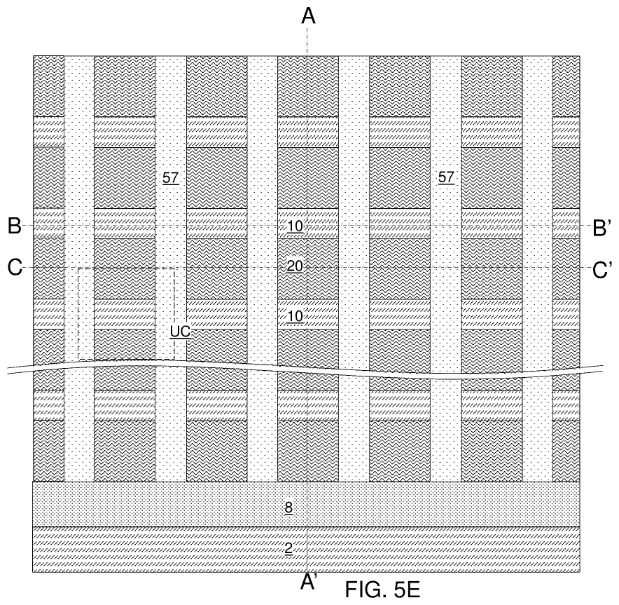

Referring to FIGS. 5A, 5B, 5C, 5D, and 5E, a second sacrificial fill material can be deposited in the lateral isolation trenches 59. The second sacrificial fill material may comprise a sacrificial fill material that is different from the first sacrificial fill material. In one embodiment, the second sacrificial fill material may comprise a carbon-based material (such as amorphous carbon or diamond-like carbon), organosilicate glass, silicon oxide, silicon nitride, or a polymer material. For example, the second sacrificial fill material may comprise silicon oxide. Generally, the second sacrificial fill material is different from the first sacrificial fill material of the sacrificial source trench fill structures 47 and the sacrificial bit-line trench fill structures 97, and may be different from, or may be the same as, the material of the sacrificial layers 20L. Excess portions of the second sacrificial fill material can be removed from above the horizontal plane including the top surfaces of the alternating stacks (20, 10) by a planarization process, which may employ a chemical mechanical polishing process and/or a recess etch process. Each portion of the second sacrificial fill material that fills a respective lateral isolation trench 59 constitutes a sacrificial isolation trench fill structure 57. In an alternative embodiment, the sacrificial source trench fill structures 47 and the sacrificial bit-line trench fill structures 97 may be formed after formation of the sacrificial isolation trench fill structure 57. Thus, the steps shown in FIGS. 2A-2E and 3A-3E may be performed after the steps shown in FIGS. 4A-4E and 5A-5E.

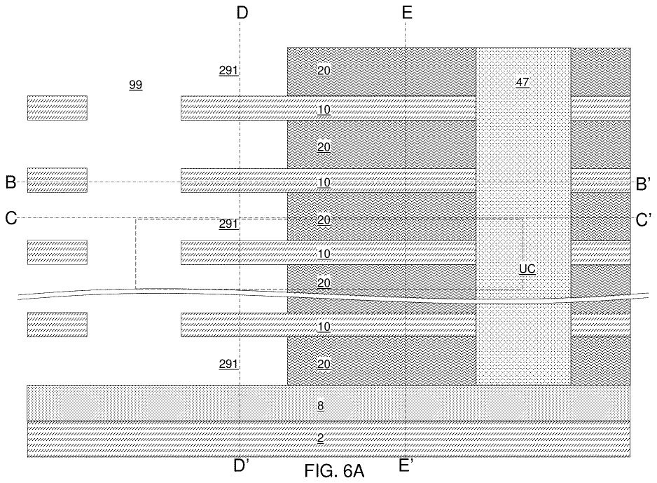

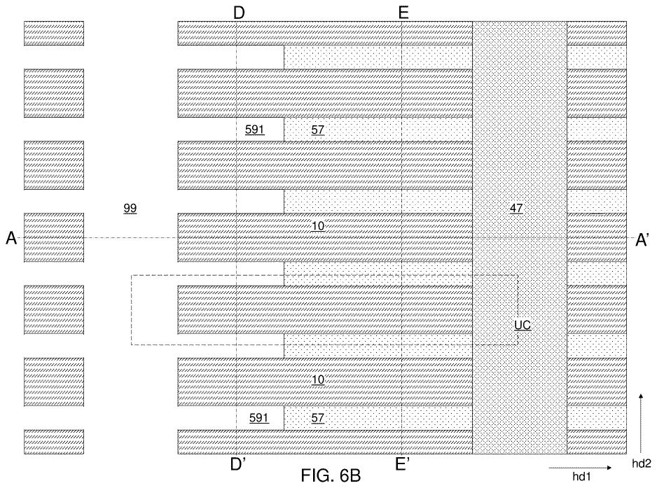

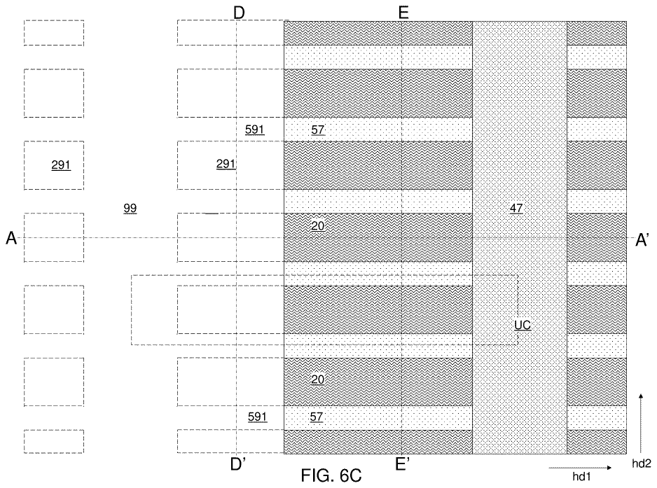

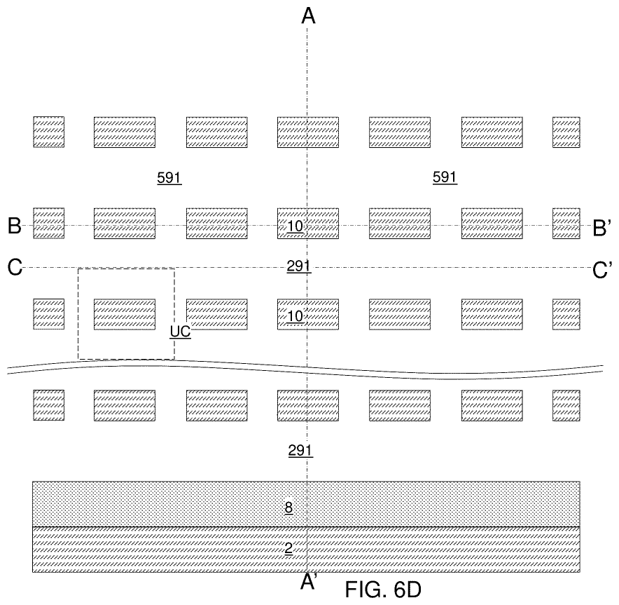

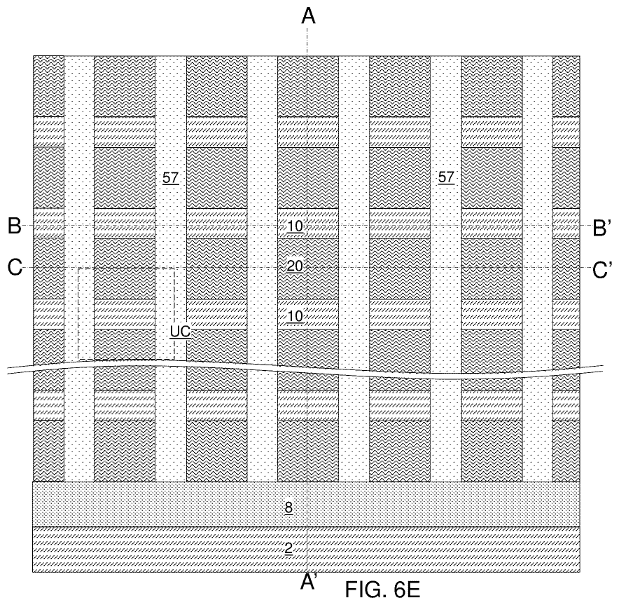

Referring to FIGS. 6A, 6B, 6C, 6D, and 6E, an etch mask layer (not illustrated), such as a photoresist layer, can be formed over the first exemplary structure, and can be patterned to form openings over the areas of the sacrificial bit-line trench fill structures 97. A first selective material removal process can be performed to remove the sacrificial bit-line trench fill structures 97 selectively to the materials of the semiconductor rails 10, the sacrificial isolation trench fill structure 57, and the etch stop structures 8.

In an illustrative example, if the sacrificial bit-line trench fill structures 97 comprise silicon nitride, a wet etch process employing hot phosphoric acid may be performed. If the sacrificial bit-line trench fill structures 97 comprise a carbon-based material such as amorphous carbon or diamond-like carbon, an ashing process may be employed to remove the sacrificial bit-line trench fill structures 97. Voids are formed in the volumes of the bit-line trenches 99.

Subsequently, at least one second selective material removal process may be performed to remove a first portion of each of the horizontally-extending sacrificial rails 20 and to remove a first portion of each of the sacrificial isolation trench fill structures 57 that are proximal to the voids within the volumes of the bit-line trenches 99. First lateral isolation trenches 591 are formed in the volumes from which the first portions of the sacrificial isolation trench fill structures 57 are removed. The first lateral isolation trenches 591 are formed between laterally-neighboring pairs of first portions of the horizontally-extending semiconductor rails 10 by removing the first portion of each of the sacrificial isolation trench fill structures 57. First inter-rail cavities 291 are formed in the volumes from which the first portions of the sacrificial rails 20 are removed. The first inter-rail cavities 291 are formed between vertically-neighboring pairs of first portions of the horizontally-extending semiconductor rails 10 by removing the first portion of each of the horizontally-extending sacrificial rails 20.

In case the sacrificial isolation trench fill structures 57 and the sacrificial rails 20 comprise different materials, the at least one second selective material removal process may comprise a set of two second selective material removal processes, each of which removes a respective material selected from the materials of the sacrificial isolation trench fill structures 57 and the sacrificial rails 20. In this case, removal of the material of the sacrificial isolation trench fill structures 57 may precede or follow removal of the material of the sacrificial rails 20. Alternatively, if the sacrificial isolation trench fill structures 57 and the sacrificial rails 20 comprise the same sacrificial material, removal of the materials of the sacrificial isolation trench fill structures 57 and the sacrificial rails 20 may proceed simultaneously. Generally, the duration of each of the at least one second selective material removal process may be selected such that the length of each physically exposed surface of the first portion of each semiconductor rail 10 along the first horizontal direction hd1 is on the order of the dimension of the horizontally-extending semiconductor channels of access transistors to be subsequently formed. For example, the ratio of the length of each first portion of the semiconductor rail 10 (i.e., the portion having physically exposed sidewalls, a physically exposed top surface, and a physically exposed bottom surface) along the first horizontal direction hd1 to the length of the entirety of each semiconductor rail 10 along the first horizontal direction may be in a range from 0.05 to 0.6, such as from 0.1 to 0.4, although lesser and greater ratios may also be employed.

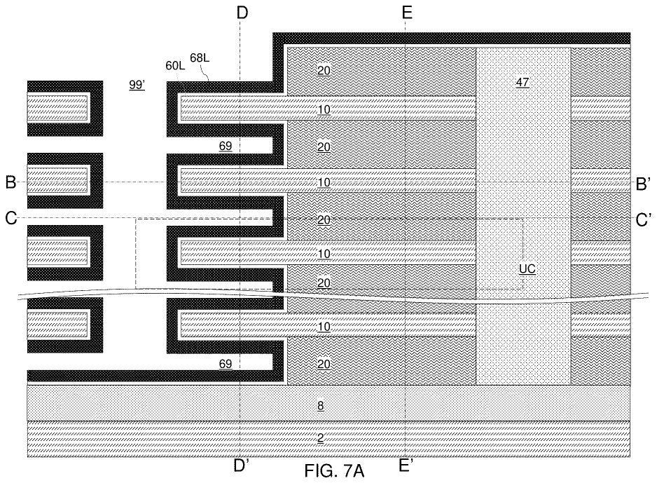

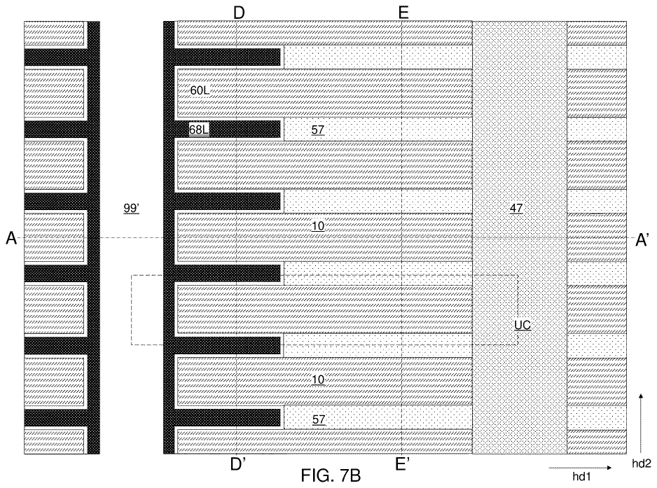

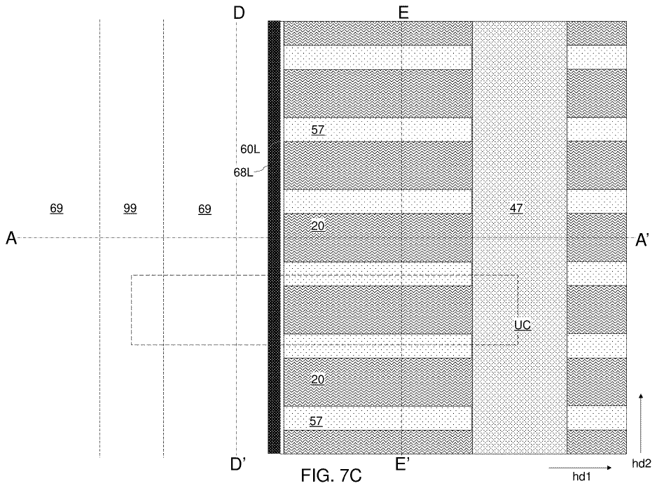

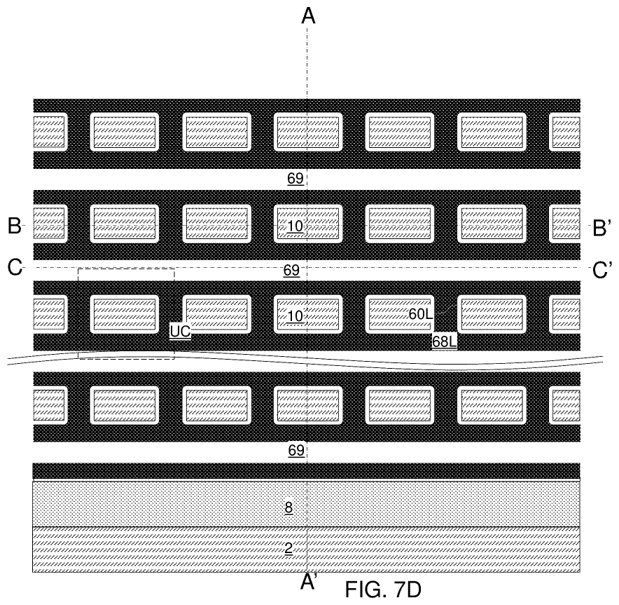

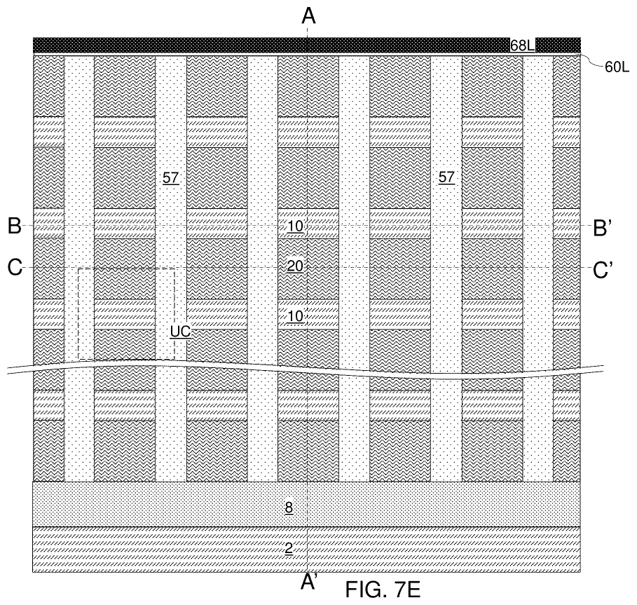

Referring to FIGS. 7A, 7B, 7C, 7D, and 7E, a first gate dielectric material layer 60L is formed by conformal deposition or oxidation of the semiconductor rails 10. The first gate dielectric material layer 60L comprises a first gate dielectric material, such as silicon oxide or a dielectric metal oxide. The thickness of the first gate dielectric material layer 60L may be in a range from 2 nm to 20 nm, such as from 3 nm to 6 nm, although lesser and greater thicknesses may also be employed.

A continuous first gate electrode material layer 68L may be conformally deposited on the first gate dielectric material layer 60L. The continuous first gate electrode material layer 68L comprises a first gate electrode material, which may comprise any suitable conductive material. For example, the continuous first gate electrode material layer 68L may comprise at least one metallic barrier layer, such as TiN, TaN, WN or MoN, and a metal fill layer such as W, Ti, Ta, Ru or Mo. The continuous first gate electrode material layer 68L can be formed around each first portion of the horizontally-extending semiconductor rails 10. The first gate electrode material of the continuous first gate electrode material layer 68L is deposited as a continuous material layer such that lateral gaps between laterally-neighboring pairs of the first portions of the horizontally-extending semiconductor rails 10 are filled with the first gate electrode material, while vertical gaps between vertically-neighboring pairs of the first portions of the horizontally-extending semiconductor rails 10 are not completely filled with the first gate electrode material. Thus, first laterally-extending voids 69 that laterally extend along the second horizontal direction hd2 are present in unfilled volumes of the vertical gaps between neighboring pairs of first portions of the semiconductor rails 10 after deposition of the first gate electrode material of the continuous first gate electrode material layer 68L. A laterally-extending void 99′ can be present within each bit-line trench 99. The etch mask layer can be subsequently removed, for example, by ashing.

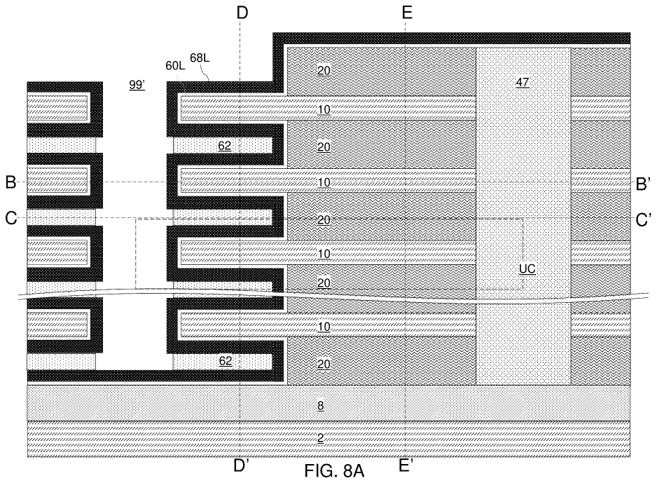

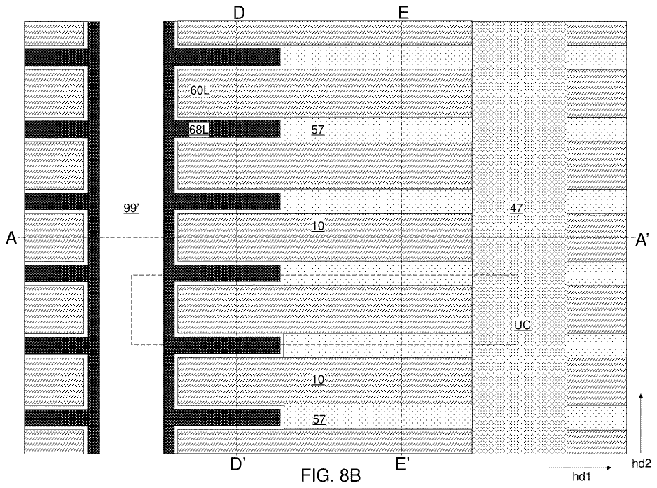

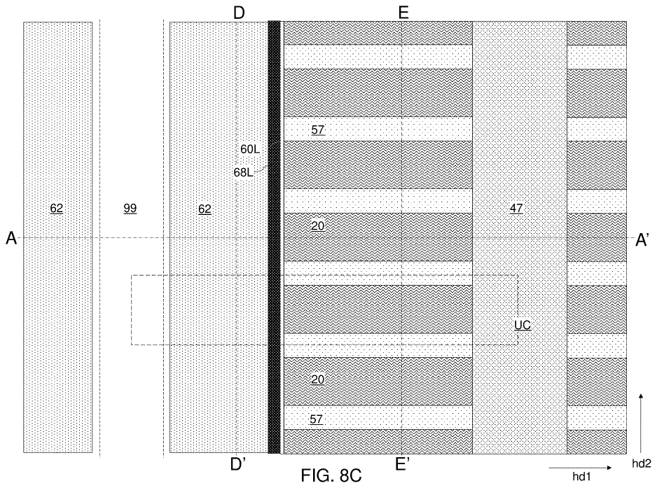

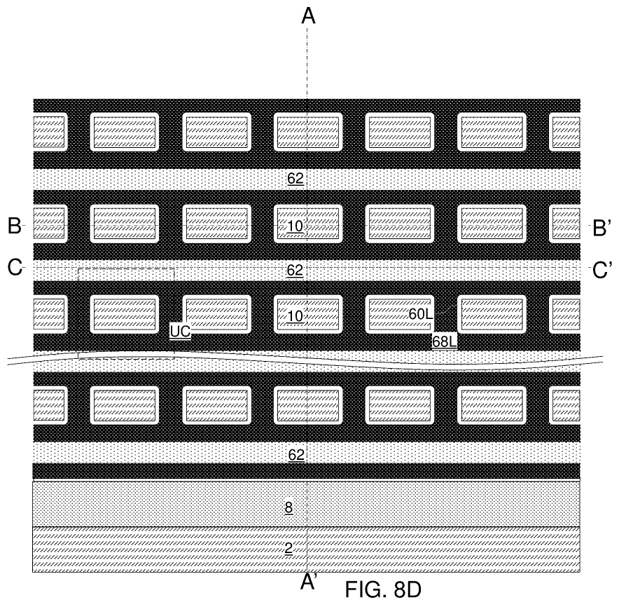

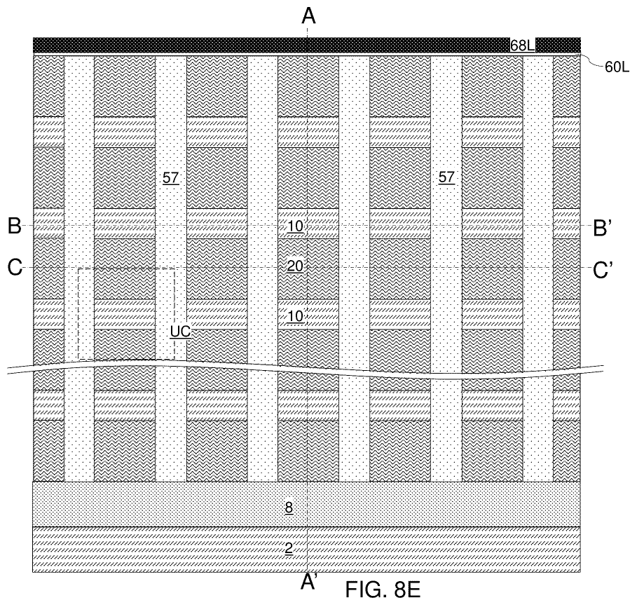

Referring to FIGS. 8A, 8B, 8C, 8D, and 8E, a first dielectric fill material, such as silicon oxide can be conformally deposited in the first laterally-extending voids 69, in peripheral portions of the bit-line trenches 99, and over the horizontally-extending portion of the continuous first gate electrode material layer 68L that overlie the three-dimensional array of semiconductor rails 10. An isotropic recess etch process may be performed to remove portions of the first dielectric fill material from outside the volumes of the first laterally-extending voids 69. Remaining portions of the first dielectric fill material that fill the first laterally-extending voids 69 comprise a two-dimensional array of first dielectric plates 62. Each first dielectric plate 62 is formed between a respective vertically neighboring pair of laterally extending portions of the continuous first gate electrode material layer 68L that laterally extend along the second horizontal direction hd2.

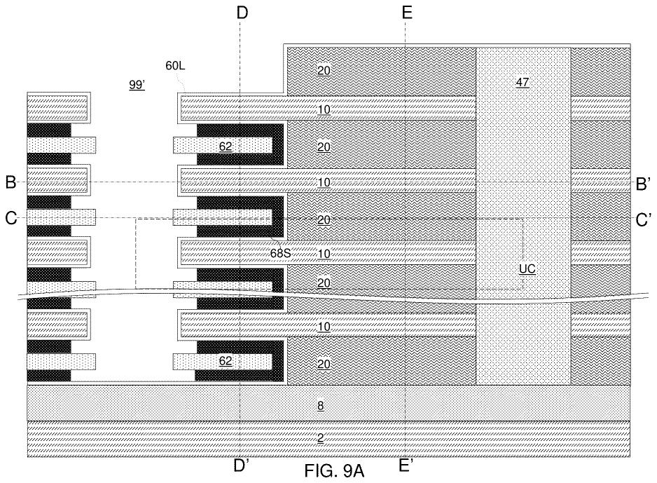

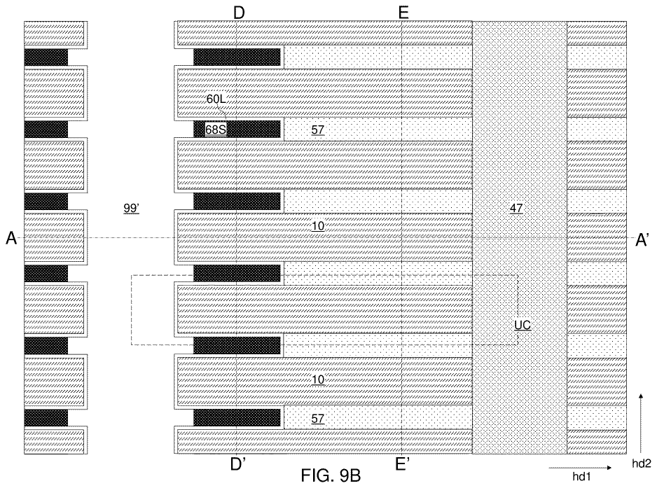

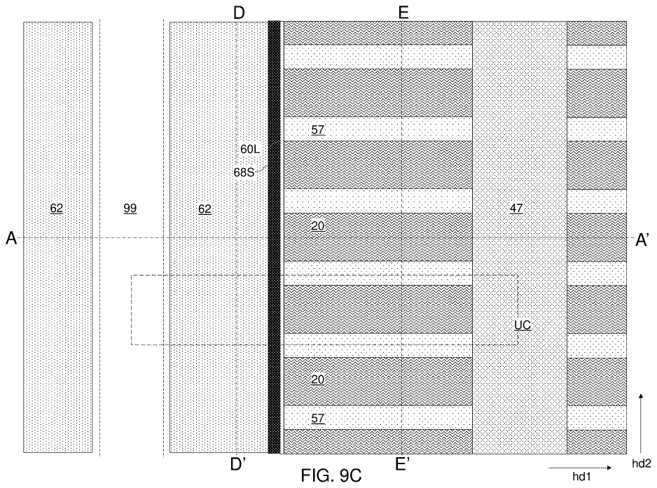

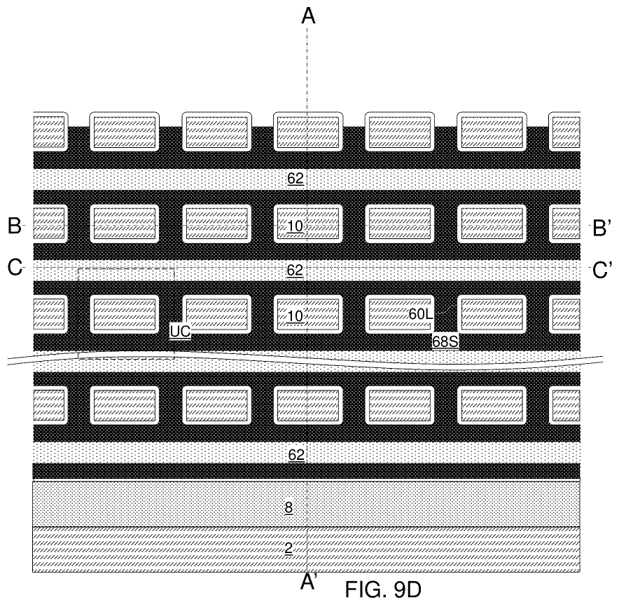

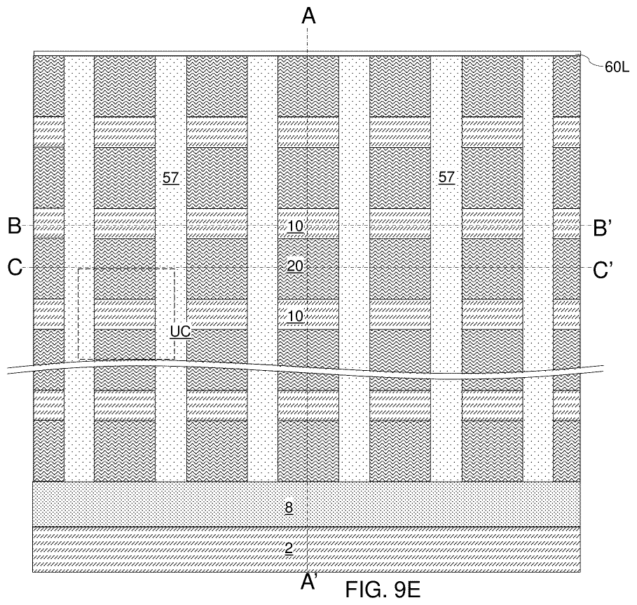

Referring to FIGS. 9A, 9B, 9C, 9D, and 9E, a first selective isotropic etch process can be performed to etch portions of the continuous first gate electrode material layer 68L that are proximal to the bit-line trenches 99 or overlie the topmost semiconductor rails 10. The first selective isotropic etch process can etch the first gate electrode material selectively to the first gate dielectric material. For example, a wet etch process that isotropically etches the first gate electrode material selectively to the first gate dielectric material may be employed. The first selective isotropic etch process patterns the continuous first gate electrode material layer 68L into a one-dimensional array of first gate electrode material layers 68S that are laterally spaced apart along the first horizontal direction hd1. Each first gate electrode material layer 68S may surround a respective two-dimensional array of semiconductor rails 10. For example, each first gate electrode material layer 68S may have a rectangular array of perforations through which a respective two-dimensional array of semiconductor rails 10 laterally extends along the first horizontal direction hd1, as shown in FIG. 9D.

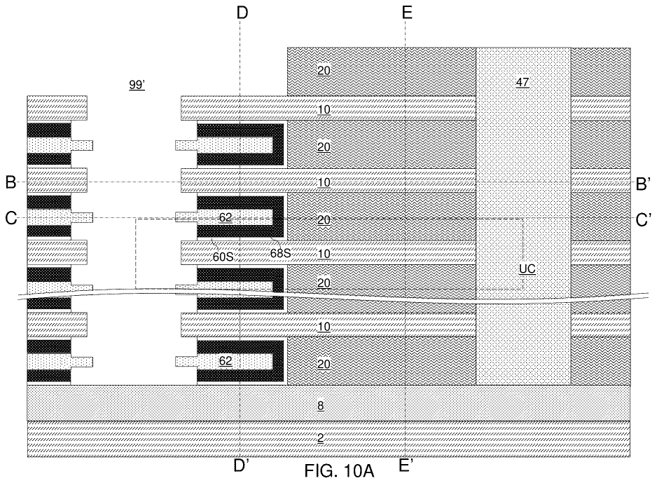

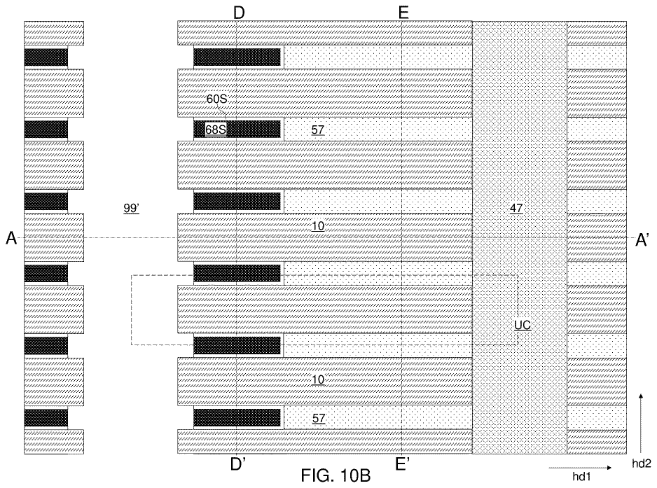

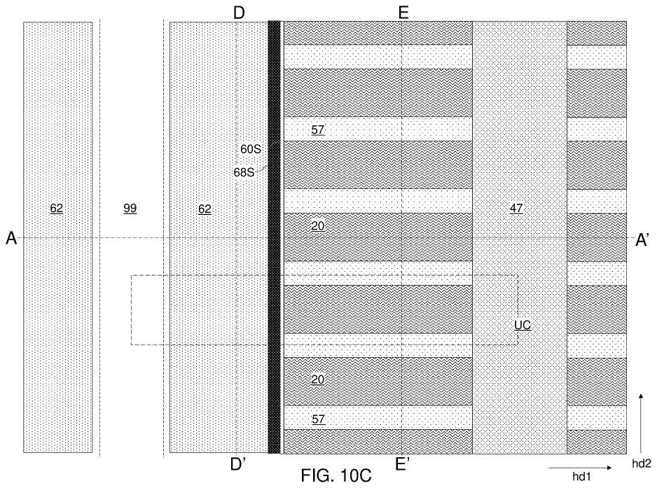

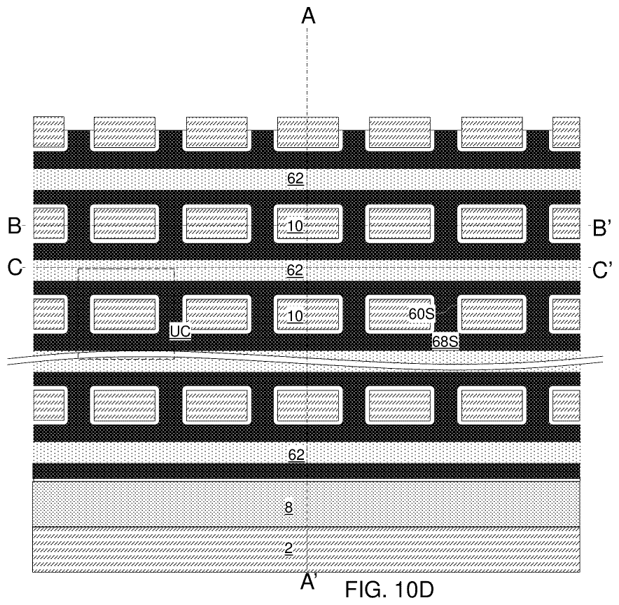

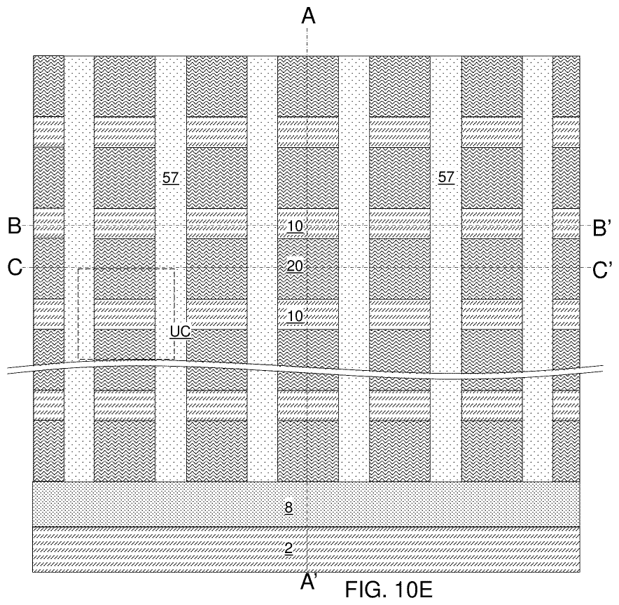

Referring to FIGS. 10A, 10B, 10C, 10D, and 10E, a second selective isotropic etch process can be performed to etch portions of the first gate dielectric material layer 60L that are proximal to the bit-line trenches 99 or overlie the topmost semiconductor rails 10. The second selective isotropic etch process can etch the first gate dielectric material selectively to the materials of the semiconductor rails 10 and the first gate electrode material layers 68S. For example, a wet etch process (e.g., a dilute hydrofluoric acid etch process) that isotropically etches the first gate dielectric material selectively to the materials of the semiconductor rails 10 and the first gate electrode material layers 68S may be employed. The second selective isotropic etch process patterns the first gate dielectric material layer 60L into a one-dimensional array of first gate dielectric layers 60S that are laterally spaced apart along the first horizontal direction hd1. Each first gate dielectric layer 60S may surround a respective two-dimensional array of semiconductor rails 10 (e.g., each first gate dielectric layer 60S may have a rectangular array of perforations through which a respective two-dimensional array of semiconductor rails 10 laterally extends along the first horizontal direction hd1, as shown in FIG. 10D). Each first gate dielectric layer 60S comprises a two-dimensional array of tubular portions having a respective rectangular vertical cross-sectional shape (in case the cut plane is perpendicular to the first horizontal direction hd1) and a vertically-extending portion that is adjoined to ends of the two-dimensional array of tubular portions. Tips of the first dielectric plates 62 that protrude beyond the ends of the first gate electrode material layers 68S along the first horizontal direction hd1 may be thinned during the second selective isotropic etch process if the first dielectric plates 62 comprise the same material (e.g., silicon oxide) as the first gate dielectric layers 60S.

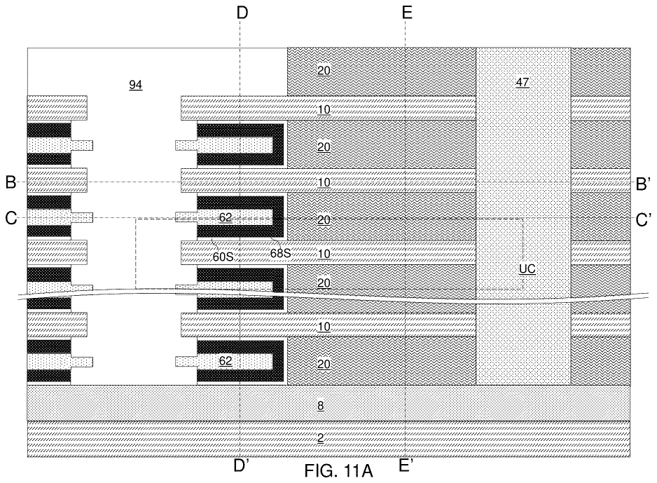

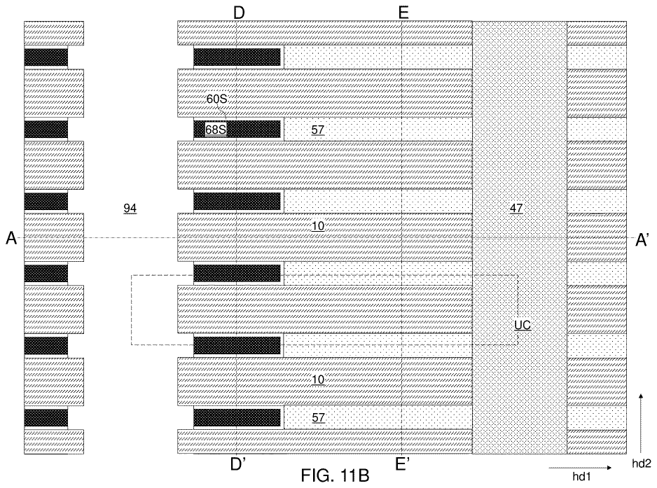

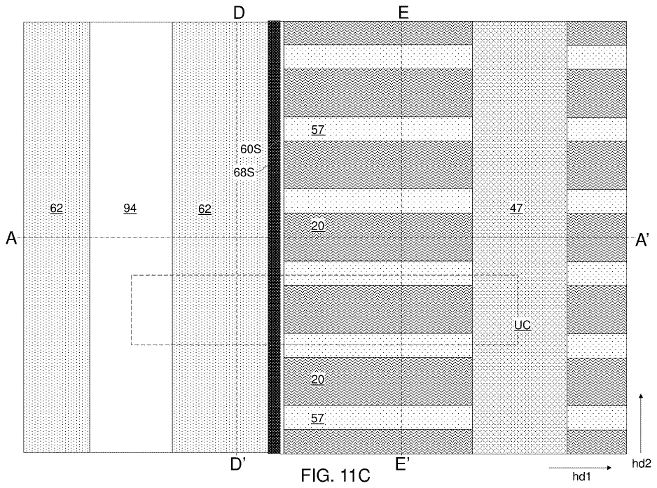

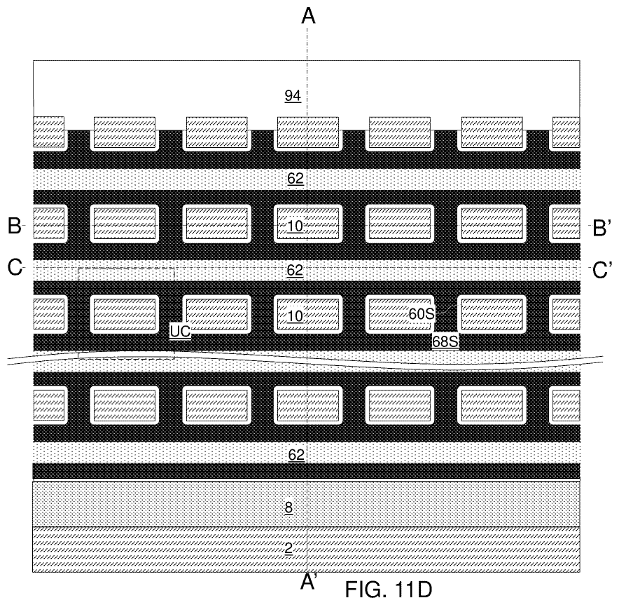

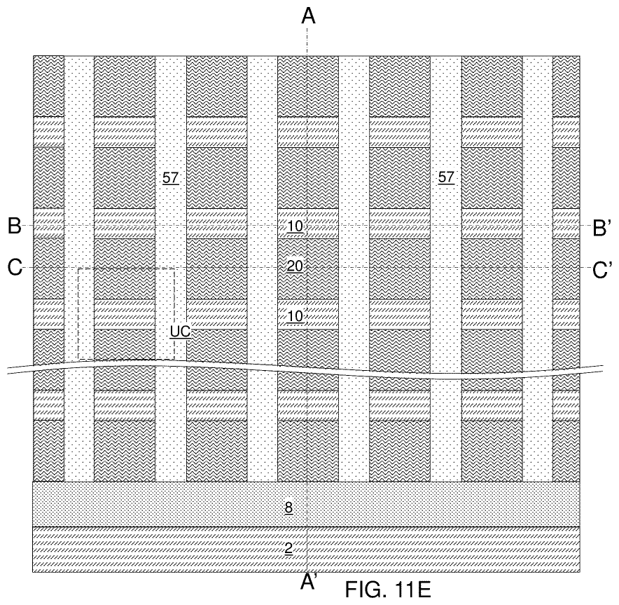

Referring to FIGS. 11A, 11B, 11C, 11D, and 11E, a dielectric fill material, such as undoped silicate glass (i.e., silicon oxide) or a doped silicate glass, can be deposited in the bit-line trenches 99. A planarization process, such as a chemical mechanical polishing process, can be performed to remove portions of the dielectric fill material from above the horizontal plane including the top surfaces of the sacrificial source trench fill structures 47. Each remaining portion of the dielectric fill material that fills the bit-line trenches 99 comprises a bit-line trench isolation structure 94. In one embodiment, top surfaces of the bit-line trench isolation structures 94 may be formed within the horizontal plane including the top surfaces of the sacrificial source trench fill structures 47. A laterally alternating sequence of bit-line trench isolation structures 94 and sacrificial source trench fill structures 47 can be arranged along the first horizontal direction hd1.

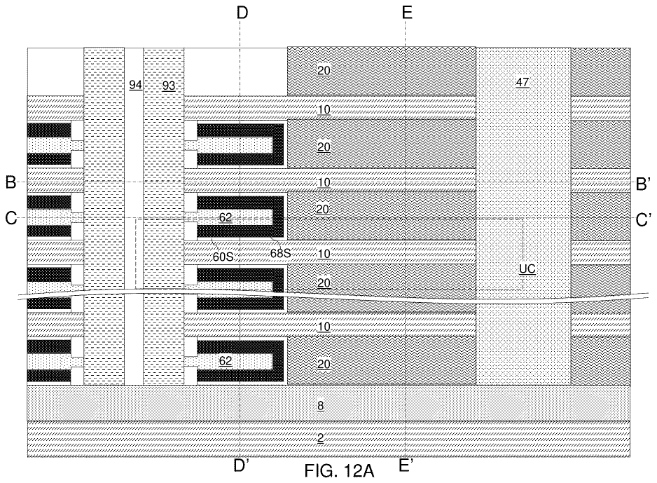

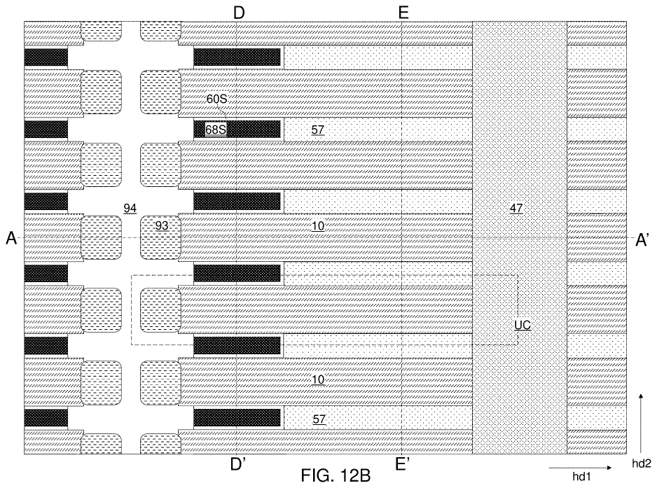

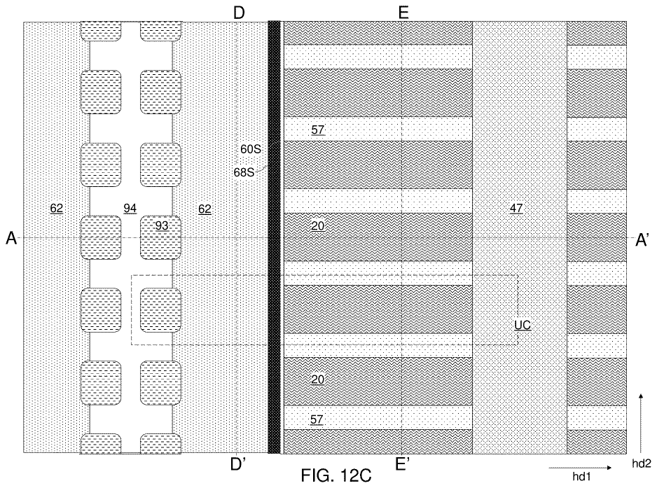

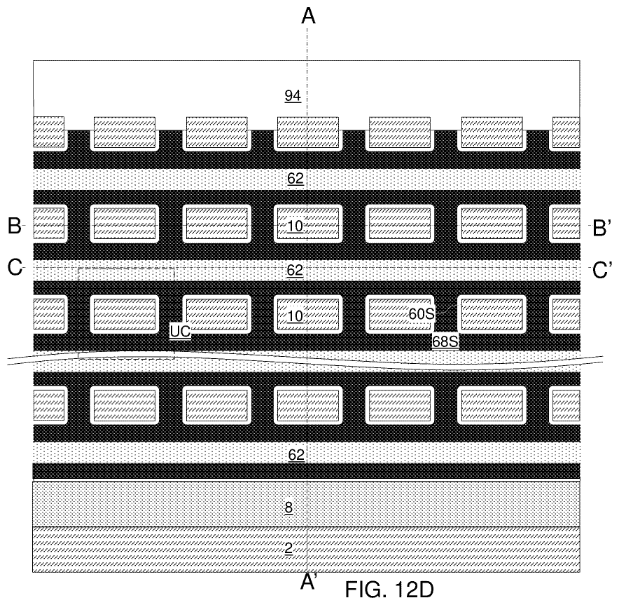

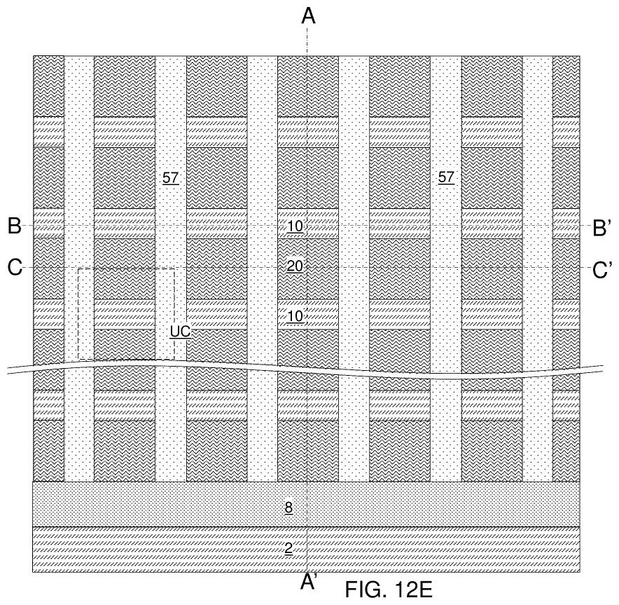

Referring to FIGS. 12A, 12B, 12C, 12D, and 12E, a photoresist layer (not shown) can be applied over the first exemplary structure, and can be lithographically patterned to form a total of L×M openings over the bit-line trench isolation structures 94. Each opening in the photoresist layer over a respective bit-line trench isolation structure 94 may have an areal overlap in a plan view with a respective vertical stack of (N+1) interfaces between (N+1) semiconductor rails 10 and a bit-line trench isolation structure 94. In one embodiment, each vertical stack of (N+1) semiconductor rails 10 includes a topmost semiconductor rail 10 that is employed as a dummy structure (i.e., a non-functional component) and N underlying semiconductor rails 10 located within a respective unit cell UC in the three-dimensional L×M×N array of unit cells.

An anisotropic etch process can be performed to transfer the pattern of the openings in the photoresist layer through the bit-line trench isolation structures 94 and first end segments of the semiconductor rails 10. Bit-line via cavities 95 vertically extending down to the etch stop structure 8 (if present) can be formed through the bit-line trench isolation structures 94. The photoresist layer can be subsequently removed, for example, by ashing.

As discussed above, instances of the unit cell UC are repeated L times along the first horizontal direction hd1, and are repeated M times along the second horizontal direction hd2. Each bit-line via cavity can be formed such that sidewalls of a respective vertical stack of (N+1) semiconductor rails 10 are physically exposed to each bit-line via cavity. In case L/2 bit-line trench isolation structures 94 are present, a 2×M rectangular array of bit-line via cavities can be formed through each of the bit-line trench isolation structures 94. In case (L/2 +1) bit-line trench isolation structures 94, a 2×M rectangular array of bit-line via cavities can be formed through each of the bit-line trench isolation structures 94 which is not an outermost bit-line trench isolation structure 94, and a 1×M rectangular array of bit-line via cavities can be formed through each of the two outermost bit-line trench isolation structures 94.

A sacrificial fill material can be deposited in the bit-line via cavities, and a planarization process (such as a chemical mechanical polishing process or a recess etch process) can be performed to remove the sacrificial fill material from above the horizontal plane including the topmost surfaces of the bit-line trench isolation structures 94. Each remaining portion of the sacrificial fill material that fills a respective bit-line via cavity constitutes a sacrificial bit-line structures 93. An L×M two-dimensional array of sacrificial bit-line structures 93 can be formed. In an illustrative example, the sacrificial bit-line structures 93 may comprise silicon nitride, a carbon-based material, a porous organosilicate glass, a polymer material, or a silicon-germanium compound semiconductor material. In some embodiments, the sacrificial bit-line structures 93 may comprise the same material as the sacrificial source trench fill structures 47. Each sacrificial bit-line structure 93 contacts first sidewalls of a respective vertical stack of (N+1) semiconductor rails 10. In some embodiments, top portions of the sacrificial bit-line structures 93 may be replaced with an etch stop capping structure to provide protection during subsequent replacement of second portions of the semiconductor rails 10 with storage devices 200 described below.

In an alternative embodiment, the bit-line via cavities 95 can vertically extend down to the substrate 2 if the etch stop structure 8 is omitted. In this case, the tips of the semiconductor rails 10 are not exposed in the bit-line via cavities 95. The exposed portion of the substrate 2 are oxidized to form a semiconductor oxide (e.g., silicon oxide) dielectric etch stop structure at the bottom of the bit-line via cavities 95. The width of the bit-line via cavities 95 is then expanded by selective etching to expose the tips of the tips of the semiconductor rails 10. The sacrificial bit-line structures 93 are then formed in the bit-line via cavities 95 in contact with the tips of the semiconductor rails 10.

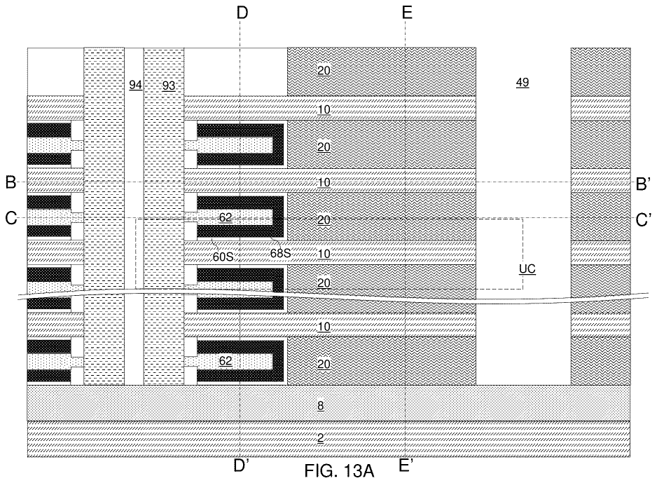

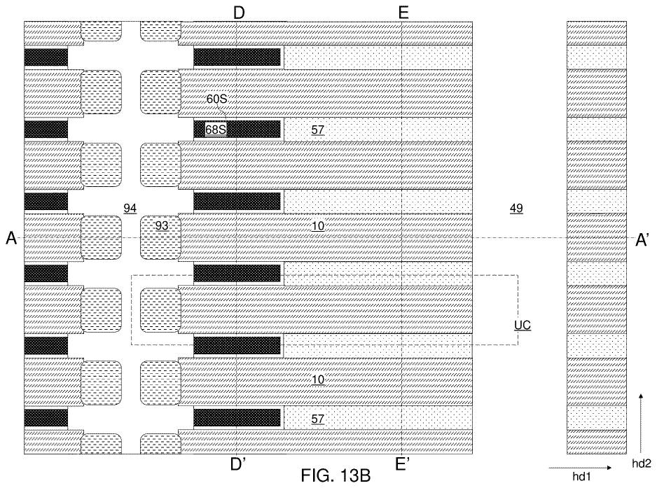

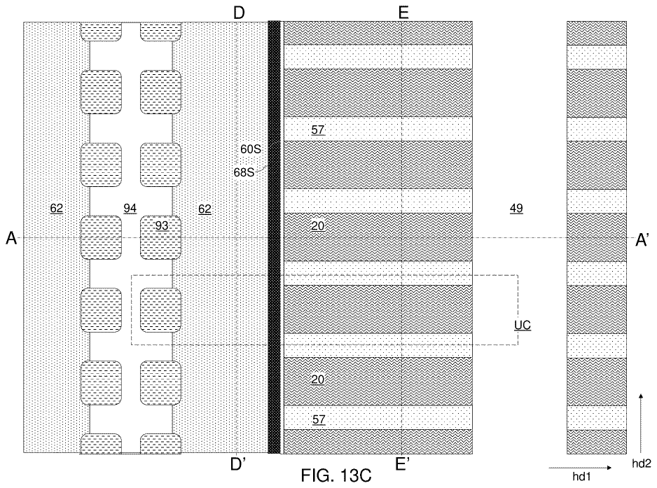

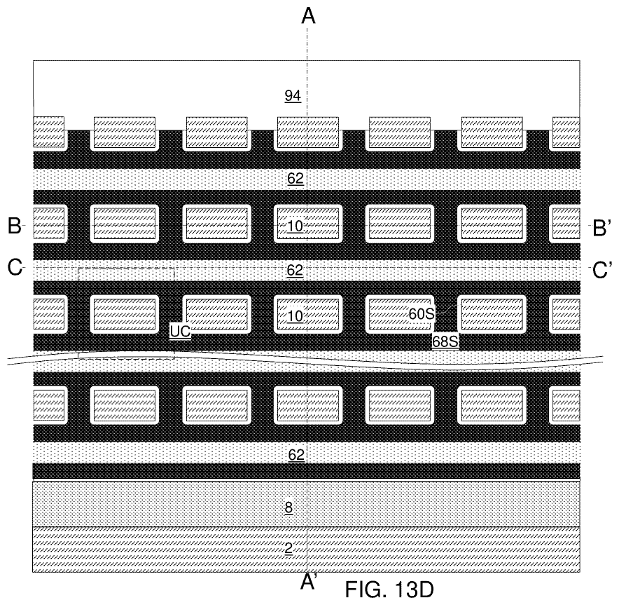

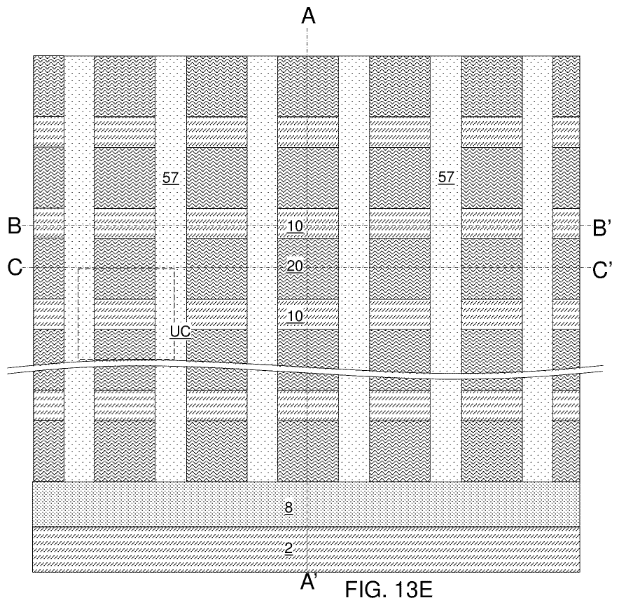

Referring to FIGS. 13A, 13B, 13C, 13D, and 13E, a third selective material removal process can be performed to remove the sacrificial source trench fill structures 47 selectively to the materials of the semiconductor rails 10, the sacrificial rails 20, and the sacrificial isolation trench fill structure 57. In some embodiments, a patterned etch mask layer (not shown), such as a patterned photoresist layer, may be employed to cover the sacrificial bit-line structure 93 and to prevent collateral removal of the sacrificial bit-line structure 93 during removal of the sacrificial source trench fill structures 47. Voids are formed in the source trenches 49, i.e., in the volumes from which the sacrificial source trench fill structures 47 are removed.

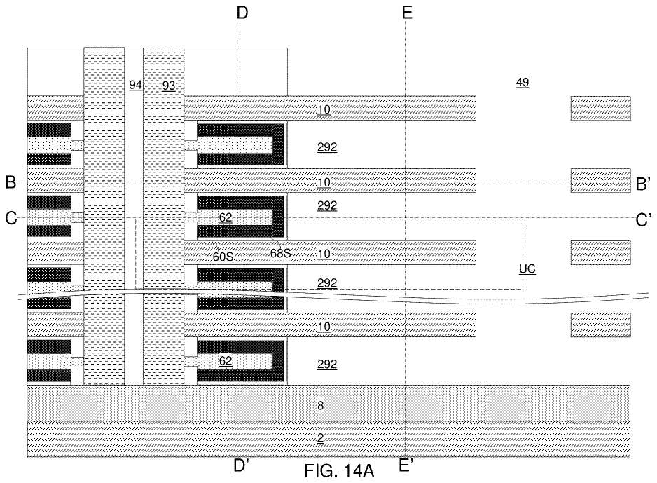

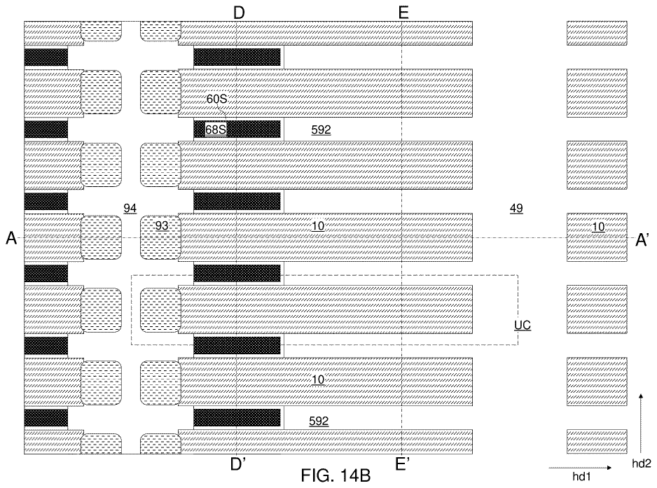

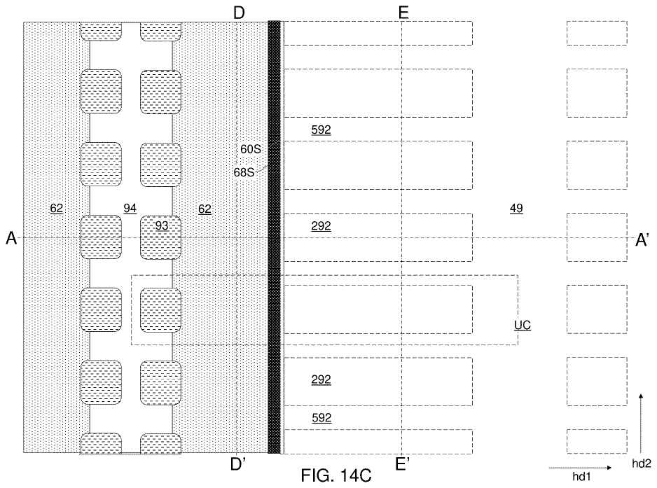

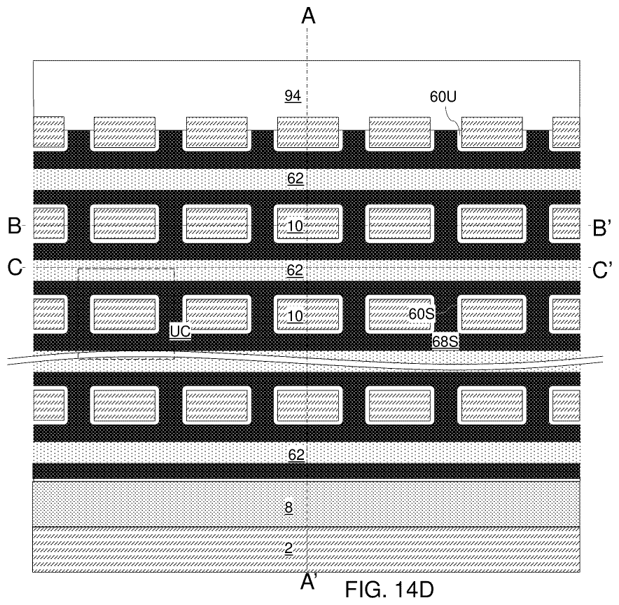

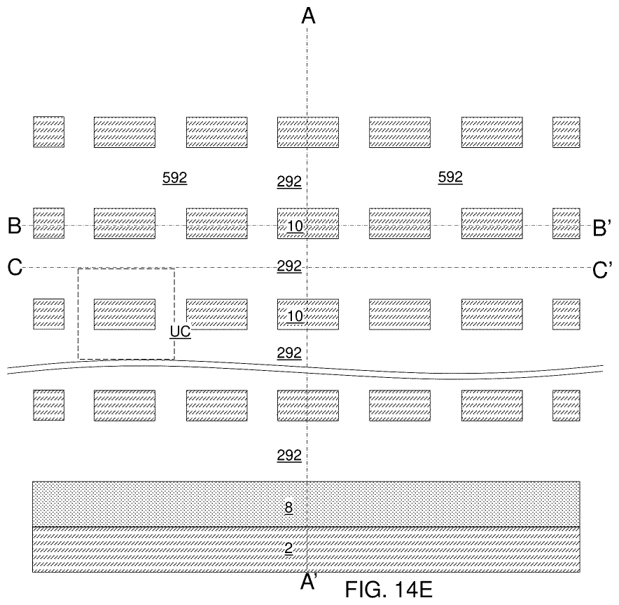

Referring to FIGS. 14A, 14B, 14C, 14D, and 14E, at least one fourth selective material removal process may be performed to remove a second portion (i.e., a remaining portion) of each of the horizontally-extending sacrificial rails 20 and to remove a second portion (i.e., a remaining portion) of each of the sacrificial isolation trench fill structures 57 that are proximal to the voids within the volumes of the source trenches 49. Second lateral isolation trenches 592 are formed in the volumes from which the second portions of the sacrificial isolation trench fill structures 57 are removed. The second lateral isolation trenches 592 are formed between laterally-neighboring pairs of second portions of the horizontally-extending semiconductor rails 10 by removing the second portion of each of the sacrificial isolation trench fill structures 57. Second inter-rail cavities 292 are formed in the volumes from which the second portions of the sacrificial rails 20 are removed. The second inter-rail cavities 292 are formed between vertically-neighboring pairs of second portions of the horizontally-extending semiconductor rails 10 by removing the second portion of each of the horizontally-extending sacrificial rails 20.

In case the sacrificial isolation trench fill structures 57 and the sacrificial rails 20 comprise different materials, the at least one fourth selective material removal process may comprise a set of two fourth selective material removal processes, each of which removes a respective material selected from the materials of the sacrificial isolation trench fill structures 57 and the sacrificial rails 20. In this case, removal of the material of the sacrificial isolation trench fill structures 57 may precede or follow removal of the material of the sacrificial rails 20. Alternatively, if the sacrificial isolation trench fill structures 57 and the sacrificial rails 20 comprise the same sacrificial material, removal of the materials of the sacrificial isolation trench fill structures 57 and the sacrificial rails 20 may proceed simultaneously. Generally, the duration of each of the at least one second selective material removal process may be selected such that the entirety of remaining portions of the sacrificial isolation trench fill structures 57 and the sacrificial rails 20 is removed selectively to the first gate dielectric layers 60S and the semiconductor rails 10. Each semiconductor rail 10 comprises a respective second portion having a pair of physically exposed sidewalls, a physically exposed top surface, a physically exposed bottom surface, and a physically exposed end surface that is perpendicular to the first horizontal direction hd1. A two-dimensional M×N array of semiconductor rails 10 protrudes laterally along the first horizontal direction hd1 through a two-dimensional array of openings through a vertically-extending portion of each first gate dielectric layer 60S. An optional M×1 array of topmost semiconductor rails 10 overlies the M×N array of semiconductor rails 10 while contacting, but without extending through an opening in, the vertically-extending portion of each topmost first gate dielectric layer 60U, as shown in FIG. 14D. The etch mask layer can be subsequently removed, for example, by ashing.

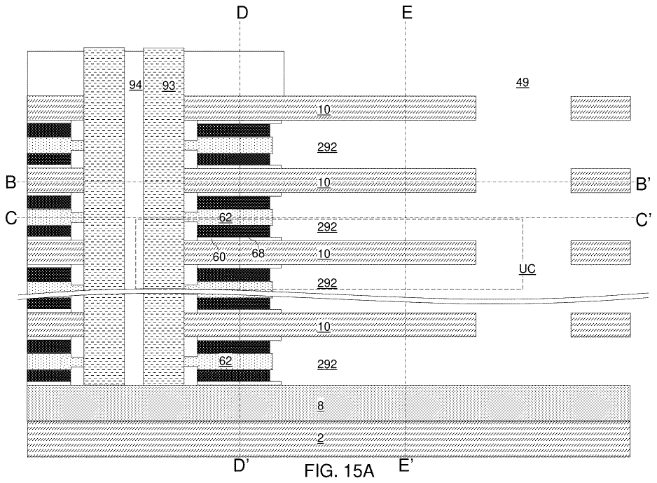

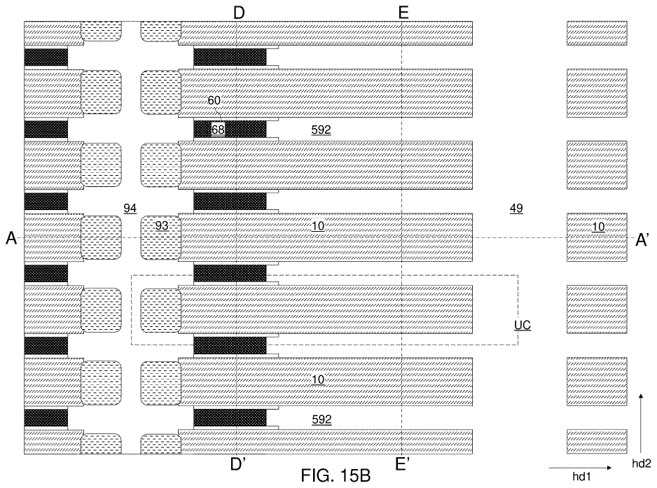

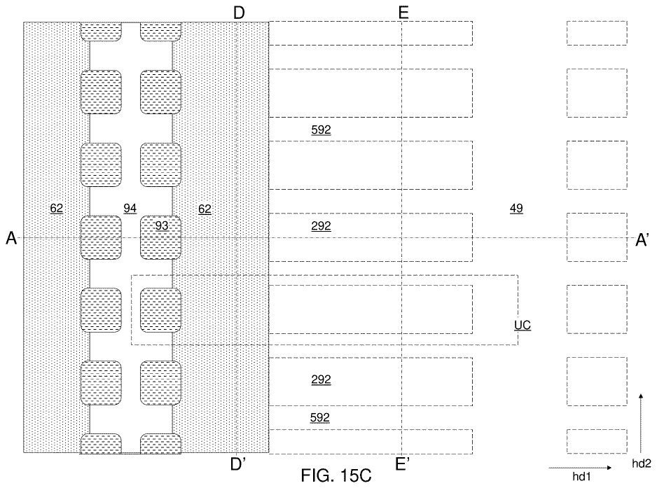

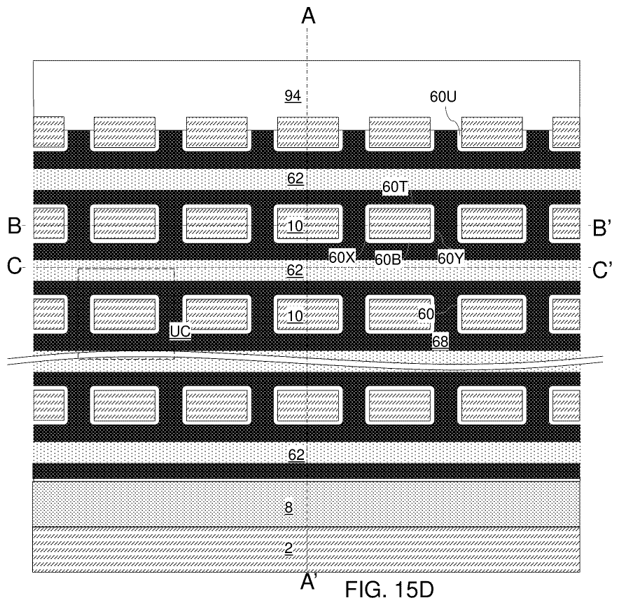

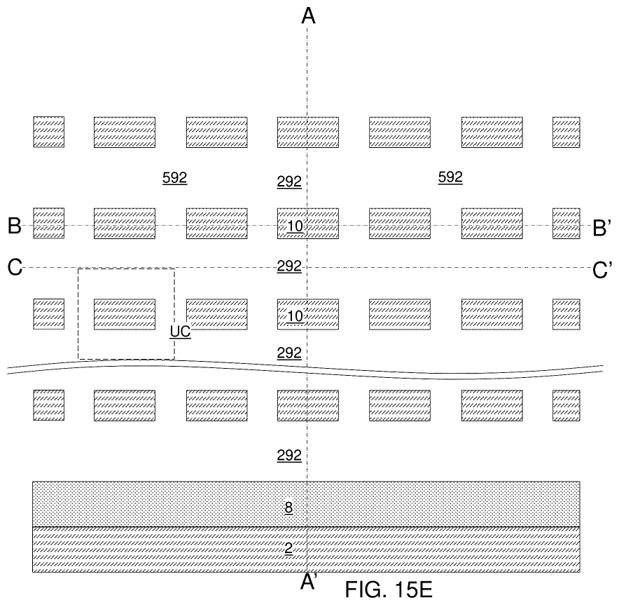

Referring to FIGS. 15A, 15B, 15C, 15D, and 15E, a first selective isotropic etch process, such as a first wet etch process, can be performed to etch each vertically-extending portion of the first gate dielectric layers 60S selectively to the semiconductor rails 10. Remaining portions of each first gate dielectric layer 60S comprise a respective M×N array of tubular gate dielectrics 60, which are also referred to as first gate dielectrics 60. Remaining portions of each topmost first gate dielectric layer 60S may further comprise a respective M×1 array of additional gate dielectrics contacting bottom portions of an M×1 array of topmost semiconductor rails 10. Each first gate dielectric layer 60S is divided into a respective two-dimensional M×N array of first gate dielectrics 60 and additional gate dielectrics. Thus, the L first gate dielectric layers 60S are divided into a three-dimensional array of first gate dielectrics 60 having a respective tubular configuration, and a two-dimensional array of additional first gate dielectrics 60U having a respective U-shaped configuration (which is a non-tubular configuration), as shown in FIG. 15D.

A second selective isotropic etch process, such as a second wet etch process, can be performed to isotropically recess the first gate electrode material layers 68S selectively to the semiconductor rails 10. Optionally, the etch distance may be greater than the lateral extent of the first gate electrode material layers 68S along the first horizontal direction hd1 at the levels of the first dielectric plates 62. Thus, each first gate electrode material layer 68S can be divided into (N+2) discrete conductive material portions. Each of N discrete conductive material portions that are patterned from each first gate electrode material layer 68S comprises a first word line 68 that laterally extends along the second horizontal direction hd2 and laterally surrounds semiconductor channels of M semiconductor rails 10 that are arranged along the second horizontal direction hd2. Thus, each first word line 68 comprises an assembly of M first gate electrodes that are adjoined to each other along the second horizontal direction hd2. The duration of the second selective isotropic etch process can be selected to optimize the gate length of the first word lines 68, i.e., the lateral extent of the first word lines 68 along the first horizontal direction hd1 which is the channel direction of access transistors to be subsequently formed. Each of the first dielectric plates 62 may comprise a respective end surface that is physically exposed to a respective row of second inter-rail cavities 292, and may comprise a respective physically exposed top surface segment and a respective physically exposed bottom surface segment. Each first gate dielectric 60 having a tubular configuration may comprise a respective set of physically exposed surface segments that are parallel to the first horizontal direction hd1.

Remaining portions of each first gate electrode material layer 68S comprise a vertical stack of N first word lines 68, a bottommost electrically conductive strip that contacts a bottom surface of a bottommost dielectric plate 62, and a topmost electrically conductive strip that contacts a top surface of a topmost dielectric plate 62. The topmost semiconductor rail 10 within each vertical stack of (N+1) semiconductor rails 10 may function as a dummy structure, and is not used as active component of an L×M×N cubic three-dimensional array of unit cells. Each first gate electrode material layer 68S is divided into a respective vertical stack of N first word lines 68. Thus, the L first gate electrode material layers 68S are divided into an L×N two-dimensional array of first word lines 68 that laterally extends along the second horizontal direction hd2.

Generally, the first gate dielectric material and the first gate electrode material can be patterned into a three-dimensional array of first gate dielectrics 60 and a two-dimensional array of first word lines 68. Each of the L×M×N first gate dielectrics 60 contacting the L×M×N array of semiconductor rails 10 (which excludes the L×M×1 array of the topmost semiconductor rails 10) may comprise a respective tubular gate dielectric 60 that laterally surrounds the first portion of a respective horizontally-extending semiconductor rail 10. Each first word line 68 comprises M first gate electrodes that are merged along the second horizontal direction and wrap around a respective row of M tubular gate dielectrics 60 in a respective vertical cross-sectional view that is perpendicular to the first horizontal direction hd1, as shown in FIG. 15D. Each tubular gate dielectric 60 comprises a top dielectric portion 60T contacting a horizontal top surface of a respective horizontally-extending semiconductor rail 10, a bottom dielectric portion 60B contacting a horizontal bottom surface of the respective horizontally-extending semiconductor rail 10, and a pair of sidewall dielectric portions (60X, 60Y) contacting a pair of sidewalls of the respective horizontally-extending semiconductor rail 10, as shown in FIG. 15D. Each of the top dielectric portion, the bottom dielectric portion, and the pair of sidewall dielectric portions is contacted by a first gate electrode, which is a portion of a respective one of the first word lines 68.

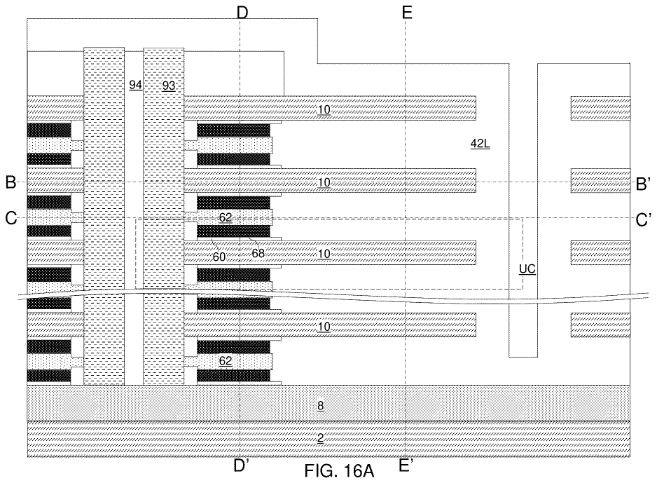

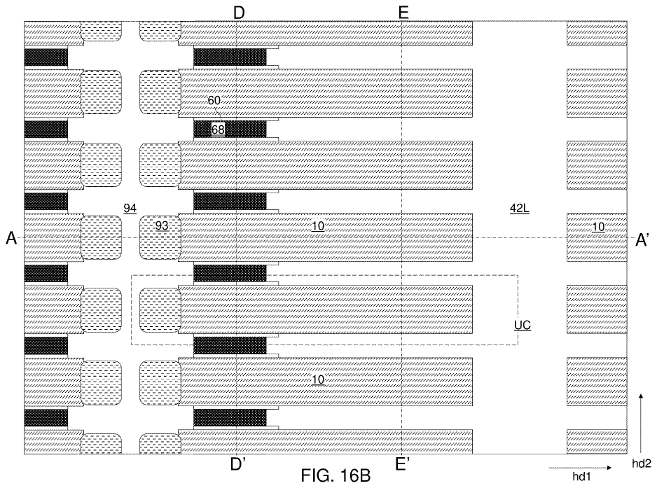

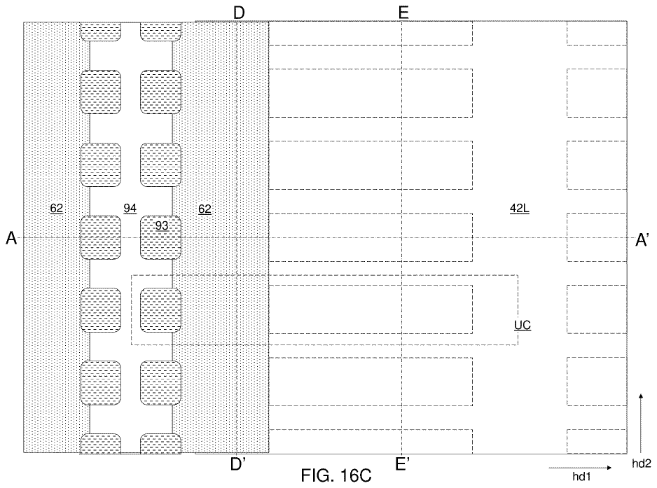

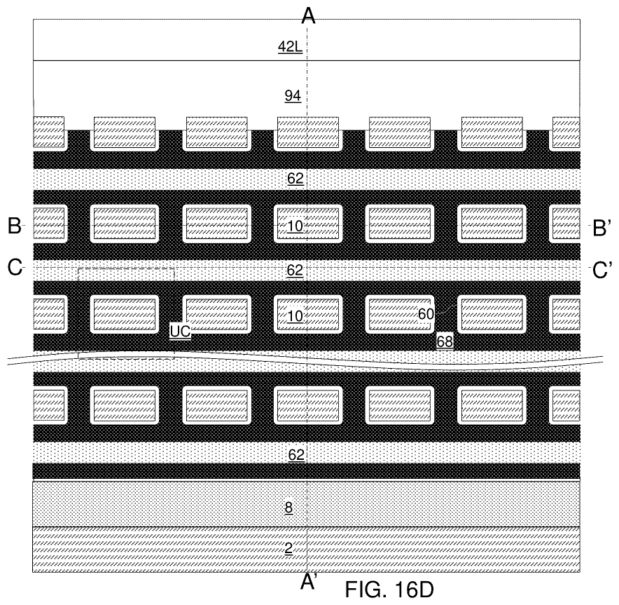

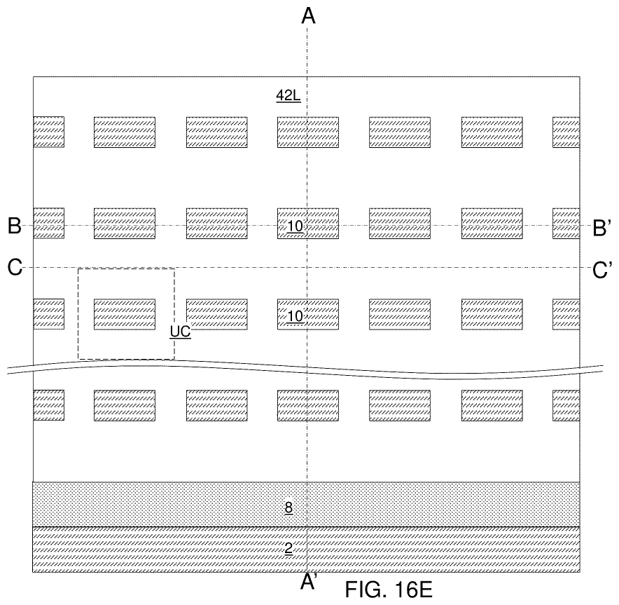

Referring to FIGS. 16A, 16B, 16C, 16D, and 16E, a dielectric matrix material layer 42L can be conformally deposited to fill the entire volume of the second lateral isolation trenches 592 and the second inter-rail cavities 292 and peripheral portions of the source trenches 49 without filling center portions of the source trenches 49. The dielectric matrix material layer 42L comprises a dielectric fill material, such as undoped silicate glass or a doped silicate glass, and can be deposited by a conformal deposition process such as a chemical vapor deposition or an atomic layer deposition process.

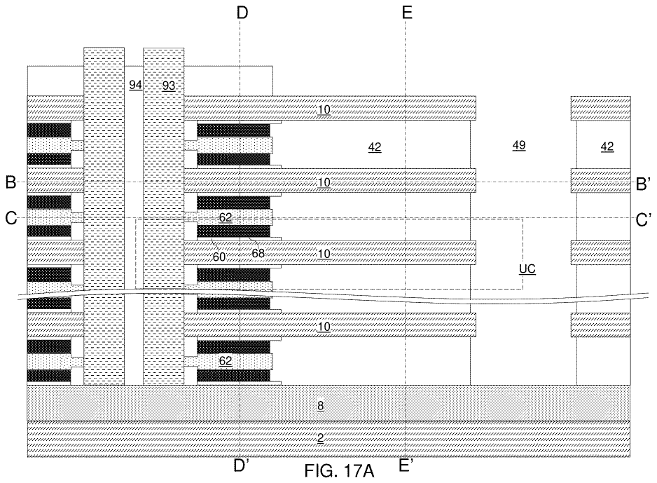

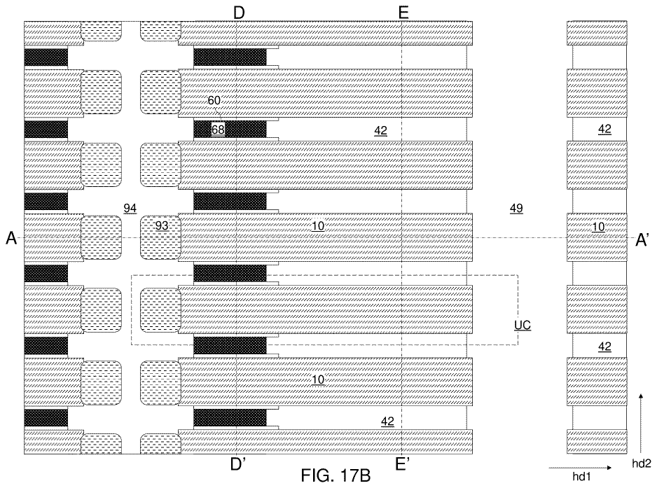

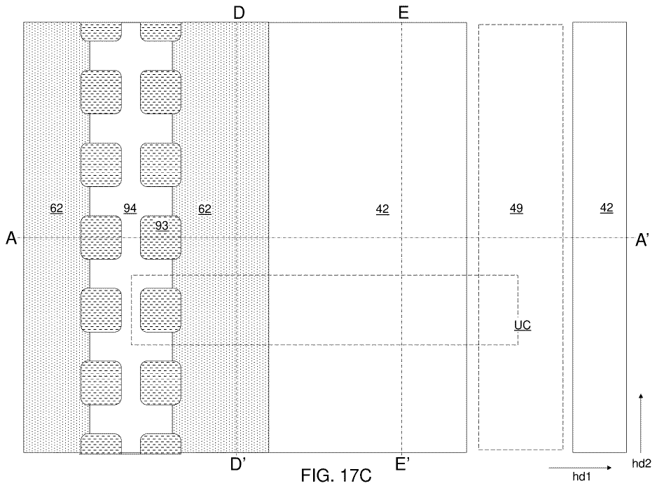

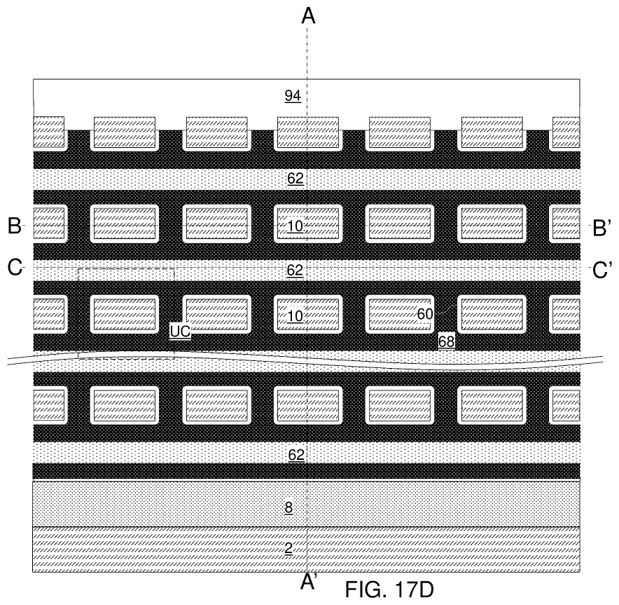

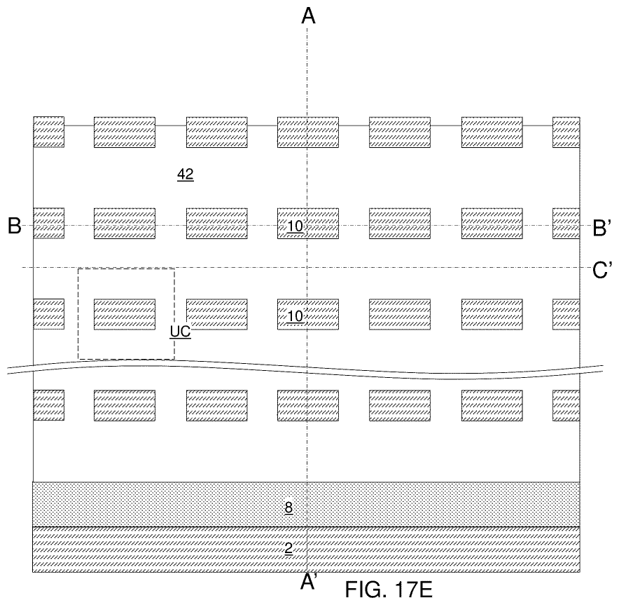

Referring to FIGS. 17A, 17B, 17C, 17D, and 17E, a recess etch process can be performed to etch the dielectric matrix material layer 42L from around the unfilled volumes of the source trenches 49 and from above the topmost semiconductor rails 10. The dielectric matrix material layer 42L can be removed from inside the volumes of the source trenches 49. Remaining portions of the dielectric matrix material layer 42L that laterally surround the second portions of the semiconductor rails 10 constitute perforated dielectric matrices 42. Thus, the dielectric matrix material layer 42L is patterned into a one-dimensional array of L perforated dielectric matrices 42 that are arranged along the first horizontal direction hd1. Each perforated dielectric matrix 42 within the one-dimension array of perforated dielectric matrices 42 includes a respective two-dimensional M×N array of perforations that laterally extend along the first horizontal direction hd1. Each of the perforated dielectric matrices 42 embeds a respective two-dimensional M×N array of semiconductor rails 10.

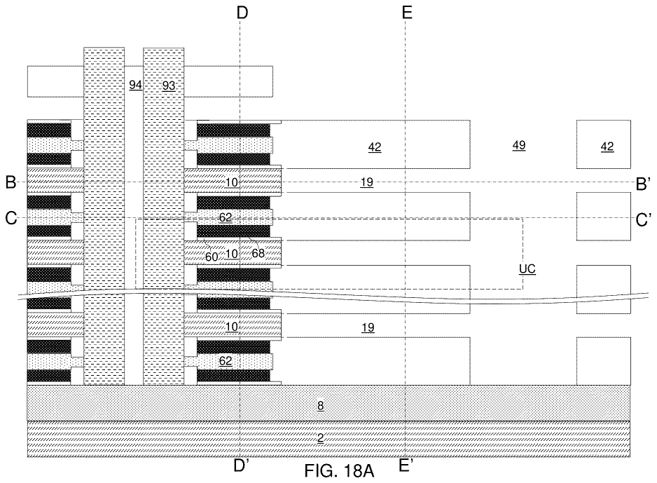

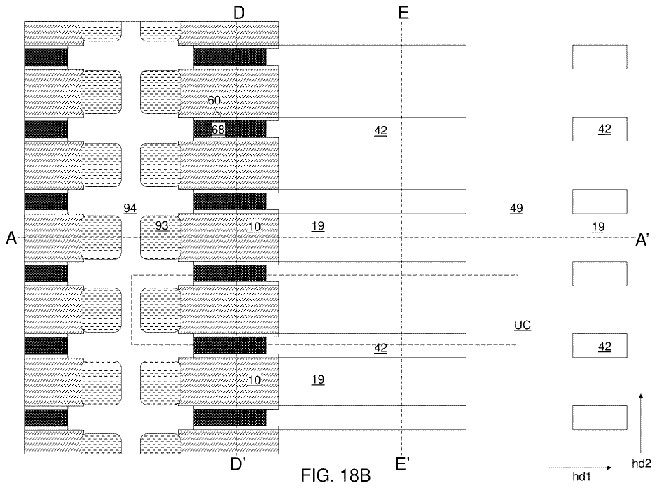

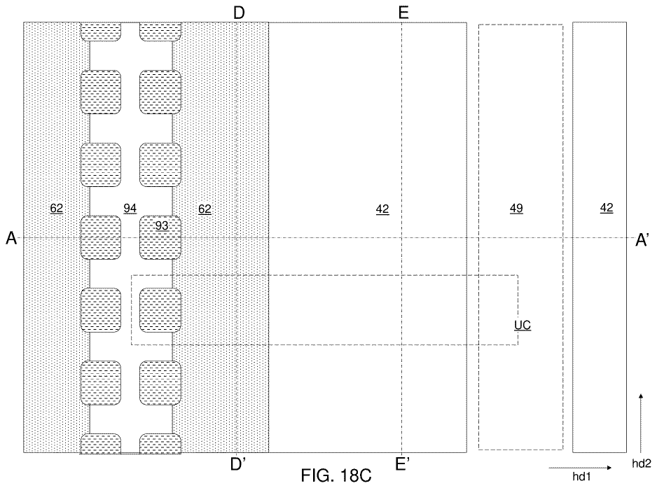

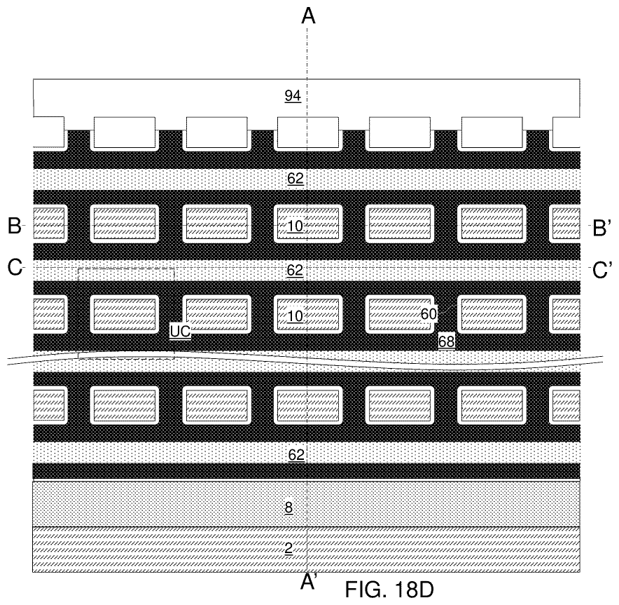

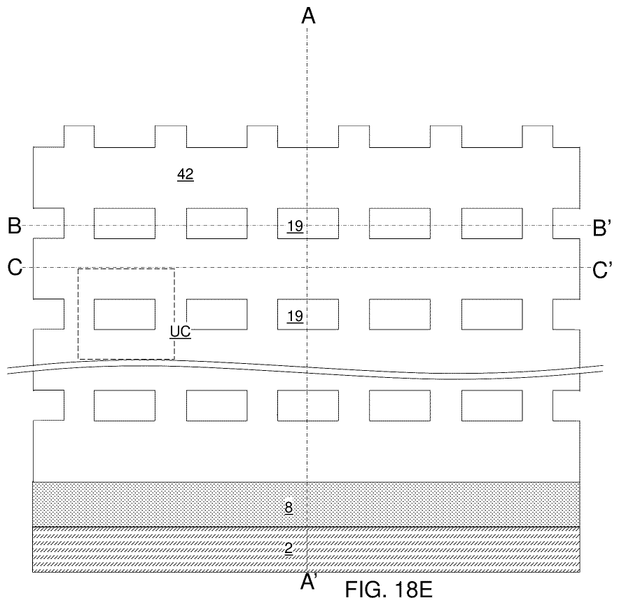

Referring to FIGS. 18A, 18B, 18C, 18D, and 18E, a selective isotropic etch process can be performed to isotropically etch the semiconductor material of the semiconductor rails 10 selectively to the materials of the perforated dielectric matrices 42, the first gate dielectrics 60, the bit-line trench isolation structures 94, and the sacrificial bit-line structures 93. for example, if the semiconductor rails 10 comprise silicon, then a wet etch process employing hot trimethyl-2 hydroxyethyl ammonium hydroxide (“hot TMY”) or tetramethyl ammonium hydroxide (TMAH) may be performed to isotropically etch the second portions of the semiconductor rails 10. The duration of the selective isotropic etch process can be selected such that the remaining portion of each semiconductor rail 10 has a sufficient channel length. For example, the lateral distance between a physically exposed sidewall of each remaining portion of the semiconductor rails 10 and a most proximal sidewall of a first word line 68 may be in a range from 3 nm to 30 nm, although lesser and greater lateral distances may also be employed. In one embodiment, the horizontal surfaces of the first word lines 68 are not physically exposed. Lateral recesses 19 are formed in the volumes from which the second portions of the semiconductor rails 10 are removed. Generally, a three-dimensional array of lateral recesses 19 can be formed by etching the second portions of the horizontally-extending semiconductor rails 10 selectively to the one-dimensional array of perforated dielectric matrices 42. If the etch stop structure 8 is omitted, portions of the substrate 2 underlying the source trenches 49 may also be etched.

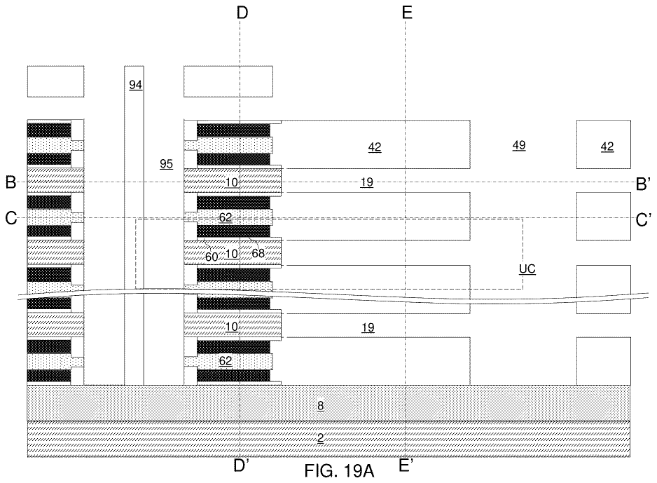

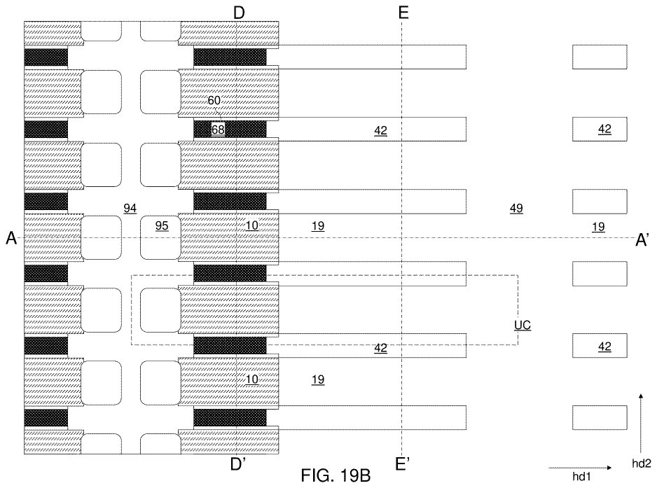

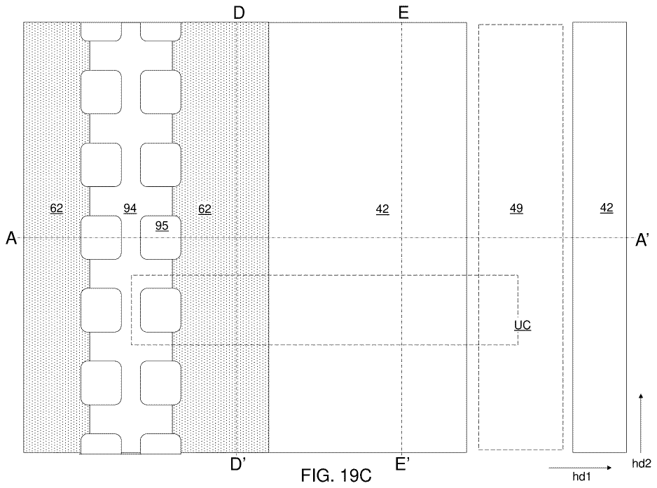

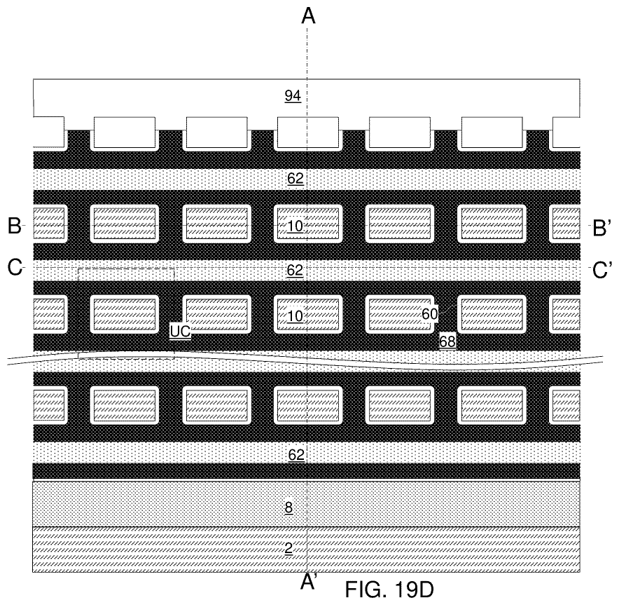

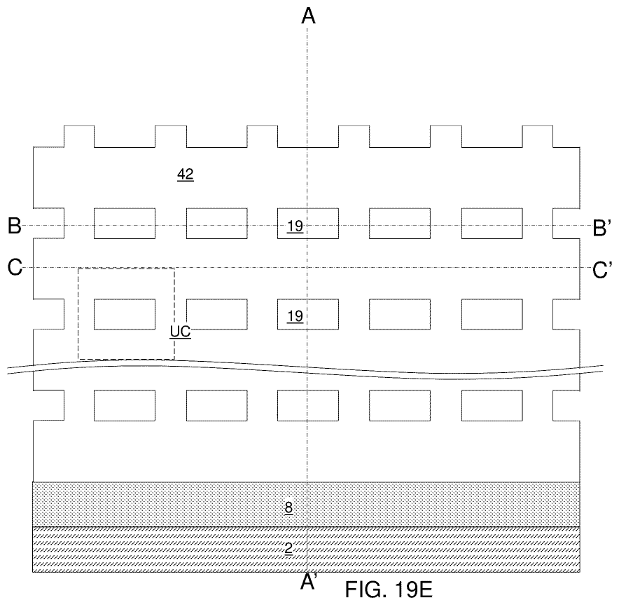

Referring to FIGS. 19A, 19B, 19C, 19D, and 19E, the sacrificial bit-line structures 93 can be removed selectively to the bit-line trench isolation structures 94 and the perforated dielectric matrices 42 by performing a selective etch process, which may comprise an isotropic etch process (such as a wet etch process) or an anisotropic etch process. Alternatively, if the sacrificial bit-line structures 93 comprise a carbon based material, then an ashing process may be used to remove the sacrificial bit-line structures 93. Voids are formed in the volumes of the bit-line via cavities 95. Each of the semiconductor rails 10 may comprise a first sidewall that is exposed to a respective one of the bit-line via cavities 95, and a second sidewall that is exposed to a respective one of the lateral recesses 19.

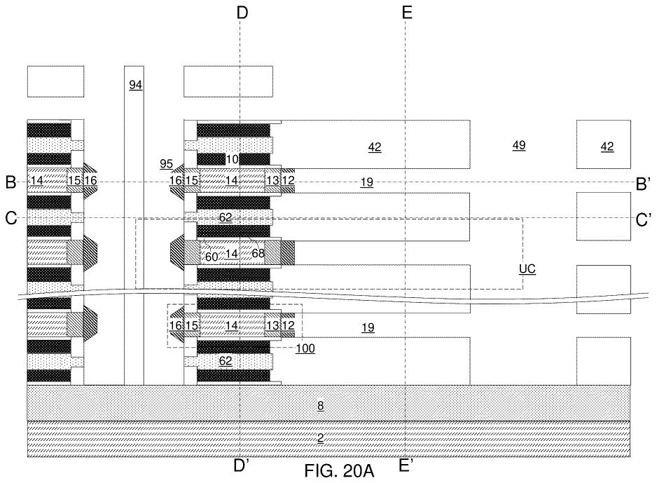

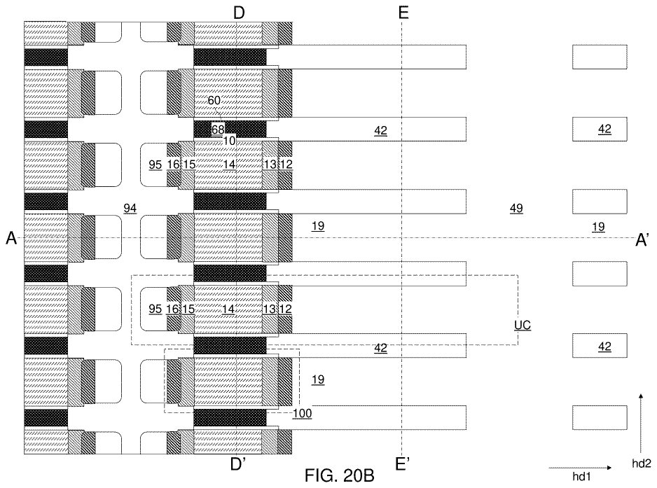

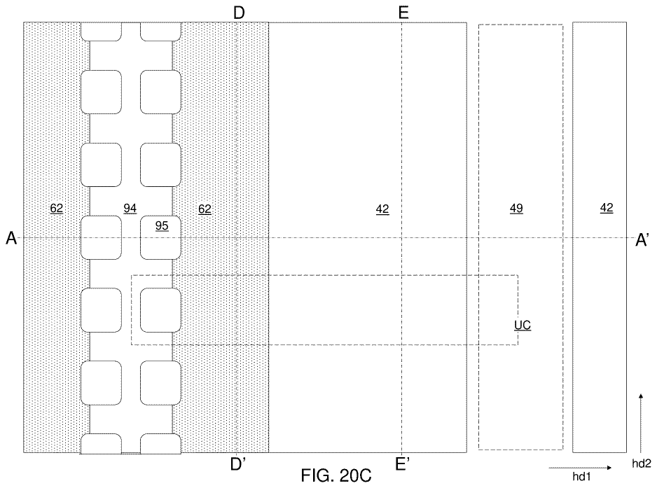

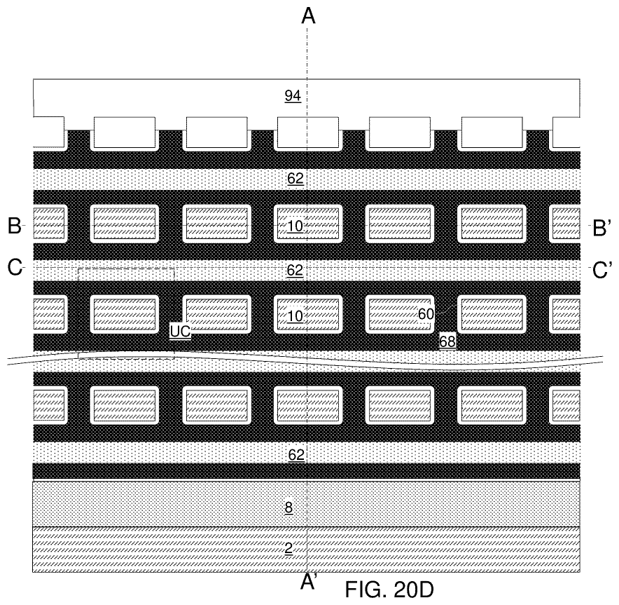

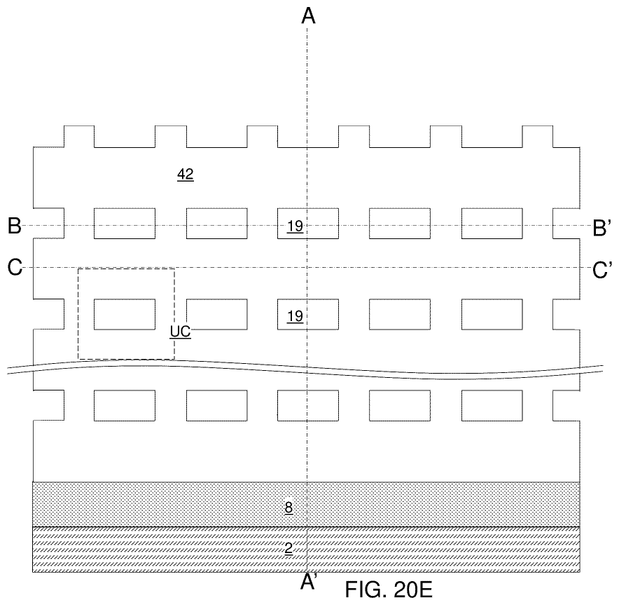

Referring to FIGS. 20A, 20B, 20C, 20D, and 20E, an optional extension region doping process may be performed to electrically dope edge portions of the semiconductor rails 10 that are proximal to the physically exposed sidewall surfaces of semiconductor rails 10. For example, a gas phase doping process or an outdiffusion process employing a conformally deposited sacrificial doped silicate glass layer (such as a sacrificial phosphosilicate glass layer) may be employed to convert surface portions of the semiconductor rails 10 that are proximal to the lateral recesses 19 into source extension regions 13, and to convert surface portions of the semiconductor rails 10 that are proximal to the bit-line via cavities 95 into drain extension regions 15. Each remaining portion of the semiconductor rails 10 that is not converted into the source extension regions 13 or the drain extension regions 15 constitute horizontally-extending semiconductor channels 14. In one embodiment, the horizontally-extending semiconductor channels 14 may have a doping of a first conductivity type, and the source extension regions 13 and the drain extension regions 15 may have a doping of a second conductivity type that is the opposite of the first conductivity type. The extension regions (13, 15) may comprise lightly doped regions of the second conductivity type (e.g., n-type). Alternatively, formation of the source extension regions 13 and the drain extension regions 15 may be omitted.

A selective doped semiconductor deposition process can be performed to grow a doped semiconductor material having a doping of the second conductivity type from first physically exposed semiconductor surfaces of the first portions of the horizontally-extending semiconductor rails 10 that are exposed to the lateral recesses 19, and from second physically exposed semiconductor surfaces of the first portions of the horizontally-extending semiconductor rails 10 that are exposed to the bit-line via cavities 95. A selective semiconductor deposition process refers to a semiconductor deposition process that grows a semiconductor material from physically exposed semiconductor surfaces while suppressing growth of the semiconductor material from dielectric surfaces. In an illustrative example, a chemical vapor deposition process employing silane, disilane, or dichlorosilane as a reactant gas; hydrogen chloride as a reactant gas; and an optional carrier gas such as hydrogen, helium, and/or nitrogen can be employed to selectively grow doped silicon from the physically exposed surfaces of the semiconductor rails 10. A dopant gas such as arsine, phosphine, stibine, or diborane may be flowed into the process chamber concurrently, or alternately with, the reactant gas to dope the deposited semiconductor material with electrical dopants of the second conductivity type. Source regions 12 are formed on first sidewalls of the semiconductor rails 10 within the lateral recesses 19, and drain regions 16 are formed on second sidewalls of the semiconductor rails 10 within the bit-line via cavities 95. The source regions 12 and the drain regions 16 may comprise heavily doped regions of the second conductivity type, which have a higher dopant concentration than the optional extension regions (13, 15). The source regions 12 have the same horizontal cross-sectional shape in vertical cross-sectional views along vertical planes that are perpendicular to the first horizontal direction hd1 as the horizontal cross-sectional shapes of the lateral recesses 19 and the semiconductor rails 10 in vertical cross-sectional views along vertical planes that are perpendicular to the first horizontal direction hd1. The drain regions 16 have different horizontal cross-sectional shapes in vertical cross-sectional views along vertical planes that are perpendicular to the first horizontal direction hd1 that vary as a function of a lateral distance from a most proximal one among the semiconductor rails 10.

In one embodiment, the source regions 12 are formed on the first physically exposed semiconductor surfaces of the first portions of the horizontally-extending semiconductor rails 10 as formed at the processing steps of FIGS. 4A, 4B, 4C, 4D, and 4E within a fraction of volumes (i.e., the volumes of the lateral recesses 19) from which the second portions of the horizontally-extending semiconductor rails 10 are removed. Each first portion of the horizontally-extending semiconductor rails 10 comprises a respective second physically exposed semiconductor surface located on an opposite side of a respective one of the first physically exposed semiconductor surfaces. The selective semiconductor deposition process grows drain regions 16 on the second physically exposed semiconductor surfaces of the first portions of the horizontally-extending semiconductor rails 10. If the etch stop structure 8 is omitted, then a doped semiconductor region of the second conductivity type is also formed on the exposed, etched portion of the substrate 2.

A three-dimensional L×M×N array of access field effect transistors 100 can be formed. Each access field effect transistor 100 comprises a set of semiconductor material portions (12, 13, 14, 15, 16) and a pair of opposing gate electrodes (which are portions of two word lines 68) located above and below the set of semiconductor material portions. The set of semiconductor material portions (12, 13, 14, 15, 16) comprises a horizontally-extending semiconductor channel 14, a source region 12, and a drain region 16, and may optionally include a source extension region 13 and a drain extension region 15. In one embodiment, the horizontally-extending semiconductor channel 14 and the source region 12 have a same uniform vertical cross-sectional shape within any vertical cross-sectional view that cuts through the horizontally-extending semiconductor channel 14 or the source region 12 and is perpendicular to the first horizontal direction hd1 irrespective of a location of a vertical cut plane for a respective vertical cross-sectional view. In one embodiment, the drain region 16 is located on an opposite side of the source region 12 relative to the horizontally-extending channel region 14. In one embodiment, the drain region 16 has a variable vertical cross-sectional shape within vertical planes that are perpendicular to the first horizontal direction hd1 as a function of a lateral distance from the horizontally-extending semiconductor channel 14.

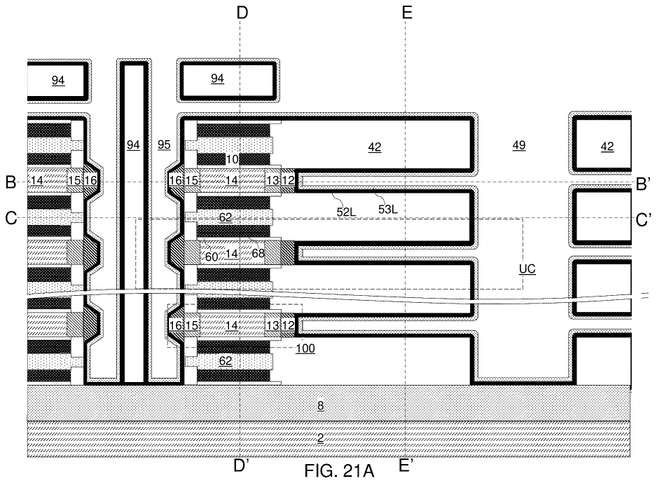

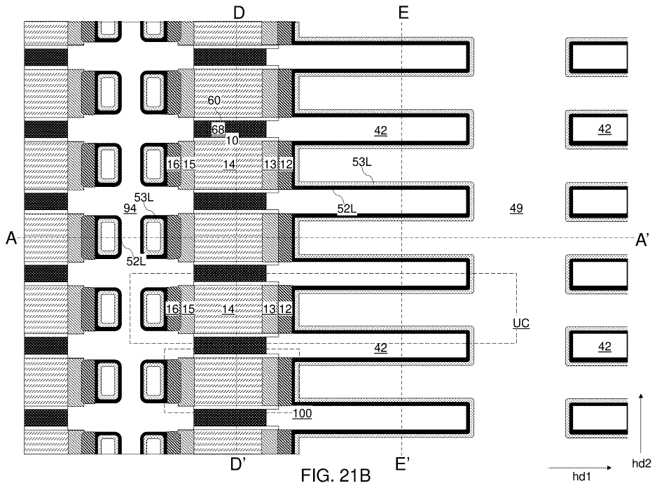

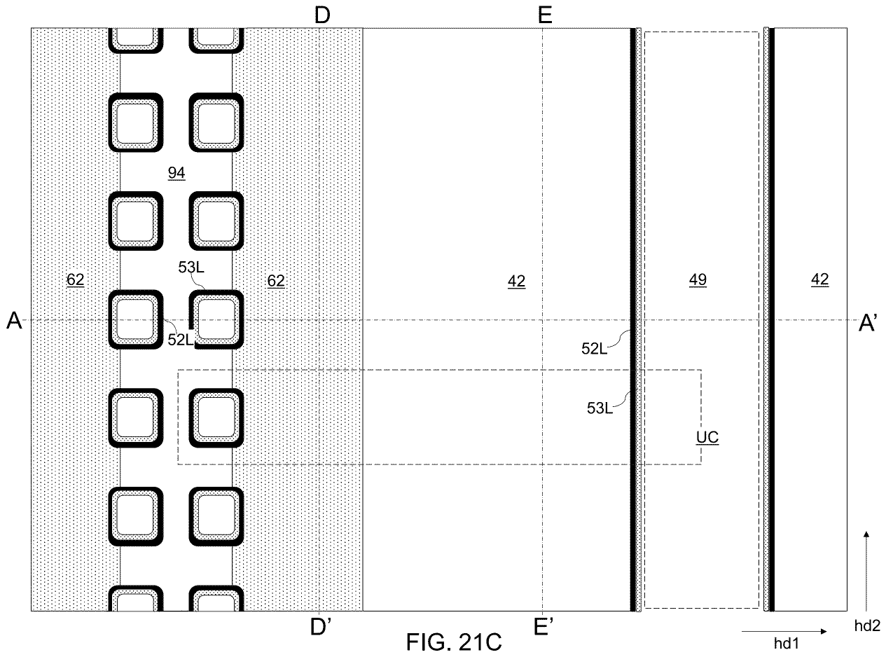

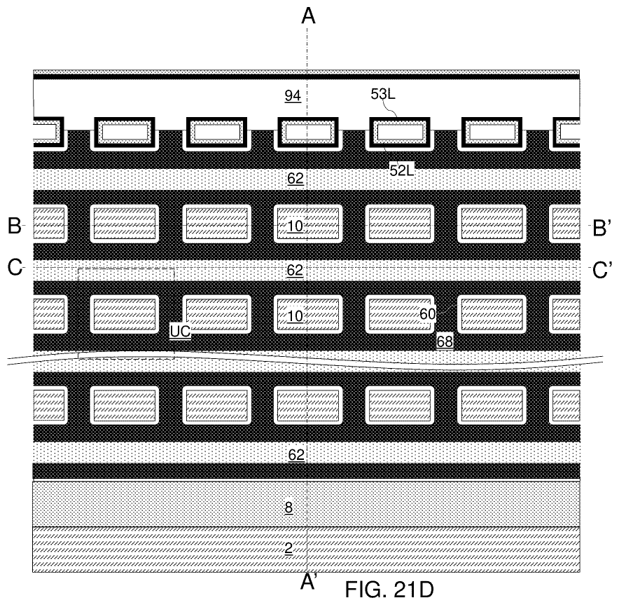

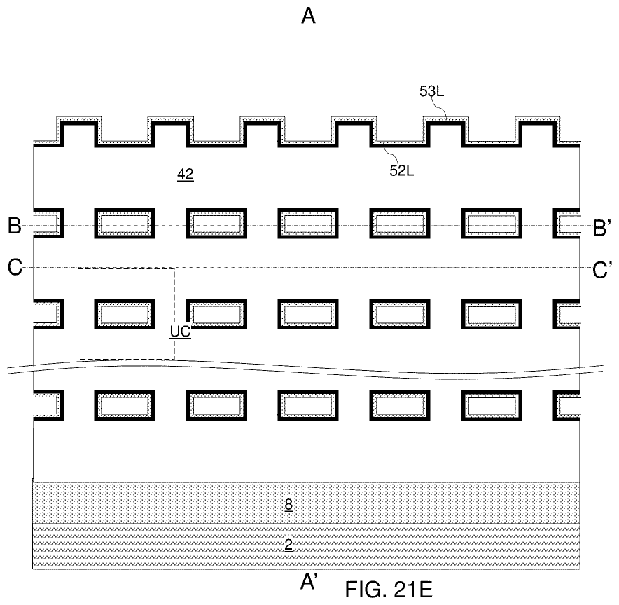

Referring to FIGS. 21A, 21B, 21C, 21D, and 21E, a first conductive material layer 52L and a sacrificial cover material layer 53L can be conformally deposited. The first conductive material layer 52L comprises a high conductivity conductive material, such as a metallic material. For example, the first conductive material layer 52L may comprise at least one metallic material such as TiN, TaN, WN, MoN, W, Ru and/or Mo. The first conductive material layer 52L may be deposited by a conformal deposition process such as a chemical vapor deposition process or an atomic layer deposition process. The thickness of the first conductive material layer 52L may be in a range from 2 nm to 40 nm, although lesser and greater thicknesses may also be employed.

The sacrificial cover material layer 53L comprises a material that can be subsequently employed as an etch mask material for etching portions of the first conductive material layer 52L. The sacrificial cover material layer 53L may comprise silicon nitride or a dielectric metal oxide material. The sacrificial cover material layer 53L may be deposited by a conformal deposition process such as a chemical vapor deposition process or an atomic layer deposition process. The thickness of the sacrificial cover material layer 53L may be in a range from 2 nm to 20 nm, although lesser and greater thicknesses may also be employed.

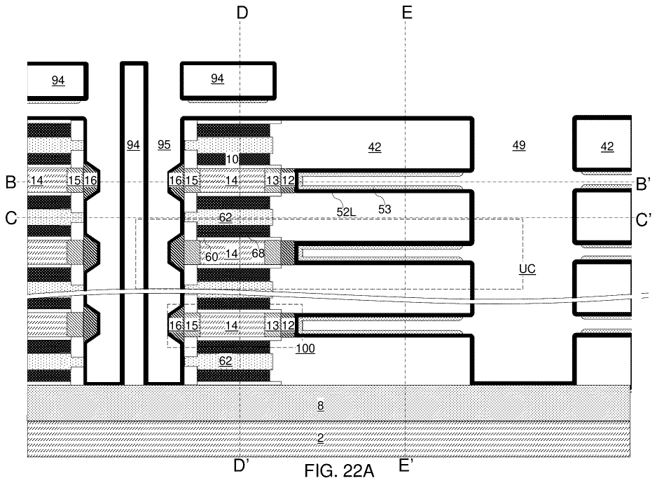

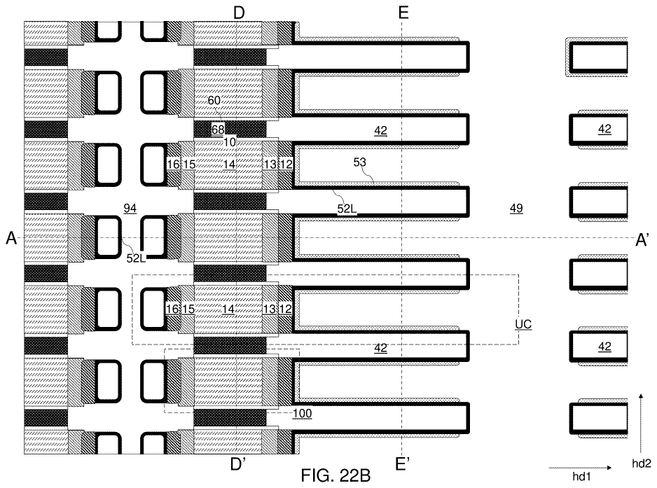

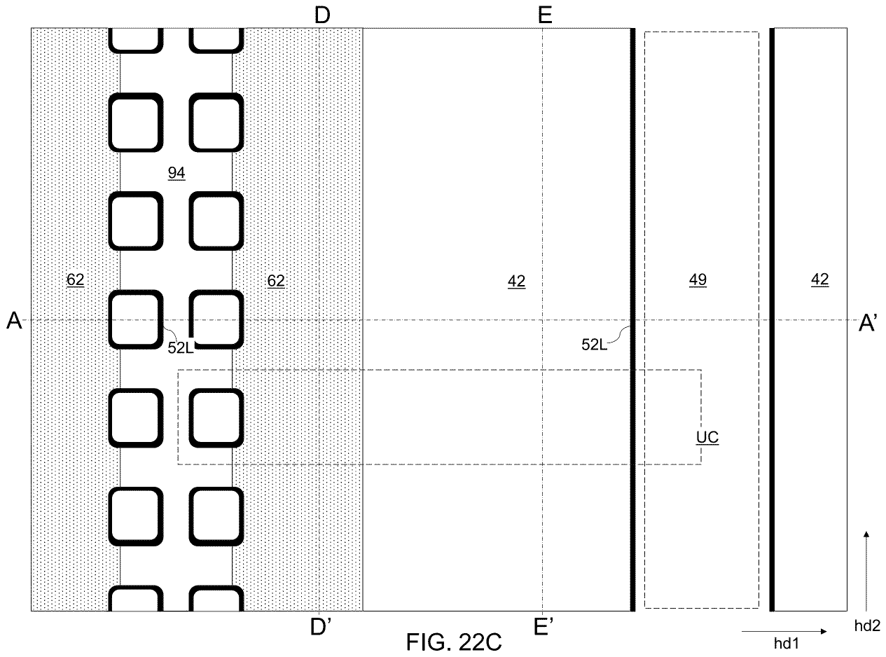

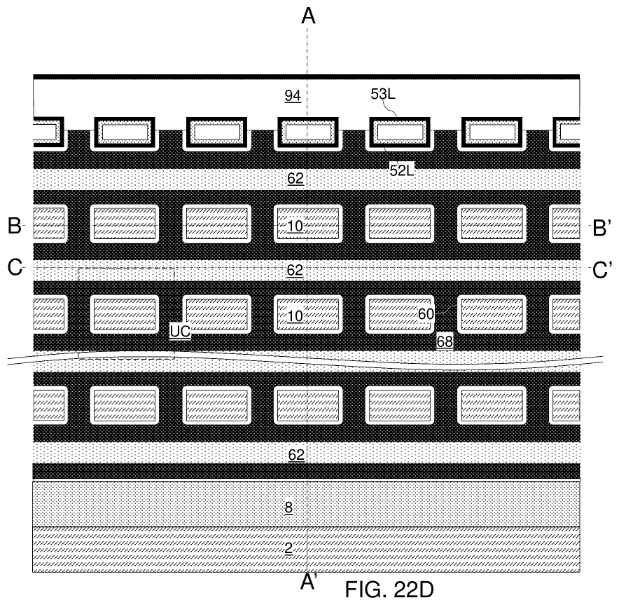

Referring to FIGS. 22A, 22B, 22C, 22D, and 22E, an anisotropic etch process can be performed to remove unmasked portions of the sacrificial cover material layer 53L from outside the volumes of the lateral recesses 19. The anisotropic etch process may have a partially isotropic etch chemistry such that portions of the sacrificial cover material layer 53L that are in the bit-line via cavities 95 may be entirely removed, or only a negligible residue of the sacrificial cover material layer 53L remains in the bit-line via cavities 95. Each remaining portion of the sacrificial cover material layer 53L that remains within a respective one of the lateral recesses 19 comprises a sacrificial cover material portion 53. A three-dimensional L×M×N array of sacrificial cover material portions 53 may be formed.

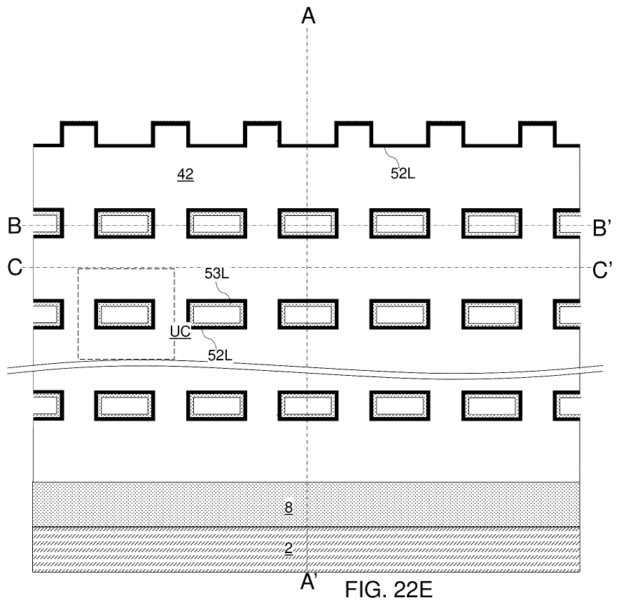

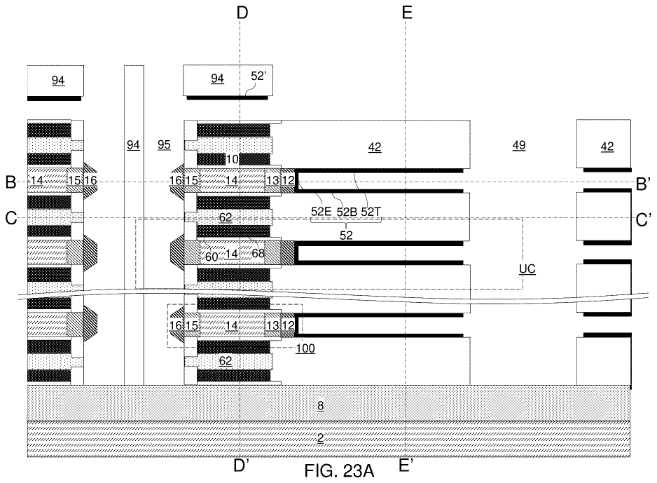

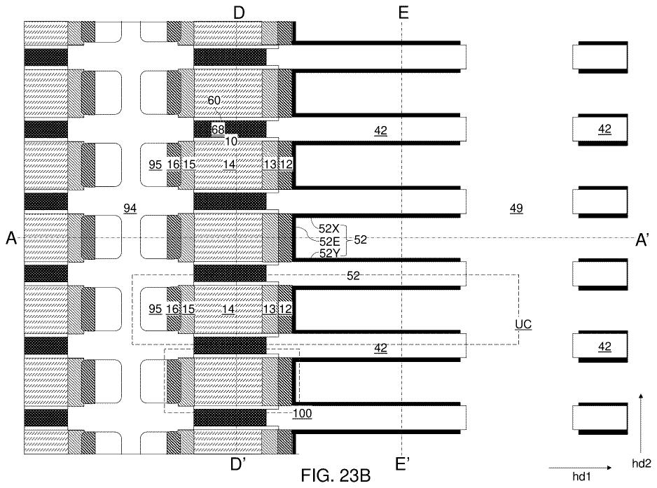

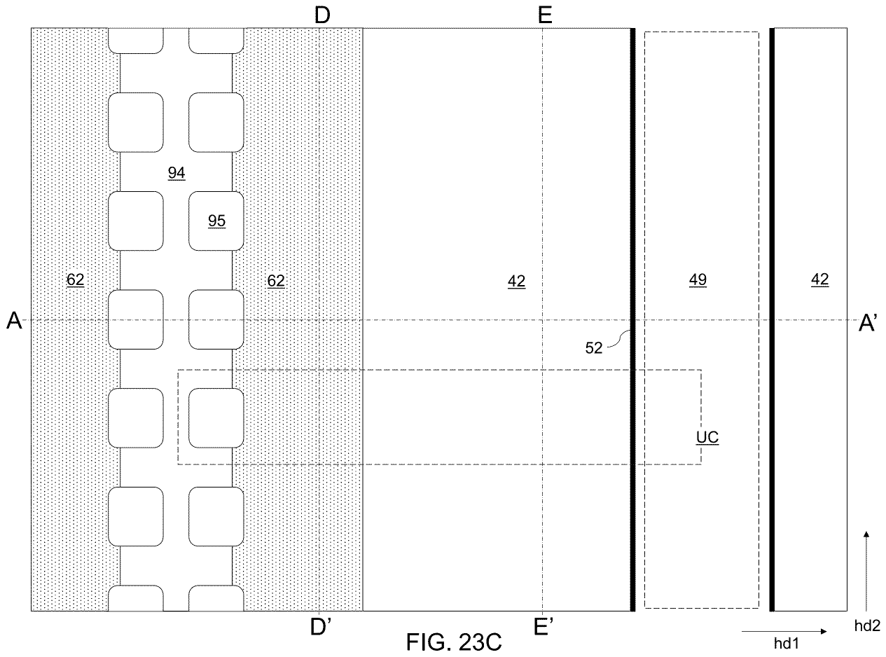

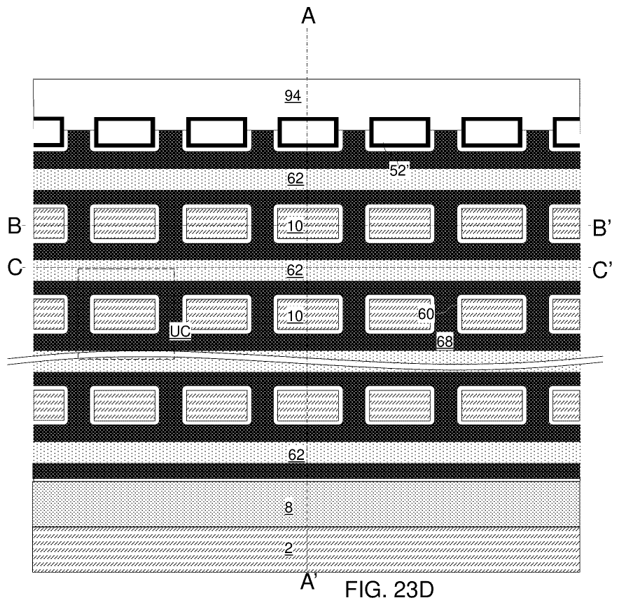

Referring to FIGS. 23A, 23B, 23C, 23D, and 23E, a selective etch process that etches the material of the first conductive material layer 52L selectively to the material of the sacrificial cover material portions 53 can be performed. For example, the selective etch process may comprise an isotropic wet etch process that etches the metallic material of the first conductive material layer 52L selectively to the material of the sacrificial cover material portions 53. The first conductive material layer 52L can be removed from inside the bit-line via cavities 95 and from inside the source trenches 49. In some embodiments, residual conductive material portions 52′ may remain on physically exposed bottom surfaces of the bit-line trench isolation structures 94. Remaining portions of the first conductive material layer 52L may comprise a three-dimensional L×M×N array of conductive material layers that form first electrodes 52 of storage devices 200 (described below) of the embodiments of the present disclosure. As used herein, a storage device 200 refers to any volatile or non-volatile storage device that can store data. In the first embodiment, the storage device 200 comprises a capacitor or a resistor. Preferably, the capacitor comprises a ferroelectric capacitor that can store data based on the ferroelectric polarization direction of the memory material layer (e.g., the capacitor ferroelectric dielectric material).

In one embodiment, a three-dimensional L×M×N array of first electrodes 52 may be formed entirely within the volumes of the three-dimensional L×M×N array of lateral recesses 19. In one embodiment, each first electrode 52 comprises an end conductive plate 52E that is perpendicular to the first horizontal direction hd1; a top conductive plate 52T adjoined to a top of the end conductive plate 52E and laterally extending along the first horizontal direction hd1; and a bottom conductive plate 52B adjoined to a bottom of the end conductive plate 52E and laterally extending along the first horizontal direction hd1. In one embodiment, for each contacting combination of a set of semiconductor material portions (12, 13, 14, 15, 16) and a first electrode 52, a top surface of the set of semiconductor material portions (12, 13, 14, 15, 16) and a top surface of the top conductive plate 52T are located in a first horizontal plane, and a bottom surface of the set of semiconductor material portions (12, 13, 14, 15, 16) and a bottom surface of the bottom conductive plate 52B are located in a second horizontal plane, as shown in FIG. 23A.

In one embodiment shown in FIG. 23B, each first electrode 52 comprises the end conductive plate 52E that is perpendicular to the first horizontal direction hd1; a first conductive sidewall plate 52X adjoined to a first vertically extending edge of the end conductive plate 52E and laterally extending along the first horizontal direction hd1; and a second conductive sidewall plate 52Y adjoined to a second vertically extending edge of the end conductive plate 52E and laterally extending along the first horizontal direction hd1. In one embodiment, for each contacting combination of a set of semiconductor material portions (12, 13, 14, 15, 16) and a first electrode 52, a first sidewall of the set of semiconductor material portions (12, 13, 14, 15, 16) and an outer sidewall of the first conductive sidewall plate 52X are located in a first vertical plane that is parallel to the first horizontal direction hd1; and a second sidewall of the set of semiconductor material portions (12, 13, 14, 15, 16) and an outer sidewall of the second conductive sidewall plate 52Y are located in a second vertical plane that is parallel to the first horizontal direction hd1.

In one embodiment, for each contacting combination of a set of semiconductor material portions (12, 13, 14, 15, 16) and a first electrode 52, the first electrode 52 has a vertical extent that is not greater than a vertical extent of the horizontally-extending semiconductor channel 14 within the set of semiconductor material portions (12, 13, 14, 15, 16), and the first electrode 52 has a lateral extent along a second horizontal direction hd2 that is not greater than a lateral extent of the horizontally-extending semiconductor channel 14 along the second horizontal direction hd2. The second horizontal direction hd2 may be perpendicular to the first horizontal direction hd1. In one embodiment, the set of semiconductor material portions (12, 13, 14, 15, 16) comprises a source region 12 in contact with the first electrode 52.

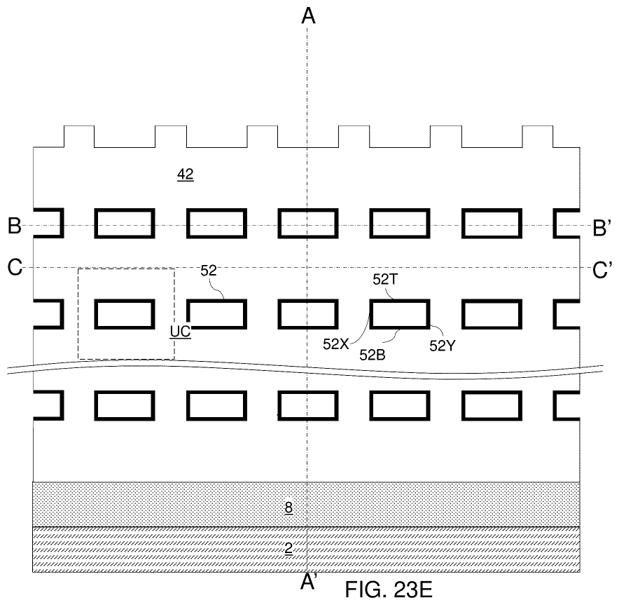

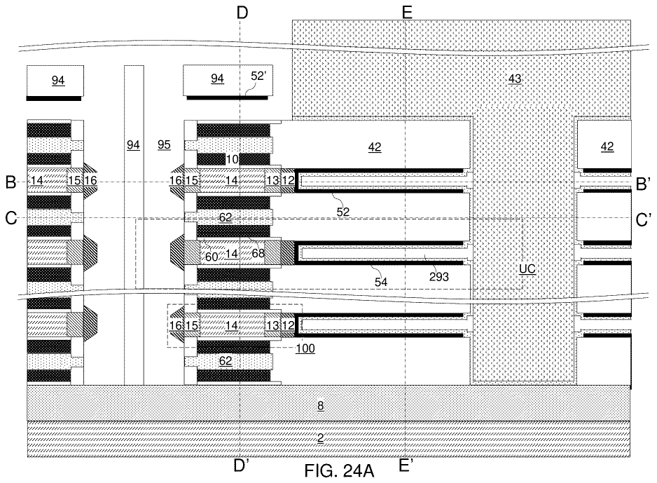

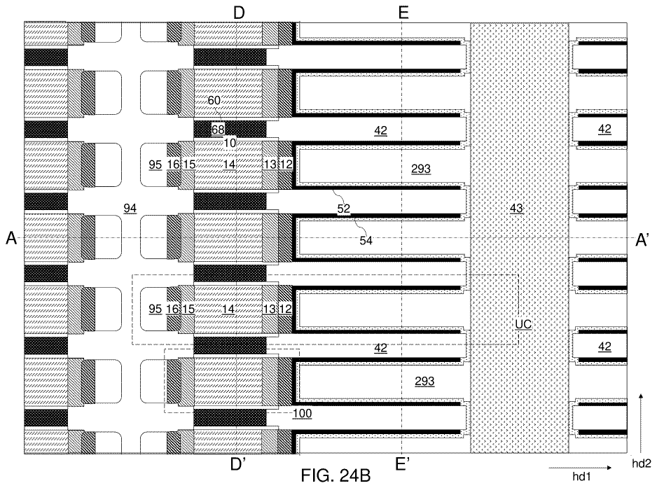

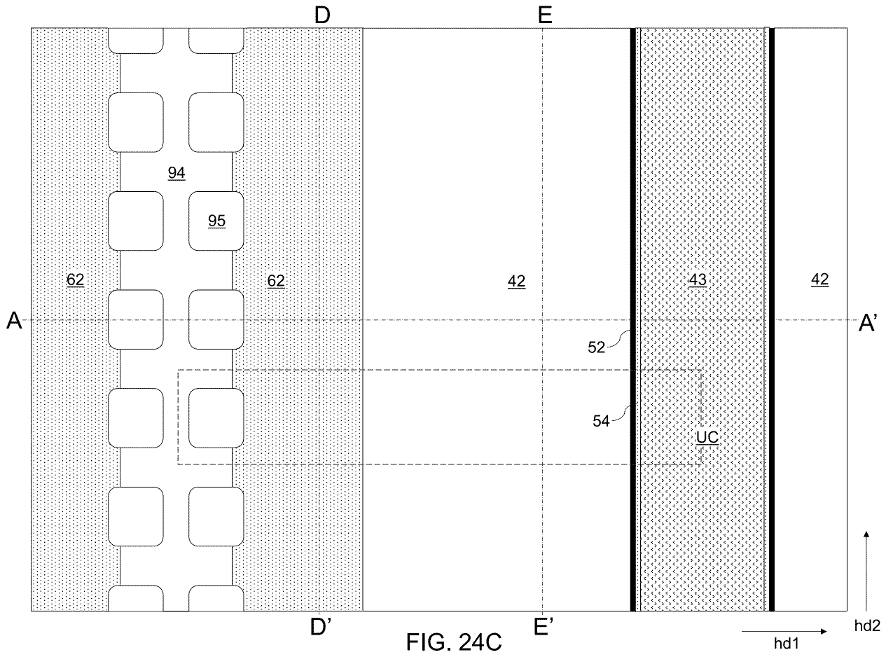

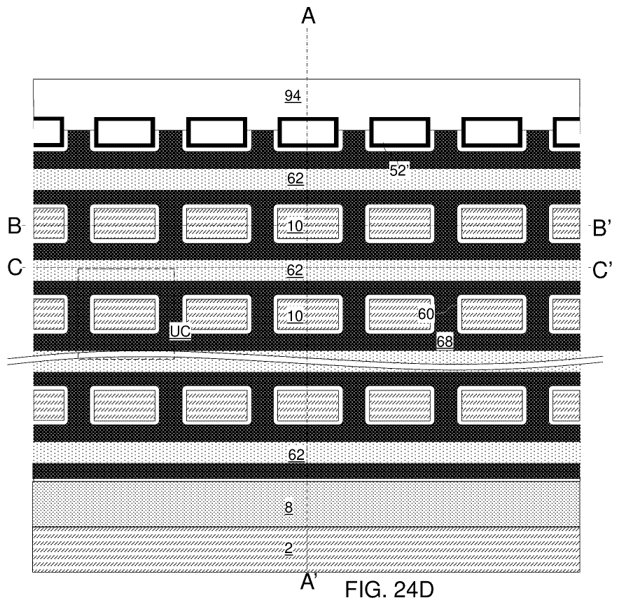

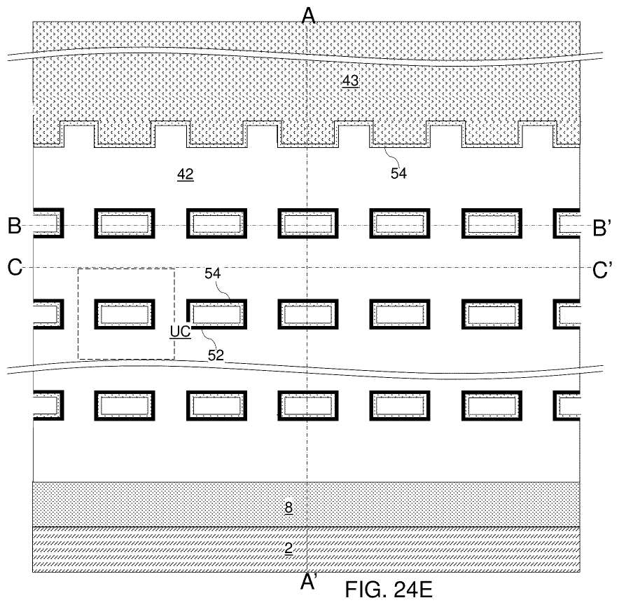

Referring to FIGS. 24A, 24B, 24C, 24D, and 24E, at least one memory material layer 54 may be formed. Specifically, a continuous memory material layer can be conformally deposited on the physically exposed surfaces of the first exemplary structure. As used herein, a “memory material” refers to any material or a set of materials that can store data therein. The memory material may store information in the form of a change in the direction of ferroelectric polarization, a change in the amount of charge carriers (e.g., electrons) stored therein, or a change in resistance of the material.

Generally, the memory material layer can be conformally deposited as a continuous material layer directly on the physically exposed surfaces of the first electrodes 52. A photoresist layer 43 can be applied over the first exemplary structure, and can be lithographically patterned to cover the source trenches 49 without covering the bit-line via cavities 95. Unmasked portions of the continuous memory material layer can be etched back by performing an etch back process. Remaining portions of the continuous memory material layer comprise memory material layers including two M×N arrays of memory layers 54. Each memory layer 54 comprises a portion of the continuous memory material layer that is located within a respective one of the lateral recesses 19. The photoresist layer 43 may be subsequently removed, for example, by ashing.

In one embodiment, the memory layer 54 comprises a ferroelectric dielectric material. In this case, the storage devices 200 comprise non-volatile capacitors that provide a variable capacitance depending on the direction of ferroelectric polarization within the ferroelectric dielectric material. Non-limiting examples of ferroelectric dielectric materials include a titanate ferroelectric dielectric material such as barium titanate, lead titanate, lead zirconate titanate, lead lanthanum zirconate titanate (PLZT), potassium niobate (KNbO₃), sodium potassium niobate (KNN), lithium niobate (LiNbO₃), lithium tantalate (LiTaO₃), and bismuth ferrite (BiFeO₃). Other ferroelectric dielectric materials include strontium bismuth tantalate (SBT), polyvinylidene fluoride (PVDF), and its copolymers, zirconium oxide (ZrO₂), hafnium oxide (HfO₂), and their doped variants such as zirconium doped hafnium oxide (HZO), aluminum doped hafnium oxide (HfAlO), and lanthanum doped hafnium oxide (HfLaO). Generally, any suitable ferroelectric dielectric material may be employed for the memory layers 54.

In another embodiment, the memory layers 54 comprise a material that can provide variable resistance with at least two programmable states providing different resistance values. In one embodiment, the memory material may comprise any material that is selected from a filament-forming resistive dielectric material, an oxygen vacancy-modulated resistive dielectric material, a phase change material, or a polymer material exhibiting resistive switching properties. Non-limiting examples of the filament-forming resistive dielectric material include tantalum oxide (TaOₓ), non-ferroelectric phase of hafnium oxide (HfOₓ), titanium dioxide (TiO₂), etc. Non-limiting examples of the oxygen vacancy-modulated resistive dielectric material include strontium ruthenate (SrRuO₃), lanthanum strontium manganite (LaSrMnO₃), and praseodymium calcium manganite (PrCaMnO₃). Non-limiting examples of the phase change material include chalcogenide semiconductor materials, such as germanium antimony telluride (Ge₂Sb₂Te₅), antimony telluride (Sb₂Te₃), and gallium antimonide (GaSb). Non-limiting examples of the polymer material exhibiting resistive switching properties include polyvinyl alcohol (PVA), polyaniline (PANI), and poly(3,4-ethylenedioxythiophene) polystyrene sulfonate (PEDOT:PSS). Additionally, other materials used in resistive switching applications include binary metal oxides like zinc oxide (ZnO) and nickel oxide (NiO), as well as complex oxides such as barium strontium titanate (BST) and lead zirconate titanate (PZT). Generally speaking, any resistive memory material known in the art may be employed as the material of the memory layers 54. In this case, the storage device 200 comprises a variable resistor.

In another embodiment, the memory layers 54 comprise a charge storage material layers, such as silicon oxide, silicon nitride, silicon oxynitride or a dielectric metal oxide. These materials store charge (e.g., electrons) that is provided from the source or drain of the respective access transistor 100. In this case, the storage device 200 comprises a capacitor of a volatile dynamic random access (DRAM) memory device which includes the access transistor and the charge storage capacitor electrically connected to a source or drain (e.g., the source 12) of the access transistor 100.

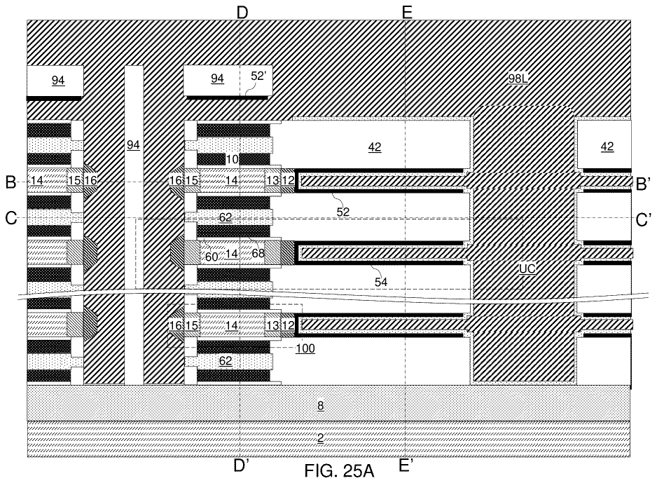

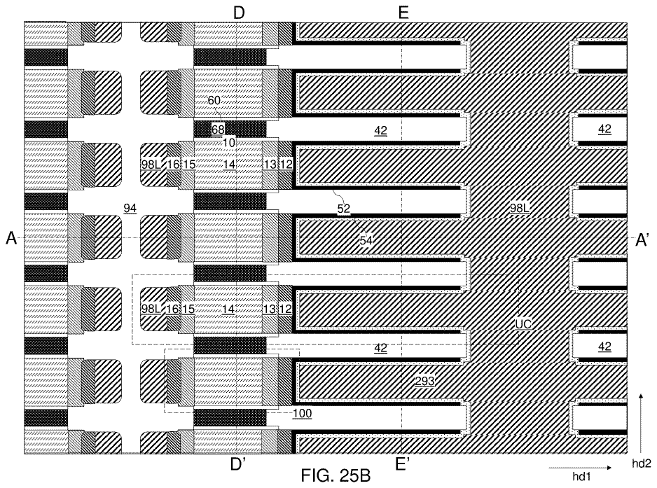

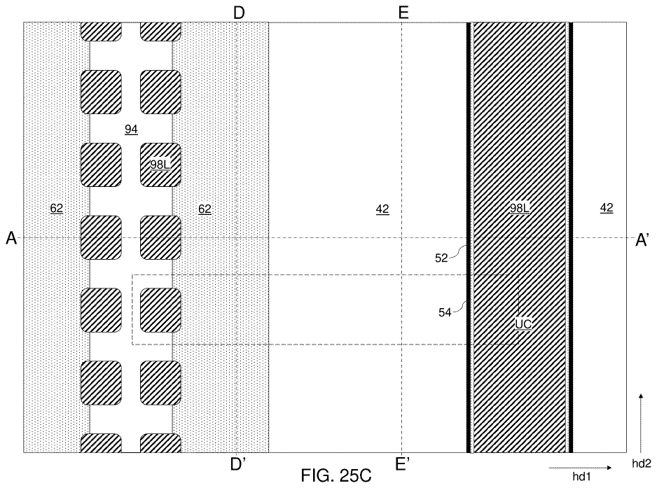

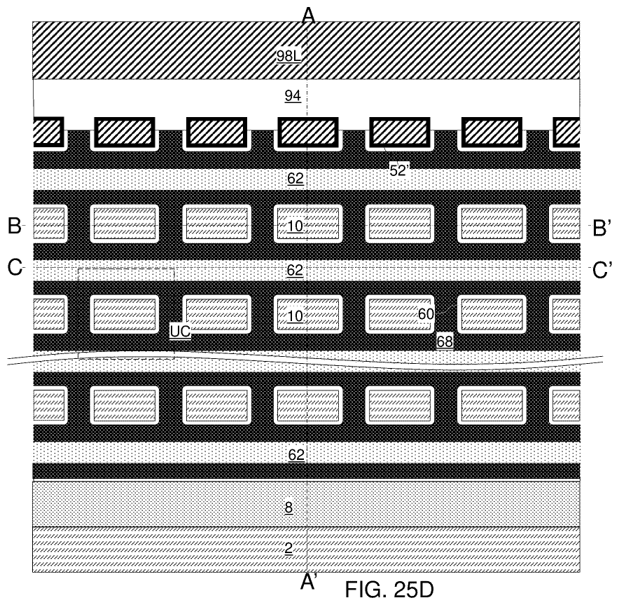

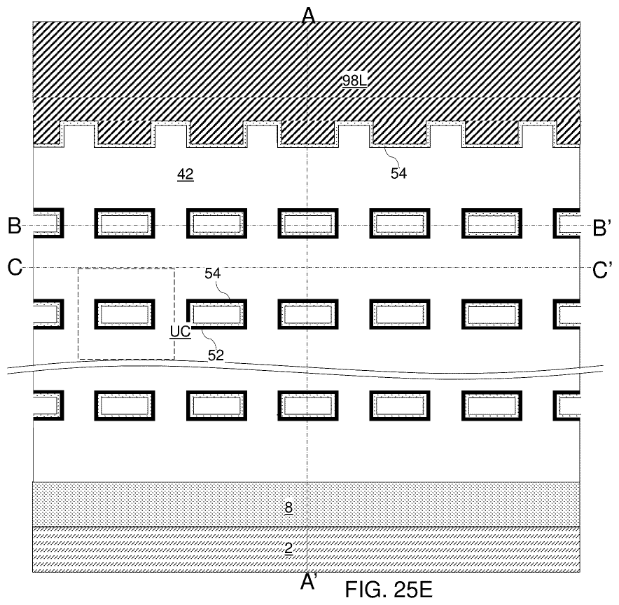

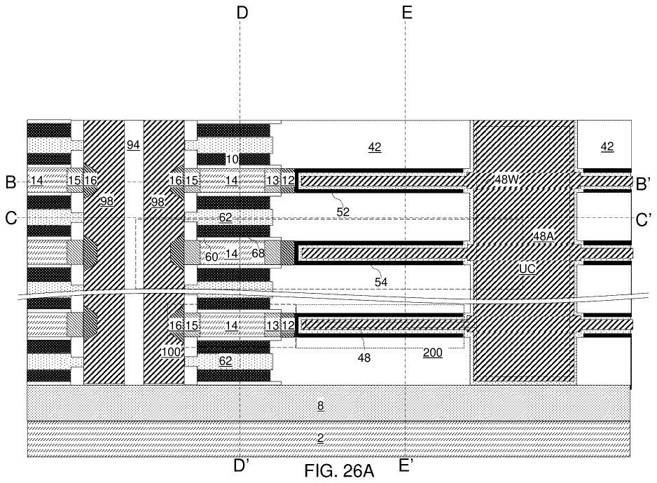

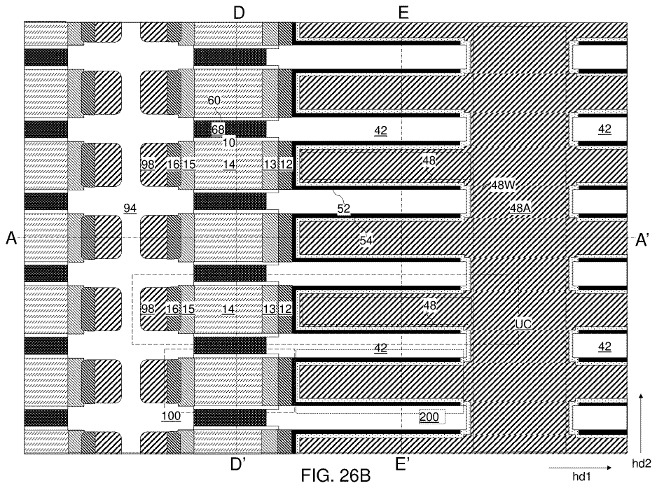

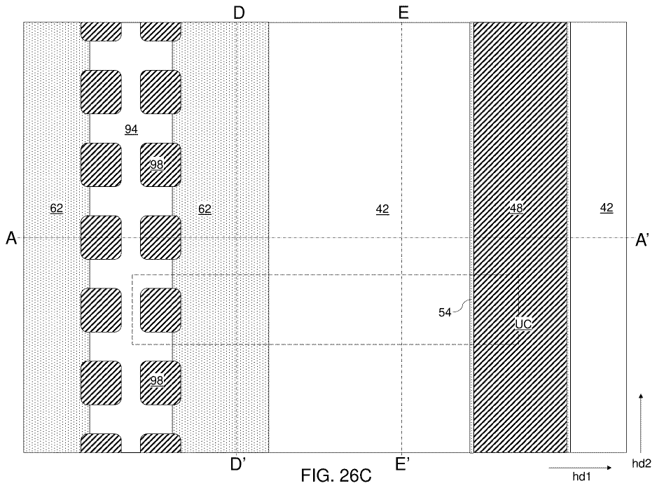

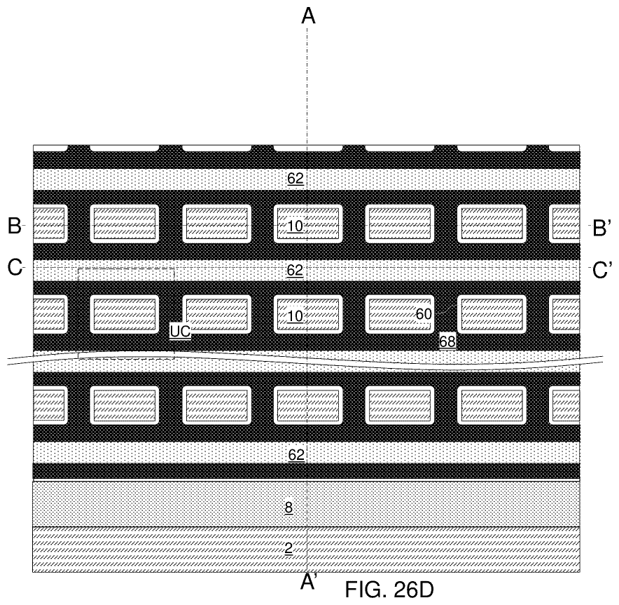

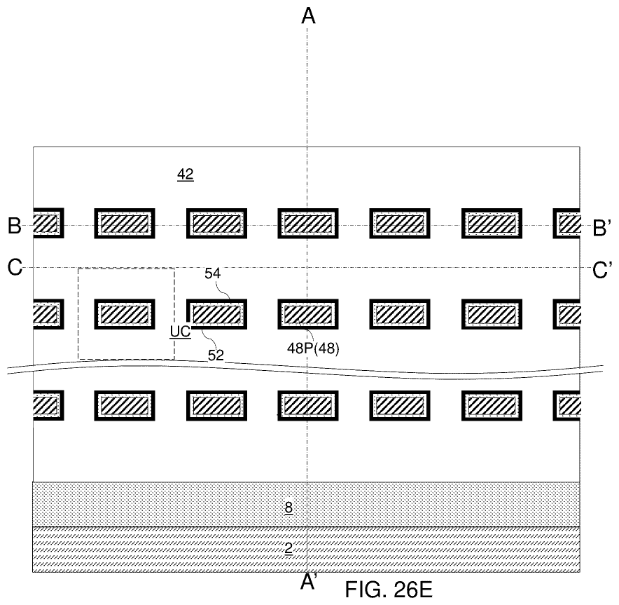

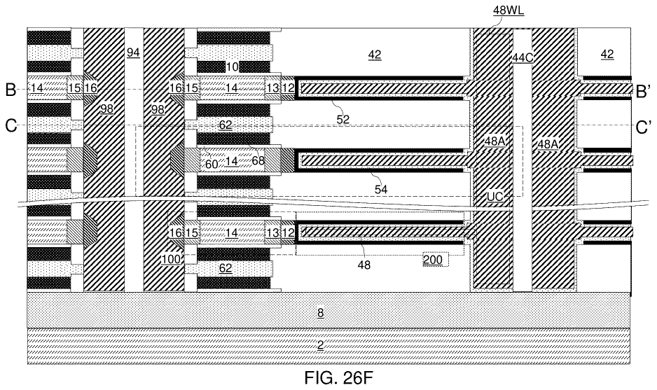

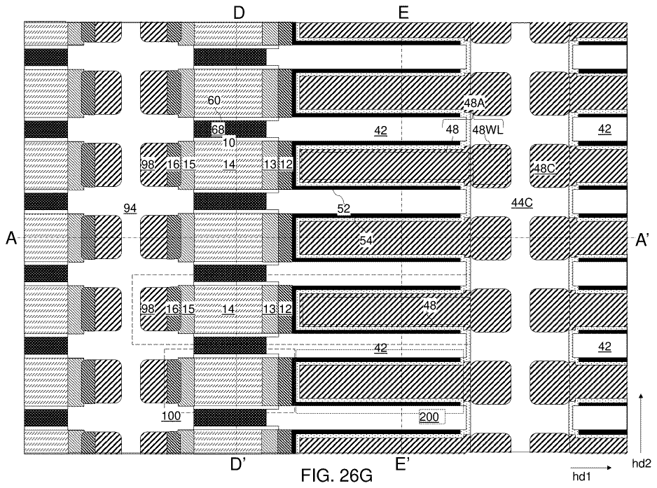

Referring to FIGS. 25A, 25B, 25C, 25D, and 25E, a second conductive material layer 98L can be deposited in the remaining volumes of the lateral recesses 19, in the source trenches 49, in the bit-line via cavities 95, and over the topmost surfaces of the perforated dielectric matrices 42 and the bit-line trench isolation structures 94. The second conductive material layer 98L may comprise at least one conductive material such as a metallic barrier material and a metallic fill material. Exemplary metallic barrier materials include TiN, TaN, WN, and/or MoN. Exemplary metallic fill materials include W, Co, Ru, Mo, Ti, Ta, Cu, etc. referring to FIGS. 26A, 26B, 26C, 26D, and 26E, the second conductive material layer 98L can be patterned into vertical bit lines 98 and a one-dimensional array of conductive structures 48A. Each conductive structure 48A comprises a vertical conductive wall structure 48W that fills a respective source trench 49 and at least one M×N array of conductive lateral protrusions that laterally protrude into a respective lateral recess 19. Each conductive lateral protrusion within the conductive structures 48A constitutes a second electrode 48. Each volume of a unit cell UC may comprise a respective portion of a conductive wall structure 48W and a respective second electrode 48. Each conductive structure 48A located between a pair of two-dimensional M×N arrays of access field effect transistors 100 may comprise two M×N arrays of second electrodes 48.

Each contiguous combination of a first electrode 52, a memory layer 54, and a second electrode 48 constitutes a storage device 200. The memory layer 54 is located between the first electrode 52 and the second electrode 48. The memory layer 54 may surround a horizontally extending first electrode 52, and the second electrode 48 may surround the memory layer 54. The second electrode 48 is electrically connected to the vertical conductive wall structure 48W (e.g., vertical write line). The first electrode 52 is connected to the source 12 of the access transistor 100. The drain region 16 of the access transistor 100 is electrically connected to a vertical bit line 98 (e.g., vertical read line). In the first embodiment, the storage device 200 comprises a two terminal device, such as a ferroelectric capacitor, a charge storage capacitor or a variable resistor. A three-dimensional array of L×M×N two terminal storage devices 200 fills the three-dimensional array of lateral recesses 19. Each storage device 200 is electrically connected in a series connection with a laterally adjacent one of the access field effect transistors 100 in a three dimensional array of the storage devices and access field effect transistors.

Generally, a one-dimensional array of conductive structures 48A arranged along the first horizontal direction hd1 can be formed. Each of the conductive structures 48A includes a respective conductive wall structure 48W that laterally extends along the second horizontal direction hd2, and further includes a respective two-dimensional array of conductive lateral protrusions (i.e., the second electrodes 48) that laterally protrude from the conductive wall structure 48W along the first horizontal direction hd1 into unfilled volumes of a respective two-dimensional array of lateral recesses 19 (which is a respective subset of the three-dimensional array of lateral recesses 19) after formation of the memory material layers. In one embodiment, each of the memory material layers may comprise at least one M×N array of memory layers 54 that are interconnected to each other by a vertically-extending portion of a respective memory material layer. The second portions of the horizontally-extending semiconductor rails 10 are replaced with a three-dimensional array of instances of an storage device 200. Each storage device 200 comprises a first electrode 52, a second electrode 48, and a memory layer 54 located between the first electrode 52 and the second electrode 48.

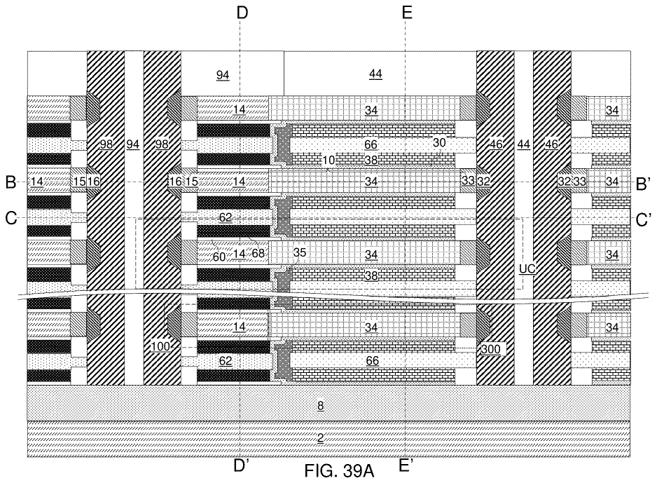

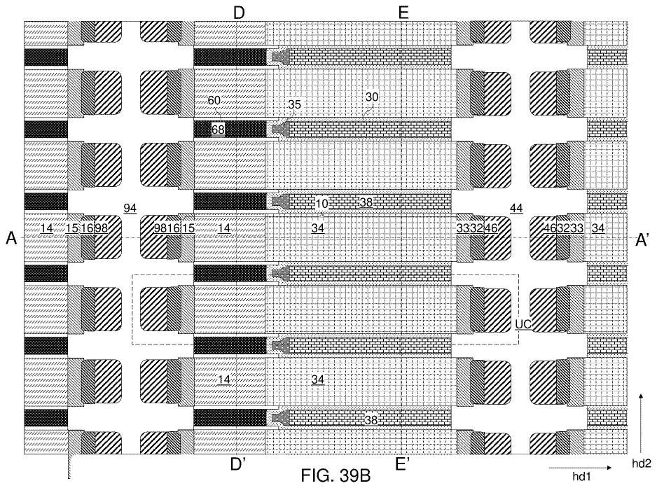

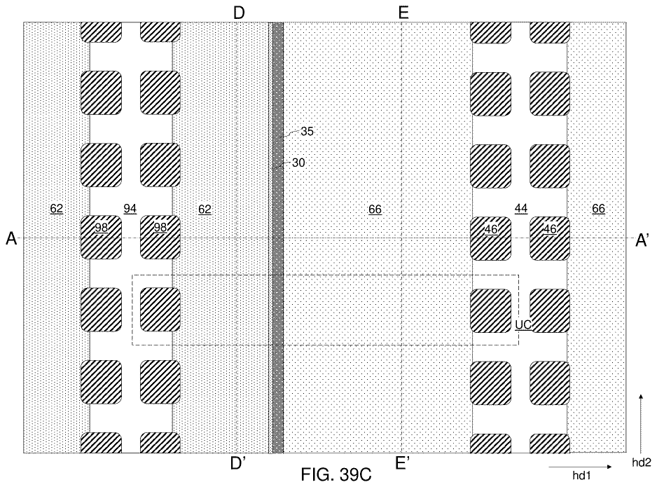

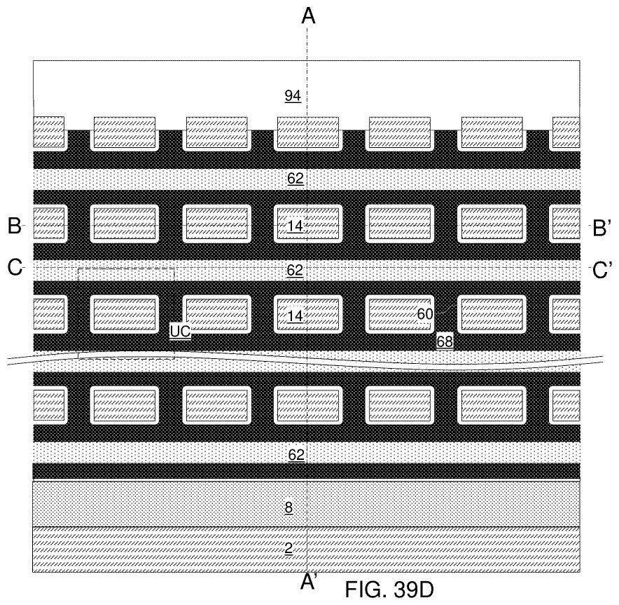

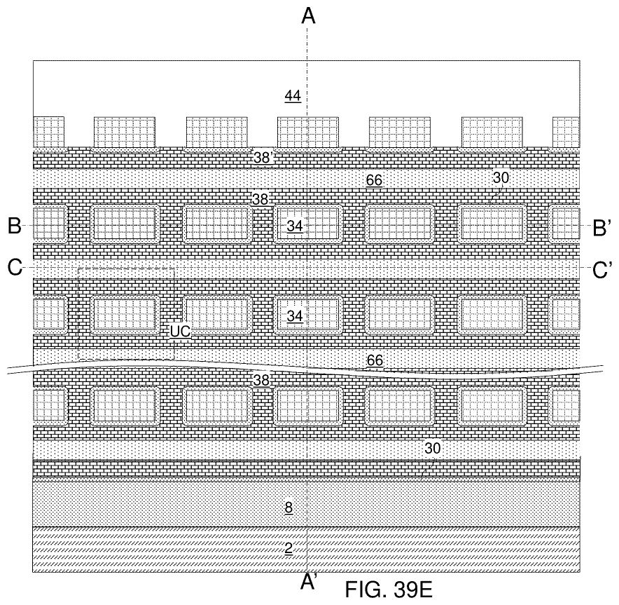

In an alternative configuration of the first embodiment shown in FIGS. 26F and 26G, the vertical conductive wall structure 48W portion of the conductive structures 48A is replaced by vertical write lines 48WL embedded in a capacitor trench isolation structure 44C. The capacitor trench isolation structure 44C may be formed at the same time as the bit-line trench isolation structure 94 in the step shown in FIG. 11A-11E. Capacitor via cavities can be formed through the capacitor trench isolation structure 44C at the same time as the bit-line cavities 95 are formed through the bit-line trench isolation structures 94, as shown in FIG. 12A-12E. The second conductive material layer 98L can also be deposited into the capacitor via cavities and then patterned to form the vertical bit lines 98 and the vertical write lines 48WL as described above with respect to FIG. 26A-26E. The vertical write lines 48WL may be similar to the vertical source lines 46 which are shown in FIG. 39A-39E and which will be described below with respect to the second embodiment.

Referring collectively to FIG. 1A-26G and according to various embodiments of the present disclosure, a device structure includes a three-dimensional array of unit cells containing vertical stacks of the unit cells UC arranged along a vertical direction (e.g., perpendicular to the top surface of an underlying substrate 2). Each of the unit cells UC includes an access field effect transistor 100 containing a set of semiconductor material portions (12, 13, 14, 15, 16) that includes a horizontally-extending semiconductor channel 14, and a storage device 200 having a first electrode electrically 52 connected to a sidewall of the set of semiconductor material portions (12, 13, 14, 15, 16), a second electrode 48 that is spaced from the access field effect transistor 100, and a memory layer 54 located between the first electrode 52 and the second electrode 48.

In one embodiment, the first electrode 52 physically contacts the sidewall of the set of semiconductor material portions (12, 13, 14, 15, 16). In one embodiment, the first electrode 52 comprises: an end conductive plate 52E that is perpendicular to the first horizontal direction hd1; a top conductive plate 52T adjoined to a top of the end conductive plate and laterally extending along the first horizontal direction hd1; and a bottom conductive plate 52B adjoined to a bottom of the end conductive plate and laterally extending along the first horizontal direction hd1, a first conductive sidewall plate 52X adjoined to a first vertically extending edge of the end conductive plate and laterally extending along the first horizontal direction hd1; and a second conductive sidewall plate 52Y adjoined to a second vertically extending edge of the end conductive plate and laterally extending along the first horizontal direction hd1.

In one embodiment, a top surface of the set of semiconductor material portions (12, 13, 14, 15, 16) and a top surface of the top conductive plate 52T are located in a first horizontal plane; and a bottom surface of the set of semiconductor material portions (12, 13, 14, 15, 16) and a bottom surface of the bottom conductive plate 52B are located in a second horizontal plane. In one embodiment, a first sidewall of the set of semiconductor material portions (12, 13, 14, 15, 16) and an outer sidewall of the first conductive sidewall plate 52X are located in a first vertical plane that is parallel to the first horizontal direction hd1; and a second sidewall of the set of semiconductor material portions (12, 13, 14, 15, 16) and an outer sidewall of the second conductive sidewall plate 52Y are located in a second vertical plane that is parallel to the first horizontal direction hd1.

In one embodiment, the set of semiconductor material portions (12, 13, 14, 15, 16) further comprises a source region 12 in contact with the first electrode 52, and drain region 16 located on an opposite side of the horizontally-extending channel 14 relative to the source region 12. In one embodiment, the horizontally-extending semiconductor channel 14 and the source region 12 have a same uniform vertical cross-sectional shape within any vertical cross-sectional view that cuts through the horizontally-extending semiconductor channel 14 or the source region 12 and is perpendicular to the first horizontal direction hd1 irrespective of a location of a vertical cut plane for a respective vertical cross-sectional view. In one embodiment, the drain region 16 has a variable vertical cross-sectional shape within vertical planes that are perpendicular to the first horizontal direction hd1 as a function of a lateral distance from the horizontally-extending semiconductor channel 14.

In one embodiment, the access field effect transistor 100 further comprises a tubular gate dielectric 60 that laterally surrounds the horizontally-extending semiconductor channel 14 and laterally extends along the first horizontal direction hd1. In one embodiment, the access transistor 100 further comprises a gate electrode that wraps around the tubular gate dielectric 60 in a vertical cross-sectional view that is perpendicular to the first horizontal direction hd1. The gate electrode comprises a portion of a word line 68 that laterally extends along a second horizontal direction as a gate electrode.

In one embodiment, the tubular gate dielectric 60 comprises a top dielectric portion 60T contacting a horizontal top surface of the horizontally-extending semiconductor channel 14, a bottom dielectric portion 60B contacting a horizontal bottom surface of the horizontally-extending semiconductor channel 14, and a pair of sidewall dielectric portions (60X, 60Y) contacting a pair of sidewalls of the horizontally-extending semiconductor channel 14; and each of the top dielectric portion, the bottom dielectric portion, and the pair of sidewall dielectric portions is contacted by the gate electrode (which is a portion of a word line 68).

In one embodiment, a vertical bit line 98 contacts the drain regions 16 of a respective one of the vertical stacks, and a vertical write line (48W, 48WL) is electrically connected to the second electrodes 48 of the respective one of the vertical stacks.

In one embodiment, the three-dimensional array of said instances of the unit cell UC is arranged to provide: M rows of respective unit cells UC arranged along a second horizontal direction hd2 that is different from the first horizontal direction hd1; L columns of respective unit cells UC arranged along the first horizontal direction hd1; and vertical stacks of respective unit cells UC (i.e., a respective set of N unit cells) arranged along a vertical direction.

In one embodiment, the device structure also includes a two-dimensional array of vertical bit lines 98 and vertical write lines (48W, 48WL). Each of the vertical bit lines 98 contacts a set of drain regions 16 located within a respective one of the vertical stacks of unit cell UC; each of the vertical write lines (48W, 48WL) comprises a vertical conductive wall structure 48W that laterally extends along the second horizontal direction hd2; and each of the second electrodes 48 comprises a conductive lateral protrusion that laterally protrudes from the conductive wall structure 48W along the first horizontal direction hd1.

In one embodiment, the storage device 200 is a ferroelectric capacitor, and memory layer 54 comprises a ferroelectric dielectric material. In another embodiment, the storage device 200 is a charge storage capacitor, and memory layer 54 comprises a charge storage dielectric material. In another embodiment, the storage device 200 is a variable resistor, and the memory layer 54 comprises a material selected from: a filament-forming resistive dielectric material; an oxygen vacancy-modulated resistive dielectric material; a phase change material; or a polymer material exhibiting resistive switching properties.

In one embodiment, the first electrode 52 has a vertical extent that is not greater than a vertical extent of the horizontally-extending semiconductor channel 14; and the first electrode 52 has a lateral extent along a second horizontal direction hd2 that is not greater than a lateral extent of the horizontally-extending semiconductor channel 14 along the second horizontal direction hd2, the second horizontal direction hd2 being perpendicular to the first horizontal direction hd1.

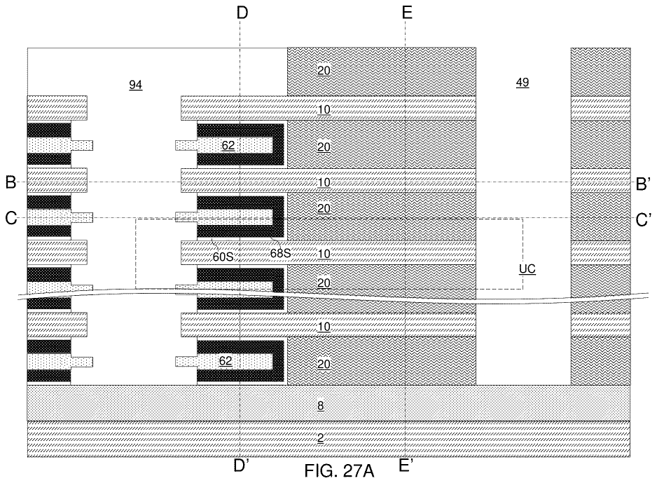

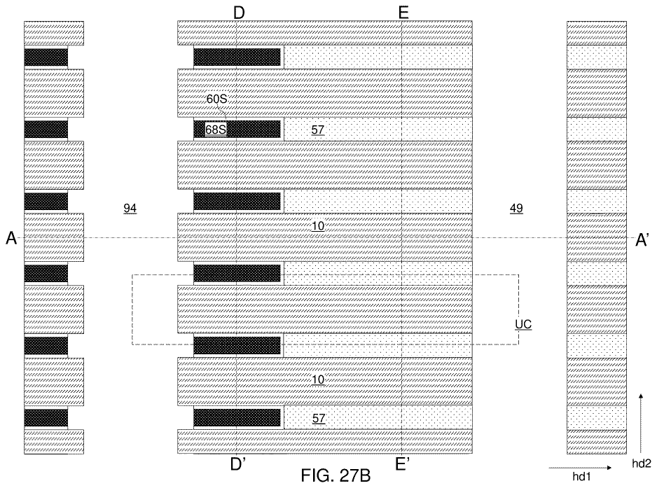

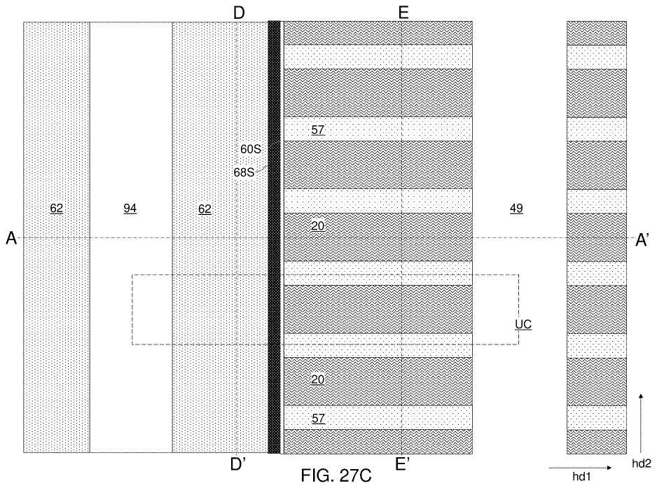

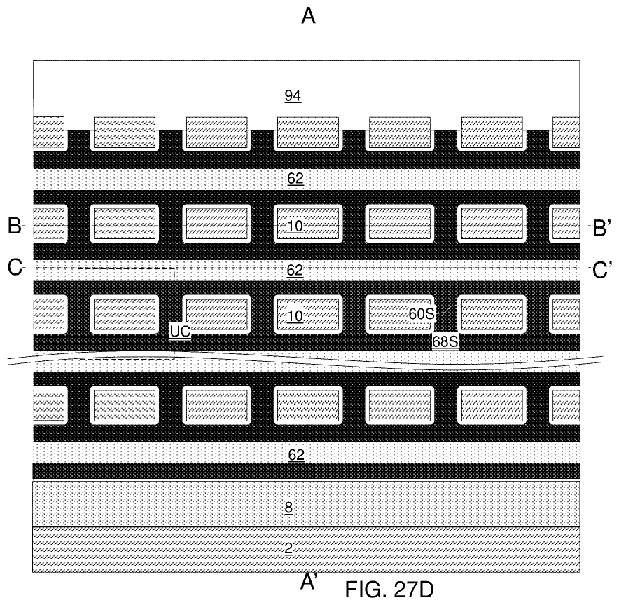

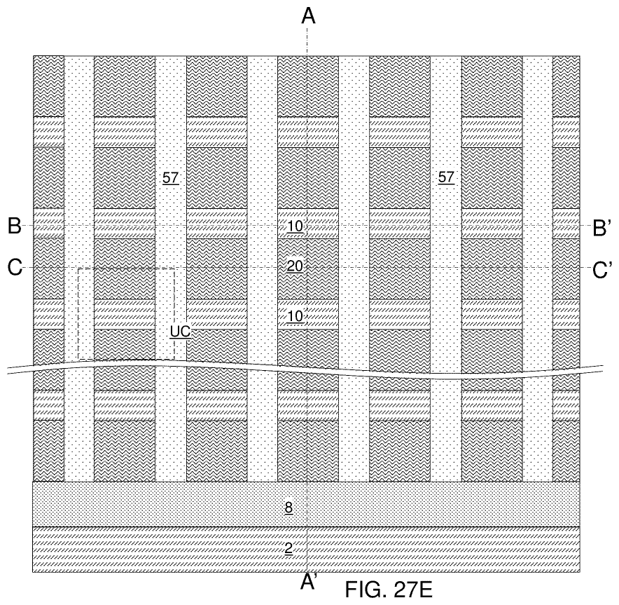

Referring to FIGS. 27A, 27B, 27C, 27D, and 27E, a second exemplary structure according to a second embodiment of the present disclosure can be derived from the first exemplary structure illustrated in FIG. 11A-11E by omitting the processing steps described with reference to FIG. 12A-12E and by performing the processing steps described with reference to FIG. 13A-13E. Thus, the bit-line trench isolation structures 94 are formed, and the sacrificial source trench fill structures 47 are removed.

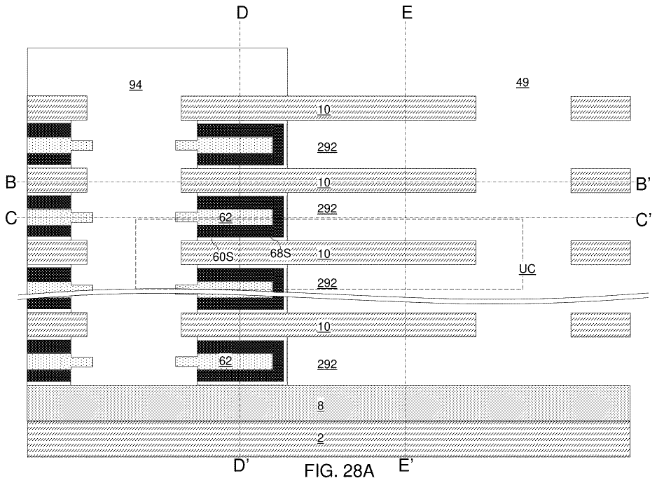

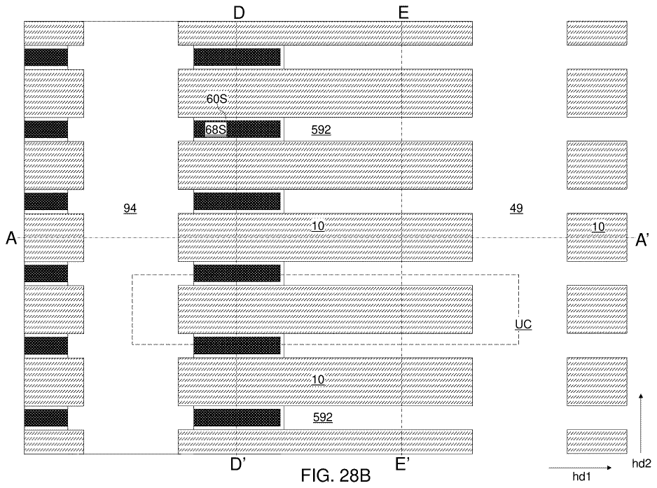

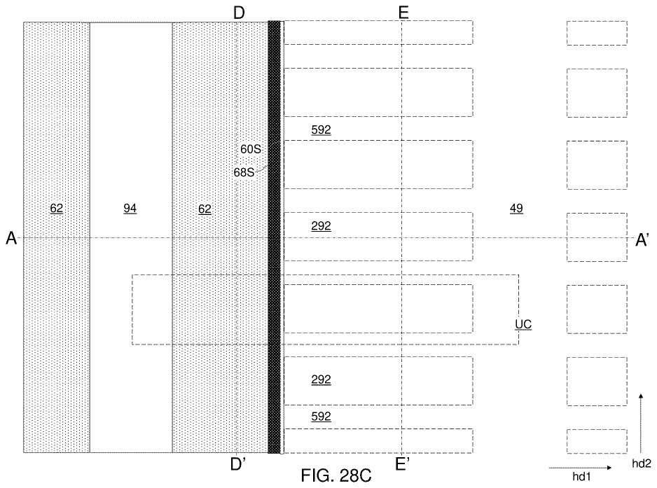

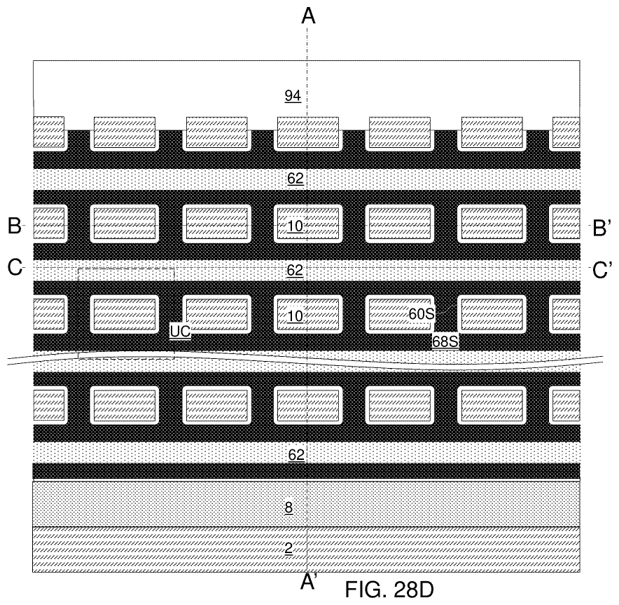

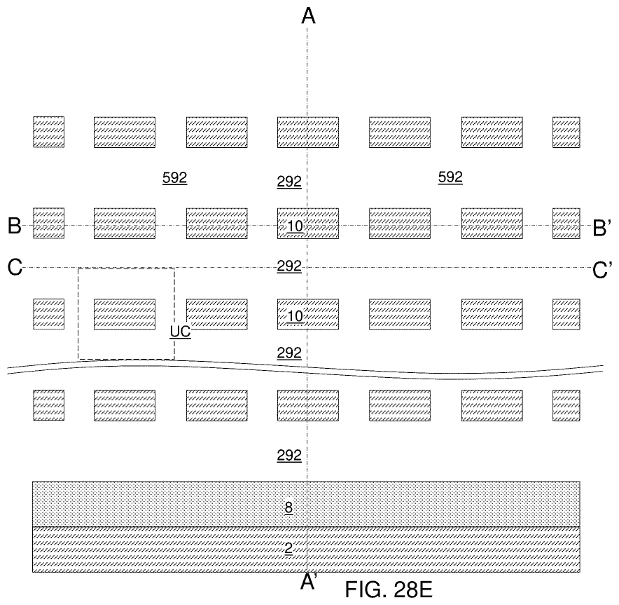

Referring to FIGS. 28A, 28B, 28C, 28D, and 28E, the processing steps described with reference to FIG. 14A-14E can be performed to form second inter-rail cavities 292 and second lateral isolation trenches 592. The second inter-rail cavities 292 can be formed between vertically-neighboring pairs of the horizontally-extending semiconductor rails 10 by removing a second portion (i.e., a remaining portion) of each of the horizontally-extending sacrificial rails 20. The second lateral isolation trenches 592 can be formed between laterally-neighboring pairs of the horizontally-extending semiconductor rails 10 by removing a second portion (i.e., a remaining portion) of each of the sacrificial isolation trench fill structures 57.

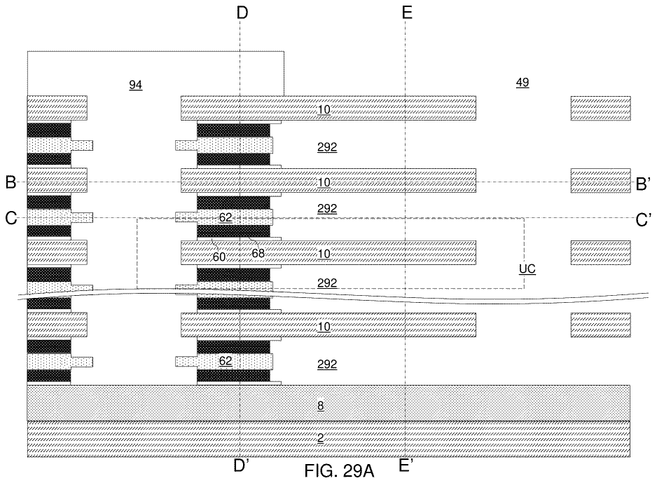

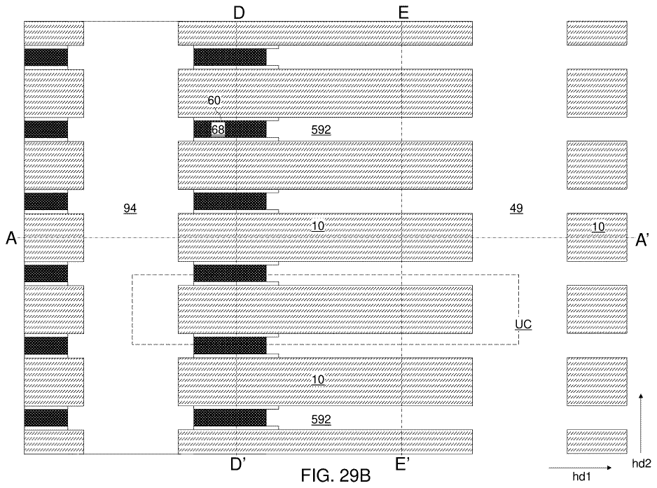

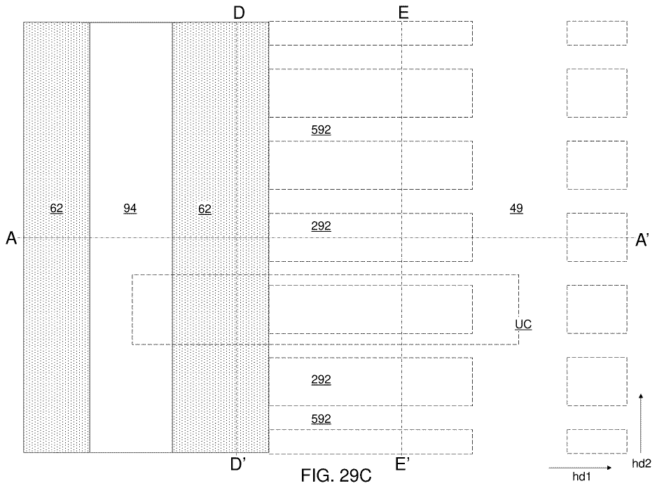

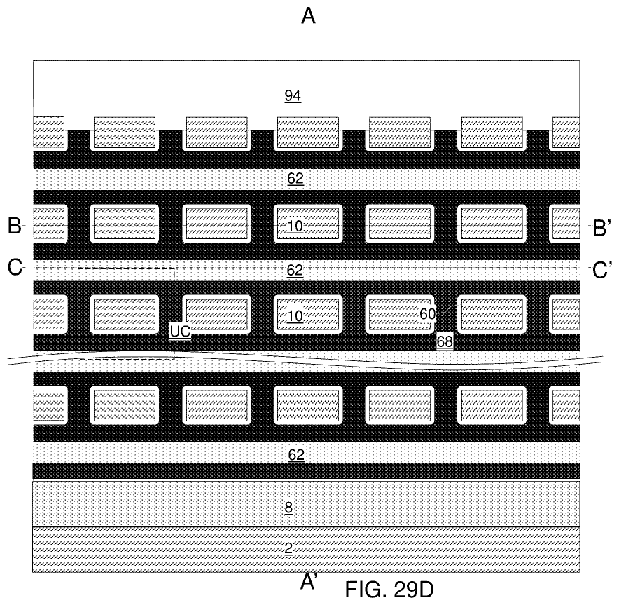

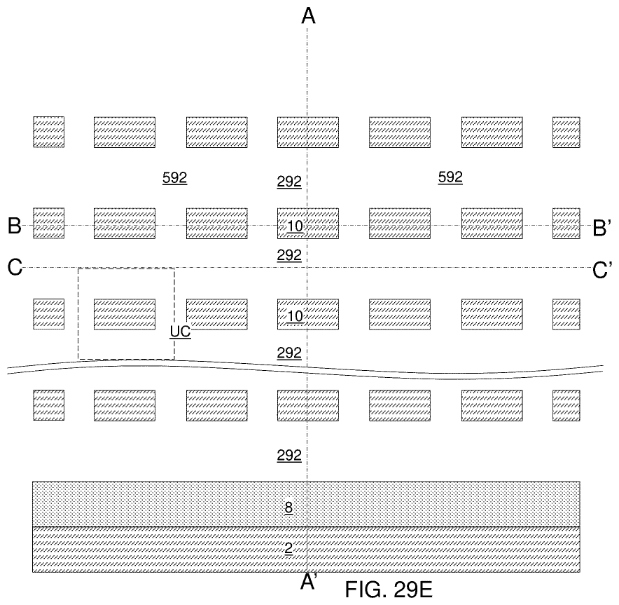

Referring to FIGS. 29A, 29B, 29C, 29D, and 29E, the processing steps described with reference to FIG. 15A-15E can be performed to pattern a one-dimensional array of first gate dielectric layers 60S into a three-dimensional array of first gate dielectrics 60, i.e., a three-dimensional array of L×M×N first tubular gate dielectrics 60, and to pattern a one-dimensional array of first gate electrode material layers 68S into a two-dimensional array of first word lines 68, i.e., a two-dimensional L×N array of first word lines 68. Each of the first word lines 68 comprises a respective row of first gate electrodes (i.e., M first gate electrodes that are merged among one another) arranged along the second horizontal direction hd2. Each first gate dielectric 60 has a first tubular configuration and laterally surrounds a first portion of a respective horizontally-extending semiconductor channel 14, and laterally extends along the first horizontal direction hd1. Each first gate electrode comprises a respective portion of a first word line 68 that laterally extends along the second horizontal direction hd2. Each first gate electrode wraps around a respective first tubular gate dielectric 60 in a vertical cross-sectional view that is perpendicular to the first horizontal direction hd1.

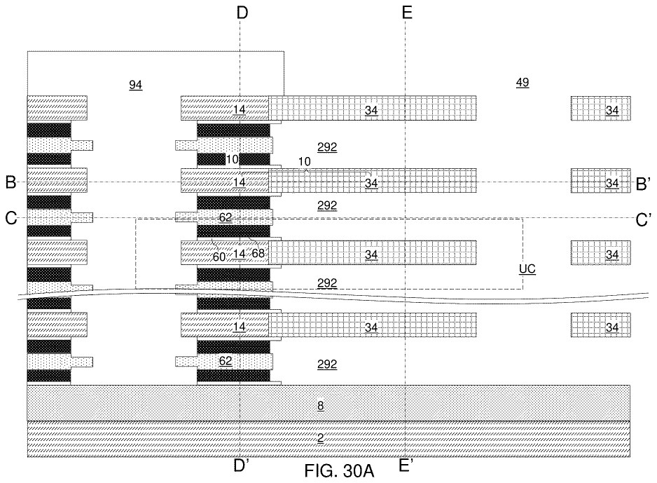

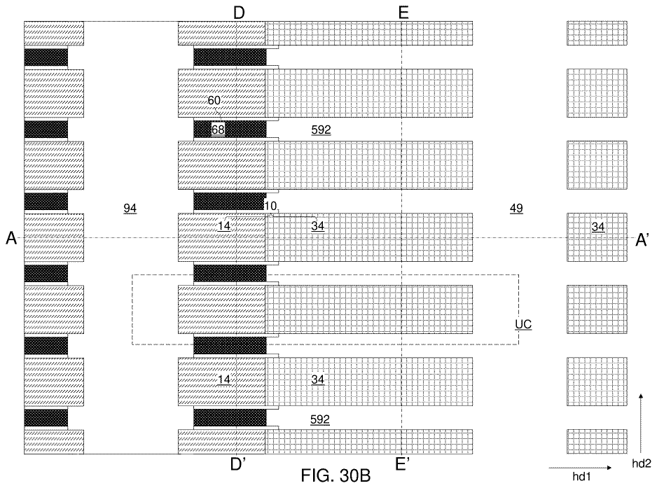

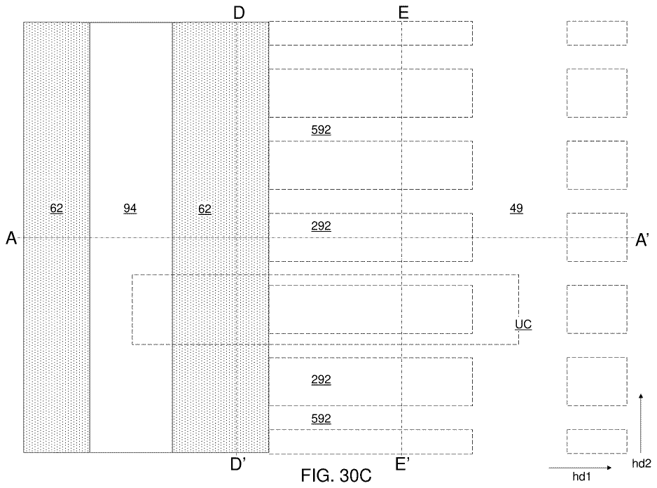

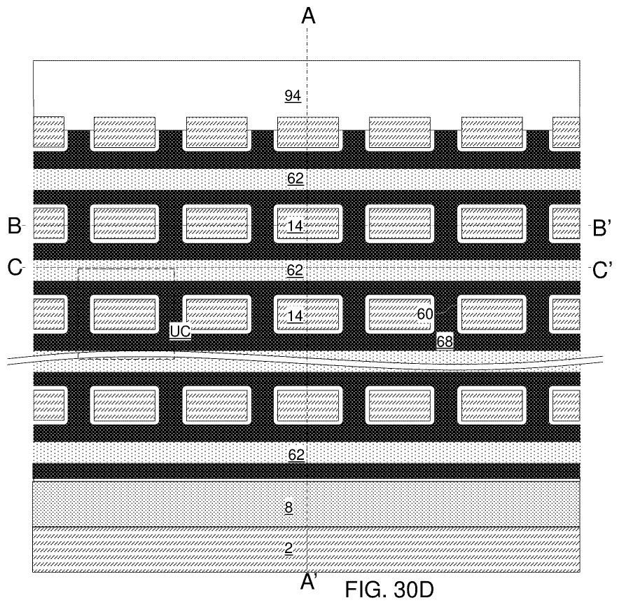

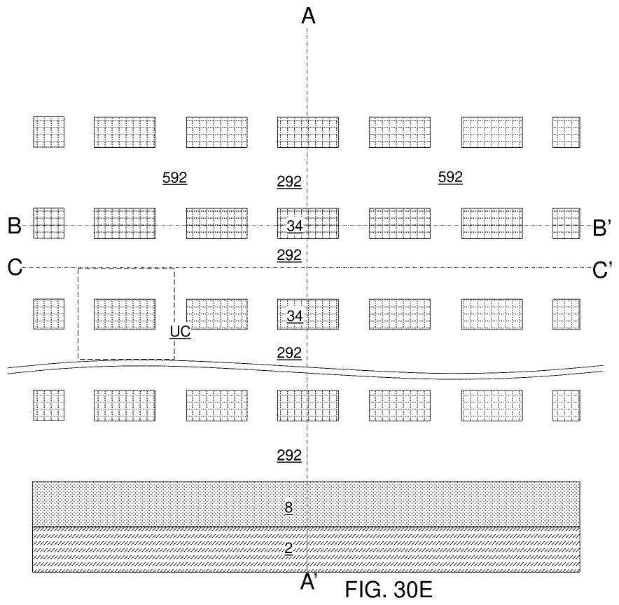

Referring to FIGS. 30A, 30B, 30C, 30D, and 30E, a doping process may be optionally performed to electrically dope the second portions of the semiconductor rails 10 that are exposed to the combination of the second inter-rail cavities 292 and the second lateral isolation trenches 592. For example, a gas phase doping process or an outdiffusion process employing a conformally deposited sacrificial doped silicate glass layer (such as a sacrificial phosphosilicate or borosilicate glass layer) may be employed to convert the second portions of the semiconductor rails 10 that are laterally surrounded by the combination of the second inter-rail cavities 292 and the second lateral isolation trenches 592 into semiconductor channel portions having a different atomic concentration of dopants than the semiconductor rails 10 as provided at the processing steps described with reference to FIG. 4A-4E. The portion of each semiconductor rail 10 having a same atomic concentration of electrical dopants as originally provided at the processing steps described with reference to FIG. 4A-4E are herein referred to as a first semiconductor channel 14, or a first horizontally-extending semiconductor channel 14. The portion of each semiconductor rail 10 having a modified atomic concentration of electrical dopants through the conformal doping process is herein referred to as a second semiconductor channel 34, or a second horizontally-extending semiconductor channel 34.

In an illustrative example, the first horizontally-extending semiconductor channels 14 may have a doping of a first conductivity type, and may include electrical dopants of the first conductivity type at an atomic concentration in a range from 1×10¹⁴/cm³ to 3×10¹⁶/cm³, although lesser and greater atomic concentrations may also be employed. The second horizontally-extending semiconductor channels 34 may have a doping of the first conductivity type, and may include electrical dopants of the first conductivity type at an atomic concentration in a range from 1×10¹⁵/cm³ to 3×10¹⁷/cm³, although lesser and greater atomic concentrations may also be employed. Thus, the first horizontally-extending semiconductor channels 14 may have a lower doping concentration than the second horizontally-extending semiconductor channels 14.

Generally, a first horizontally-extending semiconductor channel 14 is present within the first portion of each semiconductor rail 10 that is laterally surrounded by a respective first gate electrode (which includes a respective portion of a first word line 68), and a second horizontally-extending semiconductor channel 34 is present within the second portion of each semiconductor rail 10 that is laterally surrounded by the combination of the second inter-rail cavities 292 and the second lateral isolation trenches 592. The second horizontally-extending semiconductor channel 34 contacts the first horizontally-extending semiconductor channel 14 within each semiconductor rail 10. In case the doping process is performed, the second horizontally-extending semiconductor channel 34 and the first horizontally-extending semiconductor channel 14 within each semiconductor rail 10 comprise a same semiconductor material but comprise electrical dopants at different atomic concentrations.

The doping process described with reference to FIG. 30A-30E is optional, and thus, may be omitted. In case the doping process is omitted, the second horizontally-extending semiconductor channel 34 and the first horizontally-extending semiconductor channel 14 have a same material composition. In this case, the second horizontally-extending semiconductor channel 34 and the first horizontally-extending semiconductor channel 14 within each semiconductor rail 10 consist of the same semiconductor material, and thus, include electrical dopants of the same species at the same atomic concentration.

Generally, the first horizontally-extending semiconductor channel 14 and the second horizontally-extending semiconductor channel 34 have a same uniform vertical cross-sectional shape within any vertical cross-sectional view that cuts through the first horizontally-extending semiconductor channel 14 or the second horizontally-extending semiconductor channel 34 and is perpendicular to the first horizontal direction hd1 irrespective of a location of a vertical cut plane for a respective vertical cross-sectional view. In other words, the entirety of each semiconductor rail may have the same vertical cross-sectional shape within any vertical cross-sectional view that cuts through the semiconductor rail 10 and is perpendicular to the first horizontal direction hd1 irrespective of a location of a vertical cut plane for a respective vertical cross-sectional view.

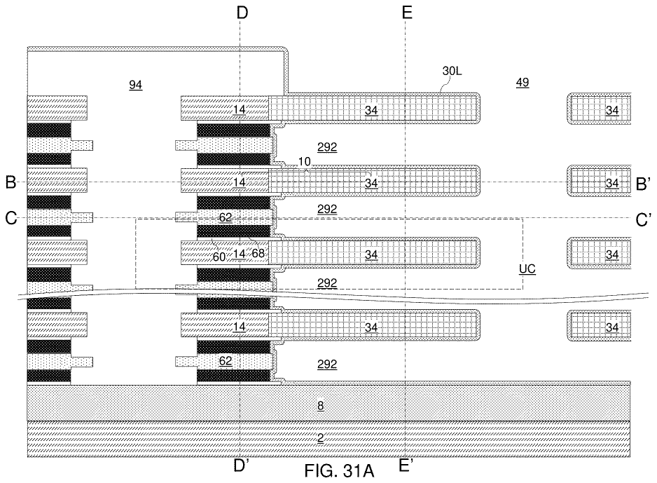

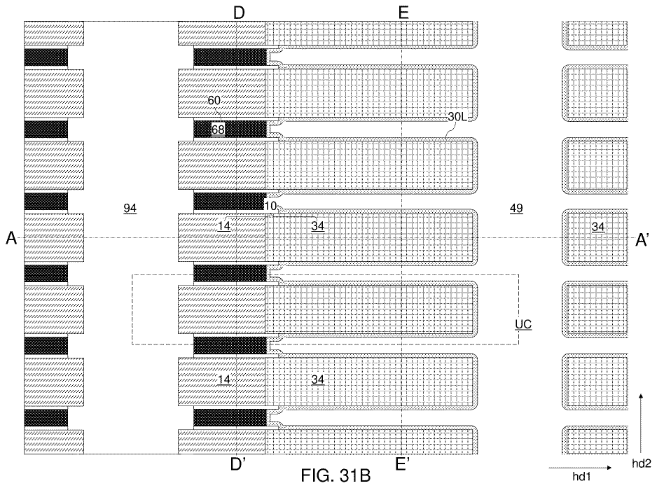

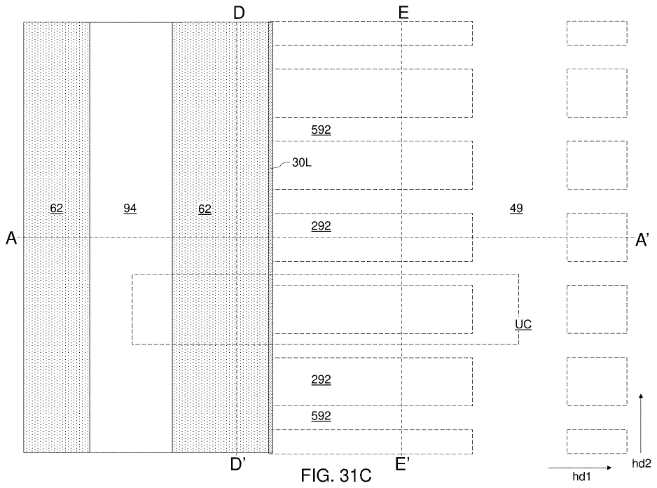

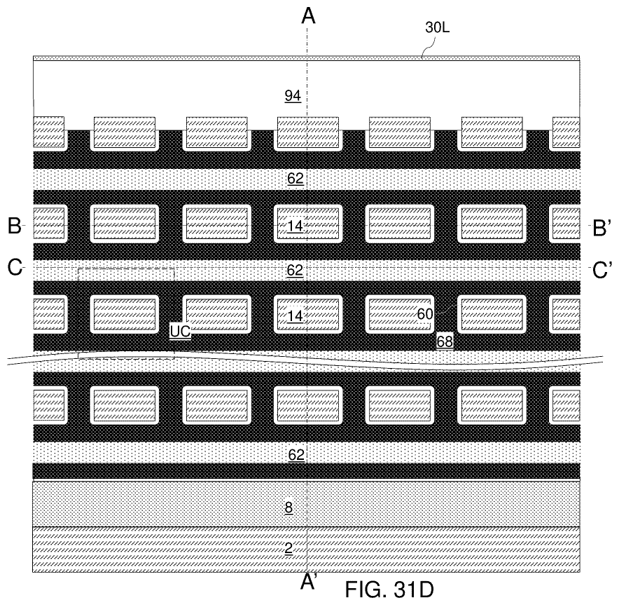

Referring to FIGS. 31A, 31B, 31C, 31D, and 31E, a second gate dielectric material can be conformally deposited to form a second gate dielectric material layer 30L. For example, a chemical vapor deposition process or an atomic layer deposition process may be employed to deposit the second gate dielectric material layer 30L. The thickness of the second gate dielectric material layer 30L may be in a range from 2 nm to 40 nm, although lesser and greater thicknesses may also be employed. The second gate dielectric material layer 30L is deposited as a continuous material layer directly on first sidewalls of the two-dimensional L×N array of first word lines 68 that are perpendicular to the first horizontal direction hd1, directly on physically exposed first sidewalls, physically exposed top surface segments, and physically exposed bottom surface segments of the two-dimensional L×N array of first dielectric plates 62, and on the lengthwise sidewalls, the top surfaces, the bottom surfaces, and end surfaces of the second horizontally-extending semiconductor channels 34 of the three-dimensional L×M×N array of semiconductor rails 10. The second gate dielectric material layer 30L can be deposited in the second inter-rail cavities 292 and around the second portion of each of the horizontally-extending semiconductor rails 10.

According to an aspect of the present disclosure, the second gate dielectric material comprises a ferroelectric or charge trapping dielectric material having at least two programmable states. In one embodiment, the second gate dielectric material comprises or consists essentially of the ferroelectric dielectric material described above. In one embodiment, the second gate dielectric material comprises a layer stack including a ferroelectric dielectric material layer and a non-ferroelectric dielectric material layer. In another embodiment, the second gate dielectric material comprises or consists essentially of a charge trapping dielectric material, such as silicon nitride or a stack of silicon oxide, silicon nitride and silicon oxide sublayers. In one embodiment, the second gate dielectric material layer 30L contacts sidewalls of the first gate electrodes of each access field effect transistor (which includes a respective contiguous combination of a first semiconductor channel 14, a first tubular gate dielectric 60, and a first gate electrode which is a portion of a first word line 68) within a three-dimensional L×M×N array of access field effect transistors.

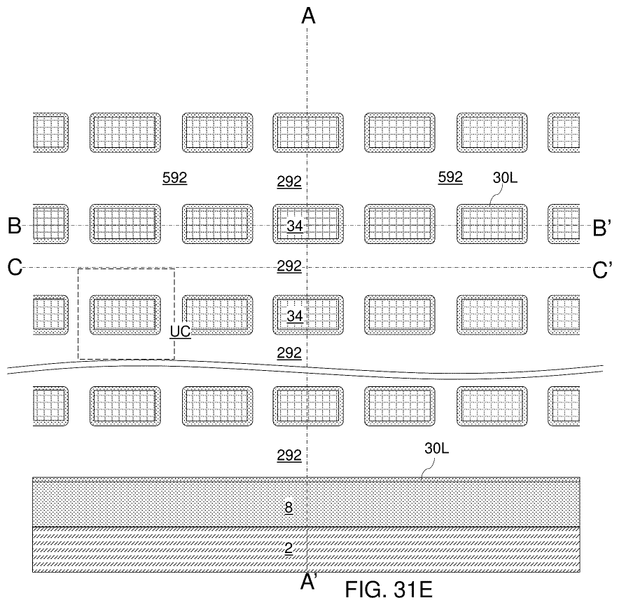

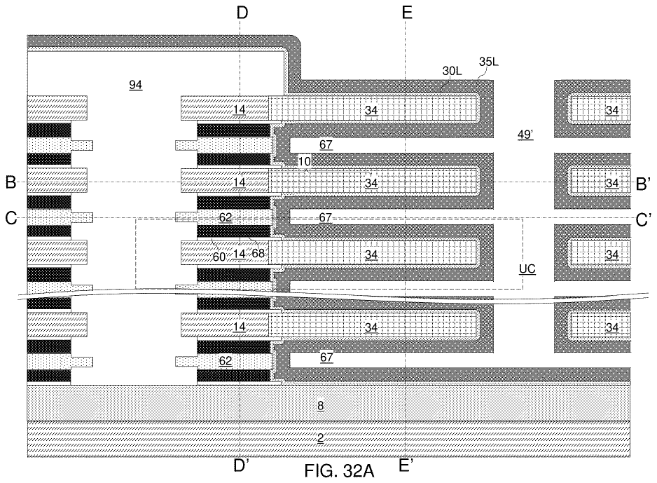

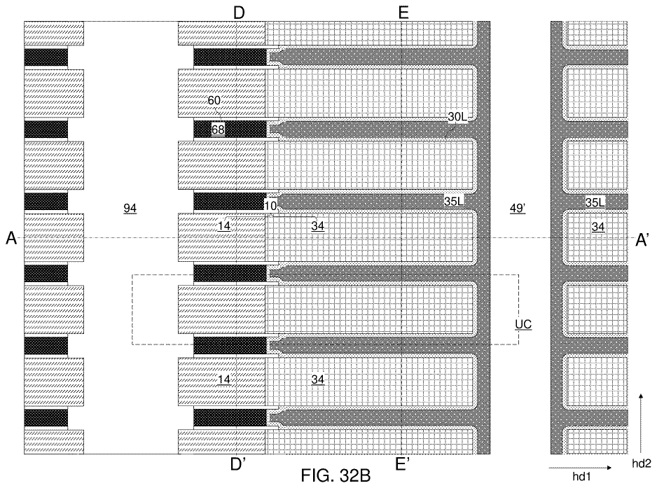

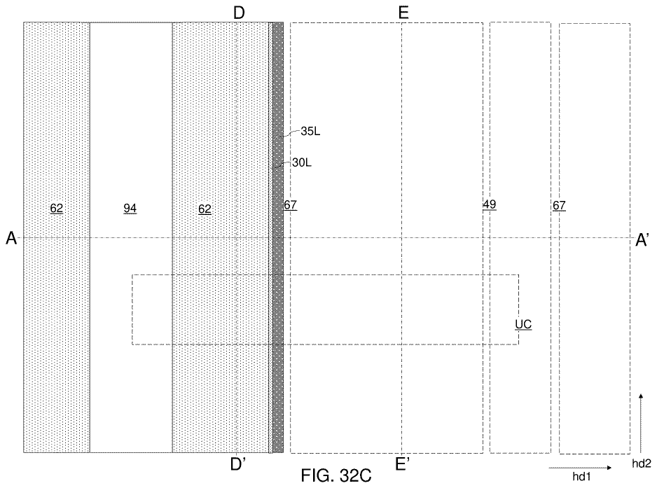

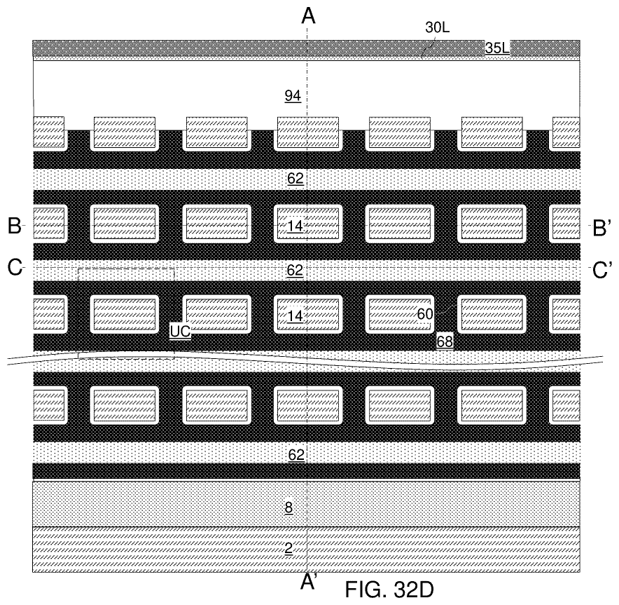

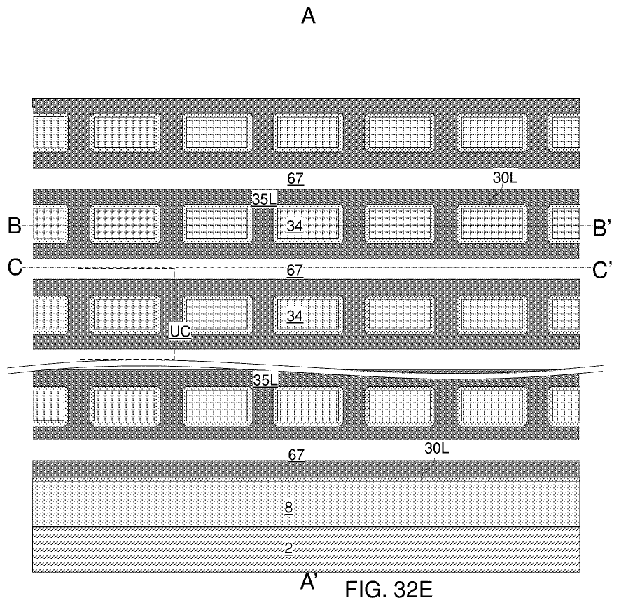

Referring to FIGS. 32A, 32B, 32C, 32D, and 32E, a dielectric gate spacer material such as silicon nitride, silicon oxide, organosilicate glass, or a dielectric metal oxide can be conformally deposited to form a dielectric gate spacer material layer 35L. Thus, the dielectric gate spacer material is deposited as a continuous material layer on the second gate dielectric material. The sum of the thickness of the second gate dielectric material layer 30L and the thickness of the dielectric gate spacer material layer 35L is greater than one half of the lateral spacing between neighboring pairs of semiconductor rails 10 that are spaced from each other along the second horizontal direction hd2. Thus, the dielectric gate spacer material fills gaps between laterally-neighboring pairs of the second portions of the horizontally-extending semiconductor rails 10.

According to an aspect of the present disclosure, the dielectric gate spacer material of the dielectric gate spacer material layer 35L is deposited as a continuous material layer such that lateral gaps between laterally-neighboring pairs of the second portions of the horizontally-extending semiconductor rails 10 are filled with the dielectric gate spacer material, while vertical gaps between vertically-neighboring pairs of the second portions of the horizontally-extending semiconductor rails 10 are not completely filled with the dielectric gate spacer material. Thus, second laterally-extending voids 67 that laterally extend along the second horizontal direction hd2 are present in unfilled volumes of the vertical gaps between neighboring pairs of second portions of the semiconductor rails 10 after deposition of the dielectric gate spacer material of the dielectric gate spacer material layer 35L. A laterally-extending void 49′ can be present within each source trench 49.

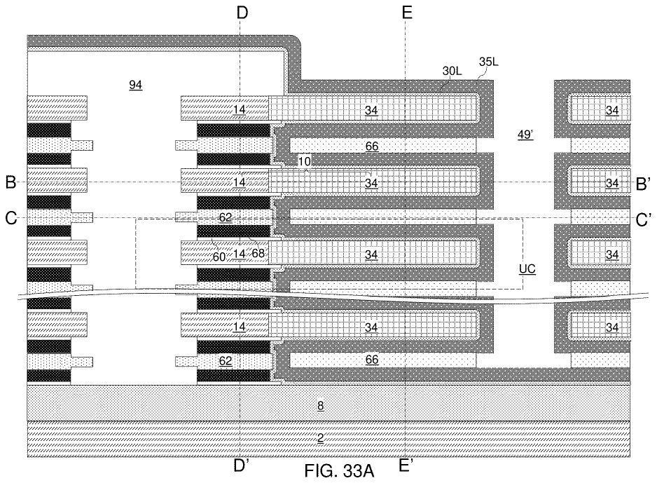

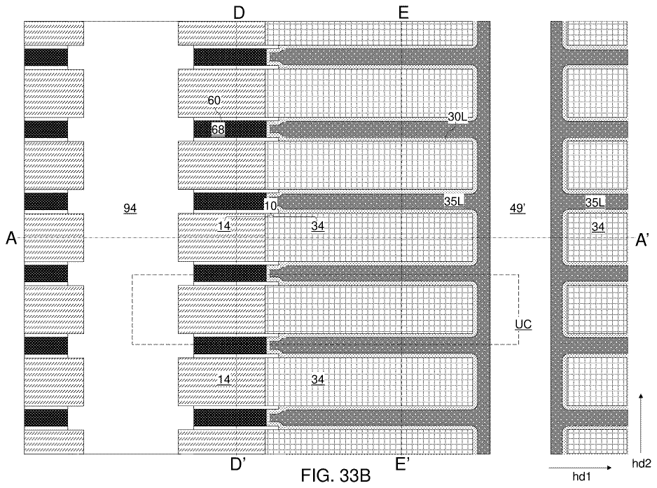

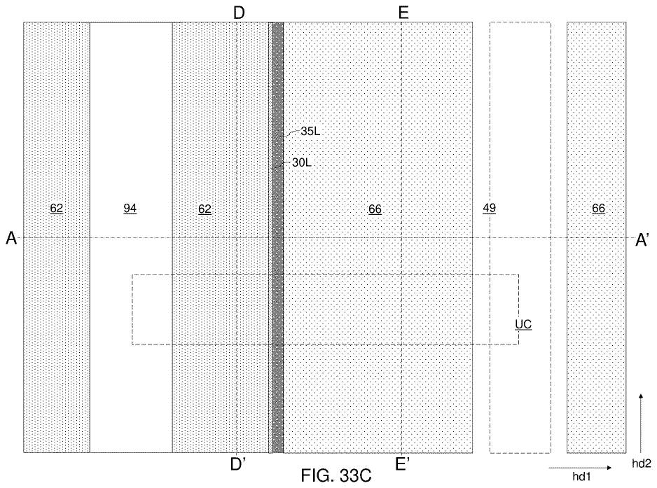

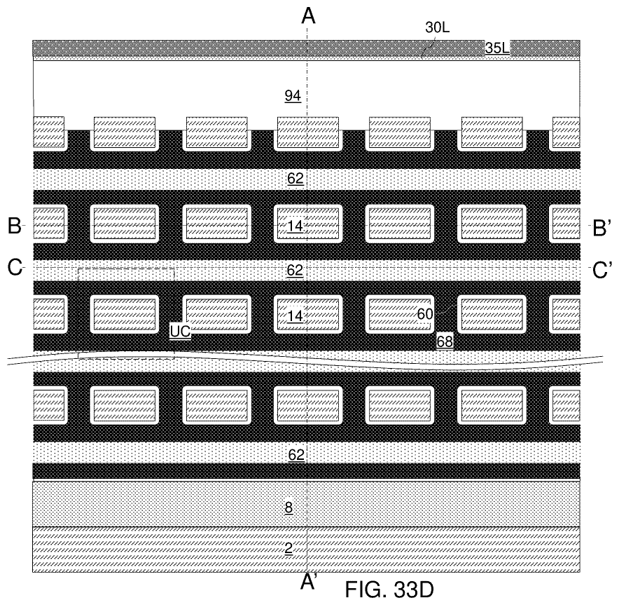

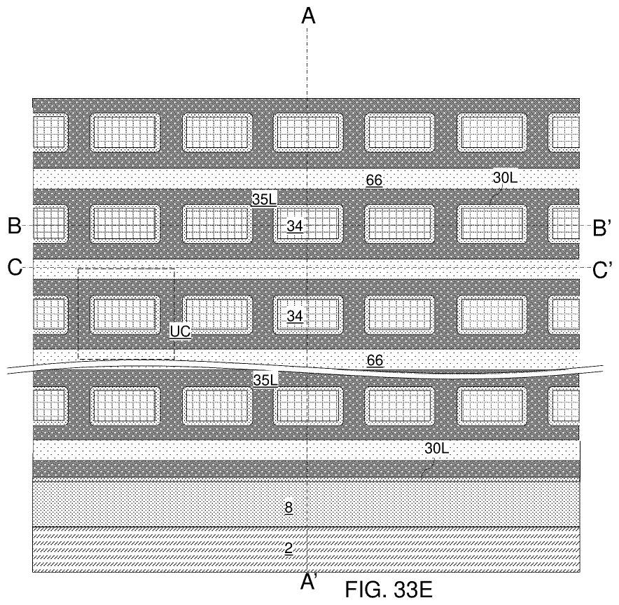

Referring to FIGS. 33A, 33B, 33C, 33D, and 33E, a two-dimensional L×N array of second dielectric plates 66 can be formed. The second dielectric plates 66 are formed between laterally-extending portions of the dielectric gate spacer material layer 35L by conformally depositing a dielectric fill material and isotropically or anisotropically recessing the dielectric fill material. Remaining portions of the dielectric fill material comprise the second dielectric plates 66. Specifically, a second dielectric fill material such as silicon oxide or silicon carbonitride which is different from the material of the dielectric gate spacer material layer 35L can be conformally deposited in the second laterally-extending voids 67, in peripheral portions of the source trenches 49, and over the horizontally-extending portion of the dielectric gate spacer material layer 35L that overlie the three-dimensional array of semiconductor rails 10. An isotropic or anisotropic recess etch process may be performed to remove portions of the second dielectric fill material from outside the volumes of the second laterally-extending voids 67. Remaining portions of the second dielectric fill material that fill the second laterally-extending voids 67 comprise a two-dimensional array of second dielectric plates 66. Each second dielectric plate 66 is formed between a respective vertically neighboring pair of laterally extending portions of the dielectric gate spacer material layer 35L that laterally extend along the second horizontal direction hd2.

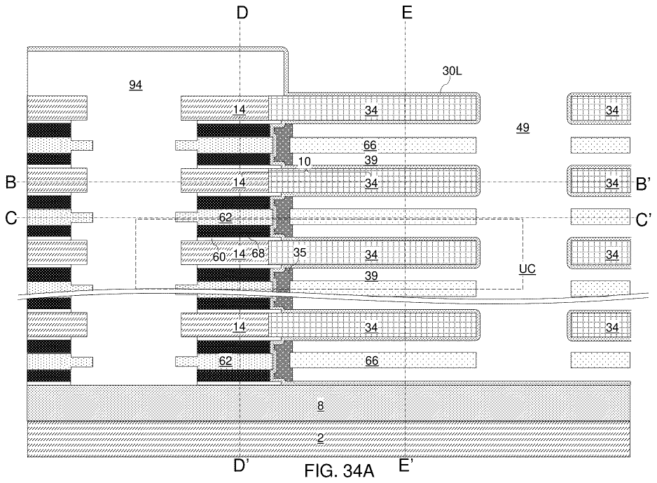

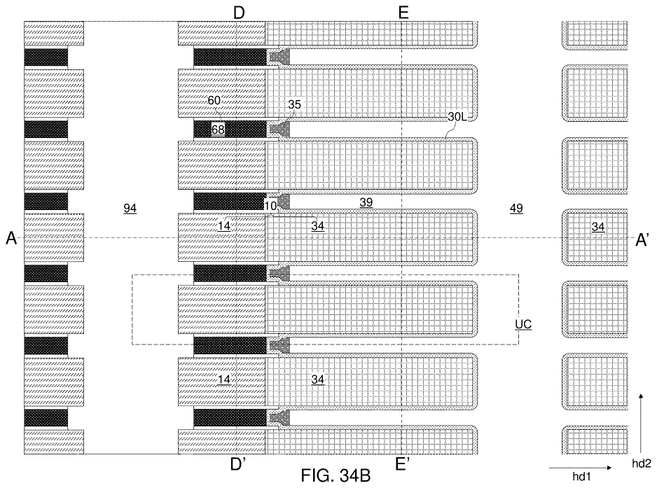

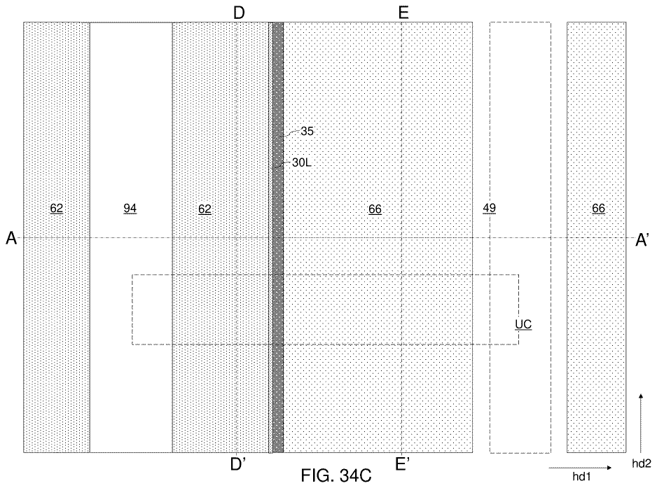

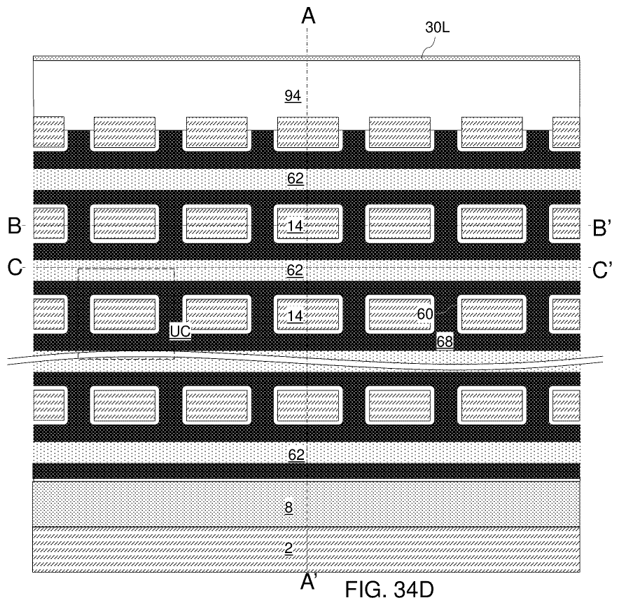

Referring to FIGS. 34A, 34B, 34C, 34D, and 34E, a selective isotropic etch process can be performed to isotropically recess the material of the dielectric gate spacer material layer 35L selectively to the materials of the second dielectric plates 66 and the second gate dielectric material layer 30L. Gate cavities 39 are formed by isotropically etching first portions of the dielectric gate spacer material selectively to materials of the second gate dielectric material and selectively to the material of the second dielectric plates 66. For example, if the dielectric gate spacer material layer 35L comprises silicon nitride, a wet etch process employing hot phosphoric acid may be performed to laterally recess the dielectric gate spacer material layer 35L relative to silicon oxide second dielectric plates 66.

Second portions of the dielectric gate spacer material are not removed during the selective isotropic etch process. Specifically, the duration of the selective isotropic etch process can be selected such that a continuous vertically-extending remaining portion of the dielectric gate spacer material layer 35L remains around each two-dimensional M×N array of semiconductor rails 10 and around each vertical stack of N second dielectric plates 66. Each continuous vertically-extending remaining portion of the dielectric gate spacer material layer 35L comprises a dielectric gate spacer 35.

According to an aspect of the present disclosure, the entirety of each sidewall of the second dielectric plates 66 that is perpendicular to the first horizontal direction hd1 and is not exposed directly to a respective source trench 49 is contacted by a respective dielectric gate spacer 35. Each dielectric gate spacer 35 contacts sidewalls of a respective vertical stack of N second dielectric plates 66 and laterally surrounds a respective two-dimensional M×N array of second horizontally-extending semiconductor channels 34. Generally, a two-dimensional M×N array of semiconductor rails 10 laterally extends through an M×N array of openings through a dielectric gate spacer 35.

The gate cavities 39 are formed within the combined volumes of the second lateral isolation trenches 592 and the second inter-rail cavities 292. A vertical stack of N gate cavities 39 is formed around each two-dimensional M×N array of semiconductor rails 10. In the second exemplary structure, the topmost semiconductor rails 10 (i.e., the L×M two-dimensional array of topmost semiconductor rails 10) are not employed to form a three-dimensional L×M×N array of unit cells UC, and the space that laterally surrounds the topmost semiconductor rails 10 is not considered to be a part of the vertical stacks of gate cavities 39. Each gate cavity 39 laterally surrounds a respective one-dimensional array of M semiconductor rails 10 that are arranged along the second horizontal direction hd2.

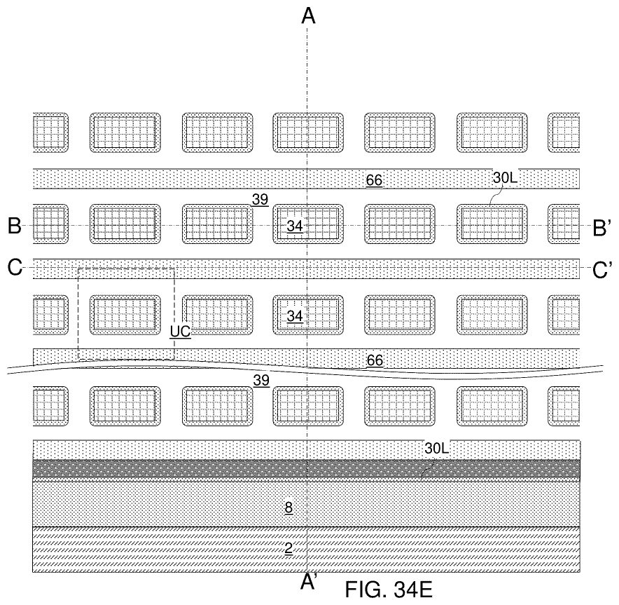

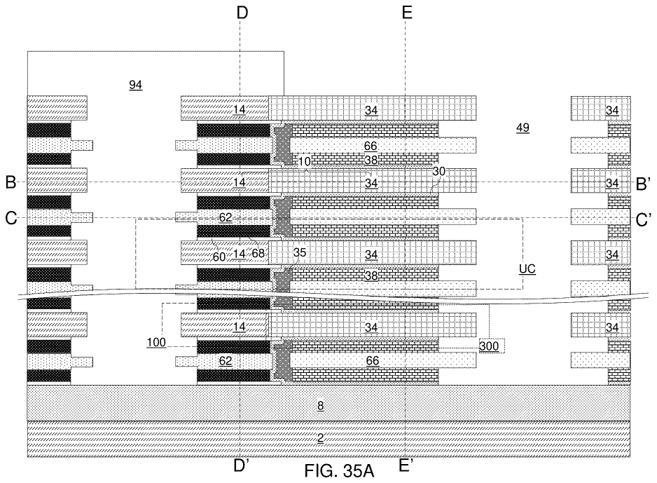

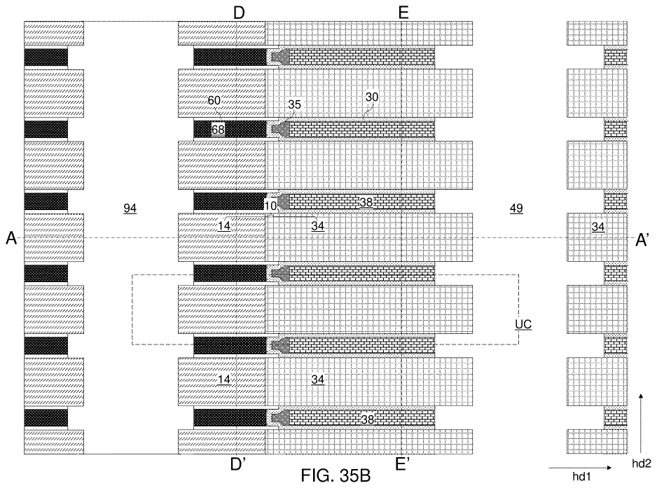

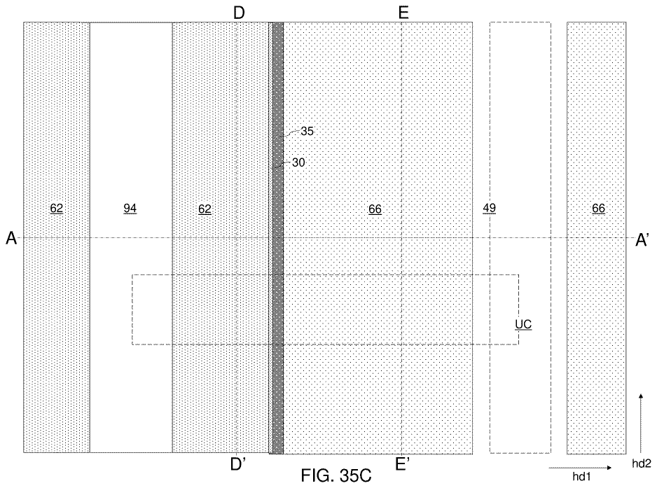

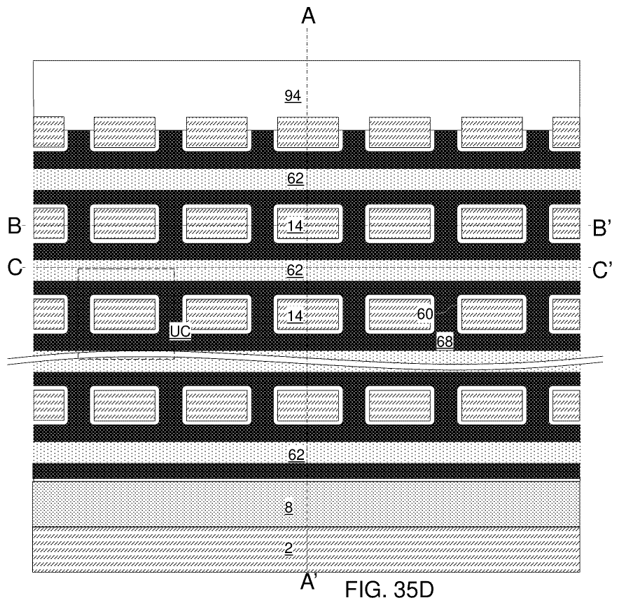

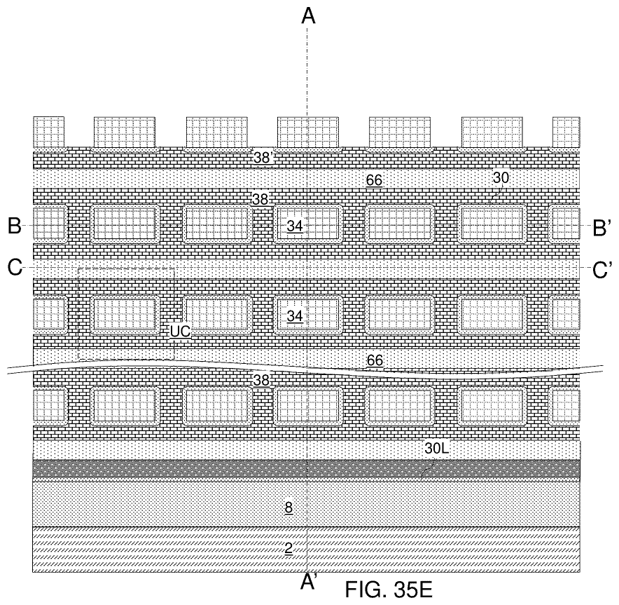

Referring to FIGS. 35A, 35B, 35C, 35D, and 35E, a second gate electrode material can be conformally deposited in the gate cavities 39, in peripheral regions of the source trenches 49, and over the topmost semiconductor rails 10. The second gate electrode material may comprise any gate electrode material known in the art. For example, the second gate electrode material may comprise at least one metallic material such as TiN, TaN, WN, MoN, W, Ru and/or Mo. The entire volume of each gate cavity 39 may be filled with the second gate electrode material.

An isotropic recess etch process (such as a wet etch process) can be performed to etch the second gate electrode material selectively to the material of the second gate dielectric material layer 30L and the second dielectric plates 66. For example, a wet etch process that etches metallic materials selectively to dielectric materials may be performed. The duration of the isotropic recess etch process can be selected such that the recessed surfaces of remaining portions of the second gate electrode material are formed on horizontal surfaces of the second dielectric plates 66. The remaining portions of the second gate electrode material comprise second word lines 38. Each second word line 38 may comprise an adjoined assembly of M second gate electrodes that extend along the second horizontal direction hd2 and laterally surround a respective one of the second horizontally-extending semiconductor channels 34. A two-dimensional L×N array of second word lines 38 is formed, which comprises a three-dimensional L×M×N array of second gate electrodes for a three-dimensional L×M×N array of memory field effect transistors 300.

Subsequently, a selective etch process can be performed to remove physically exposed portions of the second gate dielectric material layer 30L selectively to the materials of the semiconductor rails 10 and the second word lines 38. Each remaining patterned portion of the second gate dielectric material layer 30L comprises a second gate dielectric layer that laterally surrounds a respective M×N array of second horizontally-extending semiconductor channels 34. A total of L second gate dielectric layers can be formed. Each portion of a second gate dielectric layer located within the volume of a respective unit cell UC constitutes a second gate dielectric 30. Thus, each second gate dielectric layer may comprise a respective M×N array of second gate dielectrics 30. Each second gate dielectric 30 comprises a tubular portion that laterally surrounds a respective second horizontally-extending semiconductor channel 34 and a vertically-extending portion that contacts a sidewall of a respective first gate electrode (which is a portion of a respective first word line 68). Each memory field effect transistor 300 can store a data bit by programming the ferroelectric polarization direction or injecting charge carriers (e.g., electrons using Fowler-Nordheim tunneling or hot carrier injection) into the second gate dielectric material layer 30L.

Each second gate electrode 38 wraps around a respective second gate dielectric 30 in a vertical cross-sectional view that is perpendicular to the first horizontal direction hd1, as shown in FIG. 35W. A sidewall of each second gate dielectric 30 is in contact with a sidewall of the first gate electrode 38. In one embodiment, each interface between the sidewall of a second gate dielectric 30 and the sidewall of a respective first gate electrode (which is a portion of a first word line 68) is perpendicular to the first horizontal direction hd1. In one embodiment, each first gate dielectric 60 can be in contact with a respective second gate dielectric 30. In one embodiment, each interface between a first gate dielectric 60 and a second gate dielectric 30 comprises horizontal surface segments and vertical surface segments that are parallel to the first horizontal direction hd1.

In one embodiment, each second gate dielectric 30 comprises a portion which has a second tubular configuration and laterally surrounds a respective second horizontally-extending semiconductor channel 34 and laterally extends along the along the first horizontal direction hd1. A two-dimensional M×N array of second gate dielectrics 30 can be interconnected to each other to form a second gate dielectric layer, which is a continuous material layer. L two-dimensional M×N arrays of second gate dielectrics 30 comprise a three-dimensional L×M×N array of second gate dielectrics 30. The L×M×N array of unit cells UC comprises a three-dimensional memory array. Each second gate dielectric 30 within the three-dimensional memory array is a portion of a respective continuous gate dielectric layer (such as a second gate dielectric layer) that laterally extends along the second horizontal direction hd2 and contacts the first gate electrode of each access field effect transistor within a respective row of unit cells UC. In one embodiment, each second gate dielectric 30 within the three-dimensional memory array is a portion of a respective continuous gate dielectric layer (such as a second gate dielectric layer) that contacts the first gate electrode of each access field effect transistor within a respective vertical stack of unit cells UC.

In one embodiment, a two-dimension array of second dielectric plates 66 can be arranged along the first horizontal direction hd1 and along a vertical direction. In one embodiment, each second dielectric plate 66 contacts a top surface of a respective underlying second word line 38 that includes a first row (i.e., an underlying row) of the second gate electrodes and contacts a bottom surface of a respective overlying second word line 38 that includes a second row (i.e., an overlying row) of the second gate electrodes. The dielectric gate spacers 35 are located between a respective one of the first word lines 68 and a respective one of the second word lines 38 (which include a respective row of second gate electrodes). Each dielectric gate spacer 35 may be in contact with a sidewall of a respective row of second gate electrodes, and may be laterally spaced from a respective row of first gate electrodes (comprising portions of first word lines 68) and a respective row of M first gate dielectrics 60 by a respective row of second gate dielectrics 30 (that are adjoined to each other within a second gate dielectric layer).

In summary, a second gate electrode material can be deposited in the gate cavities 39, and can be isotropically recessed. Portions of the second gate electrode material that fill the gate cavities 39 comprise second gate electrodes (which comprise portions of the second word lines 38). Thus, the first portions of the dielectric gate spacer material can be replaced with the second gate electrodes (which are portions of the second word line 38). A second gate electrode (comprising a portion of a second word line 38) can be formed around a second portion of each of the horizontally-extending semiconductor rails 10.

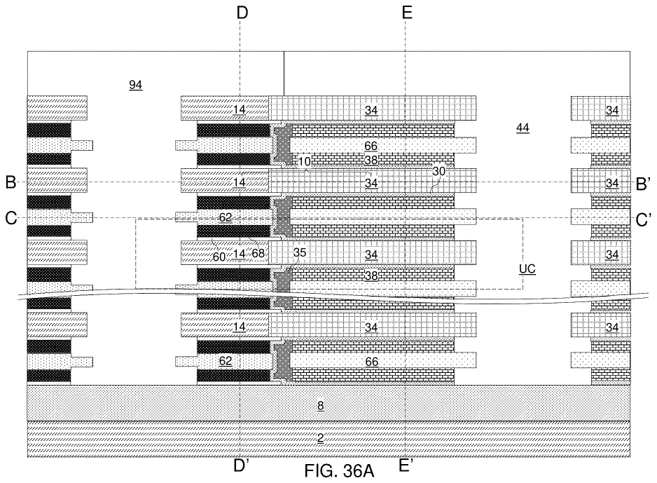

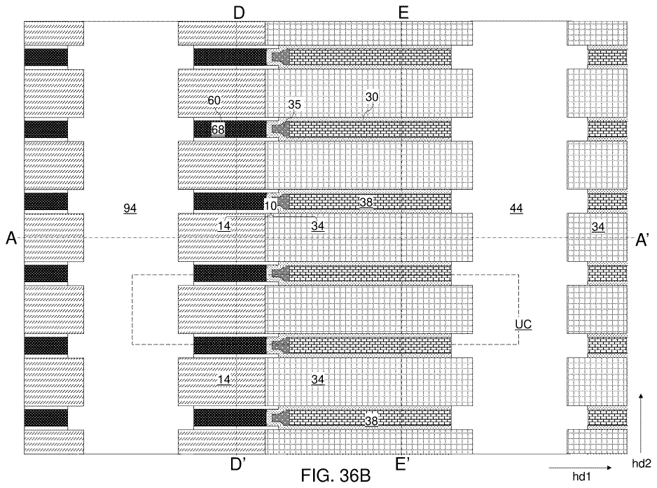

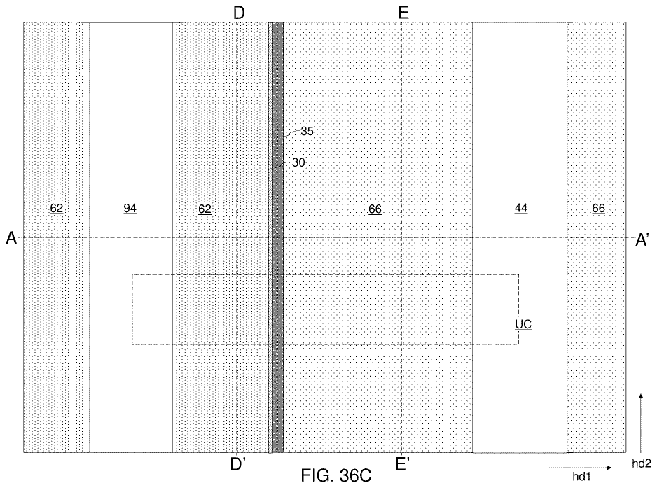

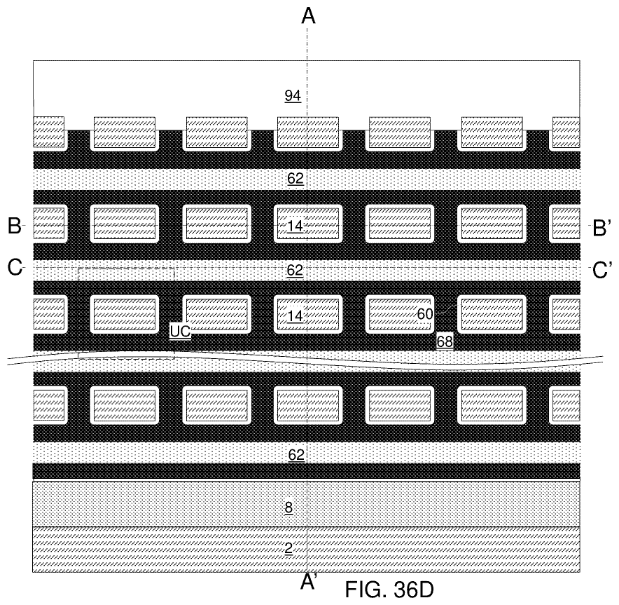

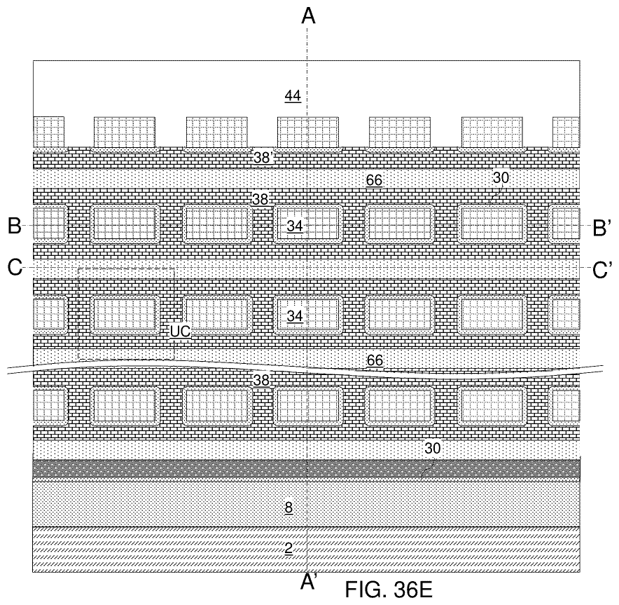

Referring to FIGS. 36A, 36B, 36C, 36D, and 36E, a dielectric fill material, such as undoped silicate glass or a doped silicate glass, can be deposited in the source trenches 49. A planarization process, such as a chemical mechanical polishing process, can be performed to remove portions of the dielectric fill material from above the horizontal plane including the top surfaces of the bit-line trench isolation structures 94. Each remaining portion of the dielectric fill material that fills the source trenches 49 comprise a source trench isolation structure 44. In one embodiment, top surfaces of the source trench isolation structures 44 may be formed within the horizontal plane including the top surfaces of the bit-line trench isolation structures 94. A laterally alternating sequence of source trench isolation structures 44 and bit-line trench isolation structures 94 can be arranged along the first horizontal direction hd1.

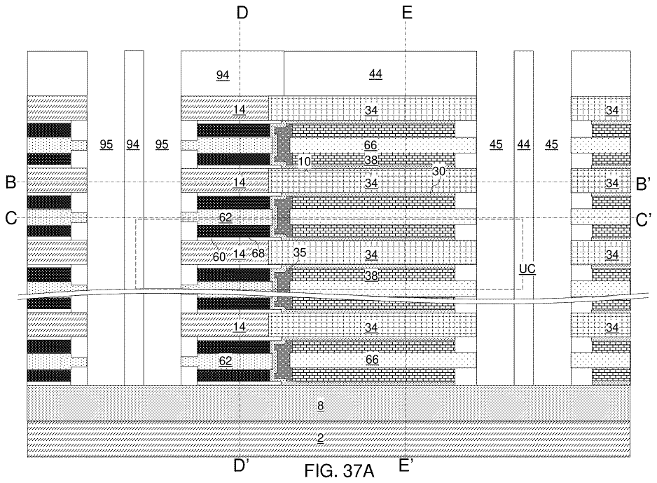

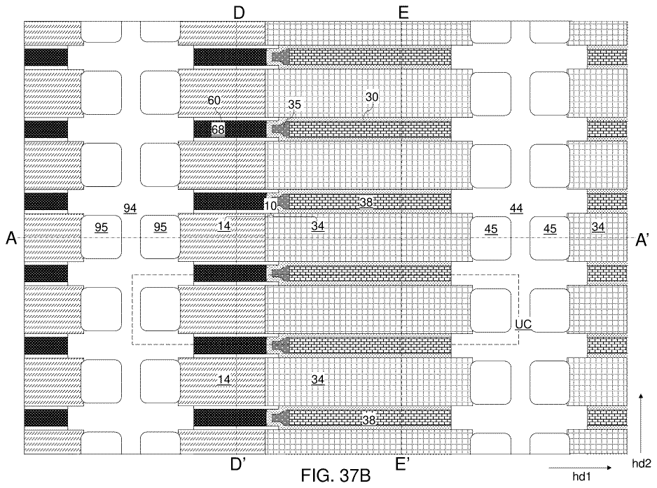

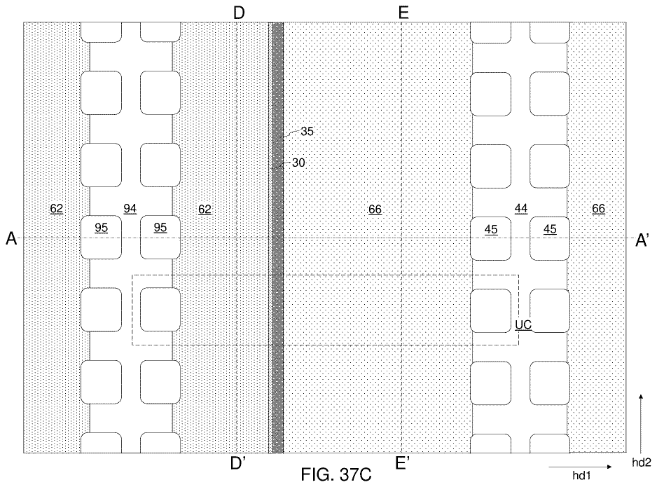

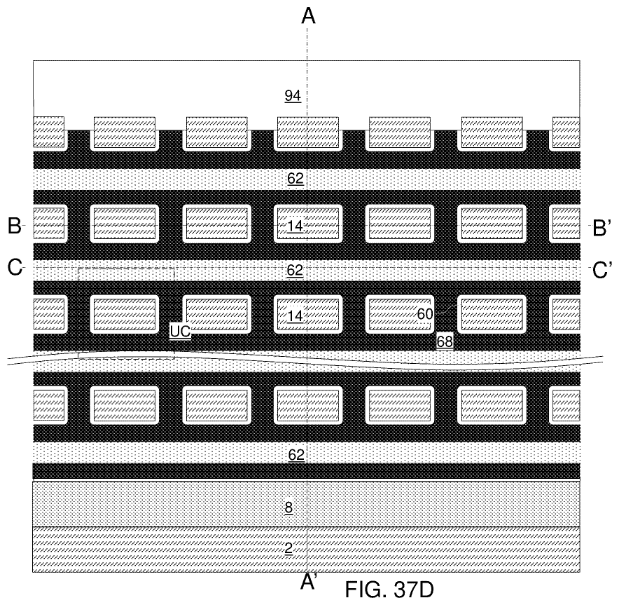

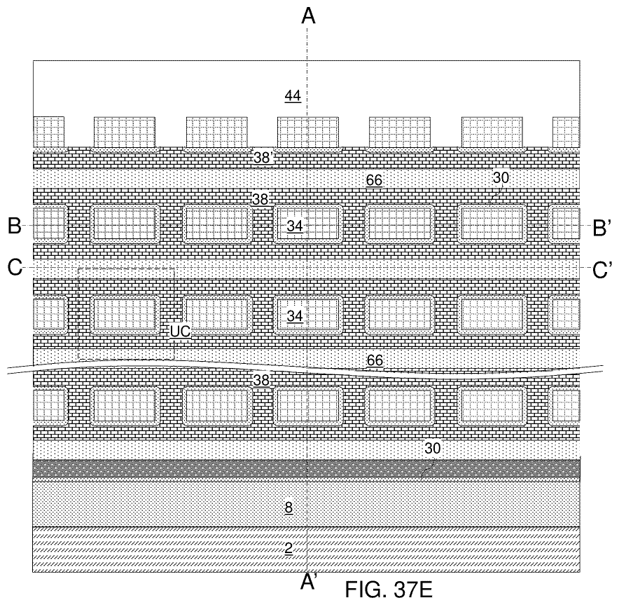

Referring to FIGS. 37A, 37B, 37C, 37D, and 37E, a photoresist layer (not shown) can be applied over the second exemplary structure, and can be lithographically patterned to form a total of (L+1)×M openings over the bit-line trench isolation structures 94 and the source trench isolation structures 44. Each opening in the photoresist layer may have an areal overlap in a plan view with a respective vertical stack of (N+1) interfaces between (N+1) semiconductor rails 10 and a bit-line trench isolation structure 94 or a source trench isolation structures 44. An anisotropic etch process can be performed to transfer the pattern of the openings in the photoresist layer through the bit-line trench isolation structures 94 and source trench isolation structures 44 and end segments of the semiconductor rails 10. Bit-line via cavities 95 vertically extending down to the etch stop structure 8 (or to the substrate 2 if the etch stop structure is omitted) can be formed through the bit-line trench isolation structures 94. Source-line via cavities 45 vertically extending down to the etch stop structure 8 (or to the substrate 2 if the etch stop structure is omitted) can be formed through the source trench isolation structures 44. The photoresist layer can be subsequently removed, for example, by ashing.

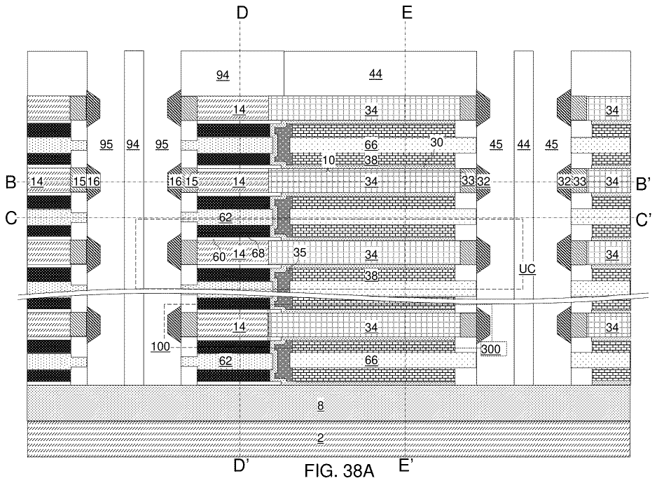

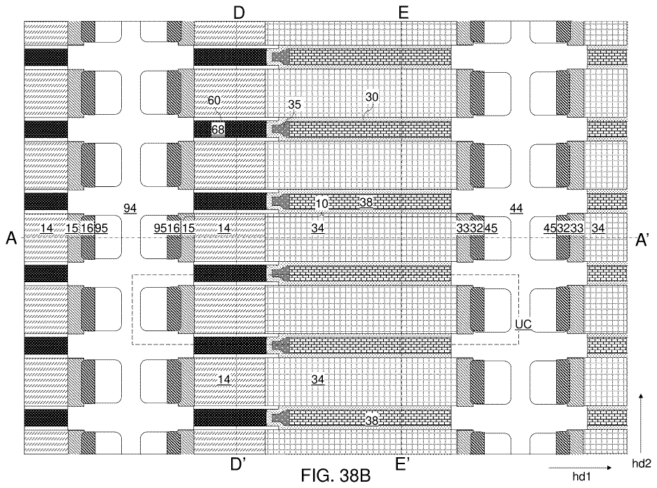

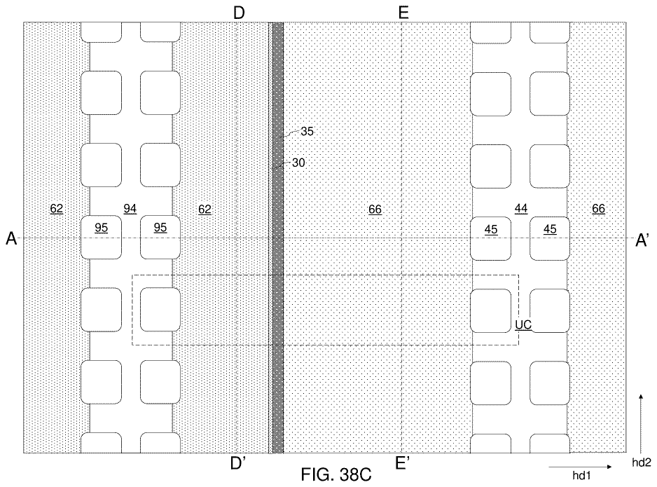

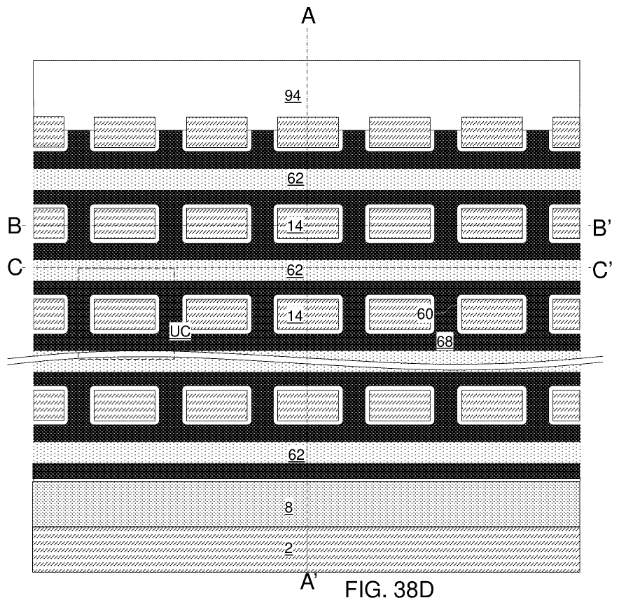

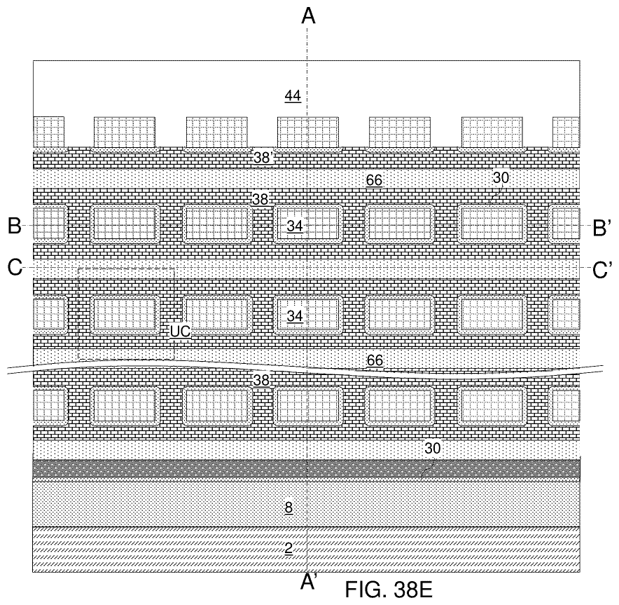

Referring to FIGS. 38A, 38B, 38C, 38D, and 38E, a conformal doping process may be performed to electrically dope surface portions of the semiconductor rails 10 that are proximal to the physically exposed surfaces of semiconductor rails 10. For example, a gas phase doping process or an outdiffusion process employing a conformally deposited sacrificial doped silicate glass layer (such as a sacrificial borosilicate glass layer or a sacrificial phosphosilicate glass layer) may be employed to convert surface portions of the second horizontally-extending semiconductor channels 34 that are proximal to the source-line via cavities 45 into source extension regions 33, and to convert surface portions of the first horizontally-extending semiconductor channels 14 that are proximal to the bit-line via cavities 95 into drain extension regions 15. In one embodiment, the first horizontally-extending semiconductor channels 14 and the second horizontally-extending semiconductor channels 34 may have a doping of a first conductivity type, and the source extension regions 33 and the drain extension regions 15 may have a doping of a second conductivity type that is the opposite of the first conductivity type. Alternatively, formation of the source extension regions 33 and the drain extension regions 15 may be omitted.

A selective semiconductor deposition process can be performed to grow a doped semiconductor material having a doping of the second conductivity type from first physically exposed semiconductor surfaces of the first portions of the horizontally-extending semiconductor rails 10 that are exposed to the source-line via cavities 45, and from second physically exposed semiconductor surfaces of the first portions of the horizontally-extending semiconductor rails 10 that are exposed to the bit-line via cavities 95. The selective semiconductor deposition process at this processing step may be substantially the same as the selective semiconductor deposition process described with reference to FIG. 20A-20E.

The selective semiconductor deposition process grows the source regions 32 on sidewalls of the second portions of the horizontally-extending semiconductor rails 10 (i.e., the portions that include the second horizontally-extending semiconductor channels 34); and grows the drain regions 16 on sidewalls of the first portions of the horizontally-extending semiconductor rails 10 (i.e., the portions that include the first horizontally-extending semiconductor channels 14) after formation of the second gate electrodes. In one embodiment, the source regions 32 are formed on first sidewalls of the semiconductor rails 10 within the source-line via cavities 45, and the drain regions 16 are formed on second sidewalls of the semiconductor rails 10 within the bit-line via cavities 95. The source regions 32 have different horizontal cross-sectional shapes in vertical cross-sectional views along vertical planes that are perpendicular to the first horizontal direction hd1 that vary as a function of a lateral distance from a most proximal one among the semiconductor rails 10. The drain regions 16 have different horizontal cross-sectional shapes in vertical cross-sectional views along vertical planes that are perpendicular to the first horizontal direction hd1 that vary as a function of a lateral distance from a most proximal one among the semiconductor rails 10.

A series connection of an access field effect transistor 100 and a memory field effect transistor 300 can be formed within each unit cell UC. The access field effect transistor comprises a first horizontally-extending semiconductor channel 14, a first gate dielectric 60, a first gate electrode (which is a portion of a first word line 68), an optional drain extension region 15, and a drain region 16. The memory field effect transistor comprises a second horizontally-extending semiconductor channel 34, a second gate dielectric 30 (which is a portion of a continuous gate dielectric layer that includes a two-dimensional M×N array of second gate dielectrics 30), a second gate electrode (which is a portion of a second word line 38), an optional source extension region 33, and a source region 12 having a same material composition as the drain region 16. Each of the source region 32 and the drain region 16 has a variable vertical cross-sectional shape within vertical planes that are perpendicular to the first horizontal direction hd1 as a function of a lateral distance from the first horizontally-extending semiconductor channel 14.

The second exemplary structure comprises a three-dimensional array of L×M×N unit cells UC. The unit cells UC may be arranged to provide: rows of a respective set of M unit cells UC arranged along a second horizontal direction hd2 that is different from the first horizontal direction hd1; columns of a respective set of L unit cells UC arranged along the first horizontal direction hd1; and vertical stacks of a respective set of N unit cells UC arranged along a vertical direction. According to an aspect of the present disclosure, the second gate dielectric 30 within each unit cell UC comprises a memory dielectric material having at least two programmable states. The at least two programmable states are selectively programmable depending on the polarity and/or the magnitude of an electrical bias across the second horizontally-extending semiconductor channel 34 and the second gate electrode 38 (which is a portion of a second word line 38 located within a respective unit cell UC).

Referring to FIGS. 39A, 39B, 39C, 39D, and 39E, at least one conductive material layer can be deposited in the remaining volumes of the bit-line via cavities 95 and the source-line via cavities 45. The at least one conductive material layer may comprise a combination of a metallic barrier material and a metallic fill material. Exemplary metallic barrier materials include TiN, TaN, WN, and/or MoN. Exemplary metallic fill materials include W, Co, Ru, Mo, Ti, Ta, Cu, etc. Excess portions of the at least one conductive material can be removed from above the horizontal plane including the top surfaces of the bit-line trench isolation structures 94 and the source trench isolation structures 44. Each remaining portion of the at least one conductive material that fills a respective source-line via cavity 45 comprises a vertical source line 46. Each vertical source line 46 contacts a vertical stack of N source regions 32 and may contact an overlying dummy source region located on a dummy semiconductor rail. An L×M array of vertical source lines 46 may be formed. Each remaining portion of the at least one conductive material that fills a respective bit-line via cavity 95 comprises a bit line 98. Each bit line 98 contacts a vertical stack of N drain regions 16 and may contact an overlying dummy drain region located on a dummy semiconductor rail. An L×M array of bit lines 98 may be formed.

Generally, a two-dimensional array of vertical bit lines 98 can be formed such that each of the vertical bit lines 98 contacts a set of drain regions 16 located within a respective vertical stack of unit cells UC. A two-dimensional array of vertical source lines 46 can be formed such that each of the vertical source lines 46 contacts a set of source regions 32 located within a respective vertical stack of unit cells UC.

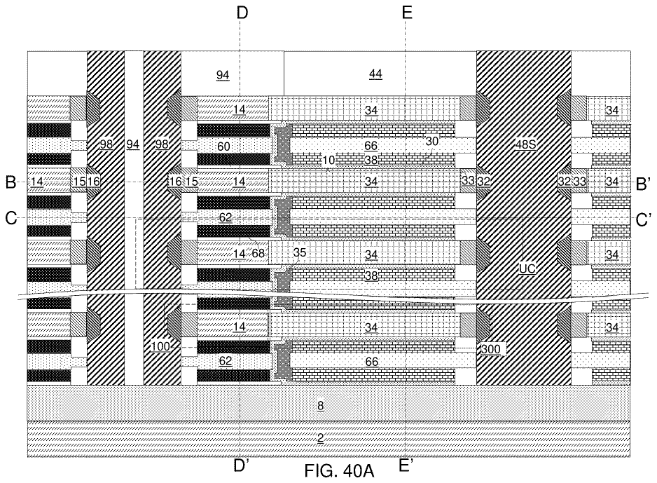

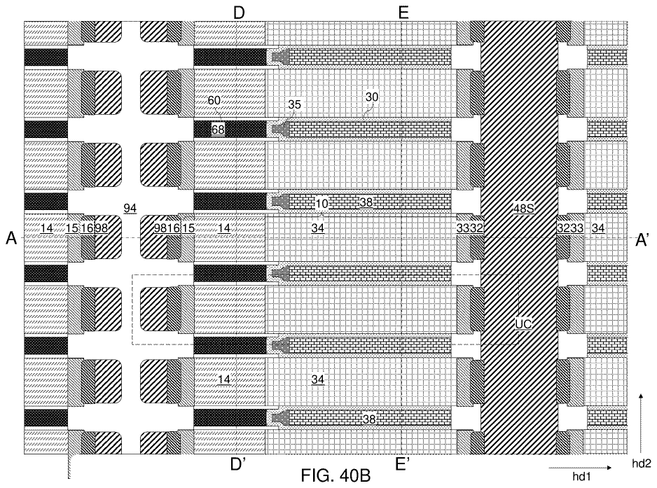

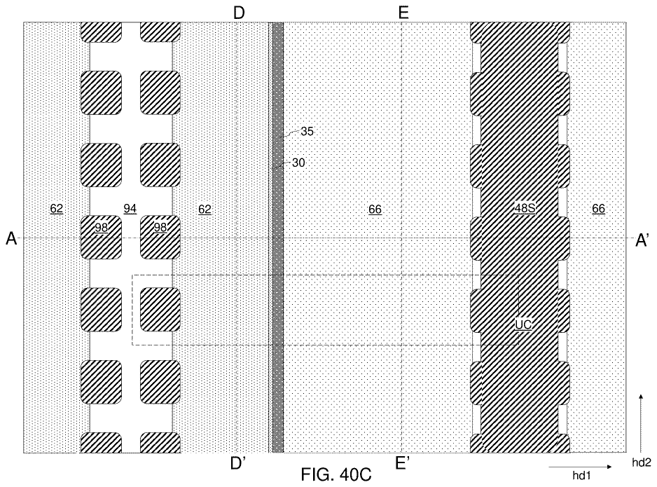

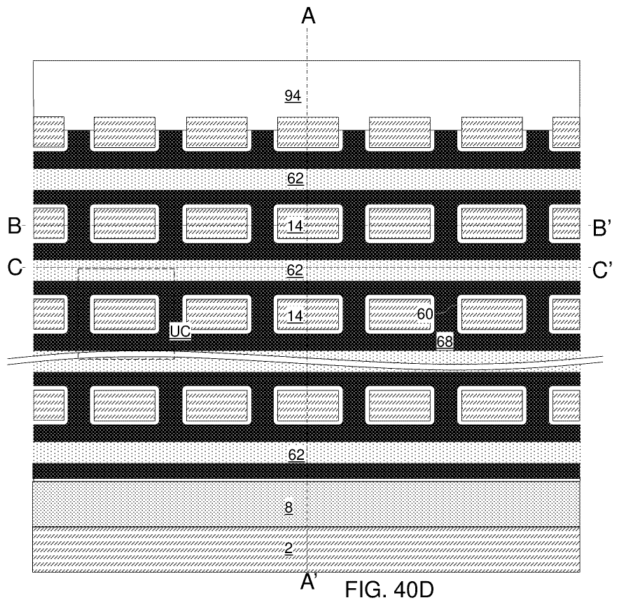

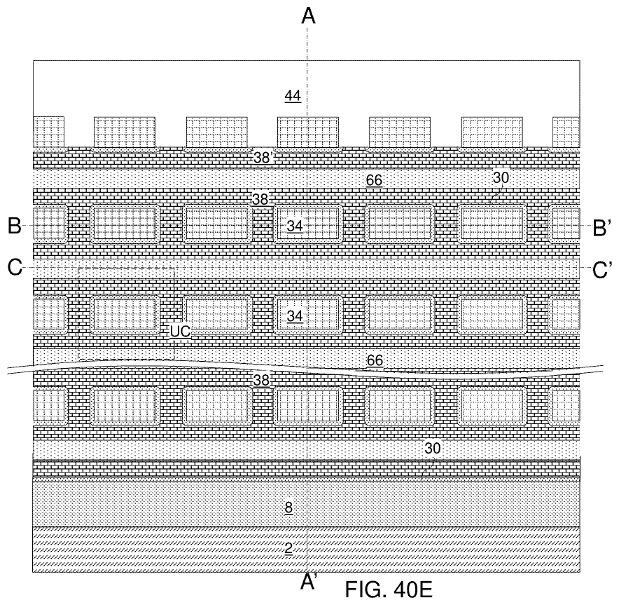

Referring to FIGS. 40A, 40B, 40C, 40D, and 40E, an alternative configuration of the second exemplary structure according to the second embodiment of the present disclosure is illustrated after formation of bit lines 98 and source structures 48S. The alternative configuration of the second exemplary structure can be derived from the second exemplary structure by replacing each array of vertical source lines 46 within a respective source trench 49 with a respective source structure 48S that contacts at least one two-dimensional array of source regions 32. Each source structure 48S that is located between two two-dimensional M×N arrays of semiconductor rails 20 may contact two two-dimensional M×N arrays of source regions 32.

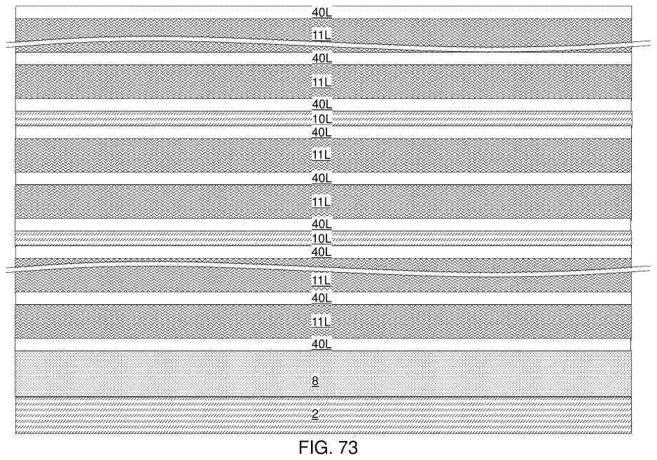

In another alternative embodiment, the laterally separated bit lines 98 located in laterally separated bit-line cavities 95 shown in FIG. 40A-40E may be replaced with a single bit line 98 located in a common bit-line cavity 95 and contacting drain regions (15, 16) of laterally adjacent field effect transistors, as shown in FIGS. 73A and 73C, and described in more detail below.

Referring collectively to FIG. 1A-11E and 27A-40E and according to the second embodiment of the present disclosure, a device structure comprising a three-dimensional array of unit cells UC is provided. Each of the unit cells UC comprises: an access field effect transistor 100 comprising a first horizontally-extending semiconductor channel 14, a first gate dielectric 60, and a first gate electrode (which is a portion of a first word line 68); and a memory field effect transistor 300 comprising a second horizontally-extending semiconductor channel 34, a second gate dielectric 30, and a second gate electrode 38 (which is a portion of a second word line 38 located within a respective unit cell UC), wherein the second gate dielectric 30 comprises a memory dielectric material having at least two programmable states.

In one embodiment, the second horizontally-extending semiconductor channel 34 contacts the first horizontally-extending semiconductor channel 14. In one embodiment, the second horizontally-extending semiconductor channel 34 and the first horizontally-extending semiconductor channel 14 comprise a same semiconductor material but comprise electrical dopants of same conductivity type at different atomic concentrations. In one embodiment, the second horizontally-extending semiconductor channel 34 and the first horizontally-extending semiconductor channel 14 have a same material composition.

In one embodiment, the first horizontally-extending semiconductor channel 14 and the second horizontally-extending semiconductor channel 34 have a same uniform vertical cross-sectional shape within any vertical cross-sectional view that cuts through the first horizontally-extending semiconductor channel 14 or the second horizontally-extending semiconductor channel 34 and is perpendicular to the first horizontal direction hd1 irrespective of a location of a vertical cut plane for a respective vertical cross-sectional view. In one embodiment, the access field effect transistor 100 comprises a drain region 16; and the memory field effect transistor 300 comprises a source region 32 having a same material composition as the drain region 16. In one embodiment, the drain region 16 has a variable vertical cross-sectional shape within vertical planes that are perpendicular to the first horizontal direction hd1 as a function of a lateral distance from the first horizontally-extending semiconductor channel 14.

In one embodiment, a sidewall of the second gate dielectric 30 is in contact with a sidewall of the first gate electrode (which is a portion of a first word line 68). In one embodiment, an interface between the sidewall of the second gate dielectric 30 and the sidewall of the first gate electrode (which is a portion of a first word line 68) is perpendicular to the first horizontal direction hd1. In one embodiment, the first gate dielectric 60 is in contact with the second gate dielectric 30. In one embodiment, an interface between the first gate dielectric 60 and the second gate dielectric 30 comprises horizontal surface segments and vertical surface segments that are parallel to the first horizontal direction hd1. In one embodiment, the device structure comprises a dielectric gate spacer 35 in contact with a sidewall of the second gate electrode 38 (which is a portion of a second word line 38 located within a respective unit cell UC) and laterally spaced from the first gate electrode and the first gate dielectric 60 by the second gate dielectric 30.

In one embodiment, the first gate dielectric 60 has a first tubular configuration and laterally surrounds the first horizontally-extending semiconductor channel 14 and laterally extends along the first horizontal direction hd1; and the second gate dielectric 30 comprises a portion which has a second tubular configuration and laterally surrounds the second horizontally-extending semiconductor channel 34 and laterally extends along the along the first horizontal direction hd1. In one embodiment, the first gate electrode comprises a portion of a first word line 68 that laterally extends along a second horizontal direction; and the second gate electrode comprises a portion of a second word line 38 that laterally extends along the second horizontal direction hd2.

In one embodiment, the first gate electrode wraps around the first gate dielectric 60 in a first vertical cross-sectional view that is perpendicular to the first horizontal direction hd1; and the second gate electrode (which is a portion of a second word line 38 located within a respective unit cell UC) wraps around the second gate dielectric 30 in a second vertical cross-sectional view that is perpendicular to the first horizontal direction hd1.

In one embodiment, the three-dimensional array of the unit cells UC is arranged to provide: rows of respective unit cells UC arranged along a second horizontal direction hd2 that is different from the first horizontal direction hd1; columns of respective unit cells UC arranged along the first horizontal direction hd1; and vertical stacks of respective unit cells UC arranged along a vertical direction. In one embodiment, each second gate dielectric 30 within the three-dimensional memory array is a portion of a respective continuous gate dielectric layer that laterally extends along the second horizontal direction hd2 and contacts the first gate electrode of each access field effect transistor within a respective row of unit cells UC.

In one embodiment, the device structure further comprises a two-dimensional array of vertical bit lines 98, wherein each of the vertical bit lines 98 contacts a set of drain regions 16 located within a respective vertical stack of unit cells UC. In one embodiment, the device structure further comprises a two-dimensional array of vertical source lines 46, wherein each of the vertical source lines 46 contacts a set of source regions 32 located within a respective vertical stack of unit cells UC.

In one embodiment, the device structure further comprises a two-dimension array of second dielectric plates 66 arranged along the first horizontal direction hd1 and along a vertical direction, wherein each second dielectric plate 66 contacts a top surface of a respective underlying second word lines 38 that includes a first row of the second gate electrodes and contacts a bottom surface of a respective overlying word line 68 that includes a second row of the second gate electrodes. In one embodiment, the second gate dielectric 30 comprises a ferroelectric dielectric material. In another embodiment, the second gate dielectric 30 comprises a charge trapping dielectric material.

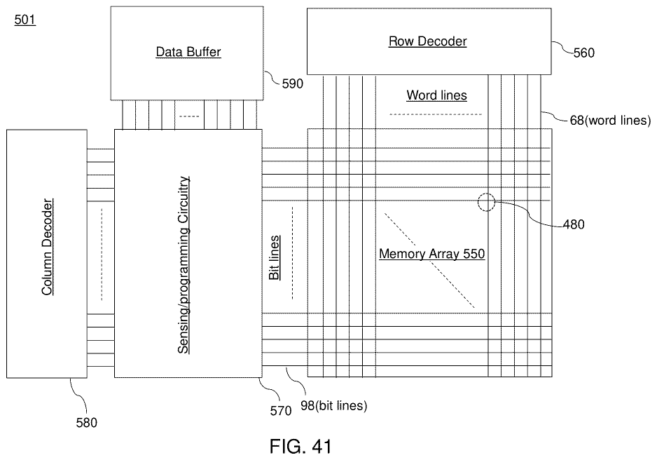

Referring to FIG. 41, a schematic circuit diagram of a first exemplary circuit is illustrated, which may be employed to implement a three-dimensional memory device including the first exemplary structure in which the storage device 200 comprises a charge storage (i.e., volatile) capacitor. The first exemplary circuit may comprise a first random access memory (RAM) device 501 including a three-dimensional array, such as a three-dimensional L×M×N array, of the integrated memory cells 480. Each unit cell UC in the first exemplary structure comprises an integrated memory cell 480 including an access field effect transistor 100 and a storage device 200. Each storage device 200 is electrically accessible through the access field effect transistor within a respective integrated memory cell 480 in the first exemplary structure. Each access field effect transistor 100 can be activated only when the bit line 98 and the word line 68 that are connected to the access field effect transistor 100 are activated. In one embodiment, the first RAM device 501 includes a memory array region 550 including word lines 68 and bit lines 98. In an illustrative example, the first RAM device 501 may contain a row decoder 560 connected to the word lines 68 and a sensing/programming circuitry 570 connected to the bit lines 98. A column decoder 580 and a data buffer 590 can be connected to the sensing/programming circuitry 570. The conductive structures 48A in the first exemplary structure can be electrically grounded.

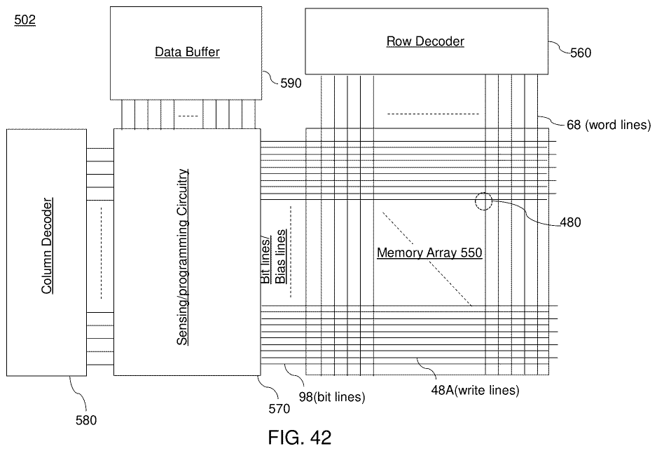

Referring to FIG. 42, a schematic circuit diagram of a second exemplary circuit is illustrated, which may be employed to implement a three-dimensional memory device including the first exemplary structure in which the storage device 200 is a non-volatile storage device, such as a ferroelectric capacitor or a variable resistor. The second exemplary circuit may comprise a second random access memory (RAM) device 502 including a three-dimensional array, such as a three-dimensional L×M×N array, of the integrated memory cells 480 in the first exemplary structure. The fourth RAM device 502 may be derived from the first RAM device 503 by adding the write line 48A. The write line 48A is used to program (i.e., write) the storage device 200, while the bit lines 98 are used to read the storage device 200.

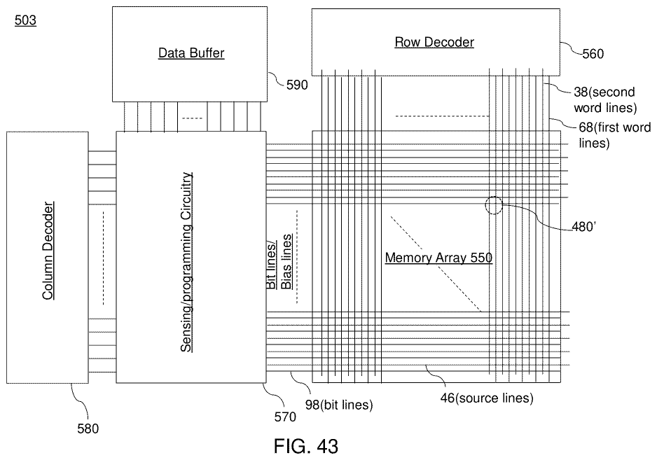

Referring to FIG. 43, a schematic circuit diagram of a third exemplary circuit is illustrated, which may be employed to implement a three-dimensional memory device including the second exemplary structure comprising the memory field effect transistor 300. The third exemplary circuit may comprise a third random access memory (RAM) device 503 including a three-dimensional array, such as a three-dimensional L×M×N array, of the integrated memory cells 480′ in the second exemplary structure. Each unit cell UC in the second exemplary structure comprises an integrated memory cell 480′ including an access field effect transistor 100 and a memory field effect transistor 300. Each memory field effect transistor 300 is electrically accessible through the access field effect transistor 100 within a respective integrated memory cell 480′. Each access field effect transistor 100 can be activated only when the bit line 98 and the first word line 68 that are connected to the access field effect transistor are activated. Each memory field effect transistor 300 can be programmed by activating the access field effect transistor within the same integrated memory cell 480′, and by electrically biasing a respective second gate electrode (which is portion of a respective second word line 38) and a respective vertical source line 46. In one embodiment, the third RAM device 503 includes a memory array region 550 including first word lines 68, second word lines 38, bit lines 98, and vertical source lines 46. In an illustrative example, the third RAM device 503 may contain a row decoder 560 connected to the first word lines 68 and to the second word lines 38, and a sensing/programming circuitry 570 connected to the bit lines 98 and the vertical source lines 46. Each pair of a bit line 98 and a vertical source line 46 that are connected to a vertical stack of N semiconductor rails 10 may be individually activated. A column decoder 580 and a data buffer 590 can be connected to the sensing/programming circuitry 570.

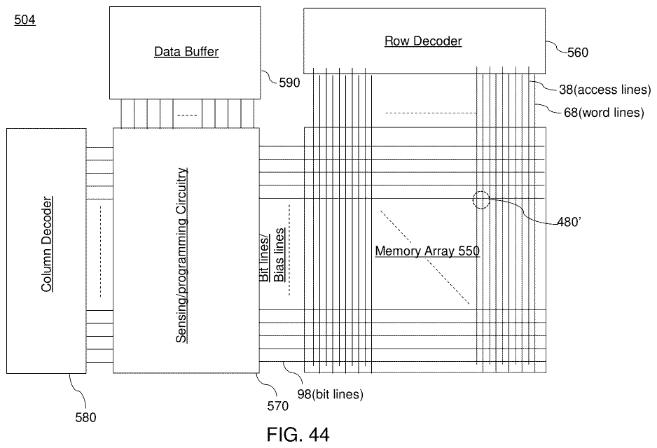

Referring to FIG. 44, a schematic circuit diagram of a fourth exemplary circuit is illustrated, which may be employed to implement a three-dimensional memory device including the alternative configuration of the second exemplary structure. The fourth exemplary circuit may comprise a fourth random access memory (RAM) device 504 including a three-dimensional array, such as a three-dimensional L×M×N array, of the integrated memory cells 480′ in the second exemplary structure. The fourth RAM device 504 may be derived from the third RAM device 503 by replacing the vertical source lines 46 with source structures 48S, which has the same effect as electrically shorting all vertical source lines 46. In this case, the source lines need not be individually driven.

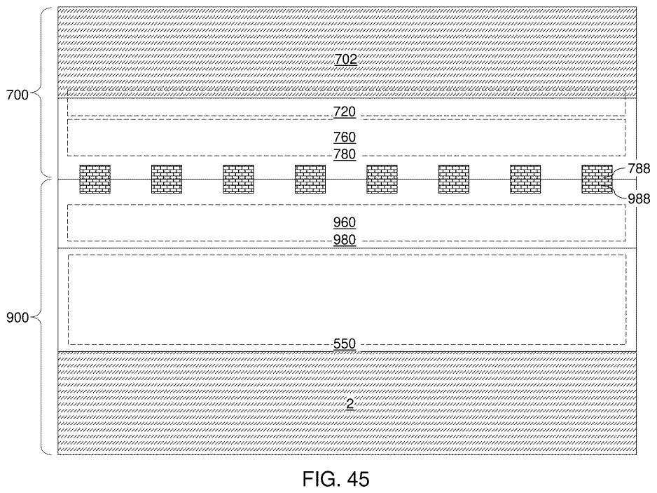

The three-dimensional memory array of the embodiments of the present disclosure may be located in various dies or bonded assemblies. FIG. 45-50 illustrate non-limiting examples of die configurations that may be employed for the three-dimensional array of memory elements of the various embodiments of the present disclosure.

Referring to FIG. 45, the three-dimensional memory array 550 may be provided within a memory die 900 over a substrate 2. Upper-level metal interconnect structures 980 embedded within upper-level dielectric material layers 960 may be formed over the three-dimensional array 550, and memory-side bonding pads 988 may be formed at the top level of the upper-level dielectric material layers 960. A logic die 700 is provided, which comprises a logic-die substrate 702, a control circuit 720 including semiconductor devices configured to control operation of the three-dimensional memory array 550, logic-side metal interconnect structures 780 embedded within logic-side dielectric material layers 760, and logic-side bonding pads 788 electrically connected to a respective subset of the logic-side metal interconnect structures 780. The control circuit 720 may comprise various CMOS circuits. The memory die 900 can be bonded to the logic die 700 through bonding between mating pairs of a memory-side bonding pad 988 and a logic-side bonding pad 788.

Generally, the memory die 900 and the logic die 700 may be bonded by metal-to-metal bonding between the memory-side bonding pads 988 and the logic-side bonding pads 788, or via solder-mediated bonding such as C4 bonding or microbump bonding. If metal-to-metal bonding is employed, the memory-side bonding pads 988 directly contact the logic-side bonding pads 788, and metallic interdiffusion is induced between the material of the memory-side bonding pads 988 and the logic-side bonding pads 788. In this case, an outermost dielectric material layer among the upper-level dielectric material layers 960 may contact an outermost dielectric material layer among the logic-side dielectric material layers 760, and dielectric-to-dielectric bonding may be induced therebetween. If C4 bonding or microbump bonding is employed, a two-dimensional array of solder material portions may be interposed between, and may be bonded with, the memory-side bonding pads 988 and the logic-side bonding pads 788. A gap between the outermost dielectric material layer among the upper-level dielectric material layers 960 and the outermost dielectric material layer among the logic-side dielectric material layers 760 may be filled with an underfill material portion.

The memory die 900 and the logic die 700 may be bonded by wafer-to-wafer bonding, by die-to-die bonding, or by die-to-wafer bonding. In the case of the wafer-to-wafer bonding, a wafer including a two-dimensional array of memory dies 900 and another wafer including a two-dimensional array of logic dies 700 may be provided. Mating pairs of memory dies 900 and logic dies 700 may be bonded simultaneously by performing a metal-to-metal bonding process or a solder-mediated bonding process. In the case of die-to-die bonding, a single memory die 900 (as provided by singulation of a wafer including a two-dimensional array of memory dies 900) may be bonded to a single logic die 700 (as provided by singulation of a wafer including a two-dimensional array of logic dies 700). In the case of die-to-wafer bonding, a memory die 900 may be bonded to a selected logic die 700 located on a wafer including a two-dimensional array of logic dies 700, or a logic die 700 may be bonded to a selected memory die 900 located on wafer including a two-dimensional array of memory dies 900.

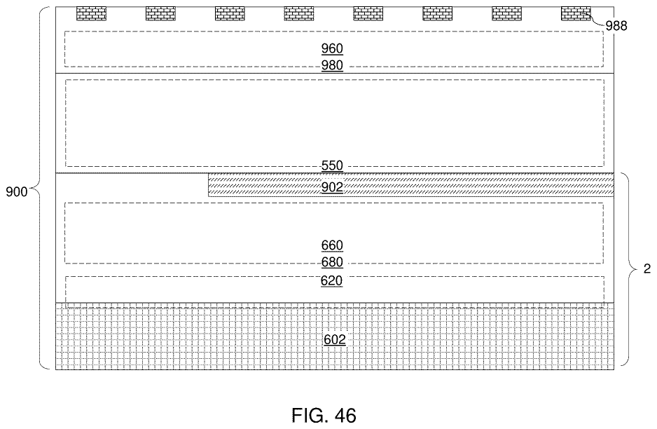

Referring to FIG. 46, a second semiconductor die containing the three-dimensional memory array 550 is illustrated. The second semiconductor die may be a memory die 900, in which the substrate 2 comprises a semiconductor material layer 902 and underlying driver circuit structures. The semiconductor material layer 902 performs the function of the substrate 2 described with reference to FIG. 1A-1E. The underlying driver circuit structures may comprise a semiconductor substrate 602 (such as a portion of a single crystalline silicon wafer), a control circuit 620 including semiconductor devices configured to control operation of the three-dimensional memory array 550, and lower-level metal interconnect structures 680 embedded within lower-level dielectric material layers 660. The semiconductor material layer 902 may comprise a polycrystalline semiconductor material layer that may be formed by deposition of a semiconductor material over the lower-level dielectric material layers 660, or may comprise a single crystalline semiconductor material layer (such as a single crystalline silicon layer) that may be formed by a layer transfer from a source single crystalline semiconductor layer, for example, employing a hydrogen-implanted cleaving layer (commonly known as the Smart-cut™ method). The semiconductor material layer 902 may be patterned as needed. Electrical interconnection between the lower-level metal interconnect structures 680 and the upper-level metal interconnect structures 980 may be formed by metal vias that pass through the levels of the semiconductor material layer 902 and the three-dimensional memory array 550. Alternatively, the semiconductor material layer 902 may be omitted. In this case, the etch stop structure 8 located at the bottommost level of the three-dimensional memory array 550 may contact the topmost layer within the lower-level dielectric material layers 660.

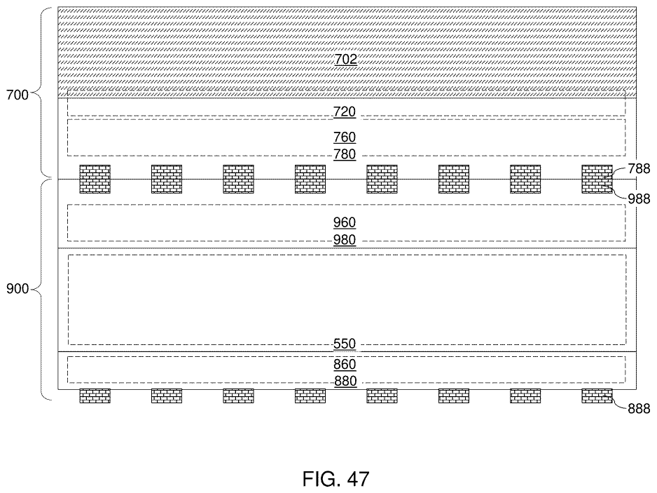

Referring to FIG. 47, a third semiconductor die containing the three-dimensional memory array 550 can be derived from the first semiconductor die illustrated in FIG. 45 by removing the substrate 2, and by subsequently forming memory-die backside structures. The removal of the substrate 2 can be performed selectively to the etch stop structure 8, for example, by grinding, polishing, an anisotropic etch process, and/or an isotropic etch process. Backside metal interconnect structures 880 embedded within backside dielectric material layers 860 may be optionally formed. Backside bonding pads 888 may be formed on the backside metal interconnect structures 888, or may be formed on electrical nodes of the three-dimensional memory array 550. The backside bonding pads 888 may be metal-to-metal bonding pads, or may be solder bonding pads.

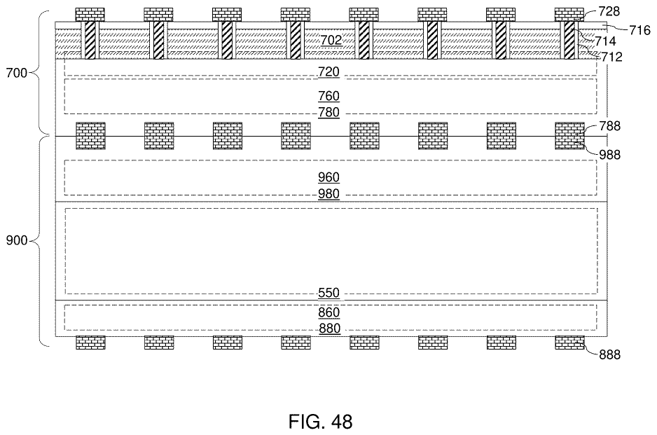

Referring to FIG. 48, a fourth semiconductor die containing the three-dimensional memory array 550 is illustrated, which may be derived from the first semiconductor die described with reference to FIG. 45 or from the third semiconductor die described with reference to FIG. 48 by forming combinations of a through-substrate-via dielectric liner 712 and a through-substrate via structure 714 in an upper portion of the logic-side substrate 702 prior to formation of the control circuit 720, by thinning the logic-die substrate 702 from the backside after the logic die 700 is bonded to the memory die 900, by forming a logic-die backside insulating layer 716 on the backside surface of the thinned logic-side substrate 702, and by forming logic-die backside bonding pads 728. The logic-die backside bonding pads 728 may be metal-to-metal bonding pads, or may be solder bonding pads.

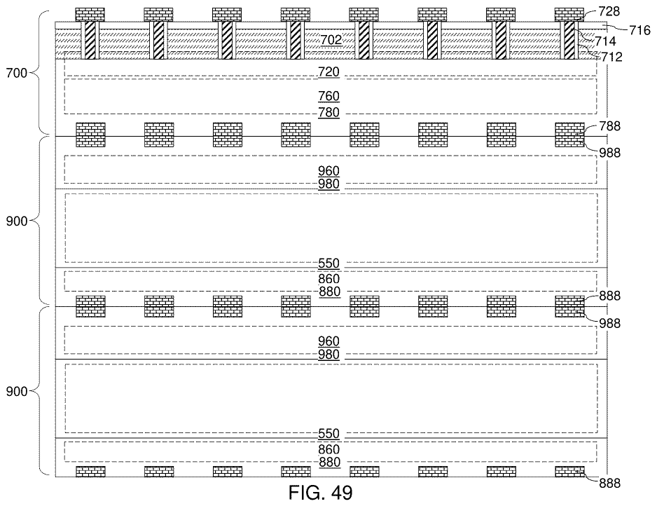

Referring to FIG. 49, a fifth semiconductor die containing the three-dimensional memory array 550 can be derived from the fourth semiconductor die described with reference to FIG. 48 by vertically stacking multiple memory dies 900. In the illustrated example, metal-to-metal bonding is employed to vertical stack multiple memory dies 900.

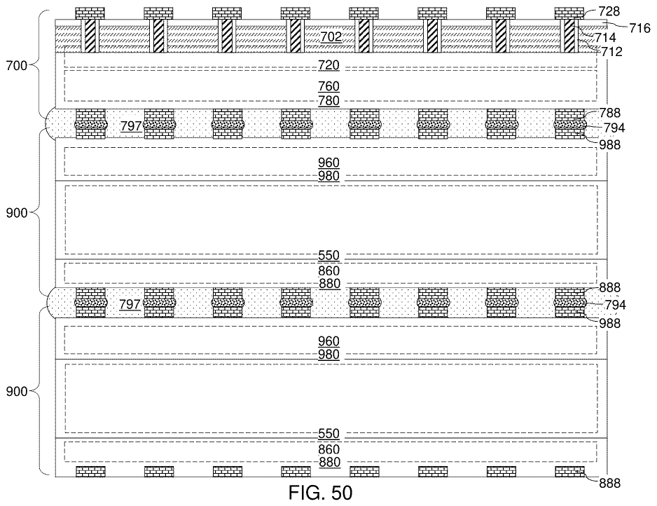

Referring to FIG. 50, a sixth semiconductor die containing the three-dimensional memory array 550 can be derived from the fourth semiconductor die described with reference to FIG. 48 by vertically stacking multiple memory dies 900. In the illustrated example, microbump bonding is employed to vertically stack multiple memory dies 900. An array of solder material portions 794 may be interposed between each vertically neighboring pair of bonding pads. An underfill material portion 797 can fill the gap between each vertically neighboring pair of semiconductor dies (700, 900).

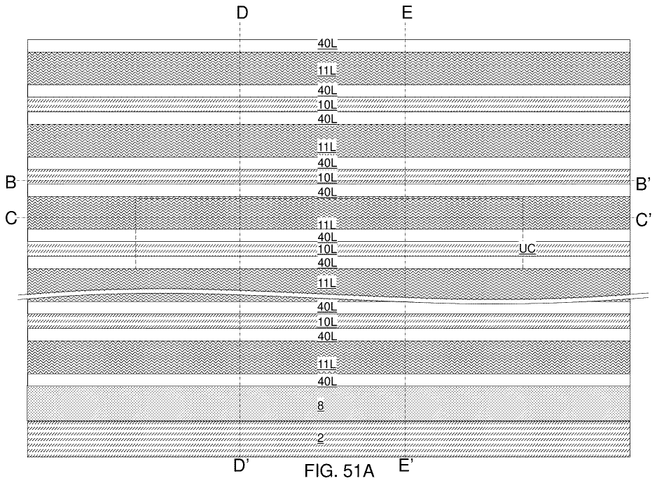

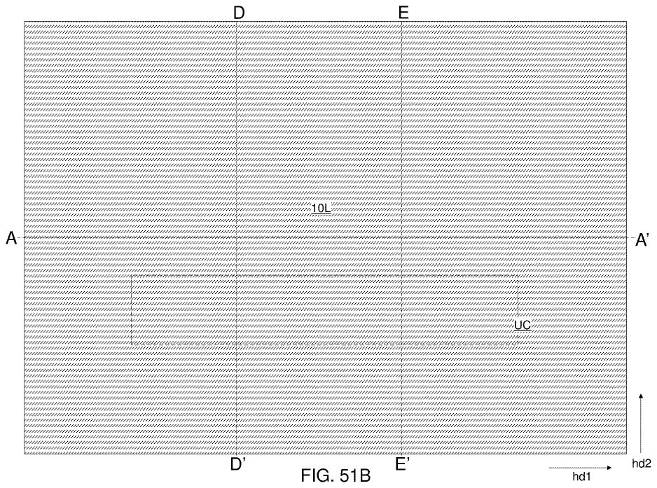

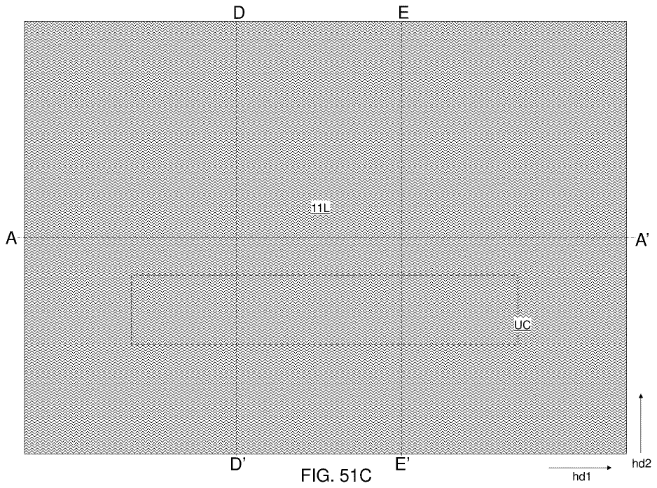

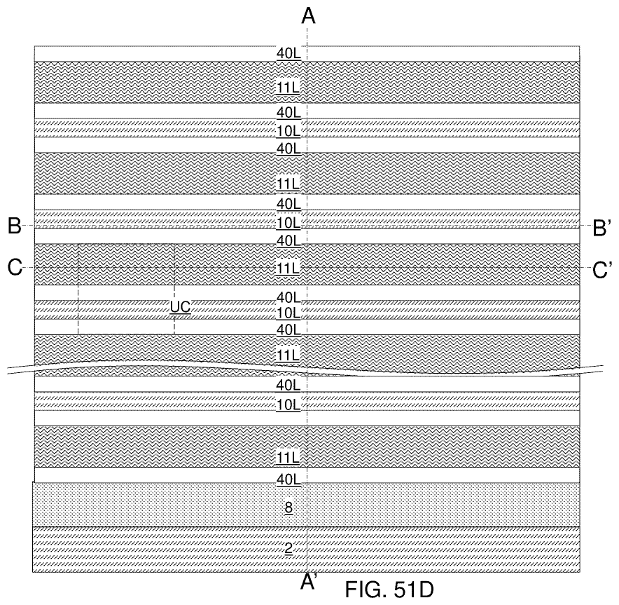

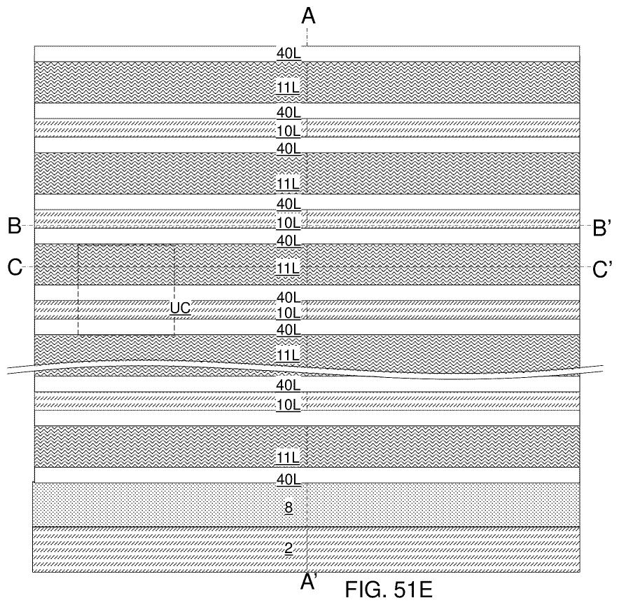

Referring to FIGS. 51A, 51B, 51C, 51D, and 51E, a third exemplary structure according to a third embodiment of the present disclosure is illustrated after formation of a vertical repetition of instances of a unit layer stack (10L, 11L, 40L). Generally, the third exemplary structure illustrated in FIGS. 51A, 51B, 51C, 51D, and 51E can be derived from the first exemplary structure illustrated in FIGS. 1A, 1B, 1C, 1D, and 1E by replacing each vertically neighboring pair of a semiconductor layer 10L and a sacrificial layer 20L with a unit layer stack (10L, 11L, 40L) including, from bottom to top, a first spacer material layer 40L, a semiconductor layer 10L, a second spacer material layer 40L, and a sacrificial layer 11L. Thus, the third exemplary structure includes a vertical repetition of instances of the unit layer stack (10L, 11L, 40L). The spacer material layers 40L are also referred to as spacer layers 40L for brevity.

According to an aspect of the present disclosure, the semiconductor layers 10L and the sacrificial layer 11L have a same material composition consisting of a first semiconductor material. Each of the semiconductor layers 10L may have a first thickness, and each of the sacrificial layers 11L may have a second thickness that is different from the first thickness. Each of the first spacer material layers 40L and the second spacer material layers 40L may have a same material composition consisting of a second semiconductor material that is different from the first semiconductor material. Generally, any semiconductor material that may be employed for the semiconductor layers 10L in the first exemplary structure may be employed as the first semiconductor material in the third exemplary structure, and any semiconductor material that may be employed for the sacrificial layers 20L in the first exemplary structure may be employed as the second semiconductor material in the third exemplary structure.

In one embodiment, the first semiconductor material is a single crystalline silicon material, and the second semiconductor material is a single crystalline silicon-germanium material.

Thus, each of the semiconductor layers 10L and the sacrificial layers 11L may comprise single crystalline silicon layers, and each of the first and the second spacer material layers 40L comprise single crystalline silicon-germanium layers. The vertical repetition of instances of the unit layer stack (10L, 11L, 40L) may be formed such that all portions of the first semiconductor material and all portions of the second semiconductor material are portions of a single crystalline structure that is single crystalline throughout and has a same set of crystallographic orientations throughout. In other words, each of the semiconductor layers 10L, the sacrificial layers 11L, the first spacer layers 40, and the second spacer layers 40 may be epitaxially aligned among one another, and the set of all semiconductor layers 10L, the sacrificial layers 11L, the first spacer layers 40, and the second spacer layers 40 may constitute a contiguous single crystalline structure having the same crystallographic orientations throughout and epitaxially aligned among one another.

In the illustrated example in FIGS. 51A, 51B, 51C, 51D, and 51E, each of the semiconductor layers 10L has a first thickness, and each of the sacrificial layers 11L has a second thickness that is greater than the first thickness. In an illustrative example, the first thickness may be in a range from 5 nm to 20 nm, and the second thickness may be in a range from 20 nm to 60 nm. Each of the spacer layers 40 may have a thickness in a range from 5 nm to 20 nm, although lesser or greater thicknesses may also be employed. Each volume of a unit cell UC for forming a unit memory device includes a portion of a unit layer stack (10L, 11L, 40L).

In an alternative embodiment, each of the semiconductor layers 10L has the first thickness, and each of the sacrificial layers 11L has the second thickness that is thinner than the first thickness. In an alternative illustrative example, the first thickness may be in a range from 20 nm to 50 nm, and the second thickness may be in a range from 5 nm to 20 nm.

The use of the unit layer stack (10L, 11L, 40L) including, from bottom to top, a first spacer material layer 40L, a semiconductor layer 10L, a second spacer material layer 40L, and a sacrificial layer 11L, in the third exemplary structure in lieu of an alternating stack of a semiconductor layer 10L and a sacrificial layer 20L in the first exemplary structure allows reduction of the average thickness of material layers in the third exemplary structure relative to the average thickness of material layers in the first exemplary structure. Generally, single crystalline silicon and a single crystalline silicon-germanium have a lattice mismatch, which causes epitaxially grown layers to gradually lose crystalline alignment with an underlying single crystalline material if the thickness of an epitaxially grown layer (i.e., a semiconductor layer that is grown on underlying single crystalline material layers) exceeds a critical thickness. The critical thickness is inversely proportional to the lattice mismatch between the epitaxially grown layer and the underlying single crystalline material layer. Reduction of the average thickness of the individual epitaxial layers in the third exemplary structure relative to the average thickness of the individual epitaxial layers in the first exemplary structure allows increase in the total number of repetitions of a unit layer stack that can be vertically repeated without losing epitaxial alignment between single crystalline layers having different compositions.

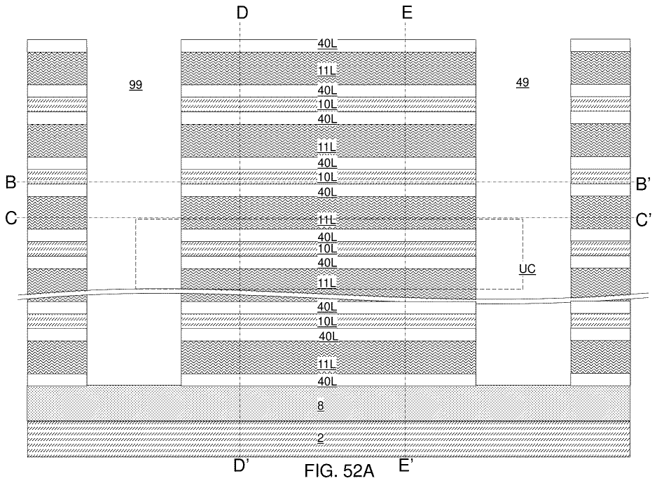

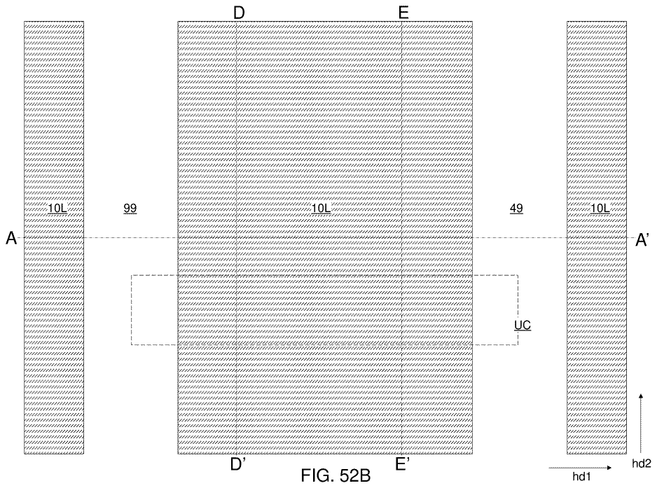

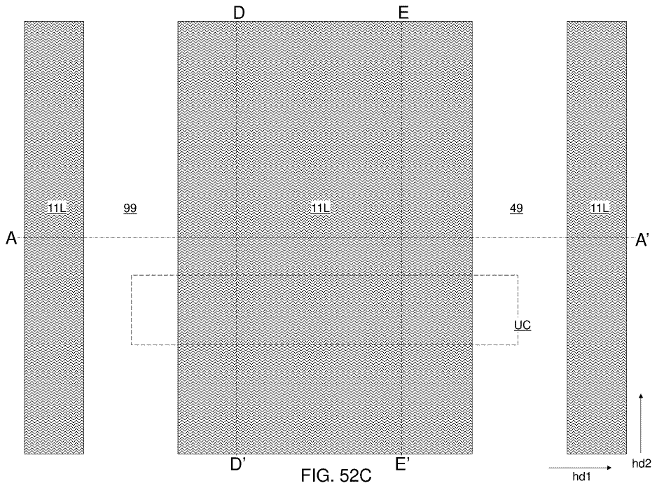

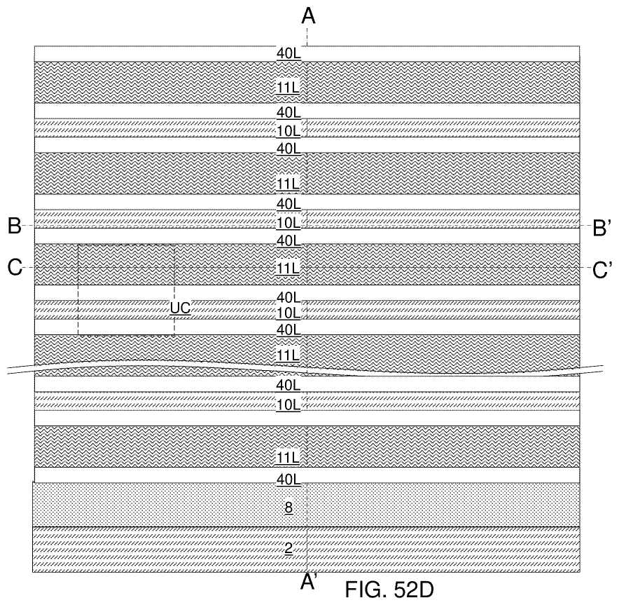

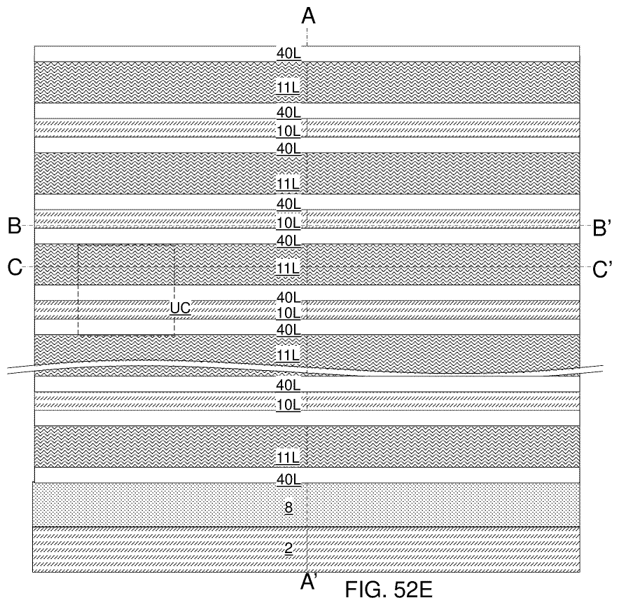

Referring to FIGS. 52A, 52B, 52C, 52D, and 52E, the processing steps described with reference to FIGS. 2A, 2B, 2C, 2D, and 2E may be performed to form a laterally alternating sequence of bit-line trenches 99 and source trenches 49. Generally, the vertical repetition of multiple instances of the unit layer stack (10L, 11L, 40L) as provided in the processing steps of FIGS. 51A, 51B, 51C, 51D, and 51E may be divided by forming a laterally alternating sequence (99, 49) of bit-line trenches 99 and source trenches 49 that alternate along the first horizontal direction hd1. Each of the bit-line trenches 99 and the source trenches 49 laterally extend along a second horizontal direction hd2.

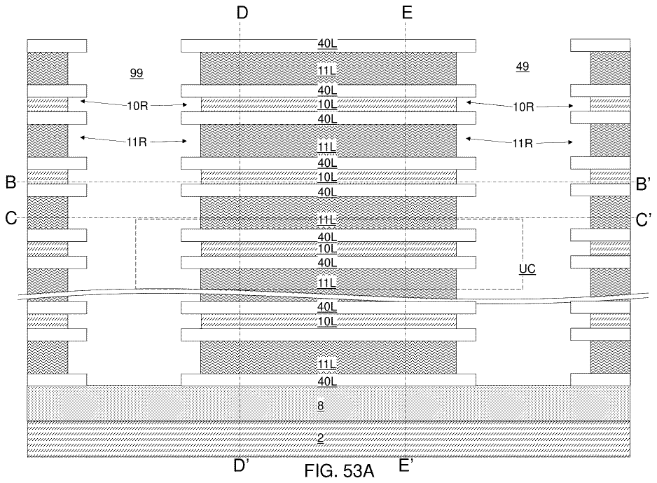

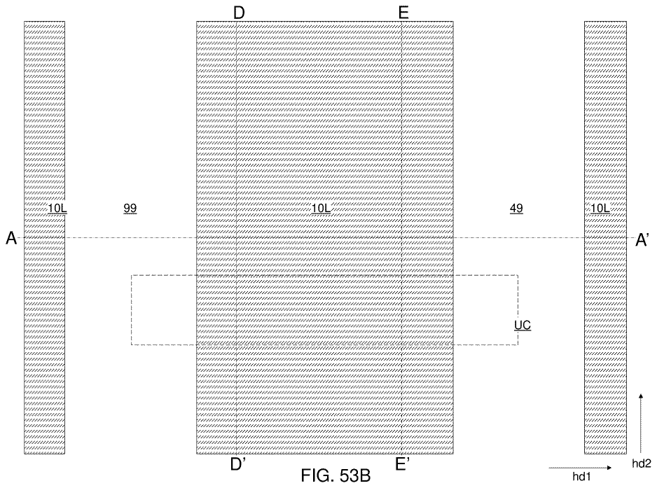

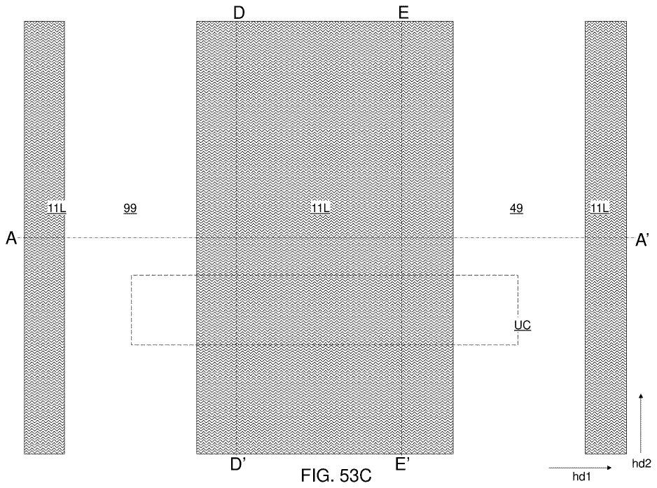

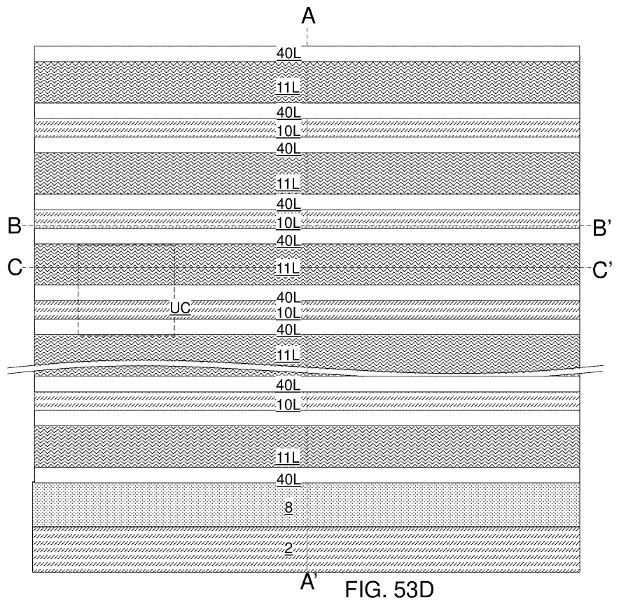

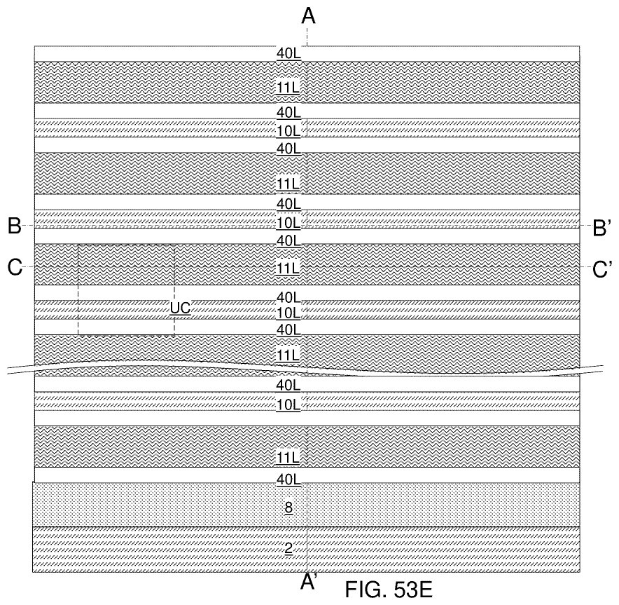

Referring to FIGS. 53A, 53B, 53C, 53D, and 53E, a selective isotropic etch process can be performed to laterally recess physically exposed sidewalls of the semiconductor layers 10L and the sacrificial layers 11L around the bit-line trenches 99 and the source trenches 49 selectively to the material of the spacer layers 40L. In one embodiment, the first semiconductor material of the semiconductor layers 10L and the sacrificial layers 11L may comprise single crystalline silicon, and the second semiconductor material of the spacer layers 40L may comprise a single crystalline silicon-germanium material including germanium at an atomic percentage in a range from 10% to 50%.

In one embodiment, the selective isotropic etch process may comprise a wet etch process employing a mixture of hydrofluoric acid (HF) and nitric acid (HNO₃). HNO₃selectively oxidizes the silicon layers (10L, 11L), while HF selectively removes the silicon oxide formed on the surface of the silicon layers, to selectively laterally etch the silicon material. This process provides a higher etch rate for silicon relative to the silicon-germanium of the spacer material layers 40L, due to the different oxidation and dissolution rates between the two materials. The isotropic nature of the process provides uniform lateral recessing of the exposed sidewalls of the silicon layers.

In another embodiment, the selective isotropic etch process may comprise an isotropic plasma etch process employing sulfur hexafluoride (SF₆) or nitrogen trifluoride (NF₃). The plasma-generated reactive fluorine radicals interact with the silicon material, forming volatile silicon fluorides, which are then evacuated from the plasma etching chamber. This approach provides selectivity due to the protective passivation effect of the etch chemistry on the silicon-germanium spacer layers, resulting in controlled lateral recessing of the exposed silicon layers (10L, 11L) around the trenches.

In yet another embodiment, the selective isotropic etch process may comprise a dry etch process employing xenon difluoride (XeF₂). XeF₂ etching is highly selective for silicon over silicon-germanium due to its rapid reaction with silicon to form volatile silicon tetrafluoride (SiF₄) while etching silicon-germanium at a slower rate. This process allows lateral etching of the silicon layers (10L, 11L) without significant etching of the spacer layers 40L.

Generally, sidewalls of remaining portions of the semiconductor layers 10L and the sacrificial layers 11L can be laterally recessed relative to sidewalls of the spacer layers 40L after formation of the bit-line trenches 99 and the source trenches 49 by a first lateral recess distance. The first lateral recess distance may be in a range from 50% to 400%, such as from 100% to 300%, of the first thickness, i.e., the thickness of the semiconductor layers 10L.

Thus, first lateral recesses 10R are formed at the sidewalls of the semiconductor layers 10L between vertically adjacent first and second spacer layers 40L. Second lateral recesses 11R are formed at the sidewalls of the sacrificial layers 11L between vertically adjacent first and second spacer layers 40L. The second lateral recesses 11R may have a greater height then the first lateral recesses 10R.

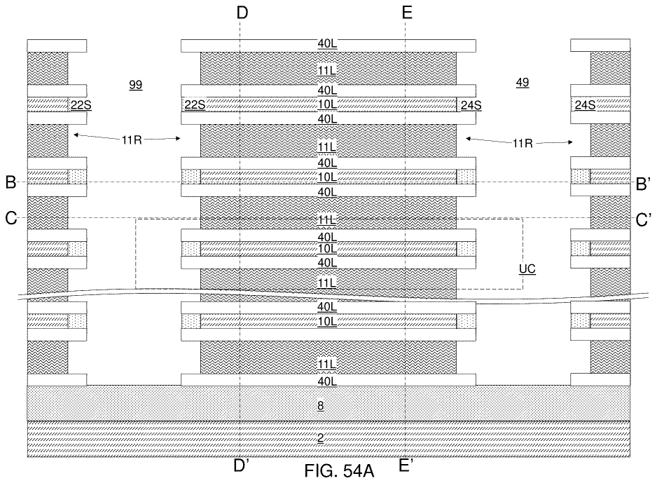

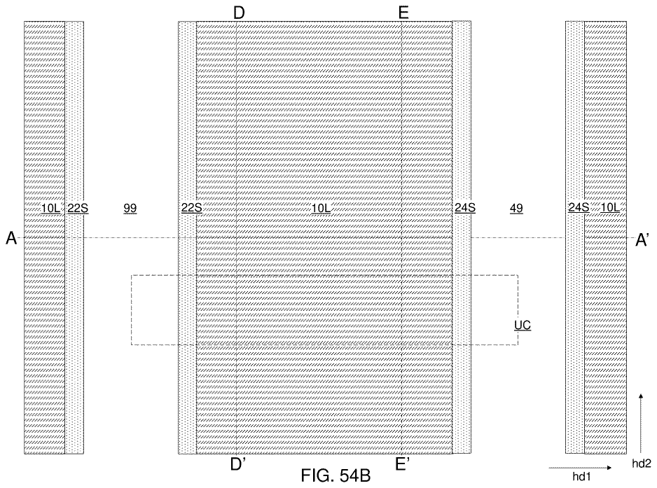

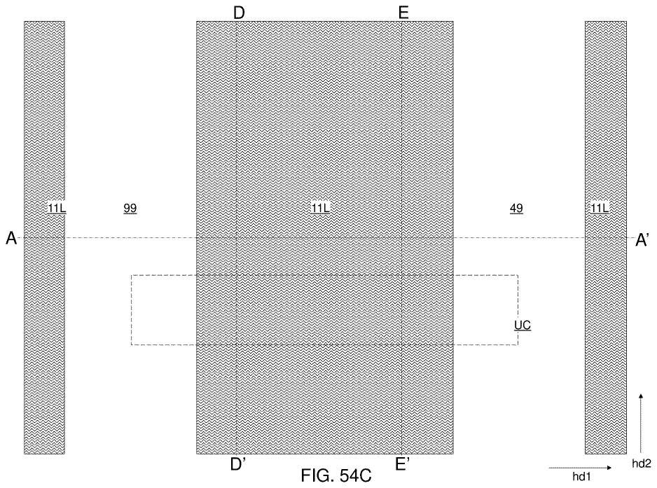

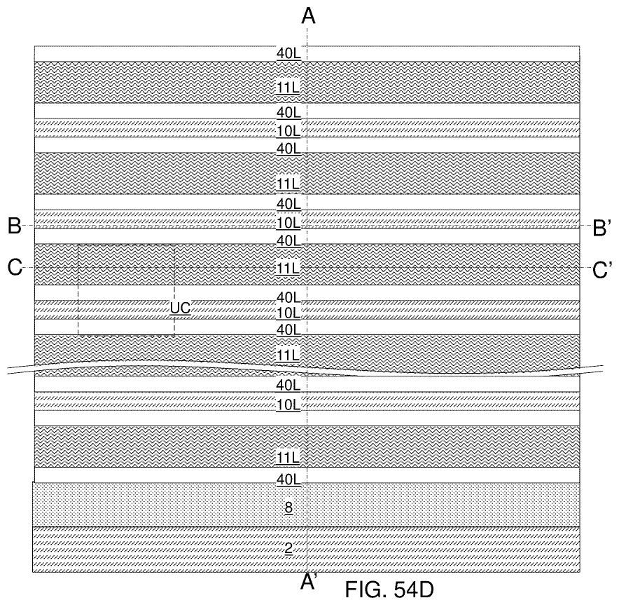

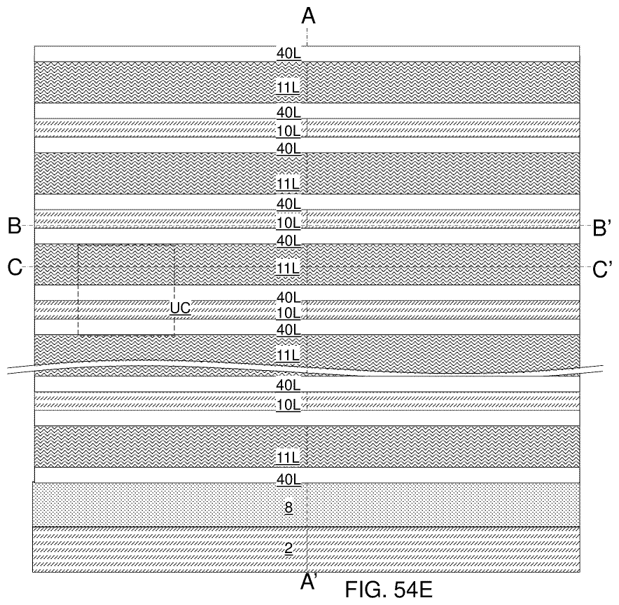

Referring to FIGS. 54A, 54B, 54C, 54D, and 54E, a capping material layer comprising a dielectric material can be conformally deposited in the lateral recesses between neighboring pairs of the spacer layers 40L. The capping material layer may comprise a dielectric material such as silicon nitride, aluminum oxide, a dielectric transition metal oxide, silicon oxide, or silicon carbonitride. The capping material layer may be deposited by a chemical vapor deposition process or an atomic layer deposition process. The capping material layer is deposited directly on physically exposed sidewalls of the semiconductor layers 10L, the sacrificial layers 11L, and the spacer layers 40L. The thickness of the capping material layer is selected such that the first lateral recesses 10R located at the levels of the semiconductor layers 10L are completely filled with portions of the capping material layer, while the second lateral recesses 11R located at the levels of the sacrificial layers 11L are not completely filled (i.e., are only partially filled) with portions of the capping material layer. For example, the thickness of the capping material layer may be greater than one half of the first thickness, and may be less than one half of the second thickness.

Subsequently, a selective isotropic etch process can be performed to isotropically etch the material of the capping material layer through the trenches (49, 99). The duration of the selective isotropic etch process can be selected such that portions of the capping material layer are removed from the trenches (49, 99) and the second lateral recesses 11R, but remain in the first lateral recesses 10R to form capping strips (22S, 24S). Remaining portions of the capping material layer located within the first lateral recesses 10R located at the levels of the semiconductor layers 10L around the bit-line trench 99 constitute capping structures, which are herein referred to bit-line-side capping strips 22S. Remaining portions of the capping material layer located within the first lateral recesses 10R around the source trench 49 constitute additional capping structures, which are herein referred to source-side capping strips 24S. Each capping strip (22S, 24S) may laterally extend along the second horizontal direction hd2 with a uniform vertical cross-sectional shape within vertical planes that are perpendicular to the second horizontal direction hd2.

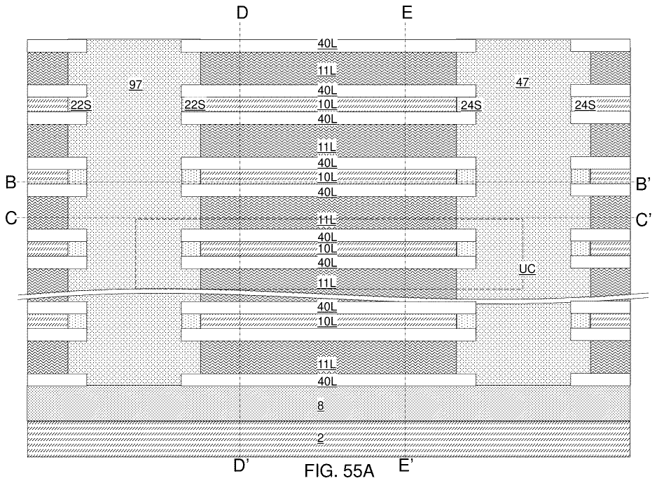

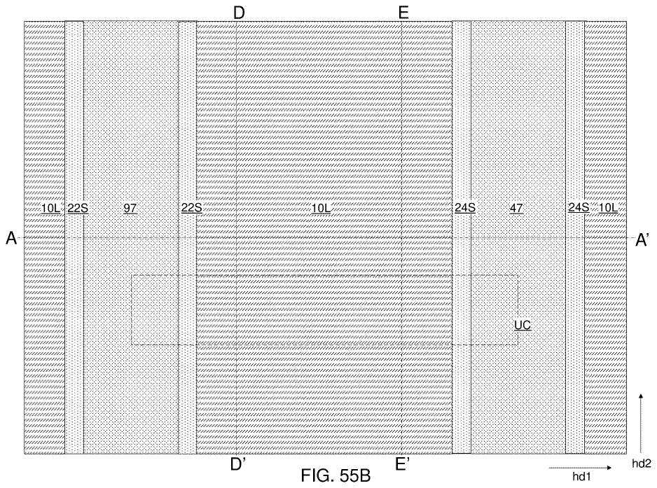

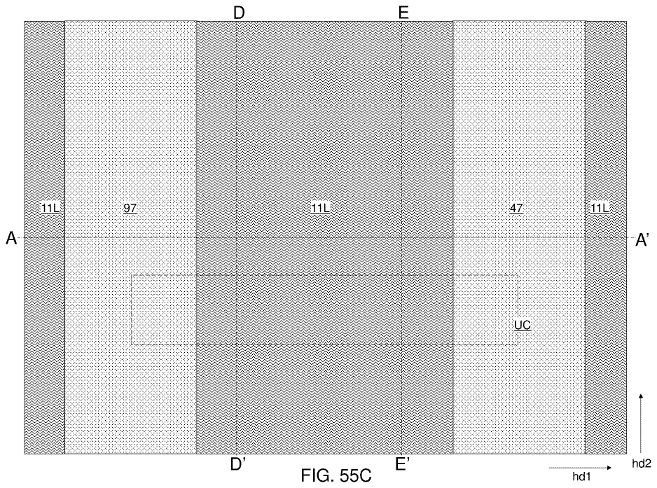

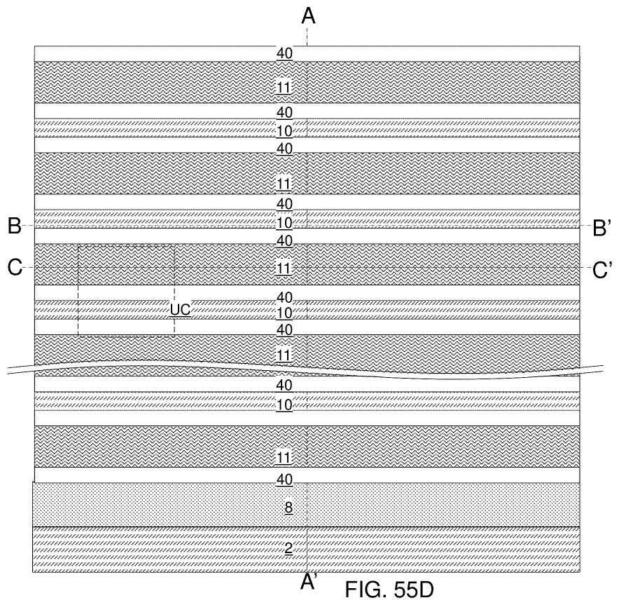

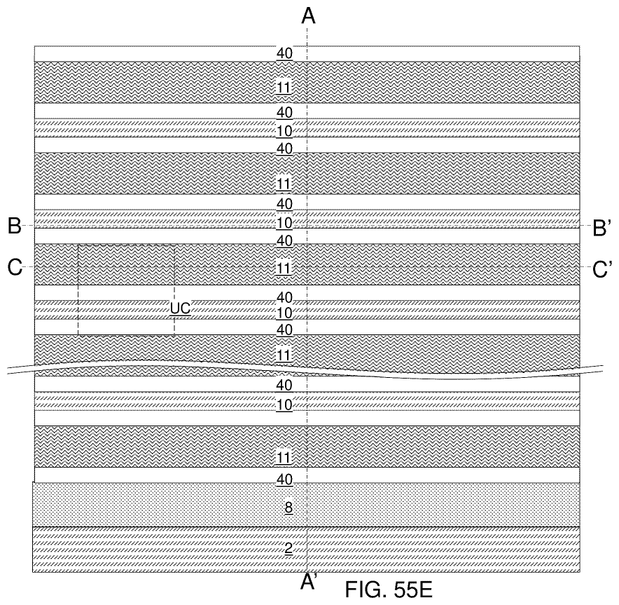

Referring to FIGS. 55A, 55B, 55C, 55D, and 55E, a first sacrificial fill material can be deposited in the source trenches 49 and the bit-line trenches 99. The first sacrificial fill material may comprise a carbon-based material (such as amorphous carbon or diamond-like carbon), organosilicate glass, silicon oxide, or a polymer material. Generally, the first sacrificial fill material is different from the material of the sacrificial layers 11, the spacer layers 40, and the capping strips (22S, 24S). Excess portions of the first sacrificial fill material can be removed from above the horizontal plane including the top surfaces of the vertical repetitions of the multiple instances of the unit layer stack (10L, 11L, 40L) by a planarization process, which may be a chemical mechanical polishing process and/or a recess etch process. Each portion of the first sacrificial fill material that fills a source trench 49 constitutes a sacrificial source trench fill structure 47. Each portion of the first sacrificial fill material that fills a bit-line trench 99 constitutes a sacrificial bit-line trench fill structure 97.

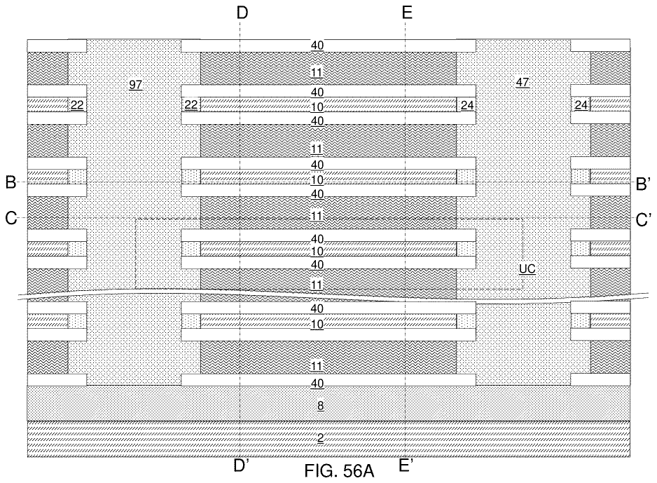

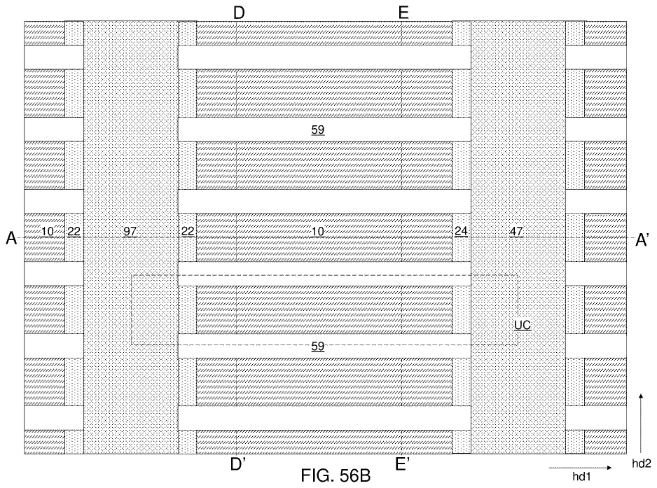

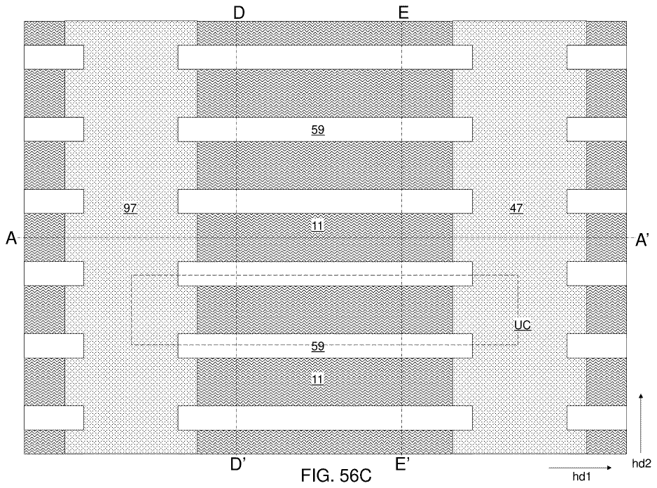

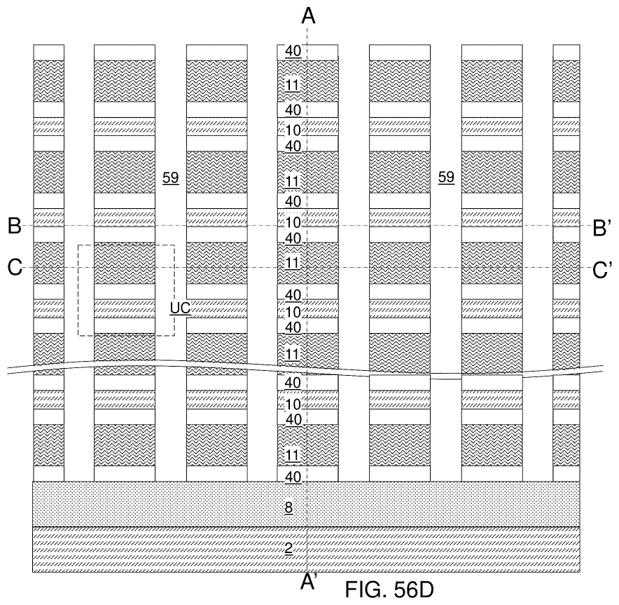

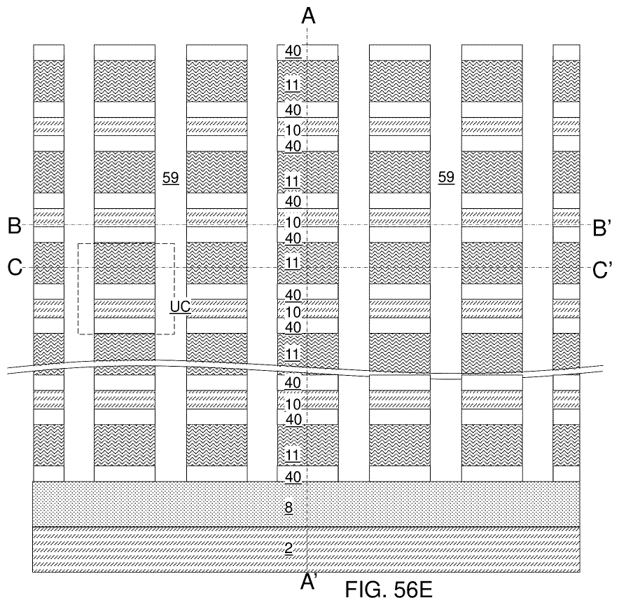

Referring to FIGS. 56A, 56B, 56C, 56D, and 56E, the processing steps described with reference to FIGS. 4A, 4B, 4C, 4D, and 4E may be performed to form lateral isolation trenches 59 through the vertical repetitions of the multiple instances of the unit layer stack (10L, 11L, 40L). The pattern of the lateral isolation trenches 59 can be selected such that each bit-line-side capping strip 22S is divided into a respective row of bit-line-side capping structures 22 (which may be referred to as first capping structures 22), and each source-side capping strip 24S is divided into a respective row of source-side capping structures 24 (which may be referred to as second capping structures 24).

In one embodiment, the lateral isolation trenches 59 laterally extend along the first horizontal direction hd1 through remaining portions of the vertical repetition and through the capping structures (22, 24) (i.e., the remaining portions of the capping material layer after removing the portions of the capping material layer outside the first recesses 10R at the levels of the semiconductor layers 10L). Each patterned portion of the semiconductor layers 10L comprises a semiconductor rail 10. Each patterned portion of the sacrificial layers 11L comprises a sacrificial rail 11. Each patterned portion of the spacer layers 40L comprises a spacer rail 40. Remaining portions of the vertical repetition of multiple instances of the unit layer stack (10L, 11L, 40L) as provided at the processing steps of FIGS. 51A, 51B, 51C, 51D, and 51E comprise the array of vertical rail stacks (10, 11, 40). Remaining portions of the capping material layer comprise the first capping structures 22 and the second capping structures 24.

In summary, a three-dimensional array of vertical rail stacks (10, 11, 40) can be formed. A two-dimensional array of vertical rail stacks (10, 11, 40) can be provided between each laterally neighboring pair of a sacrificial bit-line trench fill structure 97 and a sacrificial source trench fill structure 47. Each of the vertical rail stacks (10, 11, 40) comprises, from bottom to top, a first spacer rail 40, a semiconductor rail 10, a second spacer rail 40, and a sacrificial rail 11. Each of the vertical rail stacks (10, 11, 40) laterally extends along a first horizontal direction hd1, and each of the semiconductor rail 10 comprises a respective first semiconductor end wall contacting a respective first capping structure 22 and further comprises a respective second semiconductor end wall contacting a respective second capping structure 24.

In one embodiment, within each of the vertical rail stacks (10, 11, 40), the semiconductor rail 10 and the sacrificial rail 11 have a same material composition consisting of a first semiconductor material and have different vertical thicknesses. In one embodiment, within each of the vertical rail stacks (10, 11, 40), the first spacer rail 40 and the second spacer rail 40 have a same material composition consisting of a second semiconductor material that is different from the first semiconductor material.

In one embodiment, within each of the vertical rail stacks (10, 11, 40), the first semiconductor material is a single crystalline silicon material and the second semiconductor material is a single crystalline silicon-germanium material. In one embodiment, within each contiguous set of vertical rail stacks (10, 11, 40) that overlie or underlie one another, all portions of the first semiconductor material and all portions of the second semiconductor material are portions of a single crystalline structure that is single crystalline throughout and has a same set of crystallographic orientations throughout.

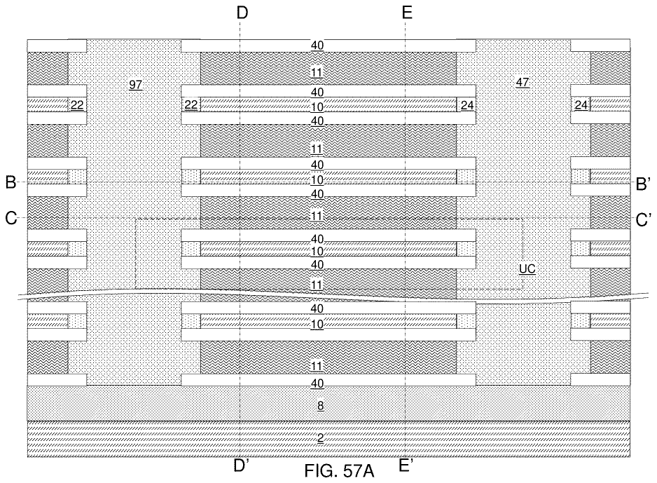

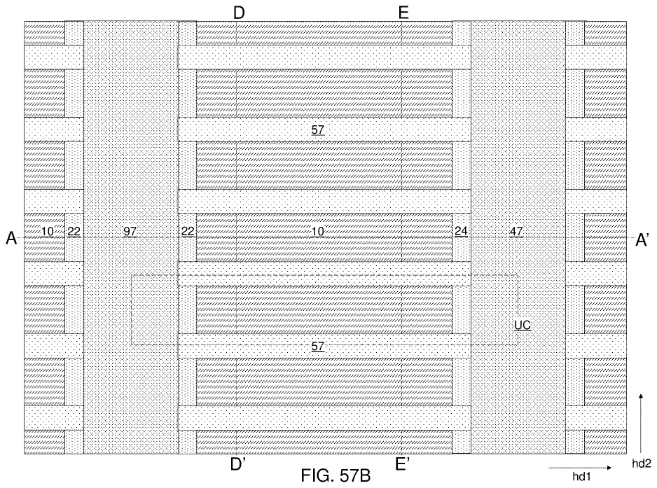

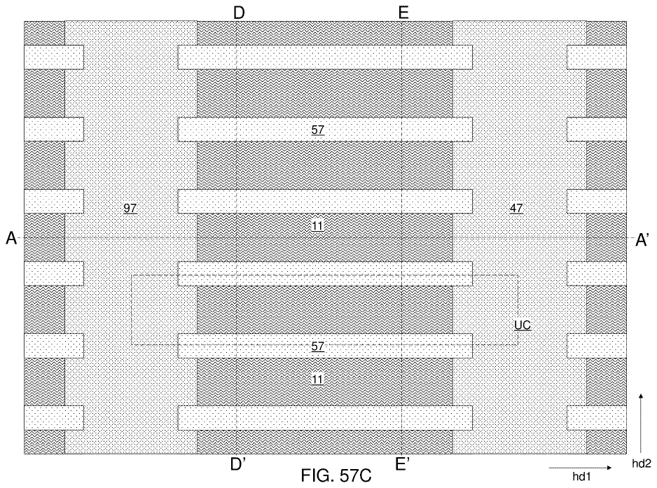

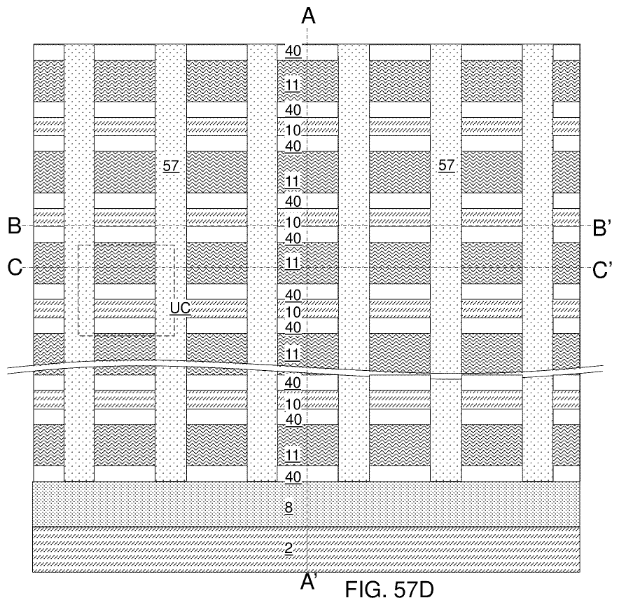

Referring to FIGS. 57A, 57B, 57C, 57D, and 57E, the processing steps described with reference to FIGS. 5A, 5B, 5C, 5D, and 5E can be performed to form sacrificial isolation trench fill structures 57 in the lateral isolation trenches 59.

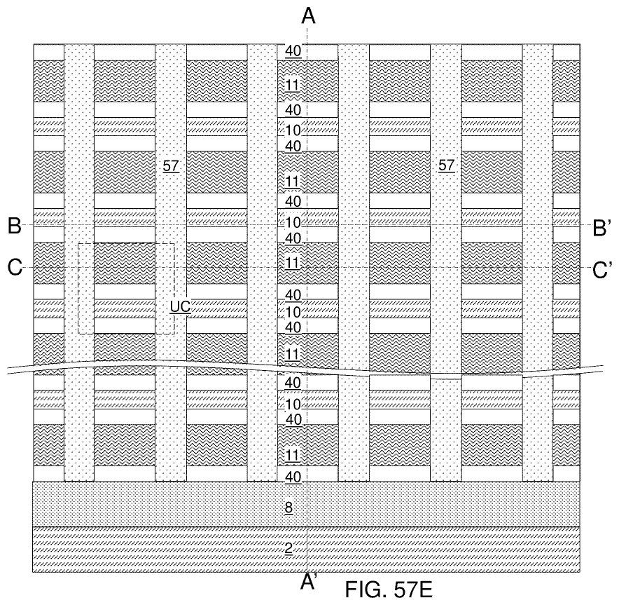

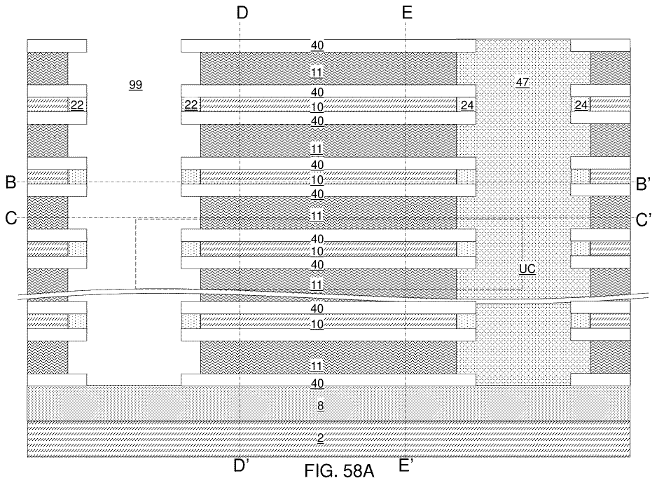

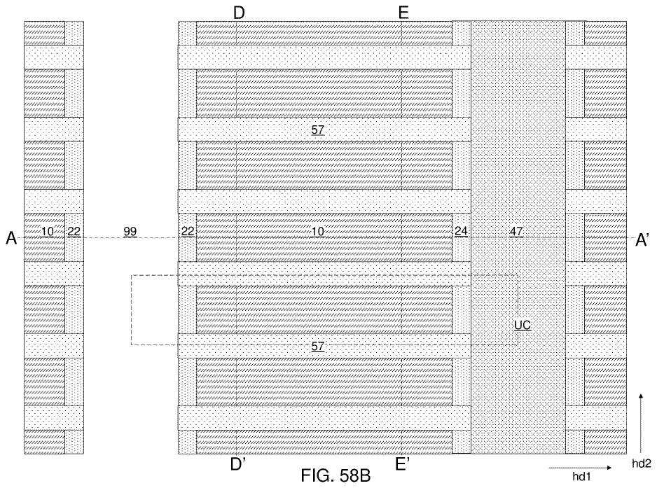

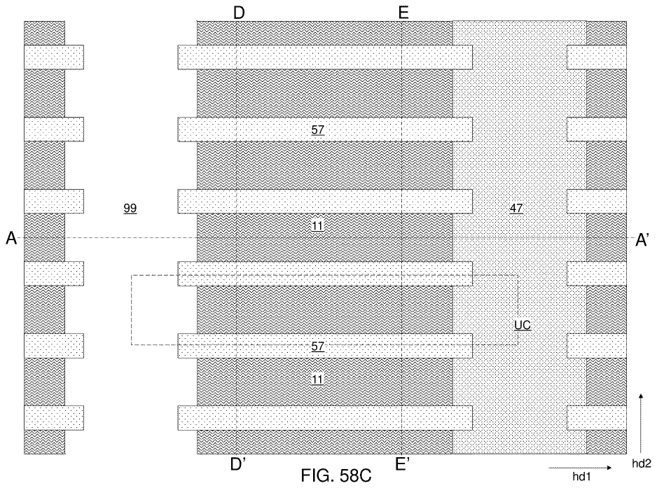

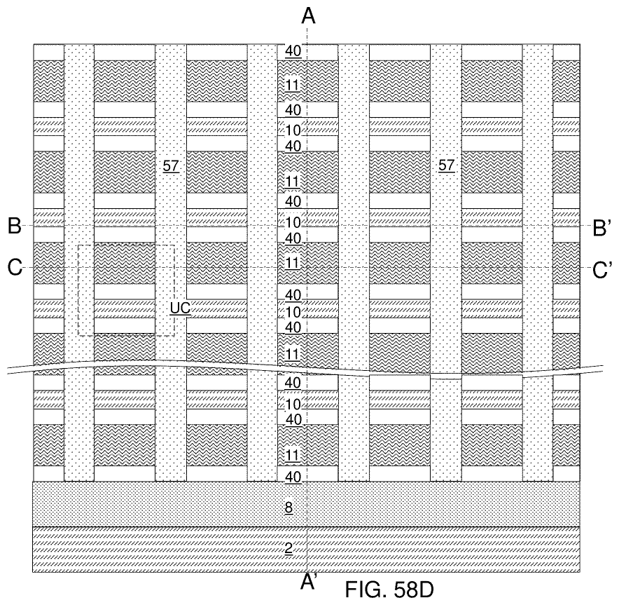

Referring to FIGS. 58A, 58B, 58C, 58D, and 58E, an etch mask layer (not illustrated), such as a photoresist layer, can be formed over the third exemplary structure, and can be patterned to form openings over the areas of the sacrificial bit-line trench fill structures 97. A first selective material removal process can be performed to remove the sacrificial bit-line trench fill structures 97 selectively to the materials of the semiconductor rails 10, the sacrificial isolation trench fill structure 57, and the etch stop structures 8. For example, if the sacrificial bit-line trench fill structures 97 comprise a carbon-based material, such as amorphous carbon or diamond-like carbon, an ashing process may be employed to remove the sacrificial bit-line trench fill structures 97. Alternatively, a selective etching process may be used. The bit-line trenches 99 are reopened such that voids are formed in the volumes of the bit-line trenches 99. Thus, the sacrificial bit-line trench fill structures 97 are removed without removing the sacrificial source trench fill structures 47.

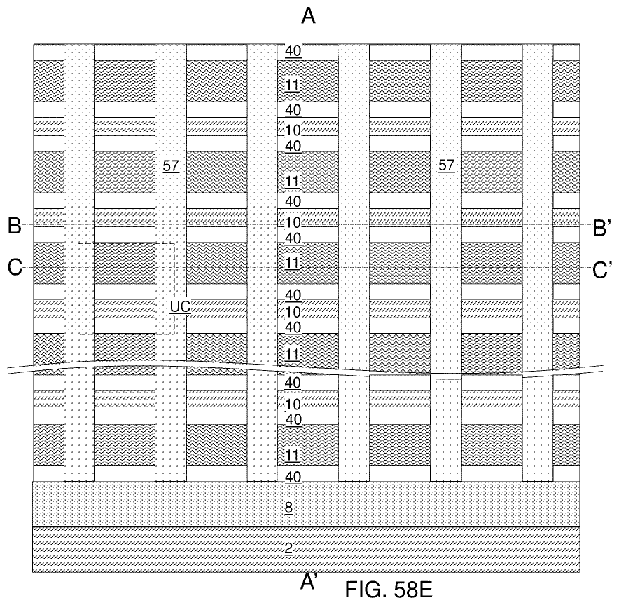

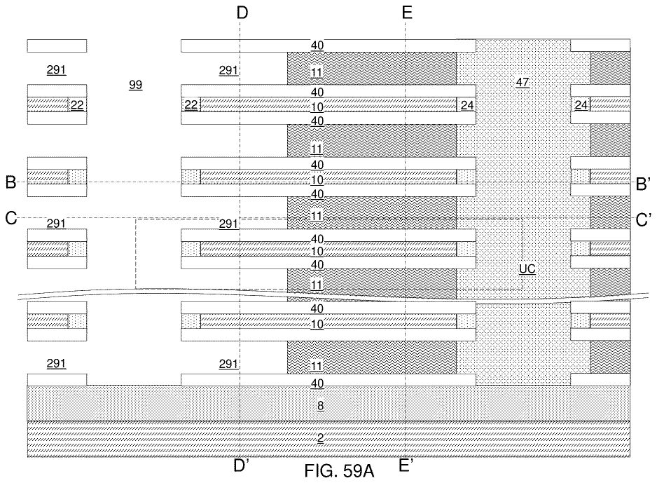

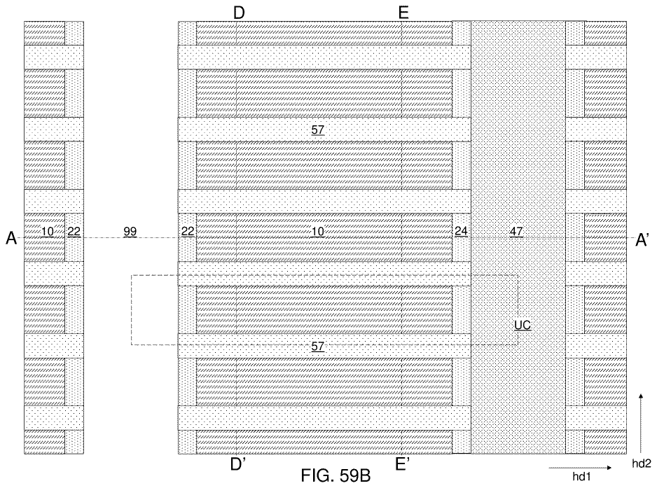

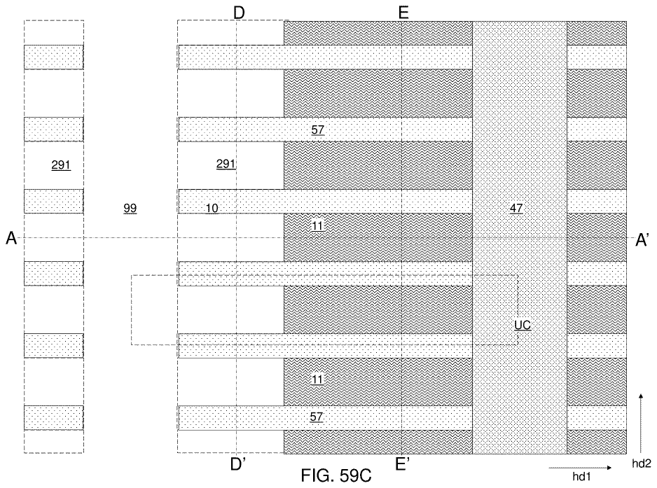

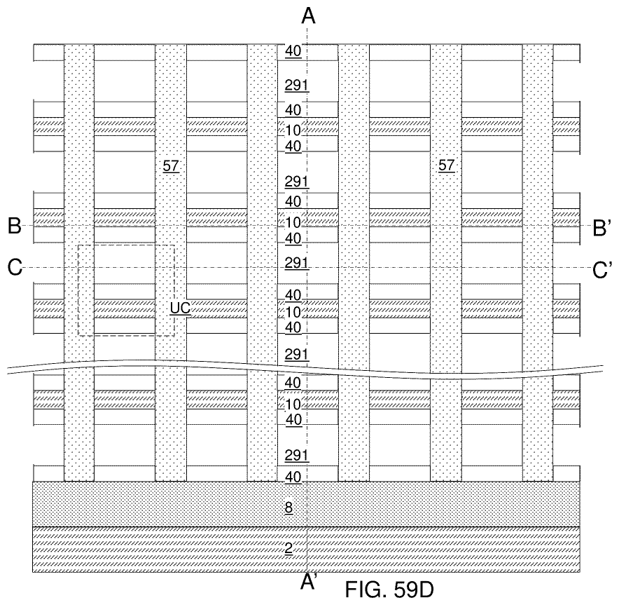

Referring to FIGS. 59A, 59B, 59C, 59D, and 59E, a second selective material removal process may be performed to extend the second lateral recesses 11R exposed in the bit-line trenches 99 by removing a first portion of each of the sacrificial rails 11 around the bit-line trenches 99 selective to the first capping structures 22 and the spacer rails 40. In one embodiment, the second selective material removal process may comprise a second selective isotropic etch process. For example, if the sacrificial rails 11 comprise single crystalline silicon, a wet etch process employing TMY or TMAH may be employed to laterally recess physically exposed portions of the sacrificial rails 11. First voids 291 are formed in the volumes from which the first portions of the sacrificial rails 11 are removed. In other words, the second lateral recesses 11R are laterally expanded around the bit-line trenches 99 to form the first voids 291. The first voids 291 are connected to the voids in the bit-line trenches 99.

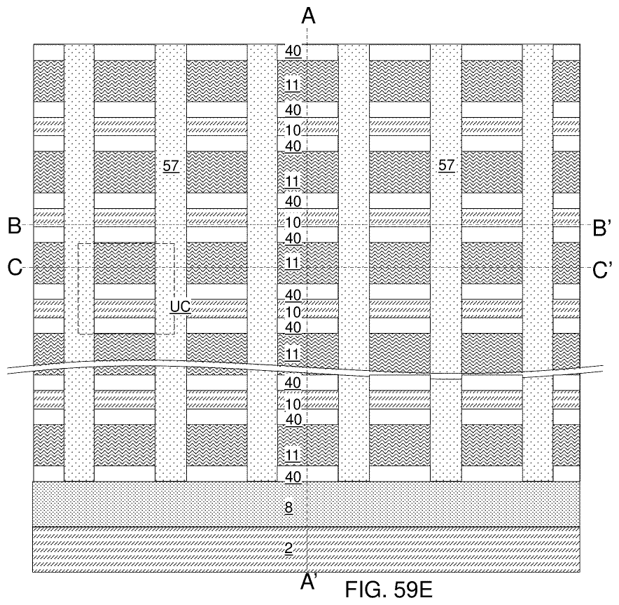

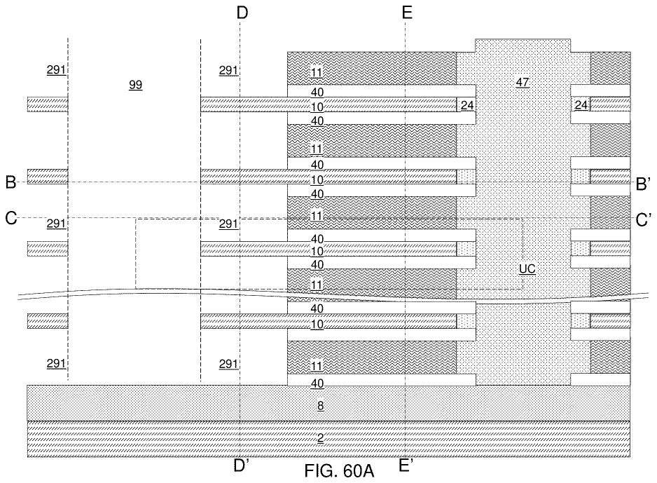

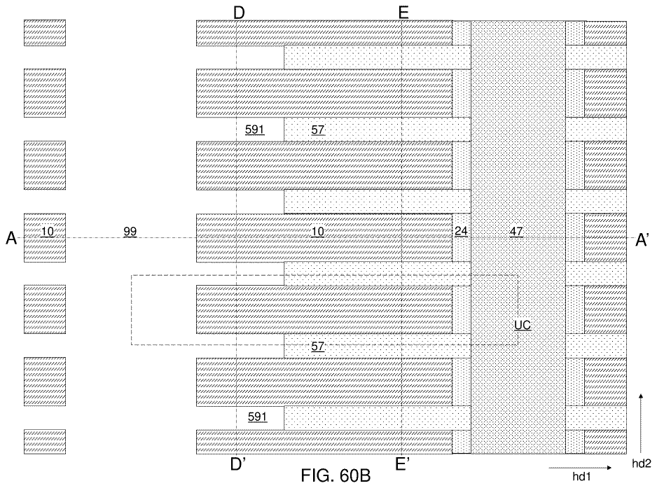

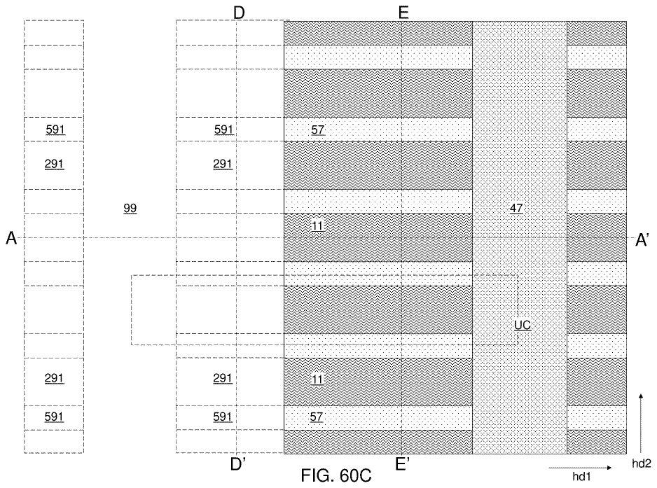

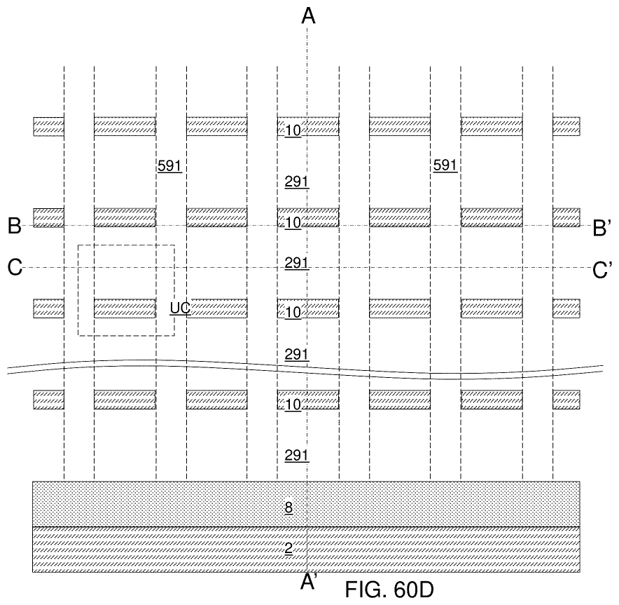

Referring to FIGS. 60A, 60B, 60C, 60D, and 60E, a third selective material removal process may be performed to remove first portions of the sacrificial isolation trench fill structures 57. The first portions of the sacrificial isolation trench fill structures 57 include portions that are proximal to the first capping structures 22 around the bit-line trenches 99. In one embodiment, the third selective material removal process may comprise a third selective isotropic etch process.

For example, if the sacrificial isolation trench fill structures 57 comprise a silicon oxide material, a wet etch process employing dilute hydrofluoric acid may be employed to laterally recess physically exposed portions of the sacrificial isolation trench fill structures 57. In one embodiment, the duration of the third selective isotropic etch process may be selected such that the etch distance of the third selective isotropic etch process for the material of the sacrificial isolation trench fill structures 57 is greater than one half of the lateral thickness of each of the sacrificial isolation trench fill structures 57 along the second horizontal direction hd2.

First lateral isolation trenches 591 are formed in the volumes from which the first portions of the sacrificial isolation trench fill structures 57 are removed. The first lateral isolation trenches 591 are formed between laterally-neighboring pairs of first portions of the horizontally-extending semiconductor rails 10 by removing the first portion of each of the sacrificial isolation trench fill structures 57 selective to the semiconductor rails 10 and to the first capping structures 22.

Further, a fourth selective material removal process may be performed to remove physically exposed first portions of the spacer rails 40. The first portions of the spacer rails 40 include portions that are proximal to the first capping structures 22 around the bit-line trenches 99. The fourth selective material removal process may be performed after or prior to the third selective material removal process. In one embodiment, the fourth selective material removal process may comprise a fourth selective isotropic etch process that does not remove the material of the semiconductor rails 10 and the first capping structures 22.

For example, if the spacer rails 40 comprise silicon-germanium, if the semiconductor rails 10 comprise silicon and if the first capping structures 22 comprise silicon nitride, a wet etch process employing ammonium hydroxide (NH₄OH) in combination with hydrogen peroxide (H₂O₂) may be employed to remove physically exposed portions of the spacer rails 40 without removing the semiconductor rails 10 or the first capping structures 22. This mixture selectively oxidizes and etches silicon-germaniums while minimizing reaction with silicon or silicon nitride.

Alternatively, a selective isotropic etch process employing a wet solution of acetic acid, nitric acid, and hydrofluoric acid (commonly known as the “RCA SC2” etch solution) may be utilized. This etch selectively dissolves silicon-germanium due to the combination of oxidizing agents and fluoride ions, while leaving silicon largely unaffected due to its slower oxidation rate.

Yet alternatively, a dry isotropic etch process employing chlorine trifluoride (ClF₃) gas may be employed. ClF₃ reacts more aggressively with silicon-germanium than with pure silicon, for selective removal of the spacer rails 40.

In one embodiment, the duration of the fourth selective isotropic etch process may be selected such that the etch distance of the fourth selective isotropic etch process for the material of the spacer rails 40 is greater than one half of the vertical thickness of each of the spacer rails 40. The first voids 291 are expanded to include the voids formed by removal of the first portions of the spacer rails 40.

The combination of the first voids 291 (as expanded by the fourth selective material removal process) and the first lateral isolation trenches 591 constitutes first cavities (291, 591). Generally, the first cavities (291, 591) are formed by removing portions of the first spacer rails 40 and the second spacer rails 40 that are proximal to the first voids 291 as formed at the processing steps of FIGS. 59A, 59B, 59C, 59D, and 59E, and by removing portions of the sacrificial isolation trench fill structures 57. The first cavities (291, 591) are connected to the voids in the bit-line trenches 99.

The first capping structures 22, i.e., the bit-line-side capping structures 22, may optionally be removed by performing a selective isotropic etch process after the second selective material removal process. The selective isotropic etch process may remove the first capping structures 22 without removing the semiconductor rails 10. For example, if the first capping structures 22 comprise silicon nitride, the selective isotropic etch process may comprise a wet etch process employing hot phosphoric acid. The removal of the first capping structures 22 may be performed prior to, between or after the third selective material removal process and the fourth selective material removal process. Alternatively, the selective isotropic etch process may be omitted and the bit-line-side capping structures 22 may be retained until the drain regions 16 are formed in the bit-line trenches 99.

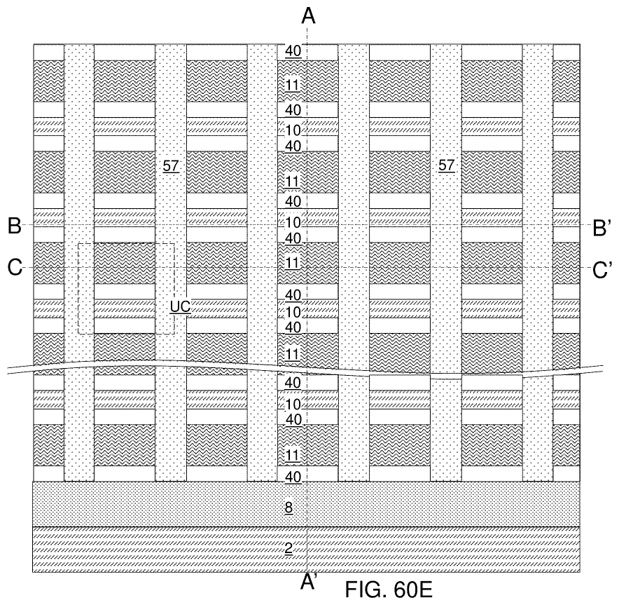

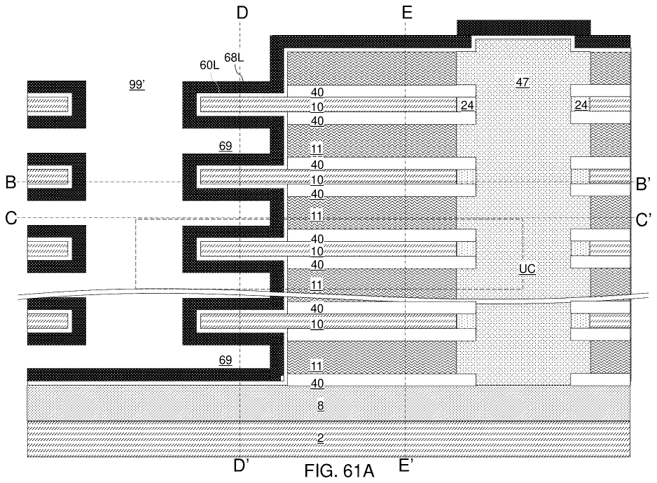

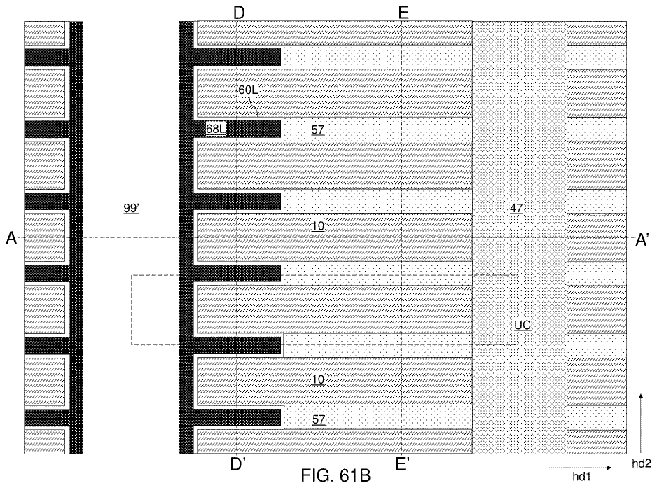

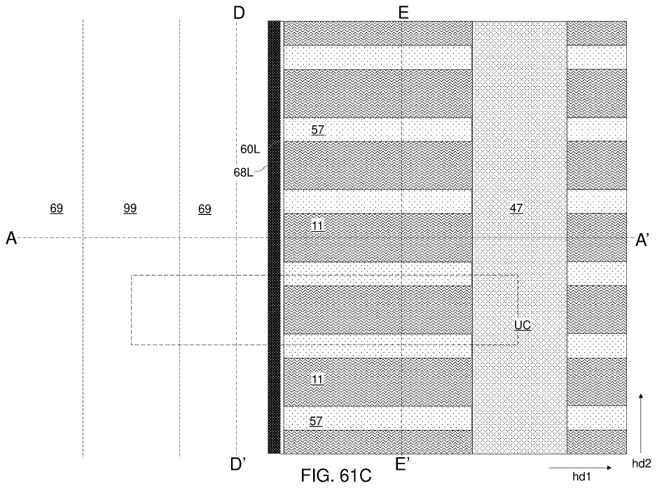

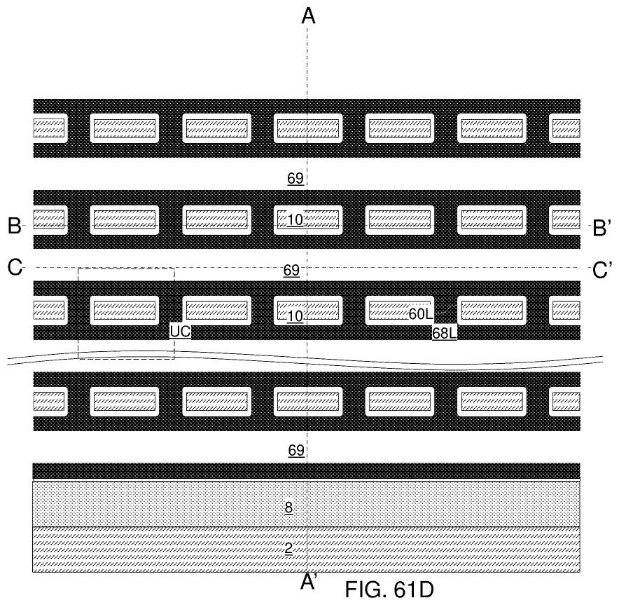

Referring to FIGS. 61A, 61B, 61C, 61D, and 61E, the processing steps described with reference to FIGS. 7A, 7B, 7C, 7D, and 7E may be performed to form a first gate dielectric material layer 60L and a continuous first gate electrode material layer 68L.

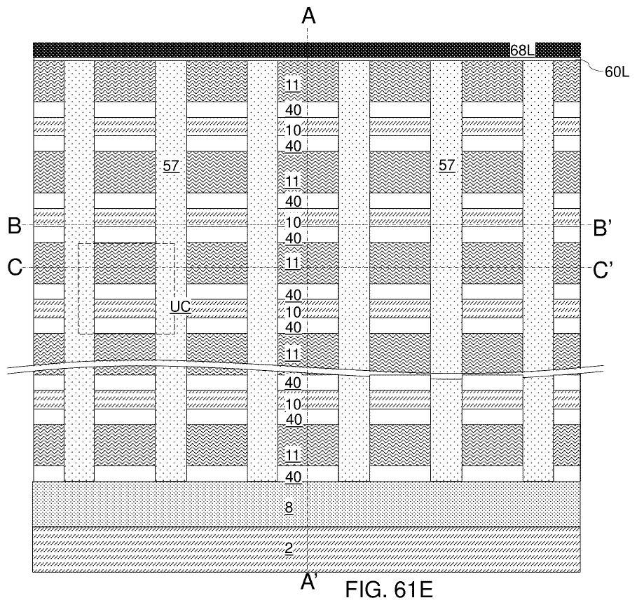

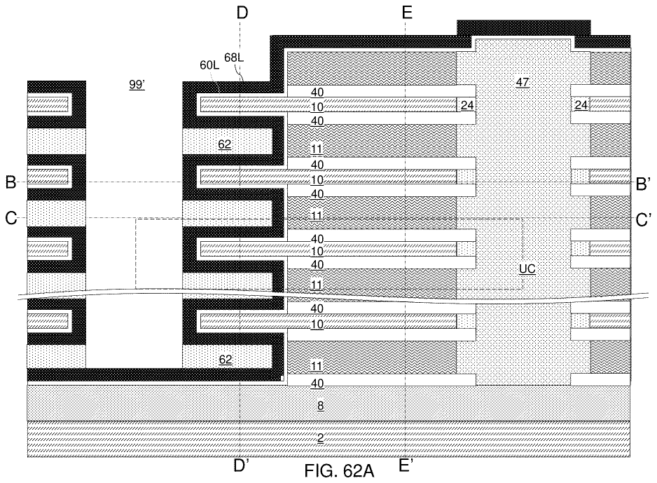

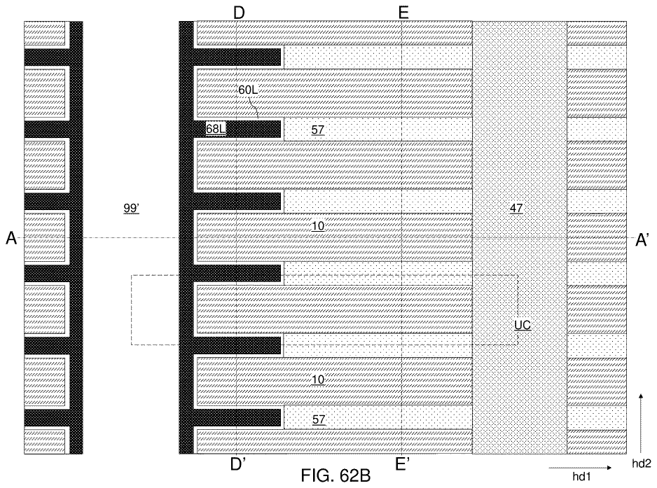

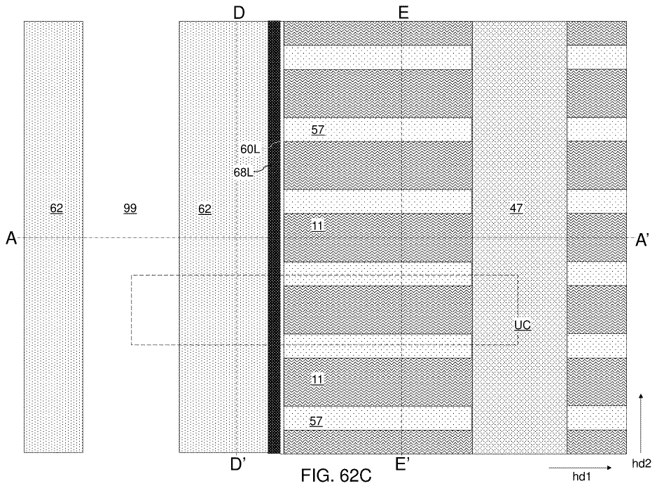

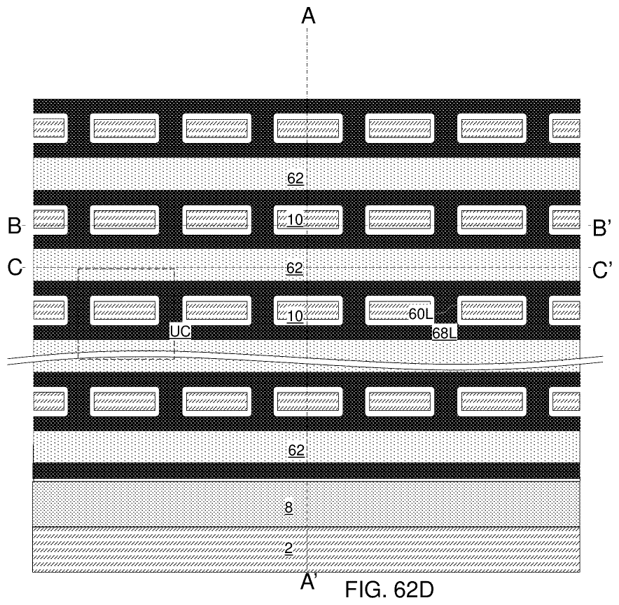

Referring to FIGS. 62A, 62B, 62C, 62D, and 62E, the processing steps described with reference to FIGS. 8A, 8B, 8C, 8D, and 8E may be performed to form a two-dimensional array of first dielectric plates 62.

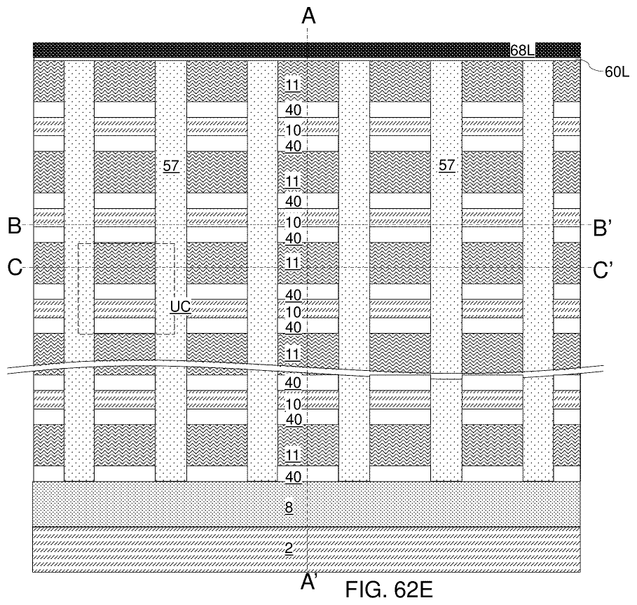

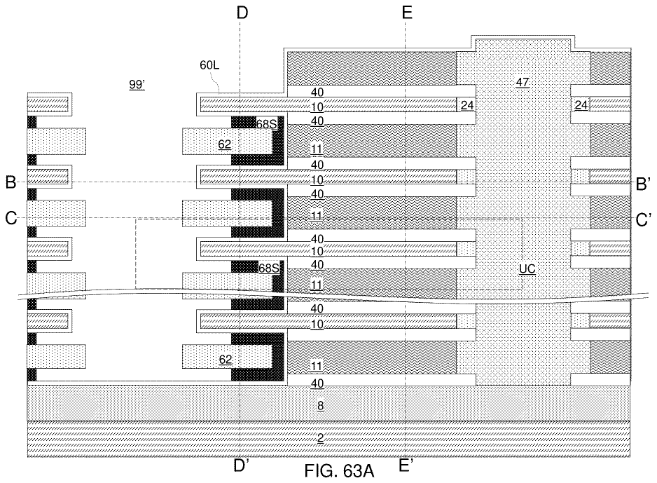

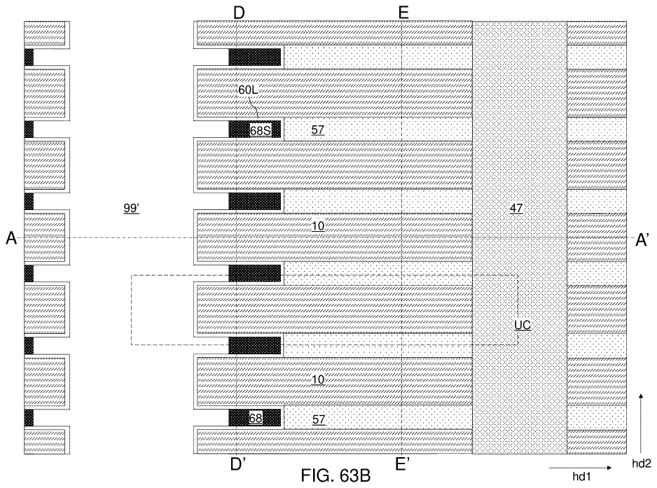

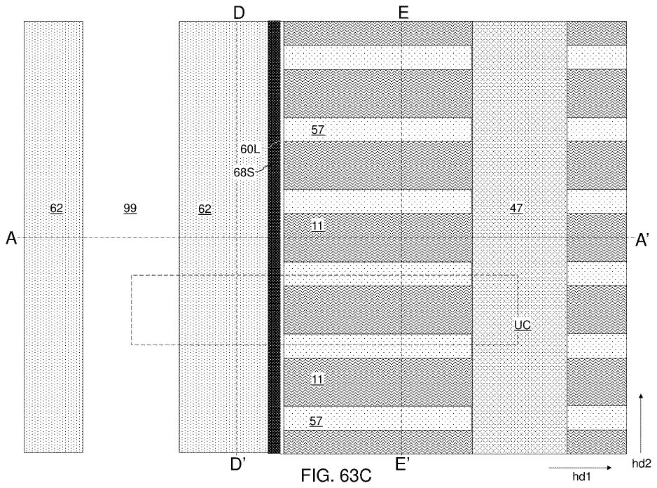

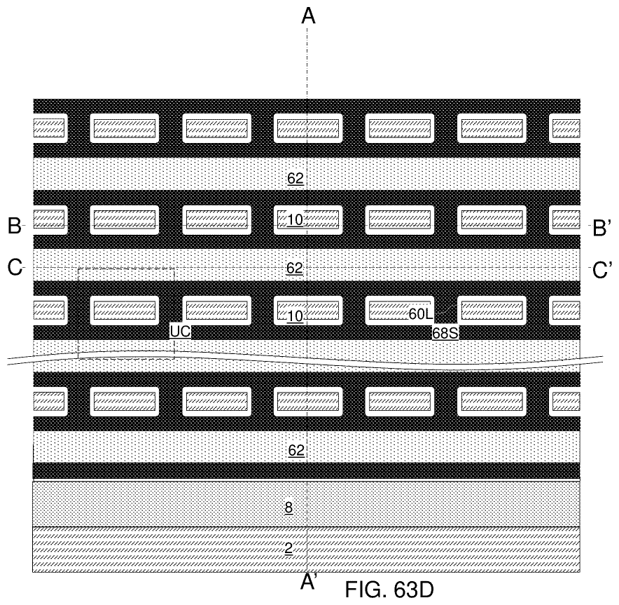

Referring to FIGS. 63A, 63B, 63C, 63D, and 63E, the processing steps described with reference to FIGS. 9A, 9B, 9C, 9D, and 9E may be performed to pattern the continuous first gate electrode material layer 68L into a one-dimensional array of first gate electrode material layers 68S that are laterally spaced apart along the first horizontal direction hd1.

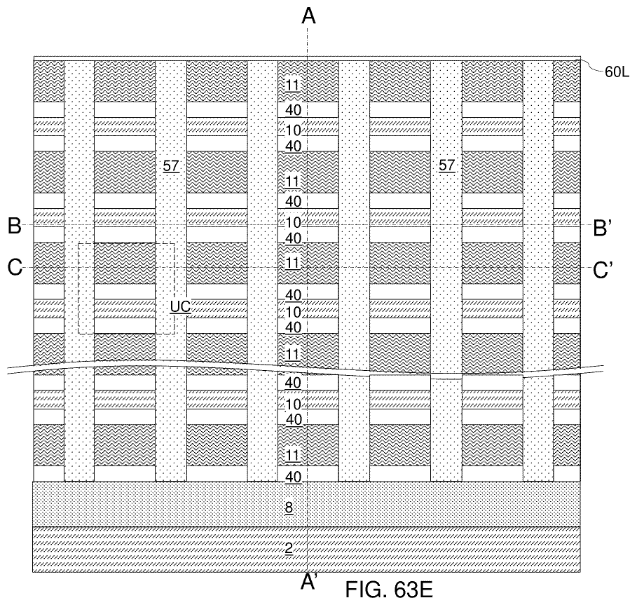

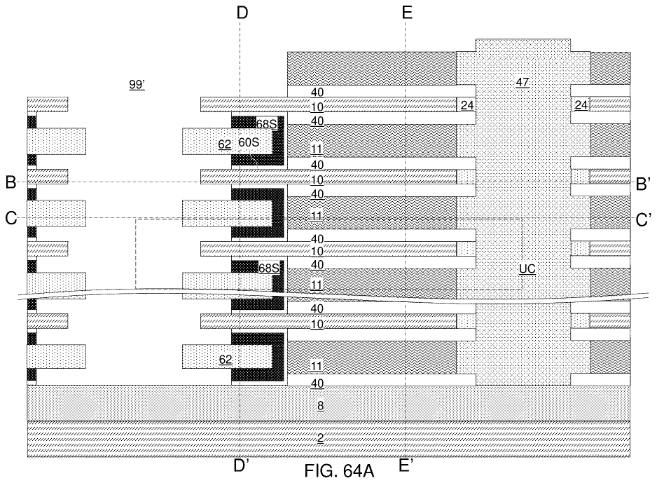

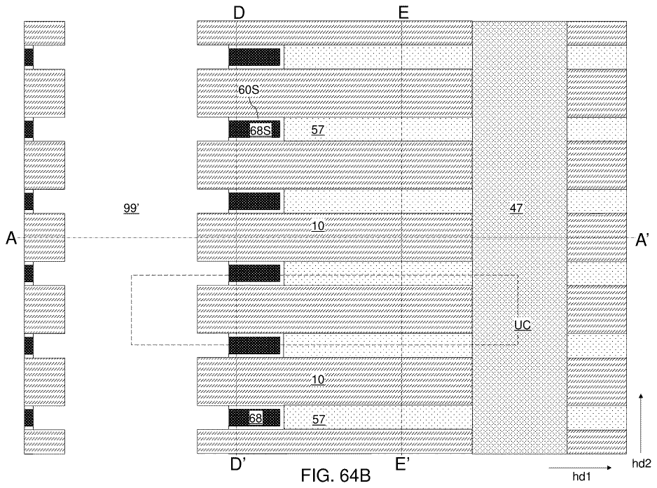

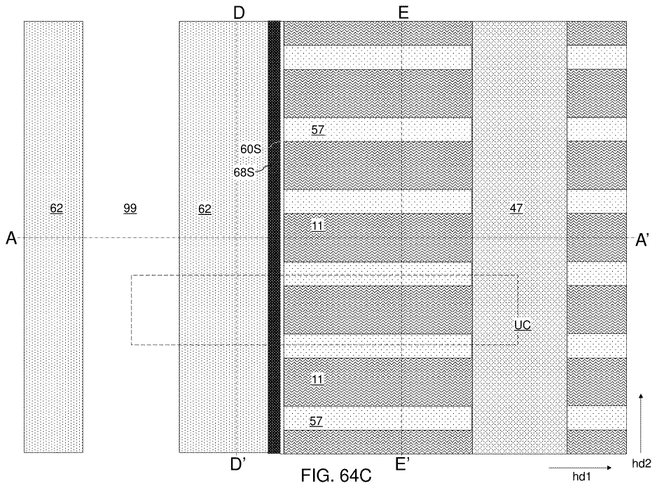

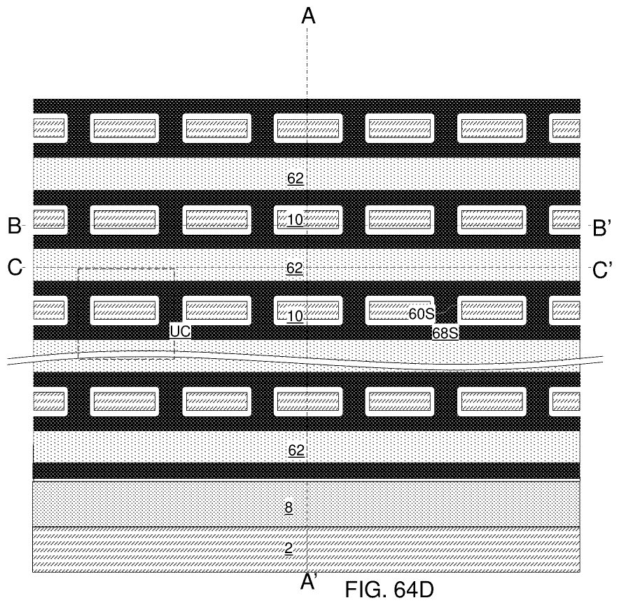

Referring to FIGS. 64A, 64B, 64C, 64D, and 64E, the processing steps described with reference to FIGS. 10A, 10B, 10C, 10D, and 10E may be performed to pattern the first gate dielectric material layer 60L into a one-dimensional array of first gate dielectric layers 60S.

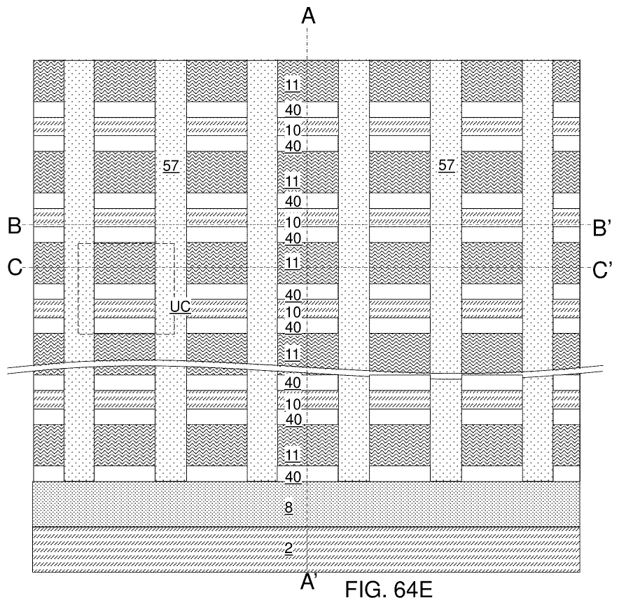

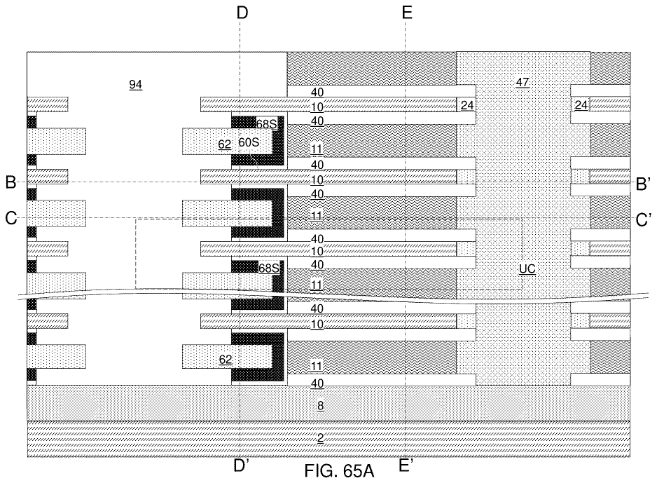

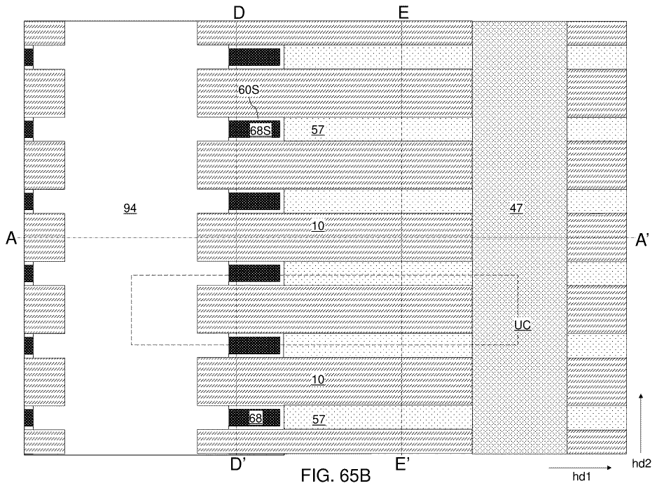

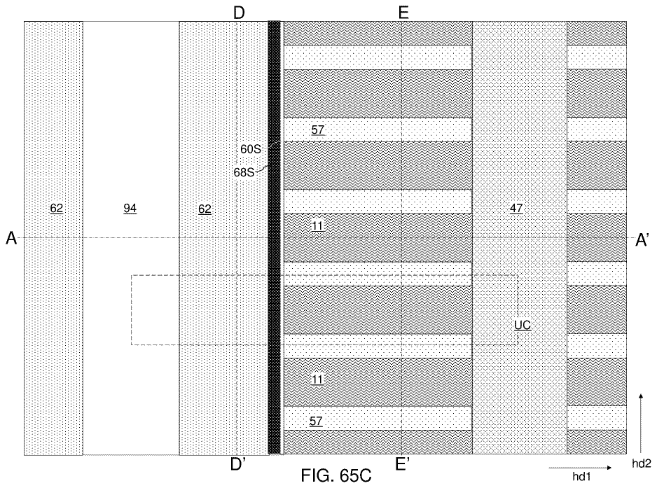

Referring to FIGS. 65A, 65B, 65C, 65D, and 65E, the processing steps described with reference to FIGS. 11A, 11B, 11C, 11D, and 11E may be performed to form bit-line trench isolation structures 94.

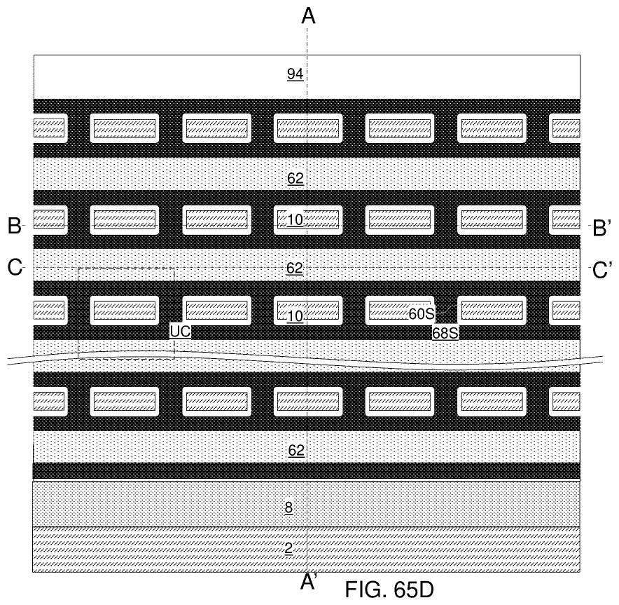

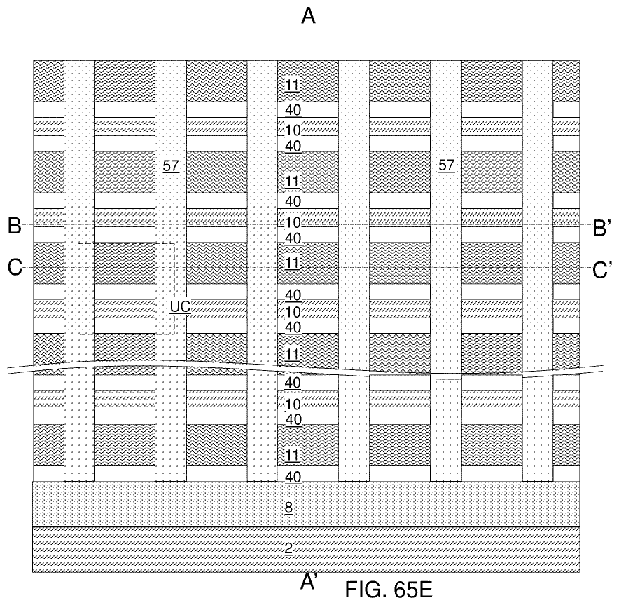

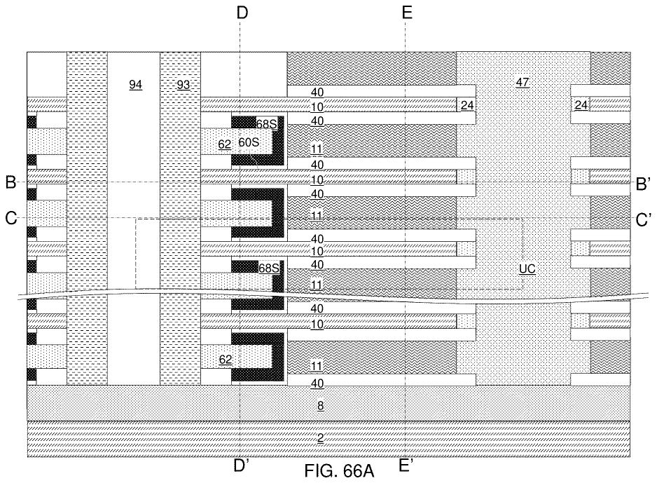

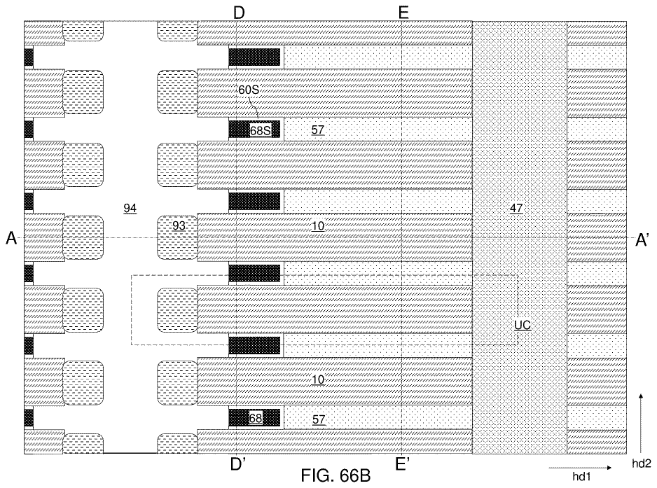

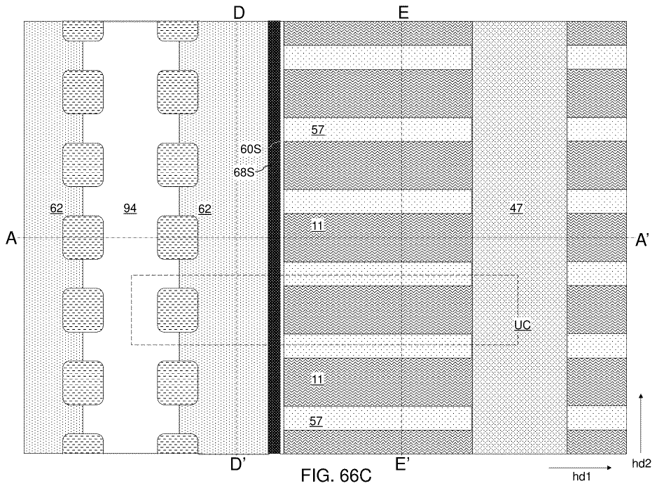

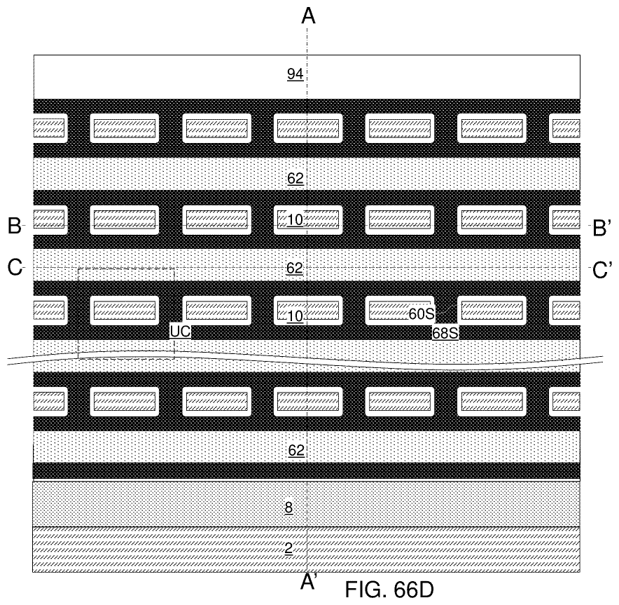

Referring to FIGS. 66A, 66B, 66C, 66D, and 66E, the processing steps described with reference to FIGS. 12A, 12B, 12C, 12D, and 12E may be performed to form sacrificial bit-line structures 93.

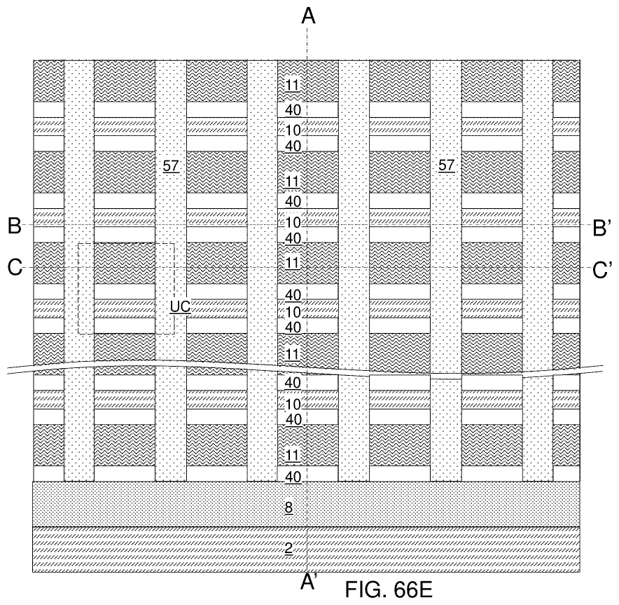

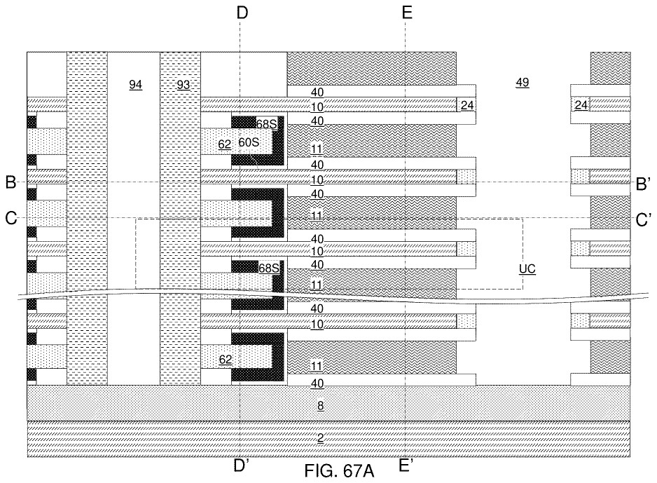

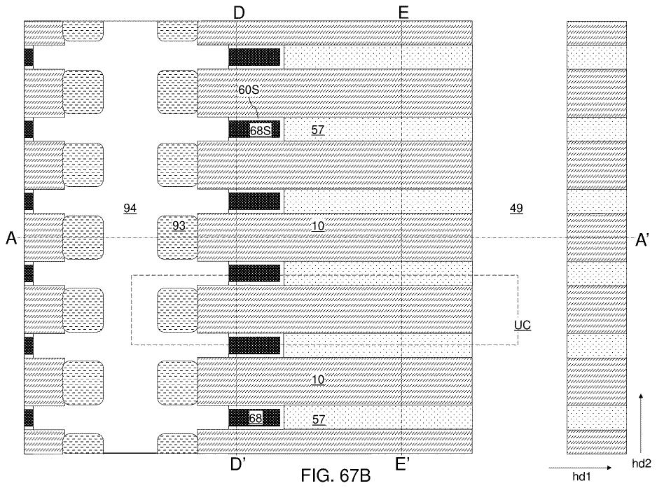

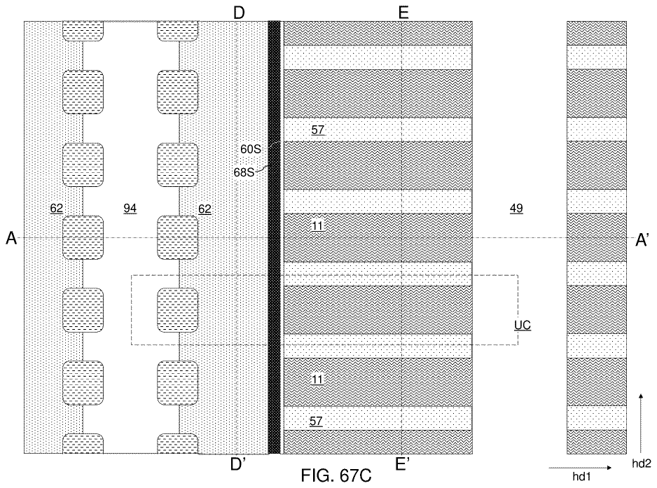

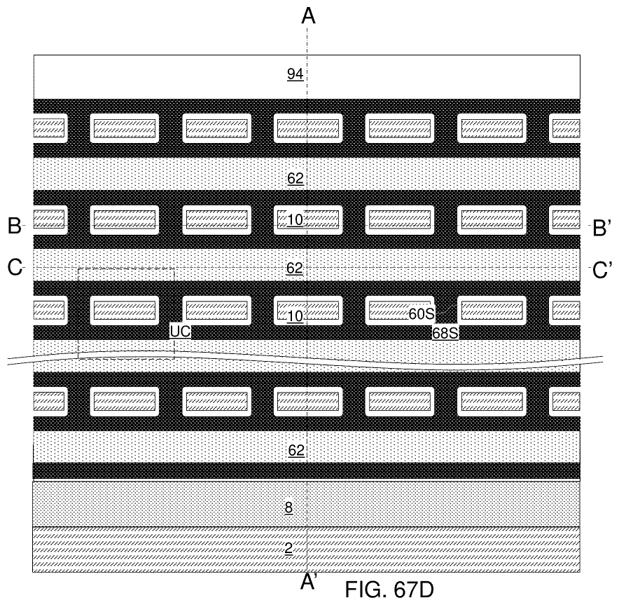

Referring to FIGS. 67A, 67B, 67C, 67D, and 67E, the processing steps described with reference to FIGS. 13A, 13B, 13C, 13D, and 13E may be performed to remove the sacrificial source trench fill structures 47. The selective material removal process that is employed to remove the sacrificial source trench fill structures 47 is herein referred to as a fifth selective material removal process. In one embodiment, the fifth selective material removal process may comprise a fifth selective isotropic etch process.

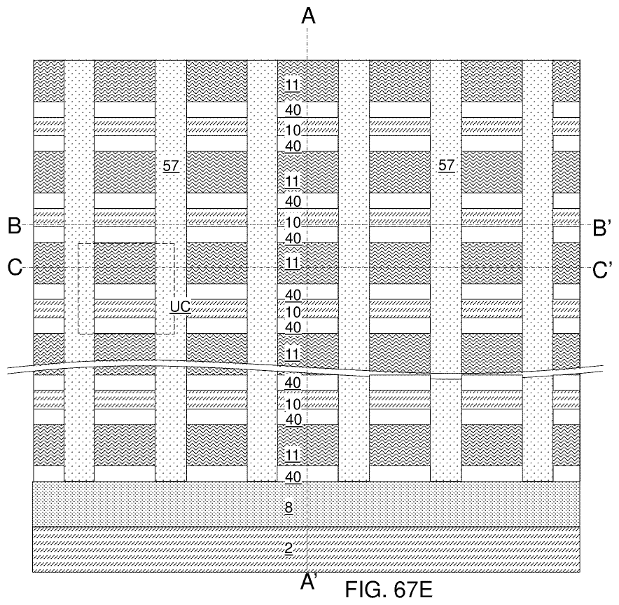

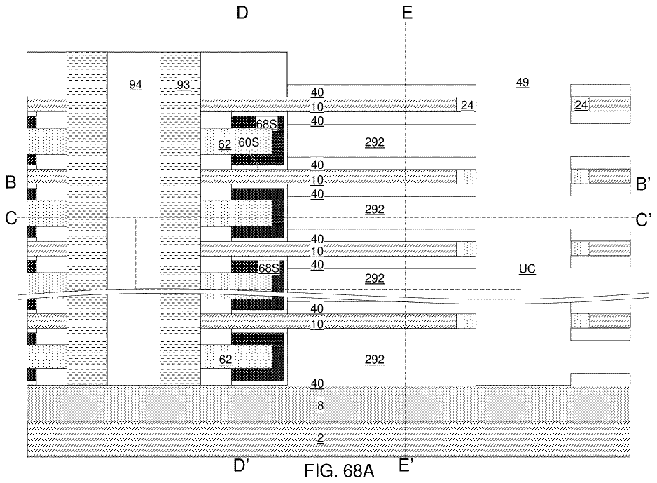

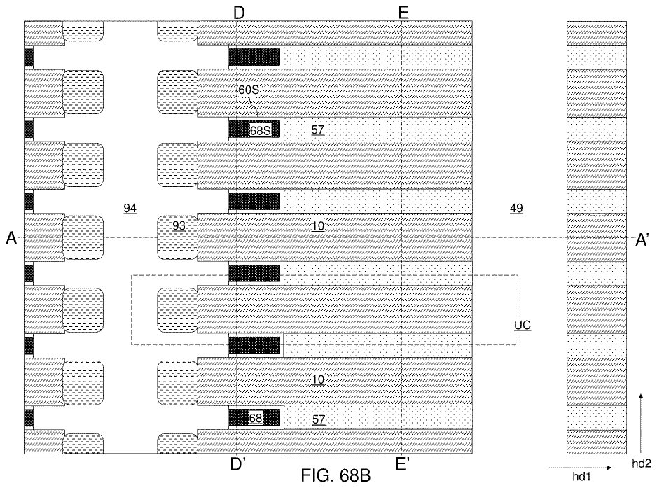

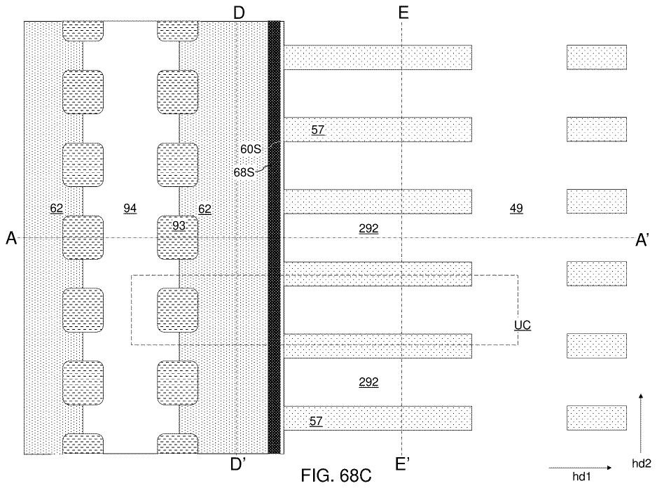

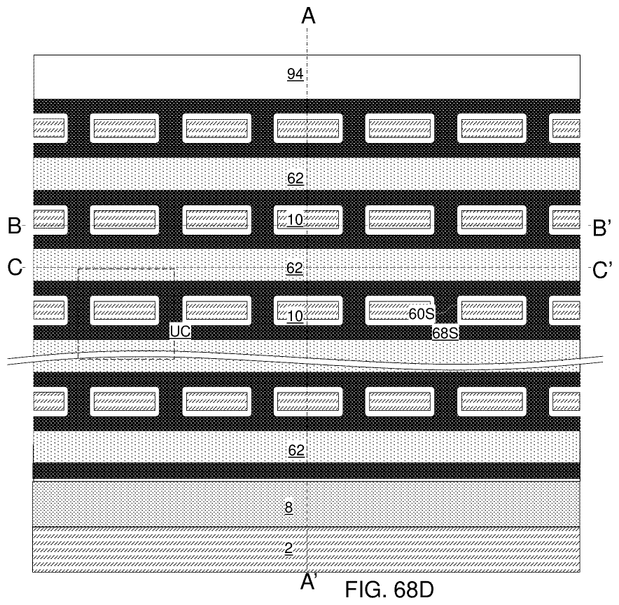

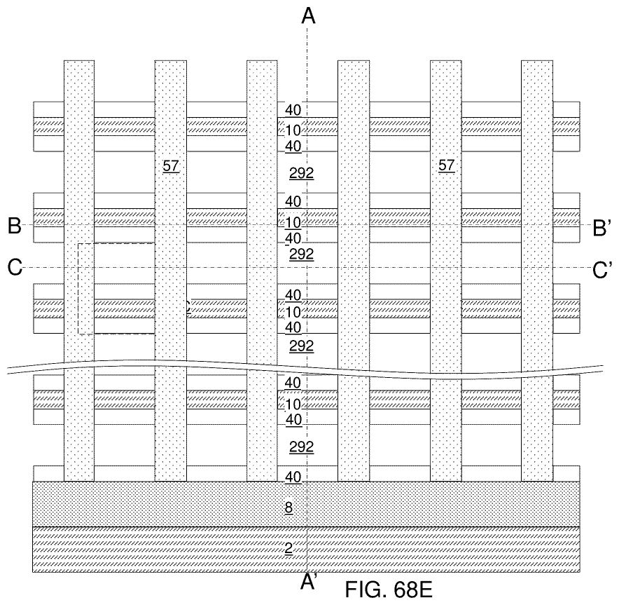

Referring to FIGS. 68A, 68B, 68C, 68D, and 68E, a sixth selective material removal process may be performed to remove a second portion (which is the remaining portion) of each of the sacrificial rails 11 that are proximal to the second capping structures 24 around the source trenches 49. In one embodiment, the sixth selective material removal process may comprise a sixth selective isotropic etch process. For example, if the sacrificial rails 11 comprise single crystalline silicon, a wet etch process employing TMY or TMAH may be employed to remove remaining portions of the sacrificial rails 11. Second voids 292 are formed in the volumes from which the second portions of the sacrificial rails 11 are removed. The second voids 292 are connected to the voids in the source trenches 49.

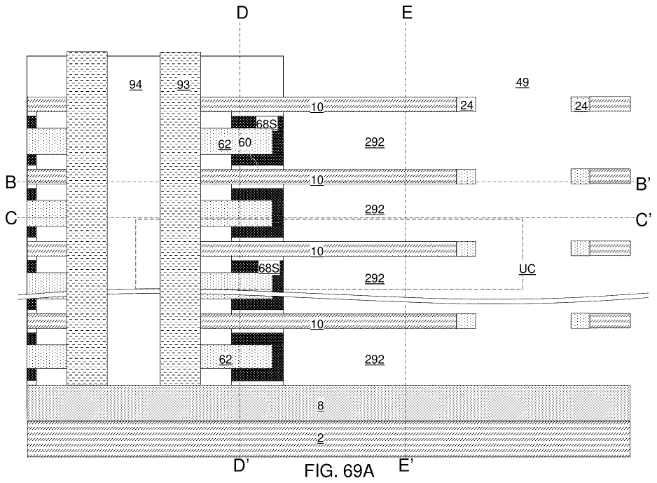

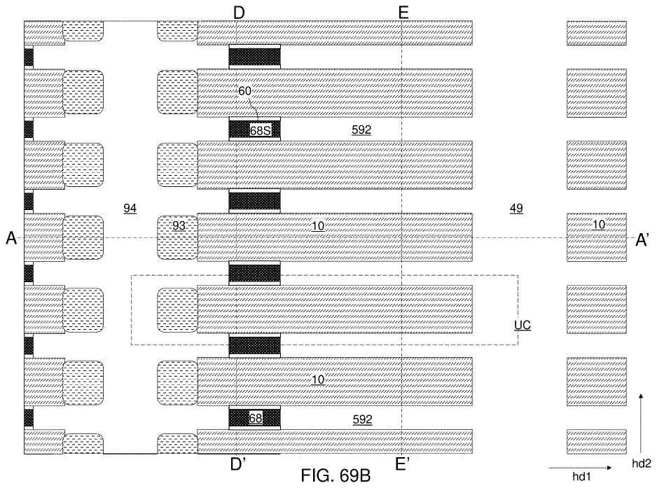

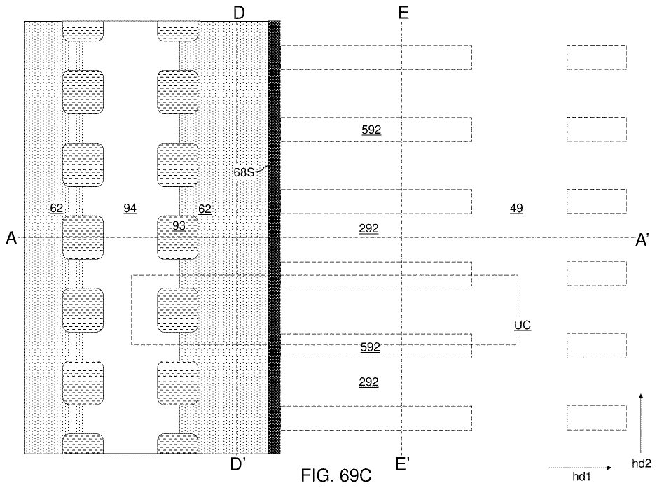

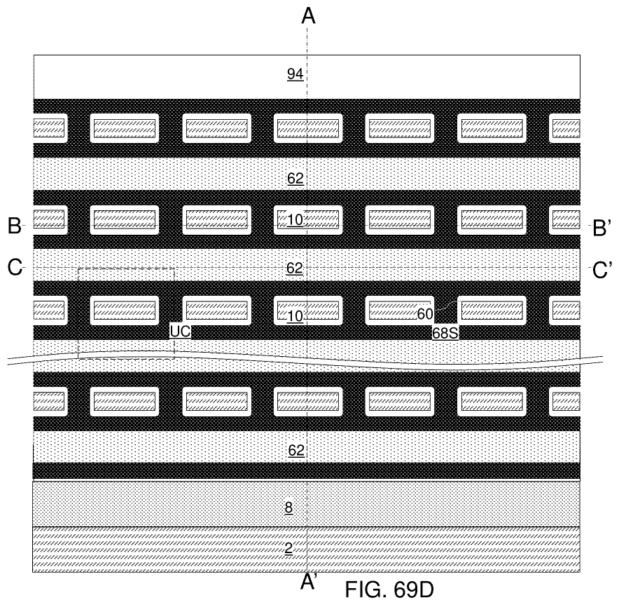

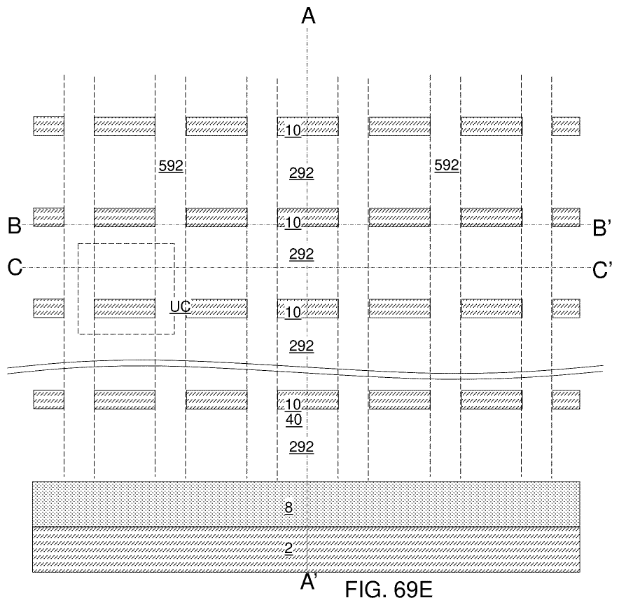

Referring to FIGS. 69A, 69B, 69C, 69D, and 69E, a seventh selective material removal process may be performed to remove second portions (i.e., remaining portions) of the sacrificial isolation trench fill structures 57. The second portions of the sacrificial isolation trench fill structures 57 include portions that are proximal to the second capping structures 24 around the source trenches 49. In one embodiment, the seventh selective material removal process may comprise a seventh selective isotropic etch process.

For example, if the sacrificial isolation trench fill structures 57 comprise a silicon oxide material, a wet etch process employing dilute hydrofluoric acid may be employed to remove remaining portions of the sacrificial isolation trench fill structures 57. In one embodiment, the duration of the seventh selective isotropic etch process may be selected such that the entirety of the remaining portions of the sacrificial isolation trench fill structures 57 is removed.

Second lateral isolation trenches 592 are formed in the volumes from which the second portions of the sacrificial isolation trench fill structures 57 are removed. The second lateral isolation trenches 592 are formed between laterally-neighboring pairs of second portions of the horizontally-extending semiconductor rails 10 by removing the second portion of each of the sacrificial isolation trench fill structures 57.

Further, an eighth selective material removal process may be performed to remove second portions (i.e., remaining portions) of the spacer rails 40. The second portions of the spacer rails 40 include portions that are proximal to the second capping structures 24 around the source trenches 49. The eighth selective material removal process may be performed after or prior to the seventh selective material removal process. In one embodiment, the eighth selective material removal process may comprise an eighth selective isotropic etch process that does not remove the material of the semiconductor rails 10. Generally, any etch chemistry that can be employed for the fourth selective material removal process may be employed for the eighth selective material removal process.

In one embodiment, the duration of the eighth selective isotropic etch process may be selected such that the entirety of the remaining portions of the spacer rails 40 are removed by the eighth selective isotropic etch process. The second voids 292 are expanded to include the voids formed by removal of the second portions of the spacer rails 40.

The combination of the second voids 292 (as expanded by the eighth selective material removal process) and the second lateral isolation trenches 592 constitutes second cavities (292, 592). Generally, the second cavities (292, 592) are formed by removing portions of the first spacer rails 40 and the second spacer rails 40 that are proximal to the second voids 292 as formed at the processing steps of FIGS. 68A, 68B, 68C, 68D, and 68E, and by removing remaining portions of the sacrificial isolation trench fill structures 57. The second cavities (292, 592) are connected to the voids in the source trenches 49.

The second capping structures 24, i.e., the source-side capping structures 24, may optionally be removed by performing a selective isotropic etch process after the sixth selective material removal process. The selective isotropic etch process may remove the second capping structures 24 without removing the semiconductor rails 10. For example, if the second capping structures 24 comprise silicon nitride, the selective isotropic etch process may comprise a wet etch process employing hot phosphoric acid. The removal of the second capping structures 24 may be performed prior to, between or after, the seventh selective material removal process and the eighth selective material removal process. Alternatively, the selective isotropic etch process may be omitted and the source-side capping structures 24 may be retained until the source regions (12 or 32) are formed through the source-line trenches 49.

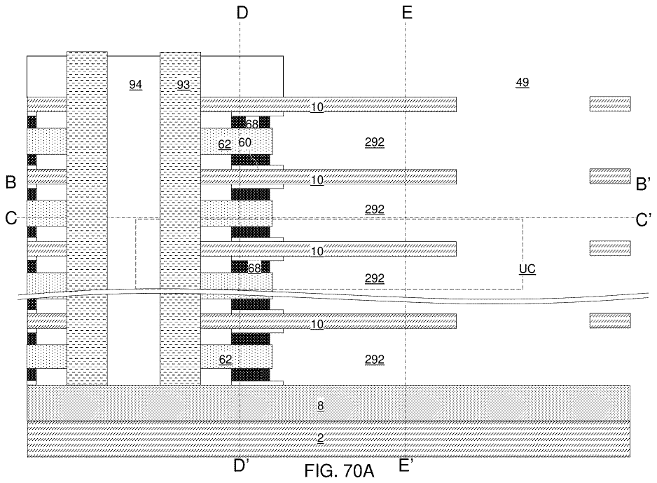

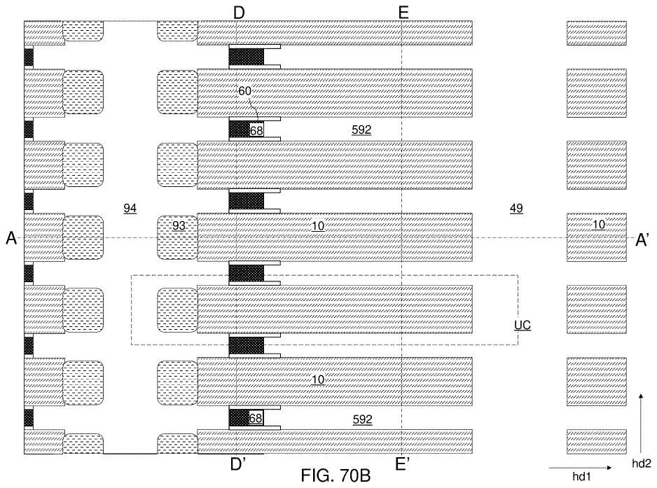

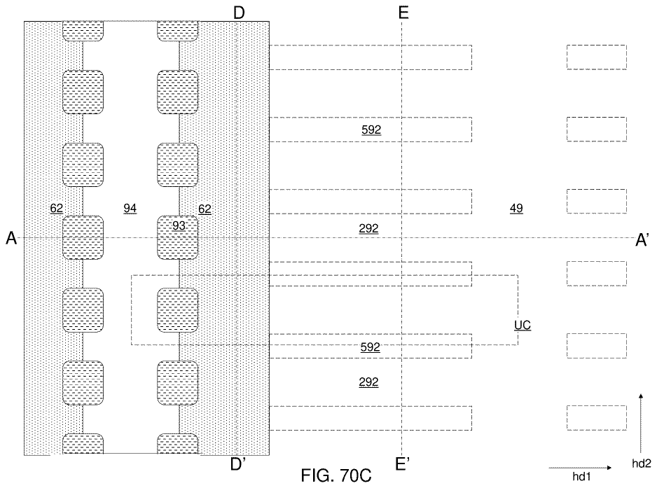

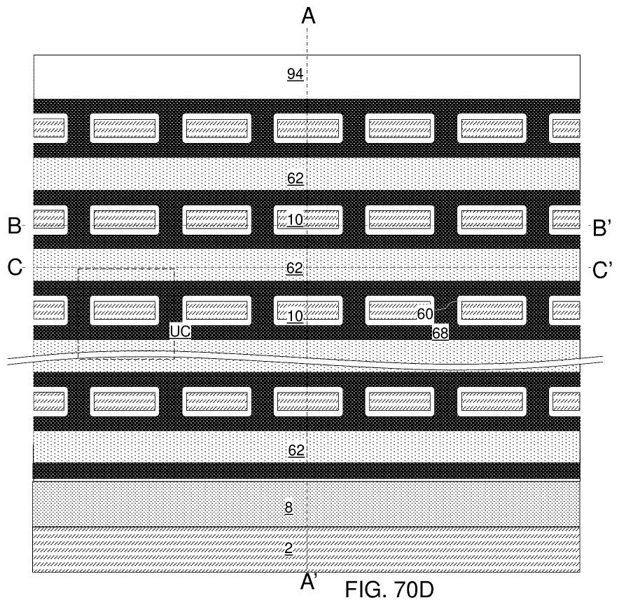

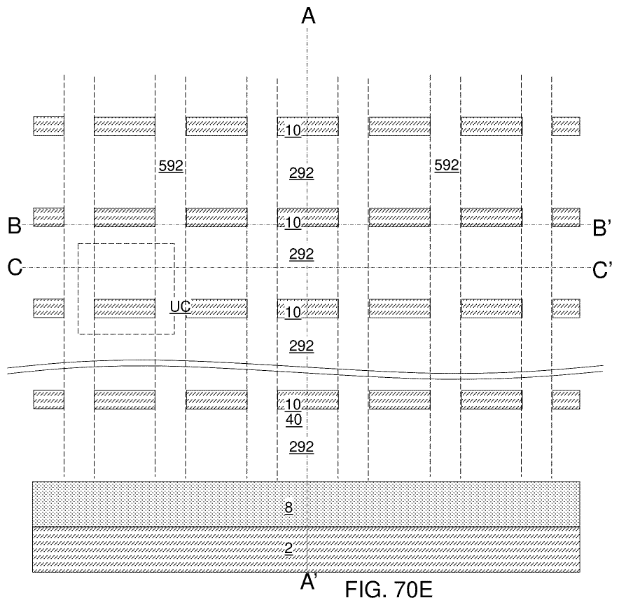

Referring to FIGS. 70A, 70B, 70C, 70D, and 70E, the processing steps described with reference to FIGS. 15A, 15B, 15C, 15D, and 15E can be performed to divide the first gate dielectric layers 60S into a three-dimensional array of first gate dielectrics 60, and to divide the first gate electrode material layers 68S into a two-dimensional array of first word lines 68. Each first word line 69 comprises a respective row of first gate electrodes that are arranged along the second horizontal direction hd2.

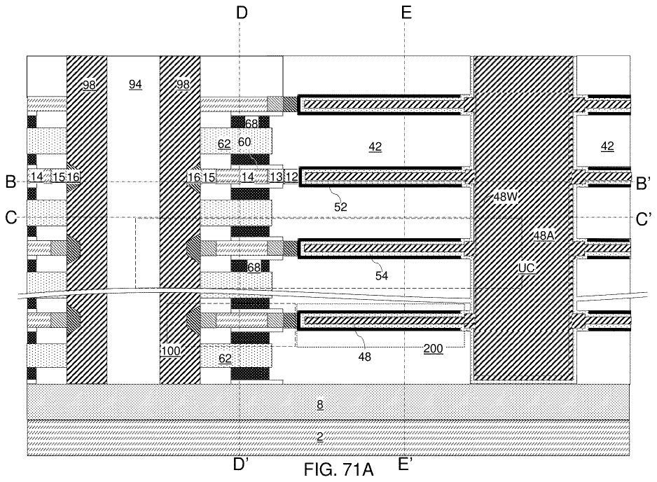

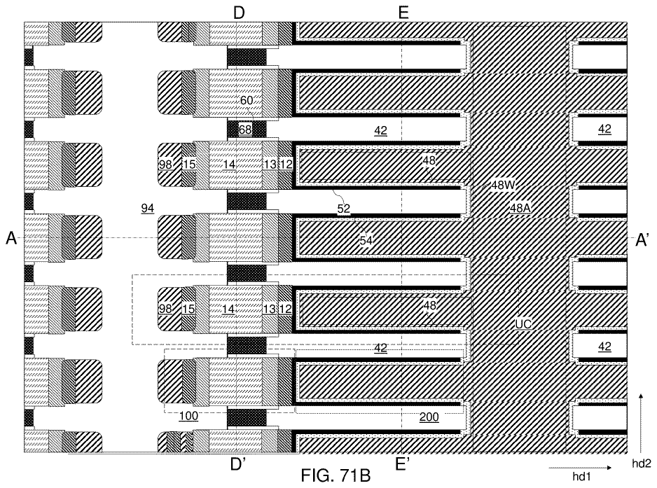

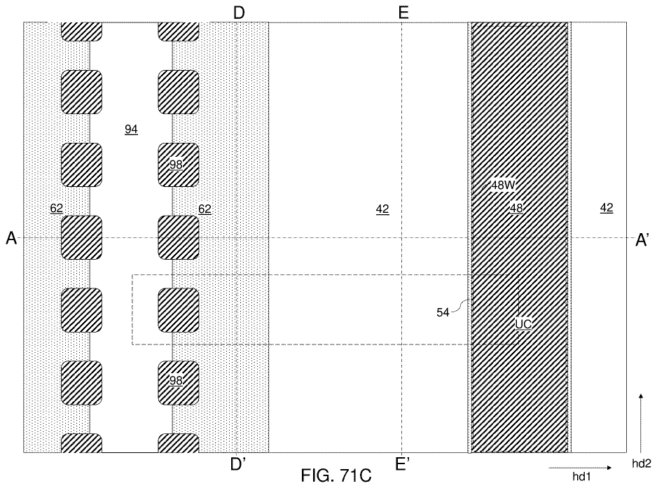

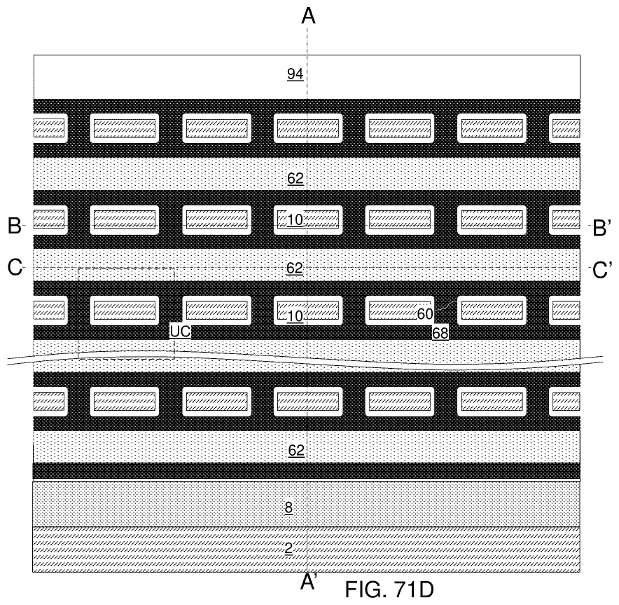

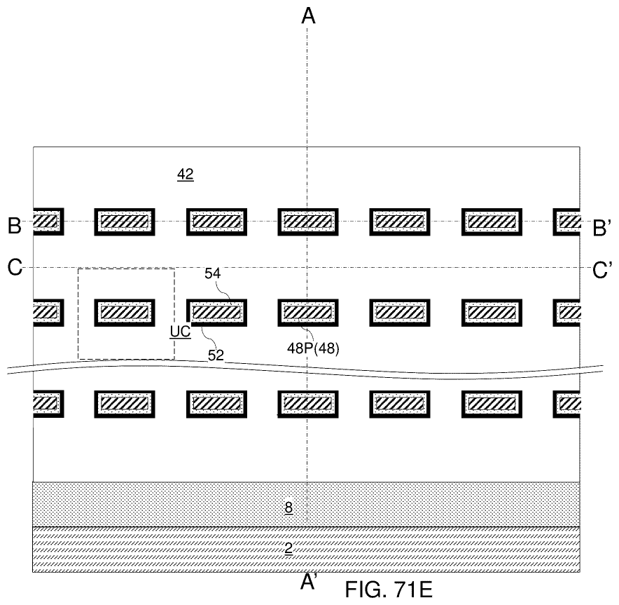

Referring to FIGS. 71A, 71B, 71C, 71D, and 71E, a sequence of processing steps described with reference to FIGS. 16A-26G may be performed, with suitable modifications if

necessary, to form a three-dimensional memory device. In this embodiment, memory cells include a respective access transistor 100 and a respective storage device 200. The memory cells are accessed by bit lines 98, and a one-dimensional array of conductive structures 48A. In this embodiment, the storage device 200 comprises a ferroelectric capacitor.

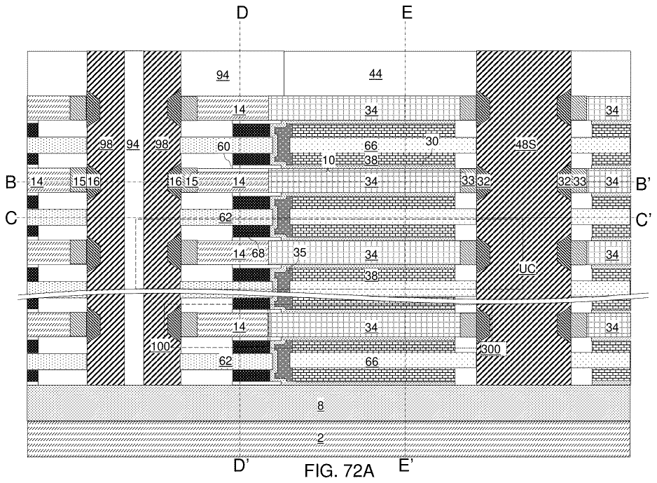

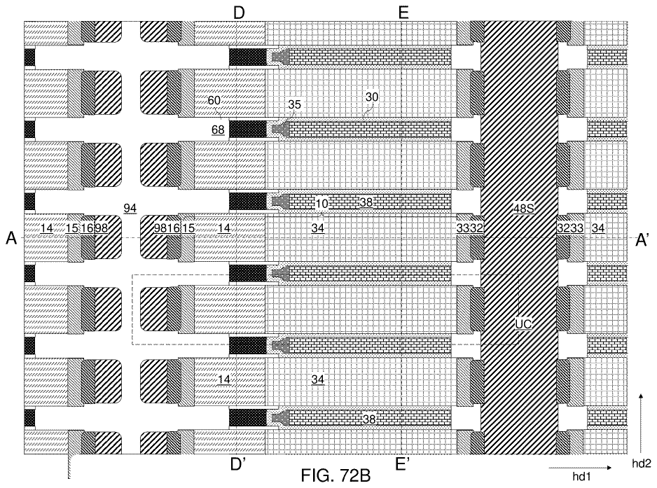

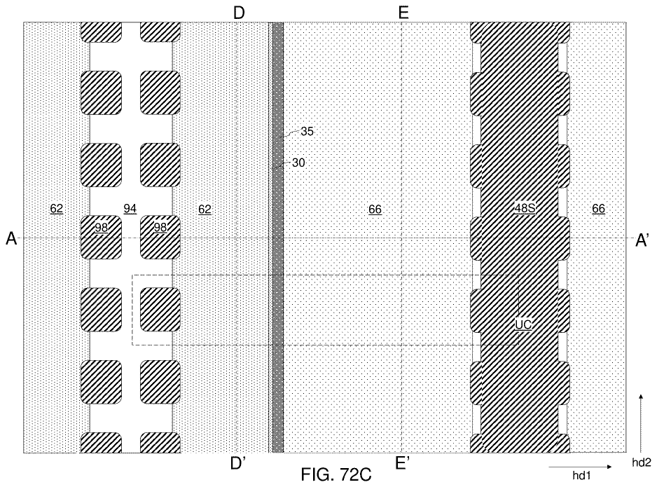

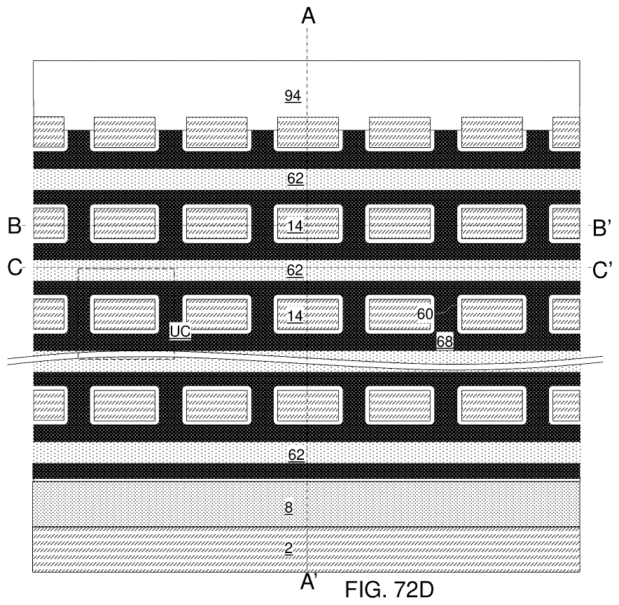

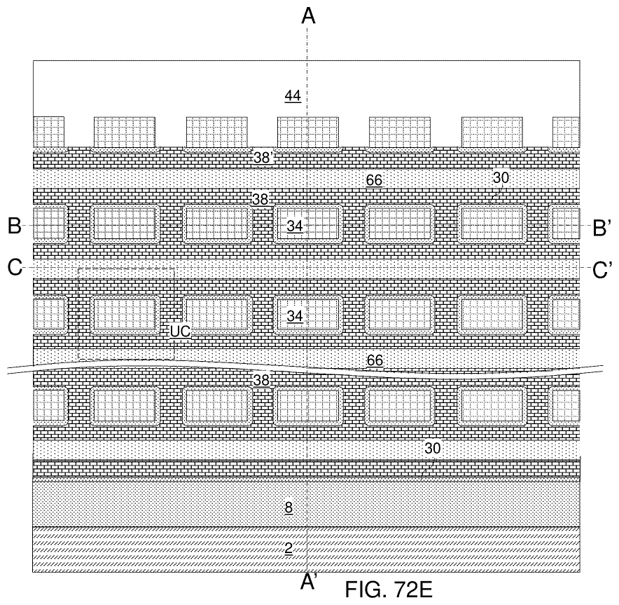

Referring to FIGS. 72A, 72B, 72C, 72D, and 72E, a first alternative embodiment of the third exemplary structure can be derived from the third exemplary structure illustrated in FIGS. 70A, 70B, 70C, 70D, and 70E by performing a sequence of processing steps described with reference to FIG. 30A-40E with suitable modifications if necessary, to form a first alternative three-dimensional memory device. In this embodiment, memory cells include a respective access transistor 100 and a respective storage transistor 300. The memory cells are accessed by bit lines 98 and source lines 48S.

FIG. 73-80 are sequential vertical cross-sectional views of a second alternative embodiment of the third exemplary structure during a subset of processing steps according to the third embodiment of the present disclosure.

Referring to FIG. 73, the second alternative embodiment of the third exemplary structure can be derived from the third exemplary structure illustrated in FIGS. 51A, 51B, 51C, 51D, and 51E by employing as a unit layer stack including, from bottom to top, a first spacer layer 40L, a semiconductor layer 10L having a first thickness, a second spacer layer 40L, a first sacrificial layer 11L having a second thickness, a third spacer layer 40L, and a second sacrificial layer 11L having the second thickness. The semiconductor layer 10L, the first sacrificial layer 11L, and the second sacrificial layer 11L may comprise a first semiconductor material as discussed with reference to FIGS. 51A, 51B, 51C, 51D, and 51E. The first spacer layer 40L, the second spacer layer 40L, and the third spacer layer 40L may comprise a second semiconductor material as discussed with reference to FIGS. 51A, 51B, 51C, 51D, and 51E.

The first thickness may be in a range from 5 nm to 20 nm, although lesser or greater thicknesses may also be employed. The second thickness may be in a range from 150% to 600% of the first thickness. For example, the second thickness may be in a range from 10 nm to 60 nm, such as from 15 nm to 30 nm, although lesser or greater thicknesses may also be employed. Each of the spacer layers 40L may have a thickness in a range from 5 nm to 20 nm, although lesser or greater thicknesses may also be employed.

In one embodiment, the first semiconductor material is a single crystalline silicon material, and the second semiconductor material is a single crystalline silicon-germanium material. The vertical repetition of instances of the unit layer stack (10L, 11L, 40L) may be formed such that all portions of the first semiconductor material and all portions of the second semiconductor material are portions of a single crystalline structure that is single crystalline throughout and has a same set of crystallographic orientations throughout. In other words, each of the semiconductor layers 10L, the sacrificial layers 11L, and the spacer layers 40 may be epitaxially aligned among one another, and the set of all semiconductor layers 10L, the sacrificial layers 11L, and the spacer layers 40 may constitute a contiguous single crystalline structure having the same crystallographic orientations throughout and epitaxially aligned among one another.

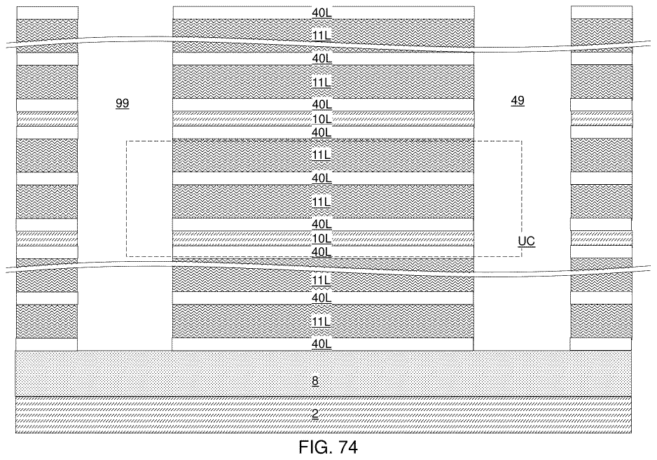

Referring to FIG. 74, the processing steps described with reference to FIGS. 2A, 2B, 2C, 2D, and 2E may be performed to form a laterally alternating sequence of bit-line trenches 99 and source trenches 49. Generally, the vertical repetition of multiple instances of the unit layer stack (10L, 11L, 40L) as provided in the processing steps of FIG. 73 may be divided by forming a laterally alternating sequence (99, 49) of bit-line trenches 99 and source trenches 49 that alternate along the first horizontal direction hd1. Each of the bit-line trenches 99 and the source trenches 49 laterally extend along a second horizontal direction hd2.

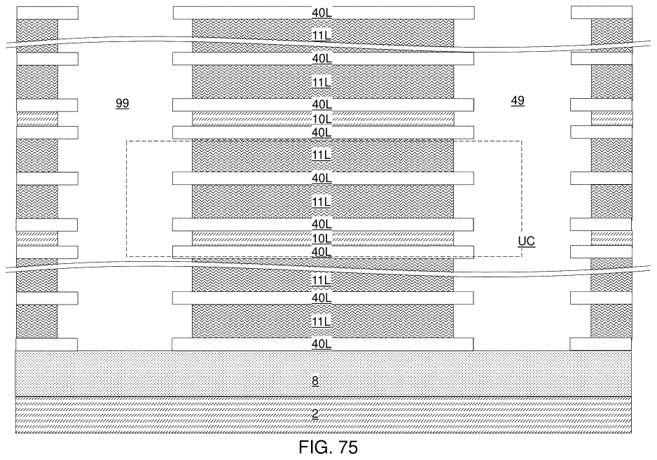

Referring to FIG. 75, the processing steps described with reference to FIGS. 53A, 53B, 53C, 53D, and 53E may be performed. A selective isotropic etch process can be performed to laterally recess physically exposed sidewalls of the semiconductor layers 10L and the sacrificial layers 11L around the bit-line trenches 99 and the source trenches 49 selectively to the material of the spacer layers 40L. In one embodiment, the first semiconductor material of the semiconductor layers 10L and the sacrificial layers 11L may comprise single crystalline silicon, and the second semiconductor material of the spacer layers 40L may comprise a single crystalline silicon-germanium material including germanium at an atomic percentage in a range from 10% to 50%.

Generally, sidewalls of remaining portions of the semiconductor layers 10L and the sacrificial layers 11L can be laterally recessed relative to sidewalls of the spacer layers 40L after formation of the bit-line trenches 99 and the source trenches 49 by a first lateral recess distance. The first lateral recess distance may be in a range from 50% to 400%, such as from 100% to 300%, of the first thickness, i.e., the thickness of the semiconductor layers 10L.

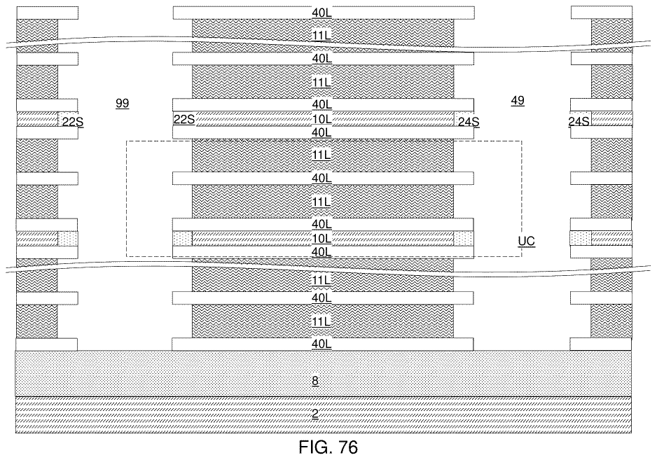

Referring to FIG. 76, the processing steps described with reference to FIGS. 54A, 54B, 54C, 54D, and 54E may be performed to form bit-line-side capping strips 22S and source-side capping strips 24S. Each capping strip (22S, 24S) may laterally extend along the second horizontal direction hd2 with a uniform vertical cross-sectional shape within vertical planes that are perpendicular to the second horizontal direction hd2.

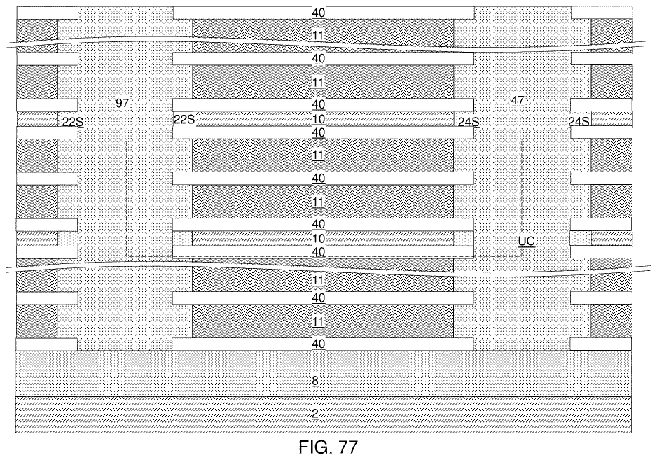

Referring to FIG. 77, the processing steps described with reference to FIGS. 55A, 55B, 55C, 55D, and 55E may be performed to form sacrificial source trench fill structures 47 and sacrificial bit-line trench fill structures 97.

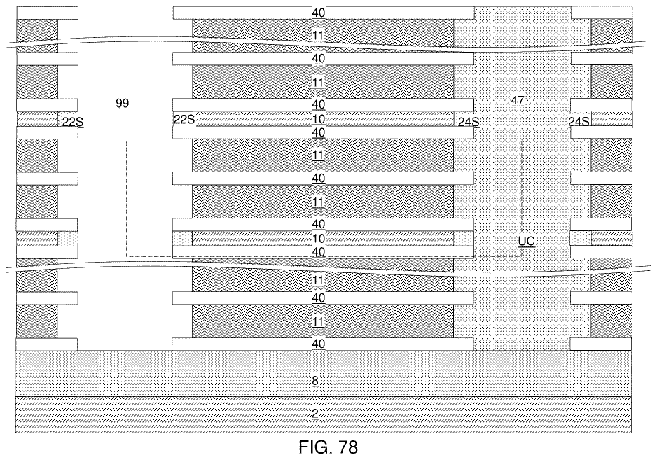

Referring to FIG. 78, the processing steps described with reference to FIGS. 56A, 56B, 56C, 56D, and 56E may be performed to form lateral isolation trenches 59 through the vertical repetitions of the multiple instances of the unit layer stack (10L, 11L, 40L). The pattern of the lateral isolation trenches 59 can be selected such that each bit-line-side capping strip 22S is divided into a respective row of bit-line-side capping structures 22 (which may be referred to as first capping structures 22), and each source-side capping strip 24S is divided into a respective row of source-side capping structures 24 (which may be referred to as second capping structures 24).

In one embodiment, the lateral isolation trenches 59 laterally extend along the first horizontal direction hd1 through remaining portions of the vertical repetition and through remaining portions of the capping material layer after removing the portions of the capping material layer outside the recesses at the levels of the semiconductor layers 10L. Each patterned portion of the semiconductor layers 10L comprises a semiconductor rail 10. Each patterned portion of the sacrificial layers 11L comprises a sacrificial rail 11. Each patterned portion of the spacer layers 40L comprises a spacer rail 40. Remaining portions of the vertical repetition of multiple instances of the unit layer stack (10L, 11L, 40L) as provided at the processing steps of FIG. 73 comprise the array of vertical rail stacks (10, 11, 40). Remaining portions of the capping material layer comprise the first capping structures 22 and the second capping structures 24.

In summary, a three-dimensional array of vertical rail stacks (10, 11, 40) can be formed. A two-dimensional array of vertical rail stacks (10, 11, 40) can be provided between each laterally neighboring pair of a sacrificial bit-line trench fill structure 97 and a sacrificial source trench fill structure 47. Each of the vertical rail stacks (10, 11, 40) comprises, from bottom to top, a first spacer rail 40, a semiconductor rail 10, a second spacer rail 40, a first sacrificial rail 11, a third spacer rail 40, and a second sacrificial rail 11,. Each of the vertical rail stacks (10, 11, 40) laterally extends along a first horizontal direction hd1, and each of the semiconductor rail 10 comprises a respective first semiconductor end wall contacting a respective first capping structure 22 and further comprises a respective second semiconductor end wall contacting a respective second capping structure 24.

In one embodiment, within each of the vertical rail stacks (10, 11, 40), the semiconductor rail 10 and the sacrificial rails 11 have a same material composition consisting of a first semiconductor material and have different vertical thicknesses. In one embodiment, within each of the vertical rail stacks (10, 11, 40), the spacer rails 40 have a same material composition consisting of a second semiconductor material that is different from the first semiconductor material.

In one embodiment, within each of the vertical rail stacks (10, 11, 40), the first semiconductor material is a single crystalline silicon material and the second semiconductor material is a single crystalline silicon-germanium material. In one embodiment, within each contiguous set of vertical rail stacks (10, 11, 40) that overlie or underlie one another, all portions of the first semiconductor material and all portions of the second semiconductor material are portions of a single crystalline structure that is single crystalline throughout and has a same set of crystallographic orientations throughout.

Subsequently, the processing steps described with reference to FIGS. 5A, 5B, 5C, 5D, and 5E can be performed to form sacrificial isolation trench fill structures 57 in the lateral isolation trenches 59.

Then, the bit-line trenches 97 are reopened to form voids are formed in the volumes of the bit-line trenches 99, as discussed above. Thus, the sacrificial bit-line trench fill structures 97 are removed without removing the sacrificial source trench fill structures 47.

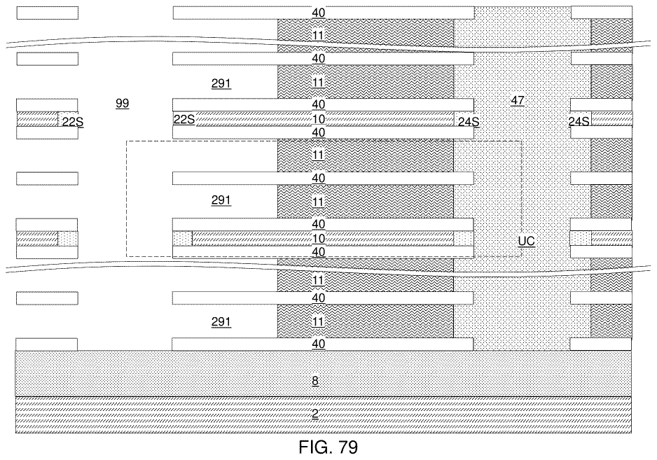

Referring to FIG. 79, the processing steps described with reference to FIGS. 59A, 59B, 59C, 59D, and 59E can be performed. Specifically, a second selective material removal process may be performed to remove a first portion of each of the sacrificial rails 11 that are proximal to the first capping structures 22 around the bit-line trenches 99. First voids 291 are formed in the volumes from which the first portions of the sacrificial rails 11 are removed. The first voids 291 are connected to the voids in the bit-line trenches 99. Two first voids 291 are formed within the volume of each unit cell UC.

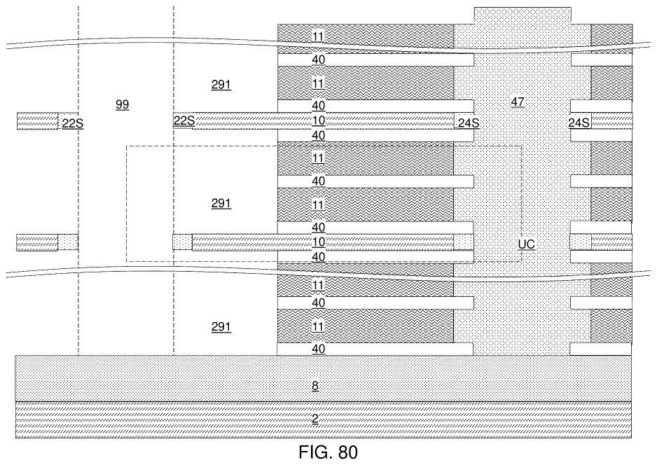

Referring to FIG. 80, the processing steps described with reference to FIGS. 60A, 60B, 60C, 60D, and 60E can be performed. Specifically, a third selective material removal process may be performed to remove first portions of the sacrificial isolation trench fill structures 57 to form the first lateral isolation trenches 591. Further, a fourth selective material removal process may be performed to remove physically exposed first portions of the spacer rails 40. The first voids 291 are expanded to include the voids formed by removal of the first portions of the spacer rails 40.

The combination of the first voids 291 (as expanded by the fourth selective material removal process) and the first lateral isolation trenches 591 constitutes first cavities (291, 591). The bit-line-side capping structures 22S, may be removed by performing a selective isotropic etch process after the second selective material removal process.

Subsequently, a sequence of processing steps described with reference to FIG. 61A 72E can be performed to provide a three-dimensional memory device.

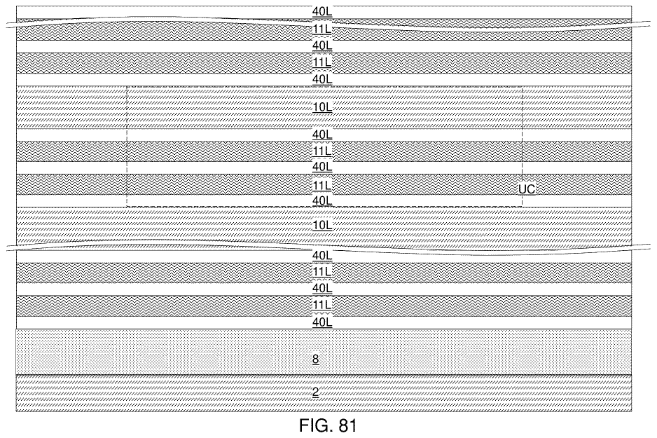

FIG. 81-91 are sequential vertical cross-sectional views of a third alternative embodiment of the third exemplary structure during a subset of processing steps according to the third embodiment of the present disclosure.

Referring to FIG. 81, the third alternative embodiment of the third exemplary structure can be derived from the third exemplary structure illustrated in FIGS. 51A, 51B, 51C, 51D, and 51E by employing as a unit layer stack including, from bottom to top, a first spacer layer 40L, a semiconductor layer 10L having a first thickness, a second spacer layer 40L, a first sacrificial layer 11L having a second thickness, a third spacer layer 40L, and a second sacrificial layer 11L having the second thickness. The semiconductor layer 10L, the first sacrificial layer 11L, and the second sacrificial layer 11L may comprise a first semiconductor material as discussed with reference to FIGS. 51A, 51B, 51C, 51D, and 51E. The first spacer layer 40L, the second spacer layer 40L, and the third spacer layer 40L may comprise a second semiconductor material as discussed with reference to FIGS. 51A, 51B, 51C, 51D, and 51E.

In the third alternative embodiment of the third exemplary structure, the first thickness is greater than the second thickness. The first thickness may be in a range from 10 nm to 60 nm, such as from 15 nm to 30 nm, although lesser or greater thicknesses may also be employed. The second thickness may be in a range from 5 nm to 20 nm, although lesser or greater thicknesses may also be employed. The first thickness may be in a range from 150% to 600% of the second thickness. Each of the spacer layers 40L may have a thickness in a range from 5 nm to 20 nm, although lesser or greater thicknesses may also be employed.

In one embodiment, the first semiconductor material is a single crystalline silicon material, and the second semiconductor material is a single crystalline silicon-germanium material. The vertical repetition of instances of the unit layer stack (10L, 11L, 40L) may be formed such that all portions of the first semiconductor material and all portions of the second semiconductor material are portions of a single crystalline structure that is single crystalline throughout and has a same set of crystallographic orientations throughout. In other words, each of the semiconductor layers 10L, the sacrificial layers 11L, and the spacer layers 40 may be epitaxially aligned among one another, and the set of all semiconductor layers 10L, the sacrificial layers 11L, and the spacer layers 40 may constitute a contiguous single crystalline structure having the same crystallographic orientations throughout and epitaxially aligned among one another.

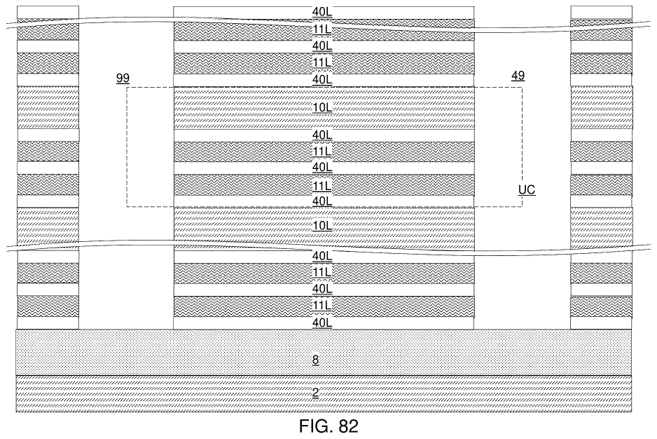

Referring to FIG. 82, the processing steps described with reference to FIGS. 2A, 2B, 2C, 2D, and 2E may be performed to form a laterally alternating sequence of bit-line trenches 99 and source trenches 49.

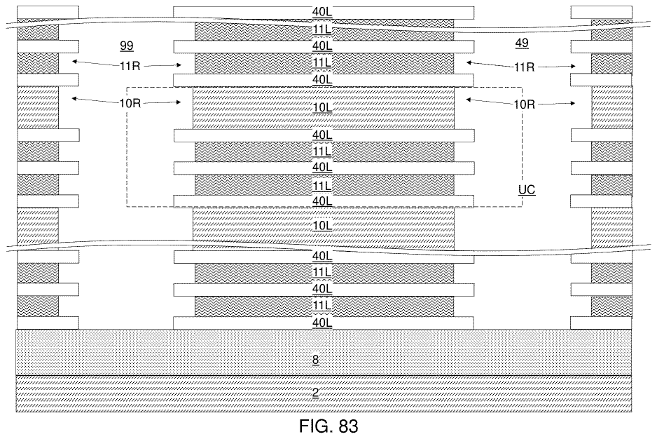

Referring to FIG. 83, the processing steps described with reference to FIGS. 53A, 53B, 53C, 53D, and 53E may be performed. A selective isotropic etch process can be performed to laterally recess physically exposed sidewalls of the semiconductor layers 10L and the sacrificial layers 11L around the bit-line trenches 99 and the source trenches 49 selectively to the material of the spacer layers 40L.

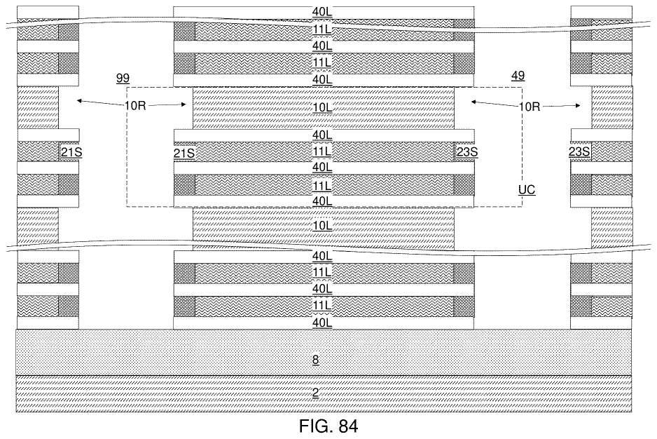

Referring to FIG. 84, a sacrificial capping material layer comprising a sacrificial fill material can be conformally deposited in the lateral recesses between neighboring pairs of the spacer layers 40L. The sacrificial capping material layer comprises a material that is different from the semiconductor materials of the semiconductor layers 10L, the sacrificial layers 11L, and the spacer layers 40L, and is different from the dielectric material to be subsequently employed for a dielectric capping material layer. For example, the sacrificial capping material layer may comprise silicon oxide, silicon carbonitride, aluminum oxide, or a dielectric transition metal oxide. The sacrificial capping material layer is deposited directly on physically exposed sidewalls of the semiconductor layers 10L, the sacrificial layers 11L, and the spacer layers 40L. The thickness of the sacrificial capping material layer is selected such that the second lateral recesses 11R located at the levels of the sacrificial layers 11L are completely filled with portions of the sacrificial capping material layer, while the first lateral recesses 10R located at the levels of the semiconductor layers 10L are partially filled (i.e., not completely filled) with portions of the sacrificial capping material layer. For example, the thickness of the sacrificial capping material layer may be greater than one half of the second thickness, and may be less than one half of the first thickness.

Subsequently, a selective isotropic etch process or a selective anisotropic etch process can be performed to isotropically remove the material of the sacrificial capping material layer from the first lateral recesses 10R without completely removing it from the volumes of the second lateral recesses 11R at the levels of the sacrificial layers 11L. In one embodiment, the selective isotropic etch process may etch the material of the sacrificial capping material layer without etching the material of the semiconductor layers 10L. Remaining portions of the sacrificial capping material layer located within the first lateral recesses 10R located at the levels of the semiconductor layers 10L around a bit-line trench 99 constitute sacrificial capping structures, which are herein referred to bit-line-side sacrificial capping strips 21S. Remaining portions of the sacrificial capping material layer located within the first lateral recesses 10R located at the levels of the semiconductor layers 10L around a source trench 49 constitute additional sacrificial capping structures, which are herein referred to source-side sacrificial capping strips 23S. Each sacrificial capping strip (21S, 23S) may laterally extend along the second horizontal direction hd2 with a uniform vertical cross-sectional shape within vertical planes that are perpendicular to the second horizontal direction hd2. The sacrificial capping strips (21S, 23S) may have the same thickness as the sacrificial layers 11L.

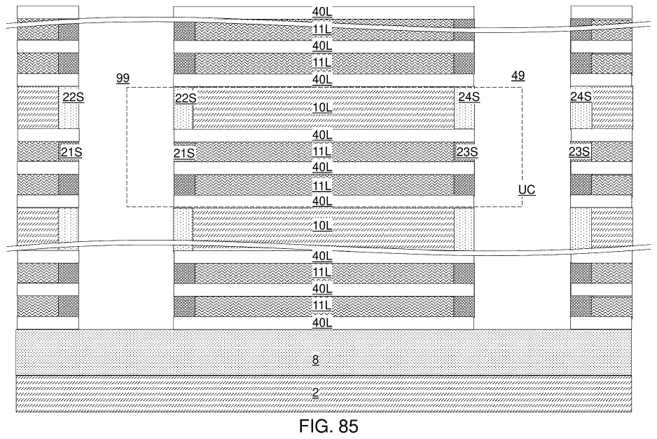

Referring to FIG. 85, a capping material layer comprising a dielectric material can be conformally deposited in the lateral recesses that are not filled with the sacrificial capping strip (21S, 23S). The capping material layer may comprise a dielectric material that is different from the material of the sacrificial capping strip (21S, 23S). For example, the capping material layer may comprise silicon nitride or silicon carbonitride. The capping material layer is deposited in the first lateral recesses 10R directly on physically exposed sidewalls of the semiconductor layers 10L and over the sacrificial capping strip (21S, 23S). The thickness of the capping material layer is selected such that the entire volume of the first lateral recesses 10R located at the levels of the semiconductor layers 10L is filled with portions of the capping material layer. For example, the thickness of the capping material layer may be greater than one half of the first thickness.

Subsequently, a selective isotropic etch process or a selective anisotropic etch process can be performed to remove the material of the capping material layer from outside the volumes of the first lateral recesses 10R at the levels of the semiconductor layers 10L. Remaining portions of the capping material layer located within the first lateral recesses 10R located at the levels of the semiconductor layers 10L around a bit-line trench 99 constitute capping structures, which are herein referred to bit-line-side capping strips 22S. Remaining portions of the capping material layer located within the first lateral recesses 10R located at the levels of the semiconductor layers 10L around a source trench 49 constitute additional capping structures, which are herein referred to source-side capping strips 24S. Each capping strip (22S, 24S) may laterally extend along the second horizontal direction hd2 with a uniform vertical cross-sectional shape within vertical planes that are perpendicular to the second horizontal direction hd2. The capping strips (22S, 24S) may have the same thickness as the thickness of the semiconductor layers 10L.

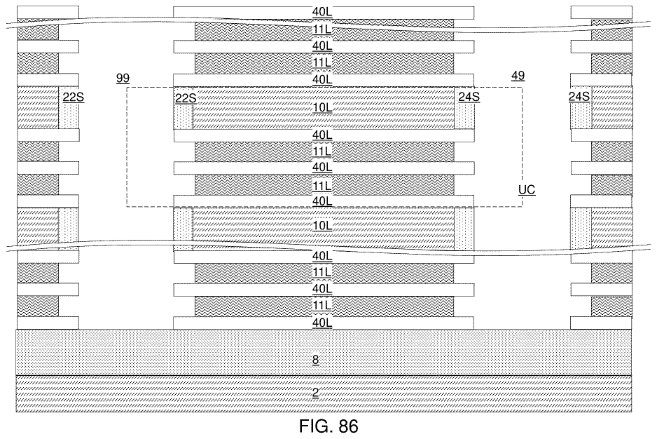

Referring to FIG. 86, the sacrificial capping strips (21S, 23S) can be removed selectively to the material of the capping strips (22S, 24S), for example, by performing an selective isotropic etch process. The etch chemistry of the selective isotropic etch process may be selected to provide etching of the material of the sacrificial capping strips (21S, 23S) without etching the material of the capping strips (22S, 24S). For example, a suitable wet etch process may be performed. Sidewalls of the sacrificial layers 11L are physically exposed.

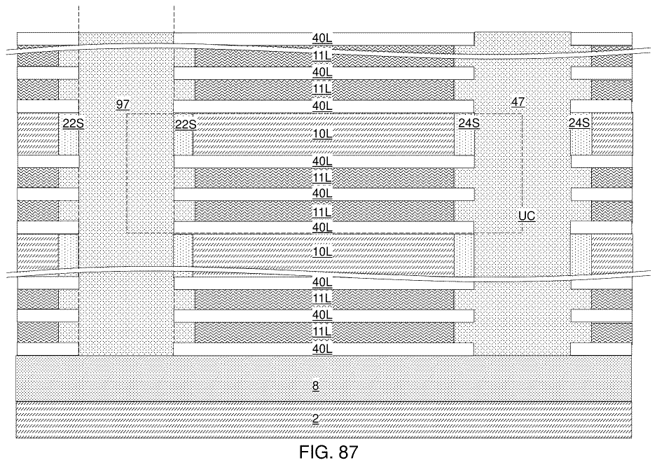

Referring to FIG. 87, the processing steps described with reference to FIGS. 55A, 55B, 55C, 55D, and 55E may be performed to form sacrificial source trench fill structures 47 and sacrificial bit-line trench fill structures 97.

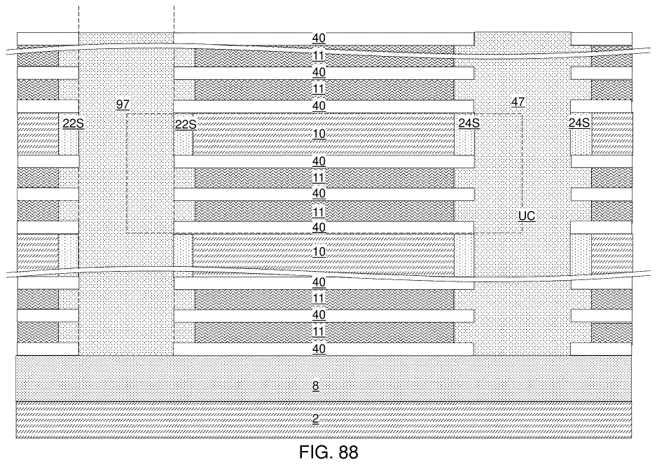

Referring to FIG. 88, the processing steps described with reference to FIGS. 56A, 56B, 56C, 56D, and 56E may be performed to form lateral isolation trenches 59 through the vertical repetitions of the multiple instances of the unit layer stack (10L, 11L, 40L).

Subsequently, the processing steps described with reference to FIGS. 5A, 5B, 5C, 5D, and 5E can be performed to form sacrificial isolation trench fill structures 57 in the lateral isolation trenches 59.

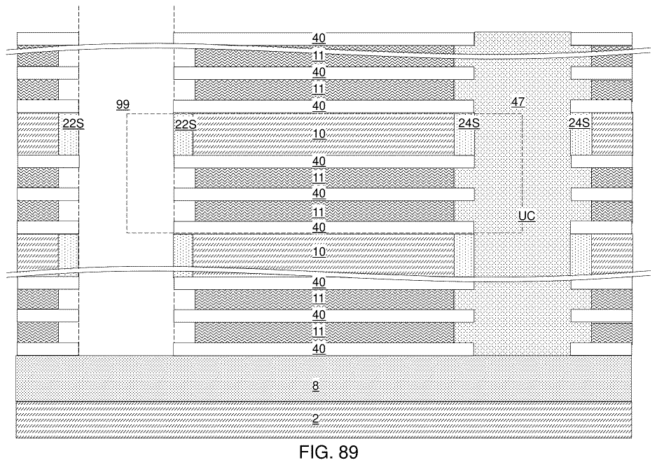

Referring to FIG. 89, the bit-line trenches 99 are reopened to form voids in the volumes of the bit-line trenches 99. Thus, the sacrificial bit-line trench fill structures 97 are removed without removing the sacrificial source trench fill structures 47.

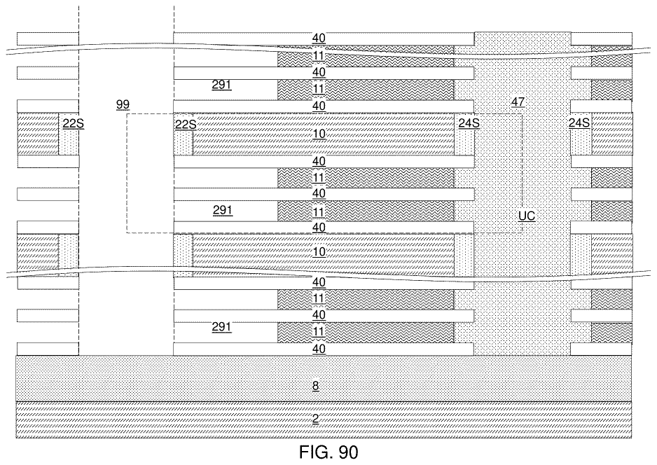

Referring to FIG. 90, the processing steps described with reference to FIGS. 59A, 59B, 59C, 59D, and 59E can be performed. Specifically, a second selective material removal process may be performed to remove a first portion of each of the sacrificial rails 11 that are proximal to the first capping structures 22S around the bit-line trenches 99. First voids 291 are formed in the volumes from which the first portions of the sacrificial rails 11 are removed. The first voids 291 are connected to the voids in the bit-line trenches 99. Two first voids 291 are formed within the volume of each unit cell UC.

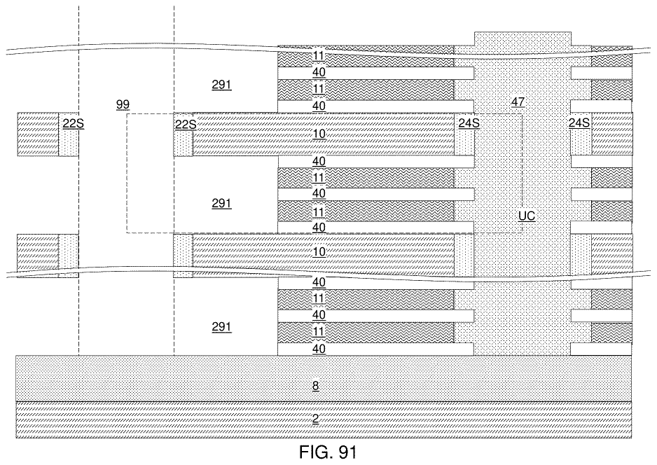

Referring to FIG. 91, the processing steps described with reference to FIGS. 60A, 60B, 60C, 60D, and 60E can be performed. Specifically, a third selective material removal process may be performed to remove first portions of the sacrificial isolation trench fill structures 57. The first portions of the sacrificial isolation trench fill structures 57 include portions that are proximal to the first capping structures 22S around the bit-line trenches 99. In one embodiment, the third selective material removal process may comprise a third selective isotropic etch process. The first lateral isolation trenches 591 are formed in the volumes from which the first portions of the sacrificial isolation trench fill structures 57 are removed. Further, a fourth selective material removal process may be performed to remove physically exposed first portions of the spacer rails 40. The combination of the first voids 291 (as expanded by the fourth selective material removal process) and the first lateral isolation trenches 591 constitutes first cavities (291, 591). The first cavities (291, 591) are connected to the voids in the bit-line trenches 99.

Subsequently, a sequence of processing steps described with reference to FIG. 61A 72E can be performed to provide a three-dimensional memory device.

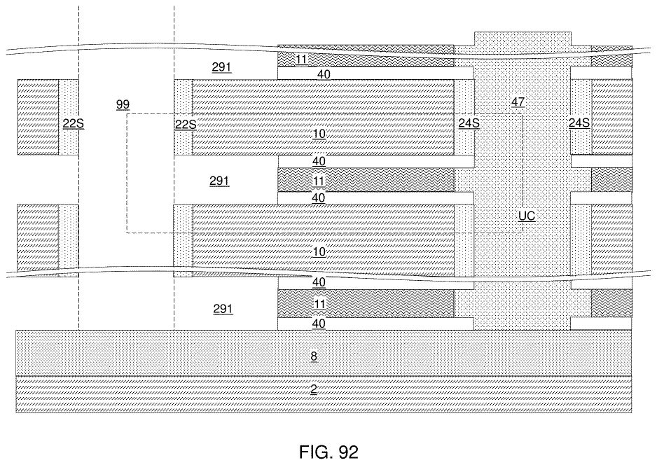

Referring to FIG. 92, the fourth alternative embodiment of the third exemplary structure can be derived from the third alternative embodiment of the third exemplary structure illustrated in FIG. 91 by omitting the third spacer rails 40. In this embodiment, the semiconductor rail 10 may be thicker than the sacrificial rail 11. Subsequently, a sequence of processing steps described with reference to FIG. 61A-72E can be performed to provide a three-dimensional memory device.

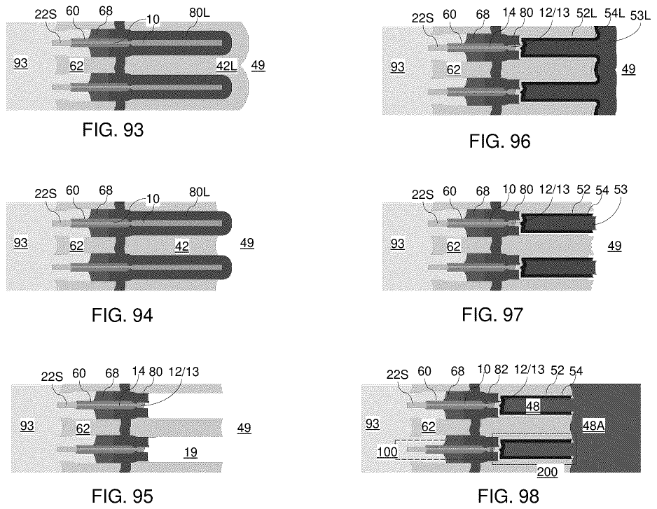

FIG. 93-98 are sequential vertical cross-sectional views of a fifth alternative embodiment of the third exemplary structure during a subset of processing steps for forming a ferroelectric capacitor storage device 200 according to the third embodiment of the present disclosure.

Referring to FIG. 93, the fifth alternative embodiment of the third exemplary structure can be derived from the third exemplary structure illustrated in FIGS. 16A-16E by depositing a dielectric liner layer 80L through the source trenches 49 into the voids (292, 592) and around the semiconductor rails 10. The dielectric matrix material layer 42L is then deposited on the dielectric liner layer 80L through the source trenches 49. The dielectric liner layer 80L may comprise any suitable insulating layer that may be selectively etched relative to the material of the dielectric matrix material layer 42L. For example, if the dielectric matrix material layer 42L comprises silicon oxide, then the dielectric liner layer 80L may comprise silicon nitride.

Referring to FIG. 94, the dielectric matrix material layer 42L may be removed from the source trenches 49 using any suitable etching method, as described above with respect to FIG. 17A-17E. The dielectric matrix material layer 42L is converted into the perforated dielectric matrix 42.

Referring to FIG. 95, a first selective isotropic etch is performed through the source trenches 49 to laterally recess the dielectric liner layer 80L selective to the perforated dielectric matrix 42. If the dielectric liner layer 80L comprises silicon nitride, then the selective isotropic etch comprises a phosphoric acid etch. The remaining portions of the dielectric liner layer 80L comprise dielectric liners 80 surrounding the respective semiconductor rails 10. A second selective isotropic etch is performed through the source trenches 49 to laterally recess the semiconductor rails 10 selective to the dielectric liners 80 and the perforated dielectric matrix 42.

Source regions 12 and source extension regions 13 may be formed by diffusion doping the exposed end portion of the semiconductor rails 10 through the source trenches 49 and the lateral recesses 19 in the perforated dielectric matrix 42, as described above with respect to FIG. 20A-20E. Remaining portions of the semiconductor rails 10 comprise semiconductor channels 14 surrounded by the dielectric liners 80.

Referring to FIG. 96, the first conductive material layer 52L, a memory material layer 54L and the sacrificial cover material layer 53L are deposited into the lateral recesses 19 through the source trenches 49, as described above with respect to FIG. 21A-21E.

Referring to FIG. 97, the first conductive material layer 52L, the memory material layer 54L and the sacrificial cover material layer 53L are removed from the source trenches 49 using an anisotropic etch process. The remaining portions of the first conductive material layer 52L, the memory material layer 54L and the sacrificial cover material layer 53L in the lateral recesses 19 comprise the first electrodes 52, the memory layers 54 and the sacrificial material cover portions 53, respectively.

Referring to FIG. 98, the sacrificial material cover portions 53 are removed from the lateral recesses 19 using a selective isotropic etch process to expose surfaces of the memory layers 54 in the lateral recesses. Conductive structures 48A are formed in the source trenches 49 and the second electrodes 48 are formed in the lateral recesses 19 on the surfaces of the memory layers 54.

The first electrodes 52 contact sidewall of the respective source regions 12. The dielectric liners 80 remain in contact with the upper and lower surfaces of the source regions 12 and with end portions of the first electrodes 52. The dielectric liners 80 comprise an insulating material that is different from the material of the tubular gate dielectric 60 of the access transistor 100. For example, the dielectric liners 80 may comprise silicon nitride, and tubular gate dielectric 60 may comprise silicon oxide. The steps described previously are then performed to form the drain regions 16 of the access transistors 100 and to form the bit lines 98 in the bit-line trenches 99.

The third embodiment provides a multi-layer stack fabrication process that uses a unit layer stack that comprises at least a first spacer material layer 40L, a semiconductor layer 10L, a second spacer material layer 40L, and a sacrificial layer 11L. The semiconductor layer 10L and sacrificial layer 11L may comprise the same semiconductor material (e.g., silicon) and the spacer material layers 40L may comprise a different semiconductor material (e.g., silicon germanium). The process of the third embodiment uses less steps and is simpler than conventional processes and reduces dimensional variation of the fabricated devices. The resulting devices have a smaller cell size, a reduced channel thickness variation, and a reduced gate length variation

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A method of forming a device structure, comprising:
forming an array of vertical rail stacks, wherein each of the vertical rail stacks comprises, from bottom to top, a first spacer rail, a semiconductor rail, a second spacer rail, and a sacrificial rail, wherein each of the vertical rail stacks laterally extends along a first horizontal direction, and each of the semiconductor rail comprises a respective first semiconductor end wall contacting a respective first capping structure and further comprises a respective second semiconductor end wall contacting a respective second capping structure;
forming first voids by removing first portions of the sacrificial rails that are proximal to the first capping structures;
forming first cavities by removing portions of the first spacer rails and the second spacer rails that are proximal to the first voids;
forming gate dielectrics and gate electrodes in the first cavities to form access transistors;
forming second voids by removing second portions of the sacrificial rails that are proximal to the second capping structures;
forming second cavities by removing remaining portions of the first spacer rails and the second spacer rails that are proximal to the second voids; and
forming memory devices that are accessed through the respective access transistors.

2. The method of claim 1, wherein the semiconductor rail and the sacrificial rail have a same material composition comprising a first semiconductor material and have different vertical thicknesses.

3. The method of claim 2, wherein the first spacer rail and the second spacer rail have a same material composition comprising a second semiconductor material that is different from the first semiconductor material.

4. The method of claim 3, wherein the first semiconductor material is a single crystalline silicon material and the second semiconductor material is a single crystalline silicon-germanium material.

5. The method of claim 3, wherein, within each contiguous set of vertical rail stacks that overlie or underlie one another, all portions of the first semiconductor material and all portions of the second semiconductor material are portions of a single crystalline structure that is single crystalline throughout and has a same set of crystallographic orientations throughout.

6. The method of claim 3, further comprising:
forming a vertical repetition of instances of a unit layer stack, wherein each instance of the unit layer stack comprises, from bottom to top, a first spacer material layer, a semiconductor layer, a second spacer material layer, and a sacrificial layer; and
dividing the vertical repetition by forming a laterally alternating sequence of bit-line trenches and source trenches that alternate along the first horizontal direction, wherein each of the bit-line trenches and the source trenches laterally extend along a second horizontal direction.

7. The method of claim 6, further comprising:
laterally recessing sidewalls of remaining portions of the semiconductor layers and the sacrificial layers after formation of the bit-line trenches and the source trenches by a first lateral recess distance;
conformally depositing a capping material layer in first recesses formed by laterally recessing the sidewalls of the remaining portions of the semiconductor layers; and
removing portions of the capping material layer outside the first recesses.

8. The method of claim 7, further comprising forming lateral isolation trenches that laterally extend along the first horizontal direction through remaining portions of the vertical repetition and through remaining portions of the capping material layer after removing the portions of the capping material layer outside the first recesses, wherein remaining portions of the vertical repetition comprise the array of vertical rail stacks, and wherein remaining portions of the capping material layer comprise the first capping structures and the second capping structures.

9. The method of claim 8, further comprising:
forming sacrificial isolation trench fill structures in the lateral isolation trenches; and
removing first portions of the sacrificial isolation trench fill structures after formation of the first voids and prior to formation of the gate dielectrics, wherein the first cavities comprise volumes of additional voids formed by removal of the first portions of the sacrificial isolation trench fill structures.

10. The method of claim 9, wherein each of the gate electrodes laterally extends along a second horizontal direction and laterally surrounds a respective row of the semiconductor rails.

11. The method of claim 7, wherein:
each of the semiconductor layers has a first thickness;
each of the sacrificial layers has a second thickness that is greater than the first thickness;
the capping material layer is deposited with a thickness that is greater than one half of the first thickness and is less than one half of the second thickness; and
the capping material layer is deposited directly on sidewalls of the sacrificial layers and are subsequently removed during removal of the portions of the capping material layer from outside the first recesses.

12. The method of claim 7, wherein:
each of the semiconductor layers has a first thickness;
each of the sacrificial layers has a second thickness that is less than the first thickness;
the method further comprises forming sacrificial capping structures on the laterally recessed sidewalls of the remaining portions of the sacrificial layers; and
the capping material layer is deposited on the sacrificial capping structures.

13. The method of claim 6, further comprising:
forming sacrificial bit-line trench fill structures in the bit-line trenches and forming sacrificial source trench fill structures in the source trenches; and
removing the sacrificial bit-line trench fill structures without removing the sacrificial source trench fill structures,
wherein:
the first voids and the first cavities are connected to voids in the bit-line trenches; and
the gate dielectrics and the gate electrodes are formed by depositing a gate dielectric layer and a gate electrode material layer and by recessing portions of the gate electrode material layer and the gate dielectric layer from around the bit-line trenches.

14. The method of claim 1, wherein each of the vertical rail stacks further comprises an additional sacrificial rail that overlies the second spacer rail, and a third spacer rail that overlies the additional sacrificial rail.

15. The method of claim 6, wherein the step of forming the memory device comprises:
forming a perforated dielectric matrix around a subset of the semiconductor rails; and
replacing first portions of the subset of the semiconductor rails that are laterally surrounded by the perforated dielectric matrix with a two-dimensional array of memory storage devices, wherein each of the memory storage devices comprises a first electrode that contacts a respective remaining portion of the subset of the semiconductor rails, a memory layer, and a second electrode.

16. The method of claim 15, further comprising:
removing a lateral portion of the semiconductor rails through the source trenches to leave the remaining portions of the semiconductor rails;
forming source regions of the access transistors in the remaining portions of the semiconductor rails through the source trenches;
forming drain regions of the access transistors in the remaining portions of the semiconductor rails through the bit-line trenches; and
forming vertical bit lines in the bit-line trenches in electrical contact with the drain regions of the access transistors.

17. The method of claim 16, wherein:
the memory layer comprises a ferroelectric capacitor dielectric layer;
the first electrodes electrically contact the respective source regions; and
channels of the access transistors are located in the remaining portions of the semiconductor rails between the respective source and drain regions.

18. The method of claim 17, further comprising forming dielectric liners in contact with the upper and lower surfaces of the source regions and with end portions of the first electrodes, wherein the dielectric liners comprise an insulating material that is different from an insulating material of the gate dielectrics of the access transistors.

19. The method of claim 6, wherein the step of forming the memory devices comprises forming memory field effect transistors comprising respective ferroelectric gate dielectrics configured to store data based on its ferroelectric polarization direction.

20. The method of claim 19, further comprising forming the ferroelectric gate dielectrics and second gate electrodes in the second cavities, wherein channels of the access transistors are located in first portions of the semiconductor rails adjacent to the bit-line trenches, and channels of the memory field effect transistors are located in second portions of the semiconductor rails adjacent to the source trenches.
